(19) United States
(12) Patent Application Publication
(10) Pub. No.: US 2014/0356771 A1
(43) Pub. Date: Dec. 4, 2014

(54) ACTINIC RAY-SENSITIVE OR RADIATION-SENSITIVE RESIN COMPOSITION, RESIST FILM USING THE SAME, PATTERN FORMING METHOD, MANUFACTURING METHOD OF ELECTRONIC DEVICE AND ELECTRONIC DEVICE

(71) Applicant: FUJIFILM Corporation, Tokyo (JP)

(72) Inventors: Shuhei YAMAGUCHI, Shizuoka (JP); Hidenori TAKAHASHI, Shizuoka (JP); Junichi ITO, Shizuoka (JP); Kei YAMAMOTO, Shizuoka (JP)

(21) Appl. No.: 14/446,599

(22) Filed: Jul. 30, 2014

Related U.S. Application Data
(63) Continuation of application No. PCT/JP2013/052296, filed on Jan. 25, 2013.

(30) Foreign Application Priority Data
Jan. 31, 2012 (JP) 2012-019099
Apr. 25, 2012 (JP) 2012-100181

(51) Int. Cl. G03F 7/038; G03F 7/20

(52) U.S. Cl. CPC G03F 7/0388; G03F 7/20; G03F 7/038
USPC 430/18; 430/285.1; 430/325; 430/311; 430/281.1

(57) ABSTRACT

There is provided an actinic ray-sensitive or radiation-sensitive resin composition, having: (A) a resin having a repeating unit represented by formula (I); (B) a compound capable of generating an acid upon irradiation with an actinic ray or radiation; and (C) a resin having at least one repeating unit (x) out of a repeating unit represented by formula (II) and a repeating unit represented by formula (III) and containing substantially neither fluorine atom nor silicon atom, wherein the content of the repeating unit (x) is 90% or more by mole based on all repeating units in the resin (C).

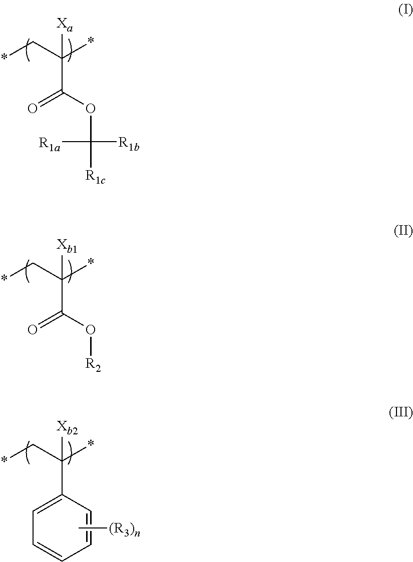

### CROSS REFERENCE TO RELATED APPLICATION

This is a continuation of International Application No. PCT/JP2013/052296 filed on Jan. 25, 2013, and claims priority from Japanese Patent Application Nos. 2012-019099 filed on Jan. 31, 2012, and 2012-100181 filed on Apr. 25, 2012, the entire disclosures of which are incorporated herein by reference.

### TECHNICAL FIELD

The present invention relates to an actinic ray-sensitive or radiation-sensitive resin composition, a resist film using the same, a pattern forming method, a manufacturing method of an electronic device, and an electronic device. More specifically, the present invention relates to an actinic ray-sensitive or radiation-sensitive resin composition suitable for the process of producing a semiconductor such as IC or the production of a liquid crystal device or a circuit board such as thermal head and further for the lithography in other photo-fabrication processes, a resist film using the same, a pattern forming method, a manufacturing method of an electronic device, and an electronic device. In particular, the present invention relates to an actinic ray-sensitive or radiation-sensitive resin composition suitable for exposure by an ArF exposure apparatus, an ArF immersion-type projection exposure apparatus or an EUV exposure apparatus each using a light source that emits far ultraviolet light at a wavelength of 300 nm or less, a resist film using the same, a pattern forming method, a manufacturing method of an electronic device, and an electronic device.

### BACKGROUND ART

Since the advent of a resist for KrF excimer laser (248 nm), a pattern forming method utilizing chemical amplification so as to compensate for sensitivity reduction caused by light absorption is used. For example, in the positive chemical amplification method, an acid generator contained in the exposed area is decomposed upon light irradiation to generate an acid.

In the course of, for example, baking after exposure (PEB: Post Exposure Bake), an alkali-insoluble group contained in the photosensitive composition is changed into an alkali-soluble group by the catalytic action of the acid generated. Thereafter, development is performed, for example, using an alkali solution. The exposed area is removed by the development, and a desired pattern is thereby obtained.

As for the alkali developer used in the method above, various developers have been proposed. For example, as the alkali developer, an aqueous alkali developer of 2.38 mass % TMAH (tetramethylammonium hydroxide) is being used for general purposes.

Miniaturization of a semiconductor device has shown progress in shortening the wavelength of the exposure light source and increasing the numerical aperture (higher NA) of the projection lens, and an exposure machine using an ArF excimer laser with a wavelength of 193 nm as the light source has been currently developed. As a technique to more increase the resolution, a method of filling the space between the projection lens and the sample with a high refractive-index liquid (hereinafter, referred to as an “immersion liquid”) (that is, an immersion method) has been proposed. Furthermore, EUV lithography of performing exposure to ultraviolet light at a shorter wavelength (13.5 nm) has been also proposed.

However, it is actually very difficult to find out an appropriate combination of a resist composition, a developer, a rinsing solution and the like, which are necessary to form a pattern having overall good performance.

In recent years, a pattern forming method using an organic solvent-containing developer is also being developed (see, for example, JP-A-2008-292975 (the term “JP-A” as used herein means an “unexamined published Japanese patent application”) and JP-A-2010-197619). For example, JP-A-2008-292975 discloses a pattern forming method including a step of coating a substrate with a resist composition capable of increasing the solubility for an alkali developer and decreasing the solubility for an organic solvent developer upon irradiation with an actinic ray or radiation, an exposure step, and a step of performing development by using an organic solvent developer. According to this method, a high-definition fine pattern can be stably formed.

It is pointed out that when a chemical amplification resist is applied to immersion exposure, the resist layer comes into contact with the immersion liquid at the exposure, as a result, the resist layer deteriorates or a component imparting adverse effects bleeds out from the resist layer to the immersion liquid. WO 2004/068242 describes a case where the resist performance is changed due to immersion of the resist for ArF exposure in water before or after exposure, and this is pointed out as a problem in the immersion exposure.

Also, in the immersion exposure process, when the exposure is performed using a scanning-type immersion exposure machine, unless the immersion liquid also moves following the movement of the lens, the exposure speed decreases and this may affect the productivity. In the case where the immersion liquid is water, the resist film is preferably hydrophobic because of good followability of water.

In this connection, as a countermeasure for avoiding such a problem in the pattern forming method using an organic solvent-containing developer, a method of adding a resin containing a silicon atom or a fluorine atom to the resist composition has been proposed (see, Japanese Patent No. 4,617,337). On the other hand, with respect to an alkali development-type resist, a method of adding a hydrophobic resin to a composition containing a resin having an acid-decomposable group in the main chain through a spacer has been proposed (see, JP-A-2008-268933).

In the positive image forming method, an isolated line or dot pattern can be successfully formed, but when an isolated space or fine hole pattern is formed, the pattern profile is liable to be deteriorated.

On the other hand, the above-described conventional pattern forming method using an organic solvent-containing developer makes it possible to have been obtained a good pattern profile, but in recent years, for example, the need for refining a hole pattern is drastically increasing, and more performance improvement is actually required also of the resist composition.

The present invention has been made under these circumstances, and an object of the present invention is to provide an actinic ray-sensitive or radiation-sensitive resin composition ensuring that in forming a fine pattern such as hole pattern having a hole diameter of 45 nmn or less, a pattern excellent in the local pattern dimension uniformity (Local CDU, nm) and exposure latitude (EL) and reduced in the generation of scum and residual water defect can be formed, a pattern forming method, a resist film, a manufacturing method of an electronic device, and an electronic device.

### SUMMARY OF INVENTION

The present invention has the following configurations, and the object of the present invention is attained by these configurations.

(1) An actinic ray-sensitive or radiation-sensitive resin composition, including:

(A) a resin containing a repeating unit represented by formula (I); (B) a compound capable of generating an acid upon irradiation with an actinic ray or radiation; and (C) a resin containing at least one repeating unit (x) out of a repeating unit represented by formula (II), and a repeating unit represented by formula (III) and containing substantially neither fluorine atom nor silicon atom, wherein a content of the repeating unit (x) is 90% or more by mole based on all repeating units in the resin (C):

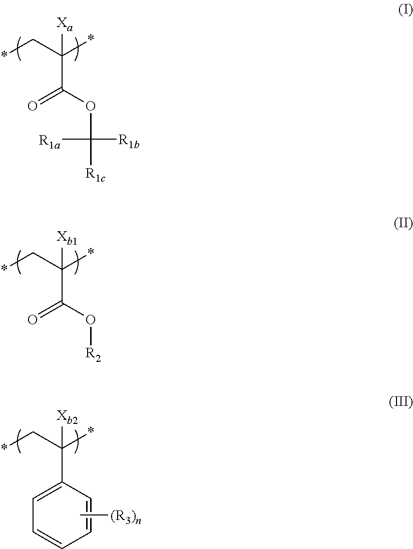

wherein Xa represents a hydrogen atom, an alkyl group, a cyano group or a halogen atom, each of R₁ₐ, R_{1b} and R_{1c} independently represents an alkyl group or a cycloalkyl group, two of R₁ₐ, R_{1b} and R_{1c} may combine to form a ring structure, X_{b1} represents a hydrogen atom, an alkyl group, a cyano group or a halogen atom, R₂ represents an organic group having at least one CH₃ partial structure and being stable to acid, X_{b2} represents a hydrogen atom, an alkyl group, a cyano group or a halogen atom, R₃ represents an organic group having at least one CH₃ partial structure and being stable to acid, and n represents an integer of 1 to 5.

(2) The actinic ray-sensitive or radiation-sensitive resin composition according to (1), wherein the at least one repeating unit (x) contains at least one repeating unit out of a repeating unit (II′) where in the formula (II) R₂ is a group having three or more CH₃ partial structures and a repeating unit (III′) where in the formula (III) R₃ is a group having three or more CH₃ partial structures.

(3) The actinic ray-sensitive or radiation-sensitive resin composition according to (1) or (2), wherein a content of the repeating unit represented by formula (I) is 15% or more by mole based on all repeating units in the resin (A).

(4) The actinic ray-sensitive or radiation-sensitive resin composition according to any one of (1) to (3), wherein the resin (C) contains a repeating unit represented by formula (II) and R₂ is an organic group having two or more CH₃ partial structures.

(5) The actinic ray-sensitive or radiation-sensitive resin composition according to any one of (1) to (4), wherein the resin (C) is a resin stable to acid.

(6) The actinic ray-sensitive or radiation-sensitive resin composition according to any one of (1) to (5), wherein a mass average molecular weight of the resin (C) is 15,000 or more.

(7) The actinic ray-sensitive or radiation-sensitive resin composition according to any one of (1) to (6), wherein a content of the resin (C) is from 0.01 to 20% by mass based on a total solid content of the actinic ray-sensitive or radiation-sensitive resin composition.

(8) The actinic ray-sensitive or radiation-sensitive resin composition according to any one of (1) to (7), wherein the compound (B) is a compound capable of generating an organic acid represented by the following formula (V) or (VI) upon irradiation with an actinic ray or radiation:

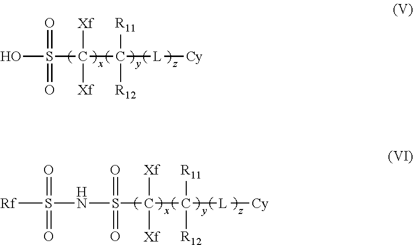

wherein each of Xf independently represents a fluorine atom or an alkyl group substituted with at least one fluorine atom, each of R₁₁ and R₁₂ independently represents a hydrogen atom, a fluorine atom or an alkyl group, each L independently represents a divalent linking group, Cy represents a cyclic organic group, Rf represents a fluorine atom-containing group, x represents an integer of 1 to 20, y represents an integer of 0 to 10, and z represents an integer of 0 to 10.

(9) The actinic ray-sensitive or radiation-sensitive resin composition according to any one of (1) to (8), further including (D) a basic compound or ammonium salt compound of which basicity decreases upon irradiation with an actinic ray or radiation.

(10) A resist film formed from the actinic ray-sensitive or radiation-sensitive resin composition according to any one of (1) to (9).

(11) A pattern forming method, including: (i) forming a film by using the actinic ray-sensitive or radiation-sensitive resin composition according to any one of (1) to (9), (ii) exposing the film; and (iii) performing development by using a developer containing an organic solvent to form a negative pattern.

(12) The pattern forming method according to (11), wherein the developer contains at least one kind of an organic solvent selected from the group consisting of a ketone-based solvent, an ester-based solvent, an alcohol-based solvent, an amide-based solvent and an ether-based solvent.

(13) A method for manufacturing an electronic device, including the pattern forming method according to (11) or (12).

(14) An electronic device manufactured by the manufacturing method of an electronic device according to (13).

### DESCRIPTION OF EMBODIMENTS

The actinic ray-sensitive or radiation-sensitive resin composition which can be used in the present invention is described below.

Also, the present invention relates to the actinic ray-sensitive or radiation-sensitive resin composition described below.

In the description of the present invention, when a group (atomic group) is denoted without specifying whether substituted or unsubstituted, the group encompasses both a group having no substituent and a group having a substituent. For example, “an alkyl group” encompasses not only an alkyl group having no substituent (unsubstituted alkyl group) but also an alkyl group having a substituent (substituted alkyl group).

In the description of the present invention, the “actinic ray” or “radiation” means, for example, a bright line spectrum of mercury lamp, a far ultraviolet ray typified by excimer laser, an extreme-ultraviolet ray (EUV light), an X-ray or an electron beam (EB). Also, in the present invention, the “light” means an actinic ray or radiation.

In the description of the present invention, the mass average molecular weight of a resin is a value in terms of polystyrene measured by the GPC method. The GPC may be performed according to a method using HLC-8120 (manufactured by Tosoh Corp.) by using TSK gel Multipore HXL-M (produced by Tosoh Corp., 7.8 mm ID×30.0 cm) and THF (tetrahydrofuran) as a column and eluent, respectively.

The actinic ray-sensitive or radiation-sensitive resin composition according to the present invention is used for negative development (development where the solubility for a developer is decreased upon exposure, as a result, the exposed area remains as a pattern and the unexposed area is removed). That is, the actinic ray-sensitive or radiation-sensitive resin composition according to the present invention can be an actinic ray-sensitive or radiation-sensitive resin composition for organic solvent development, which is used for development using an organic solvent-containing developer. The “for organic solvent development” as used herein means usage where the composition is subjected to at least a step of performing development by using an organic solvent-containing developer.

Also, in the present invention, the “stable to acid” means that decomposition by the action of an acid does not occur between exposure and development of the photosensitive composition, and the “stable to alkali” means that decomposition does not occur when the photosensitive composition is developed using an alkali.

The actinic ray-sensitive or radiation-sensitive resin composition of the present invention is typically a resist composition and is preferably a negative resist composition (that is, a resist composition for organic solvent development), because particularly high effects can be obtained. The composition according to the present invention is typically a chemical amplification resist composition.

The actinic ray-sensitive or radiation-sensitive resin composition of the present invention is an actinic ray-sensitive or radiation-sensitive resin composition containing (A) a resin having a repeating unit represented by the following formula (I), (B) a compound capable of generating an acid upon irradiation with an actinic ray or radiation, and (C) a resin having at least one repeating unit (x) out of a repeating unit represented by the following formula (II) and a repeating unit represented by the following formula (III) and containing substantially neither fluorine atom nor silicon atom, wherein the content of the repeating unit (x) is 90 mol % or more based on all repeating units in the resin (C)

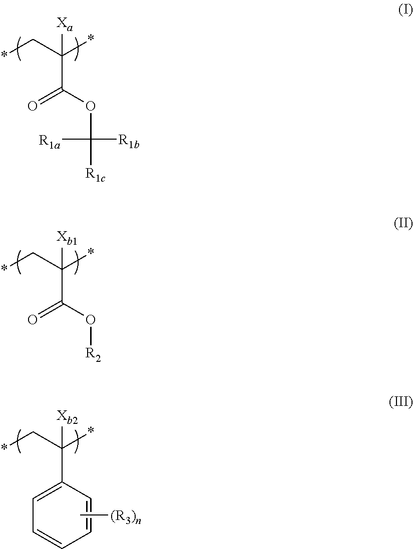

In formula (I), Xa represents a hydrogen atom, an alkyl group, a cyano group or a halogen atom, each of R₁ₐ, R_{1b} and R_{1c} independently represents an alkyl group or a cycloalkyl group, and two members of R₁ₐ, R_{1b} and R_{1c} may combine to form a ring structure.

In formula (II), X_{b1} represents a hydrogen atom, an alkyl group, a cyano group or a halogen atom, and R₂ represents an organic group having one or more CH₃ partial structures and being stable to acid.

In formula (III), X_{b2} represents a hydrogen atom, an alkyl group, a cyano group or a halogen atom, R₃ represents an organic group having one or more CH₃ partial structures and being stable to acid, and n represents an integer of 1 to 5.

The reason why the actinic ray-sensitive or radiation-sensitive resin composition according to the present invention ensures that in forming a fine pattern such as hole pattern having a hole diameter of 45 nm or less by negative pattern formation using an organic solvent-containing developer, a pattern excellent in the local pattern dimension uniformity (Local CDU) and exposure latitude (EL) and reduced in the generation of scum and residual water defect can be formed, is not clearly known but is presumed as follows.

First, the repeating unit represented by formula (I) contained in the resin (A) as a repeating unit having a group capable of decomposing by the action of an acid to produce a polar group tends to increase the glass transition temperature of the resin (A) as compared with a repeating unit where, for example, in formula (I), an ester bond and a group represented by —C(R₁ₐ)(R_{1b})(R_{1c}) are bonded through a linking group. This is considered to make it possible to keep the acid generated from the compound (B) (sometimes referred to as acid generator) upon irradiation with an active ray or radiation in the exposed area from excessively diffusing into the unexposed area and realize an excellent exposure latitude (EL).

Next, a repeating unit represented by formula (II) and/or a repeating unit represented by formula (III) each containing a CH₃ partial structure are contained in the resin (C) in a large ratio (more specifically, in a ratio of 90 mol % or more based on all repeating units in the resin (C)) and therefore, the surface free energy of the resin (C) is considered to be reduced. Incidentally, because these repeating units are a repeating unit stable to acid, the action capable of reducing the surface free energy of the resin (C) is thought to be readily maintained over the exposure and development steps.

In the resist film formed from the actinic ray-sensitive or radiation-sensitive resin composition of the present invention, the resin (C) exerting the above-described action is very likely to be unevenly distributed to the surface layer of the resist film, and this is considered to increase the static/dynamic contact angle on the resist film surface for water used as the immersion liquid and in turn, prevent production of a residual water defect attributable to the immersion liquid remaining as a droplet during exposure scanning.

In the case of exposing a resist film formed using an actinic ray-sensitive or radiation-sensitive resin composition containing an acid generator, the surface layer part of the resist film is exposed to a high degree as compared with the inside and comes to have a high concentration of the acid generated, as a result, the above-described reaction of an acid with the resin (A) tends to more proceed in that part. If the thus-exposed film is developed using an organic solvent-containing developer, the pattern dimension uniformity and exposure latitude (EL) may be deteriorated in the region defining a hole pattern (that is, the exposed area).

On the other hand, in the actinic ray-sensitive or radiation-sensitive resin composition of the present invention, as described above, the surface free energy of the resin (C) is low and the resin (C) is liable to be unevenly distributed in a high concentration to the surface layer part of the resist film.

In turn, the solubility of the surface layer part of the resist film for an organic solvent-containing developer is enhanced, and this enhanced solubility of the surface layer part of the resist film for an organic solvent-containing developer, which is brought about by the resin (C), is presumed to offset or suppress the deterioration of the pattern dimension uniformity and exposure latitude (EL) due to the generated acid that is unevenly distributed in excess to the surface layer of the exposed area.

As a result, the reaction using the acid as a catalyst to make the resist film insoluble or slightly soluble in an organic solvent-containing developer is allowed to proceed more uniformly with respect to the thickness direction of the resist film, and this is presumed to enable enhancing the pattern dimension uniformity and exposure latitude (EL) in the region defining a hole pattern.

Furthermore, the resin (C) contains substantially neither a fluorine atom nor a silicon atom and therefore, it is presumed that the unexposed area of the resist film containing the resin (C) exhibits high hydrophilicity for an organic solvent-containing developer during development and generation of scum is reduced.

[1](A) Resin having a repeating unit represented by the following formula (I)

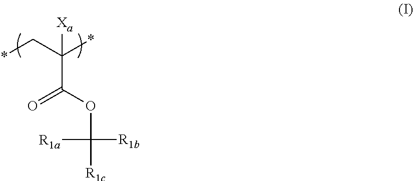

In formula (I), Xa represents a hydrogen atom, an alkyl group, a cyano group or a halogen atom, each of R₁ₐ, R_{1b} and R_{1c} independently represents an alkyl group or a cycloalkyl group, and two members of R₁ₐ, R_{1b} and R_{1c} may combine to form a ring structure.

The alkyl group of Xa may have a substituent, and examples of the substituent include a hydroxyl group and a halogen atom (preferably fluorine atom).

The alkyl group of Xa is preferably an alkyl group having a carbon number of 1 to 4, and examples thereof include a methyl group, an ethyl group, a propyl group, a hydroxymethyl group and a trifluoromethyl group, with a methyl group being preferred.

Xa is preferably a hydrogen atom or a methyl group.

The alkyl group of R₁ₐ, R_{1b} and R_{1c} is preferably an alkyl group having a carbon number of 1 to 4, such as methyl group, ethyl group, n-propyl group, isopropyl group, n-butyl group, isobutyl group and tert-butyl group.

The cycloalkyl group of R₁ₐ, R_{1b} and R_{1c} is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The ring structure formed by combining two members of R₁ₐ, R_{1b} and R_{1c} is preferably a monocyclic cycloalkane ring such as cyclopentyl ring and cyclohexyl ring, or a polycyclic cycloalkyl group such as norbornane ring, tetracyclodecane ring, tetracyclododecane ring and adamantane group, more preferably a monocyclic cycloalkane ring having a carbon number of 5 to 6.

Each of R₁ₐ, R_{1b} and R_{1c} is independently, preferably an alkyl group, more preferably a linear or branched alkyl group having a carbon number of 1 to 4.

Each of the groups above may further have a substituent. Examples of the substituent include a halogen atom, an alkoxy group (having a carbon number of 1 to 4), a carboxyl group, and an alkoxycarbonyl group (having a carbon number of 2 to 6), and the carbon number of the substituent is preferably 8 or less.

The repeating unit represented by formula (I) is a repeating unit having a group capable of decomposing by the action of an acid to produce a polar group (carboxyl group).

Accordingly, the resin (A) having a repeating unit represented by formula (I), which is used in the actinic ray-sensitive or radiation-sensitive resin composition of the present invention, is a resin having an acid-decomposable group, and this is a resin capable of increasing the polarity by the action of an acid to decrease the solubility for an organic solvent-containing developer.

The resin (A) is also a resin capable of increasing the polarity by the action of an acid to increase the solubility in an alkali developer.

Specific examples of the repeating unit represented by formula (I) are illustrated below, but the present invention is not limited thereto.

In specific examples, Rx represents a hydrogen atom. CH₃, CF₃ or CH₂OH. Each of Rxa and Rxb represents an alkyl group having a carbon number 1 to 4. Z represents a substituent and when a plurality of Z's are present, each Z may be the same as or different from every other Z. p represents 0 or a positive integer. Specific examples and preferred examples of Z are the same as specific examples and preferred examples of the substituent which may be substituted on each of the groups such as R₁ₐ to R_{1c}.

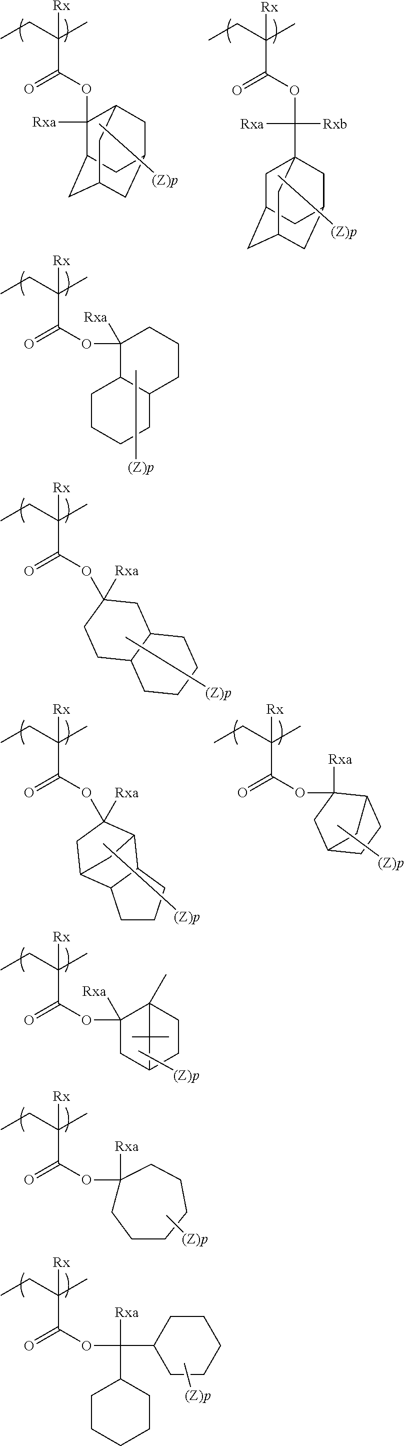

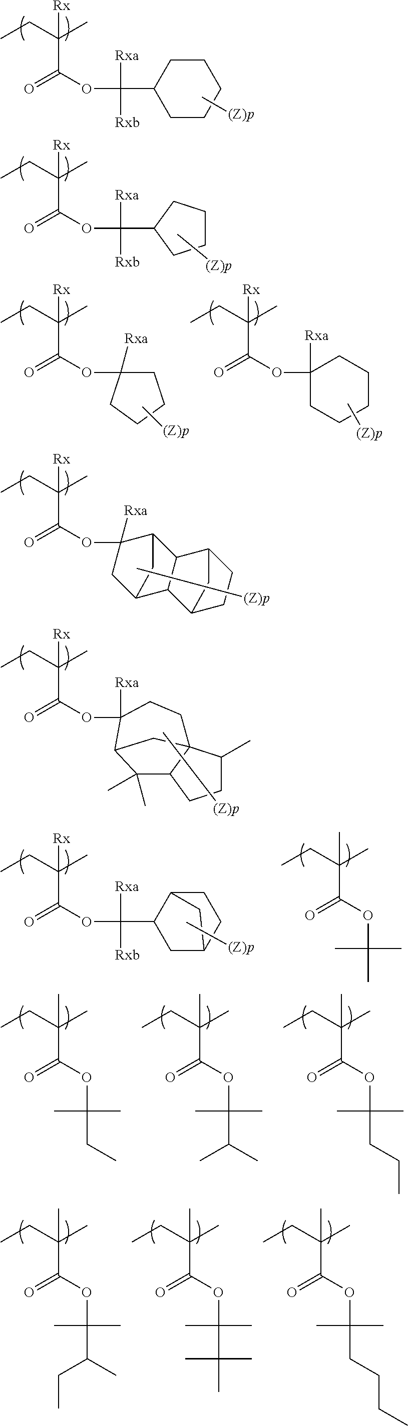

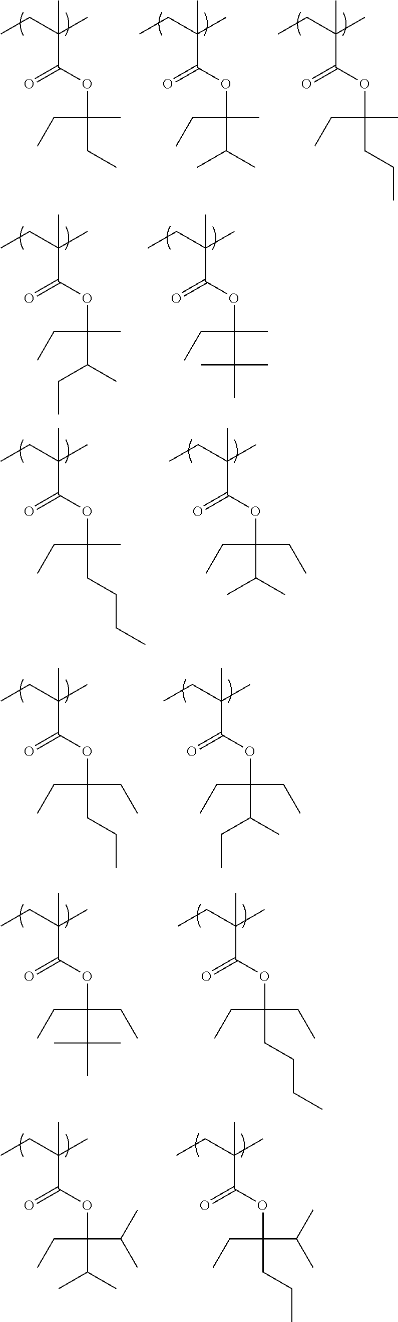

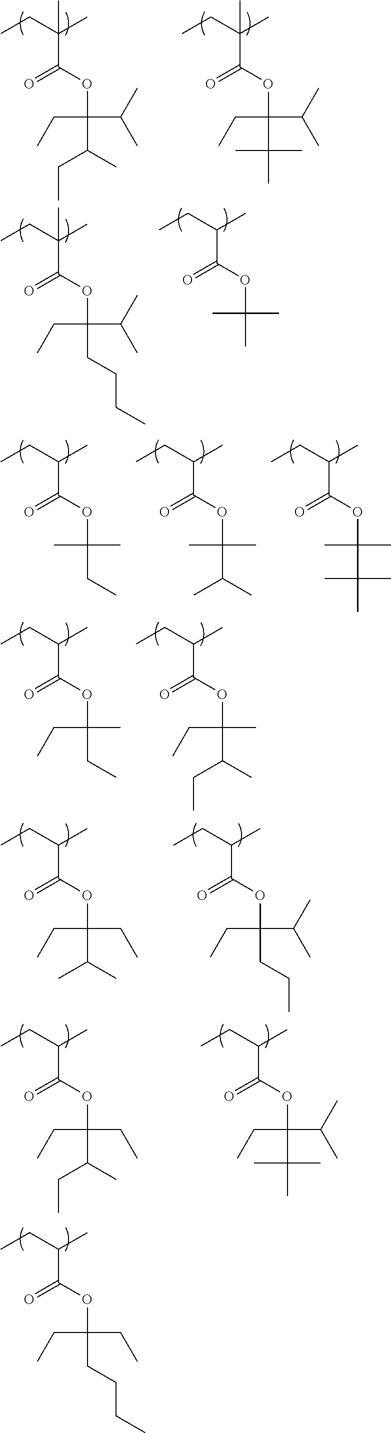

As for the repeating unit represented by formula (I), one kind may be used, or two or more kinds may be used in combination.

The resin (A) preferably contains the repeating unit represented by formula (I) in a ratio of 15 mol % or more, more preferably from 30 to 90 mol %, still more preferably from 40 to 80 mol %, based on all repeating units in the resin (A).

In the present invention, the resin (A) may contain a repeating unit (hereinafter, sometimes referred to as “different acid-decomposable repeating unit”) having a group capable of decomposing by the action of an acid to produce a polar group (hereinafter, sometimes referred to as “acid-decomposable group”), which is different from the repeating unit represented by formula (I).

The acid-decomposable group in the different acid-decomposable repeating unit preferably has a structure where a polar group is protected by a group capable decomposing and leaving by the action of an acid.

The polar group is not particularly limited as long as it is a group capable of becoming slightly soluble or insoluble in an organic solvent-containing developer, but examples thereof include a carboxyl group, an acidic group (a group capable of dissociating in an aqueous 2.38 mass % tetramethylammonium hydroxide solution which has been conventionally used as the developer for a resist) such as sulfonic acid group, and an alcoholic hydroxyl group.

The alcoholic hydroxyl group is a hydroxyl group bonded to a hydrocarbon group and indicates a hydroxyl group other than a hydroxyl group directly bonded on an aromatic ring (phenolic hydroxyl group), and an aliphatic alcohol substituted with an electron-withdrawing group such as fluorine atom at the α-position (for example, a fluorinated alcohol group (e.g., hexafluoroisopropanol)) is excluded from the hydroxyl group. The alcoholic hydroxyl group is preferably a hydroxyl group having a pKa of 12 to 20.

The group preferred as the acid-decomposable group is a group where a hydrogen atom of the group above is substituted for by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having a carbon number of 1 to 8, and examples thereof include a methyl group, an ethyl group, a propyl group, an n-butyl group, a sec-butyl group, a hexyl group, and an octyl group.

The cycloalkyl group of R₃₆ to R₃₉, R₀₁ and R₀₂ may be monocyclic or polycyclic.

The monocyclic cycloalkyl group is preferably a cycloalkyl group having a carbon number of 3 to 8, and examples thereof include a cyclopropyl group, a cyclobutyl group, a cyclopentyl group, a cyclohexyl group, and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group.

The aryl group of R₃₆ to R₃₉, R₀₁ and R₀₂ is preferably an aryl group having a carbon number of 6 to 10, and examples thereof include a phenyl group, a naphthyl group, and an anthryl group.

The aralkyl group of R₃₆ to R₃₉, R₀₁ and R₀₂ is preferably an aralkyl group having a carbon number of 7 to 12, and examples thereof include a benzyl group, a phenethyl group, and a naphthylmethyl group.

The alkenyl group of R₃₆ to R₃₉, R₀₁ and R₀₂ is preferably an alkenyl group having a carbon number of 2 to 8, and examples thereof include a vinyl group, an allyl group, a butenyl group, and a cyclohexenyl group.

The ring formed by combining R₃₆ and R₃₇ is preferably a cycloalkyl group (monocyclic or polycyclic). The cycloalkyl group is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group, more preferably a monocyclic cycloalkyl group having a carbon number of 5 to 6, still more preferably a monocyclic cycloalkyl group having a carbon number of 5.

The different acid-decomposable repeating unit includes a repeating unit represented by the following formula (AI):

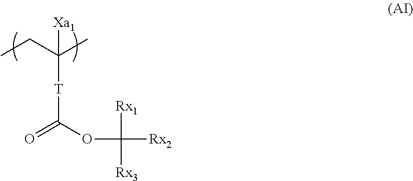

In formula (AI), Xa₁ represents a hydrogen atom, an alkyl group, a cyano group or a halogen atom.

T represents a divalent linking group.

Each of Rx₁ to Rx₃ independently represents an alkyl group or a cycloalkyl group.

Two members out of Rx₁ to Rx₃ may combine to form a ring structure.

Examples of the divalent linking group of T include an alkylene group, a —COO-Rt- group, a —O-Rt- group, and a phenylene group. In the formulae, Rt represents an alkylene group or a cycloalkylene group.

T is preferably a —COO-Rt- group. Rt is preferably an alkylene group having a carbon number of 1 to 5, more preferably a —CH₂— group, —(CH₂)₂— group, or a —(CH₂)₃— group.

Specific examples and preferred examples of the alkyl group of Xa₁ are the same as specific examples and preferred examples of the alkyl group of Xa in formula (I).

Specific examples and preferred examples of the alkyl group and cycloalkyl group of Rx₁ to Rx₃ are the same as specific examples and preferred examples of the alkyl group and cycloalkyl group of R₁ₐ to R_{1c} in formula (I).

Specific examples and preferred examples of the ring structure formed by combining two members of Rx₁ to Rx₃ are the same as specific examples and preferred examples of the ring structure formed by combining two members of R₁ₐ to R_{1c} in formula (I).

Each of the groups above may have a substituent, and examples of the substituent include an alkyl group (having a carbon number of 1 to 4), a cycloalkyl group (having a carbon number of 3 to 8), a halogen atom, an alkoxy group (having a carbon number of 1 to 4), a carboxyl group, and an alkoxycarbonyl group (having a carbon number of 2 to 6). The carbon number is preferably 8 or less. Above all, from the standpoint of more enhancing the dissolution contrast for an organic solvent-containing developer between before and after acid decomposition, the substituent is preferably a group free from a heteroatom such as oxygen atom, nitrogen atom and sulfur atom (for example, preferably not an alkyl group substituted with a hydroxyl group), more preferably a group composed of only a hydrogen atom and a carbon atom, still more preferably a linear or branched alkyl group or a cycloalkyl group.

The different acid-decomposable repeating unit may be a repeating unit represented by the following formula (IV):

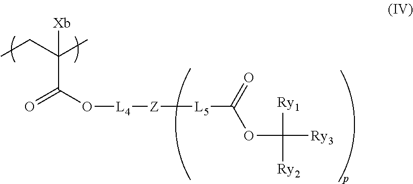

In formula (IV), Xb represents a hydrogen atom, an alkyl group, a cyano group or a halogen atom.

Each of Ry₁ to Ry₃ independently represents an alkyl group or a cycloalkyl group, and two members out of Ry₁ to Ry₃ may combine to form a ring.

Z represents a (p+1)-valent linking group having a polycyclic hydrocarbon structure which may have a heteroatom as a ring member. It is preferred that Z does not contain an ester bond as an atomic group constituting the polycyclic ring (in other words, it is preferred that Z does not contain a lactone ring as a ring constituting the polycyclic ring).

Each of L₄ and L₅ independently represents a single bond or a divalent linking group.

p represents an integer of 1 to 3.

When p is 2 or 3, each L₅, each Ry₁, each Ry₂ and each Ry₃ may be the same as or different from every other L₅, Ry₁, Ry₂ and Ry₃, respectively.

The alkyl group of Xb may have a substituent, and examples of the substituent include a hydroxyl group and a halogen atom (preferably, fluorine atom).

The alkyl group of Xb is preferably an alkyl group having a carbon number of 1 to 4, and examples thereof include a methyl group, an ethyl group, a propyl group, a hydroxymethyl group, and a trifluoromethyl group, with a methyl group being preferred.

Xb is preferably a hydrogen atom or a methyl group.

Specific examples and preferred examples of the alkyl group and cycloalkyl group of Ry₁ to Ry₃ are the same as specific examples and preferred examples of the alkyl group and cycloalkyl group of R₁ₐ to R_{1c} in formula (I).

Specific examples and preferred examples of the ring structure formed by combining two members of Ry₁ to Ry₃ are the same as specific examples and preferred examples of the ring structure formed by combining two members of R₁ₐ to R_{1c} in formula (I).

Each of Ry₁ to Ry₃ is independently preferably an alkyl group, more preferably a chain or branched alkyl group having a carbon number of 1 to 4. Also, the total of the carbon numbers of the chain or branched alkyl groups as Ry₁ to Ry₃ is preferably 5 or less.

Each of Ry₁ to Ry₃ may further have a substituent, and examples of the substituent are the same as those of the substituent which may be further substituted on Rx₁ to Rx₃ in formula (AI).

The linking group having a polycyclic hydrocarbon structure of Z includes a ring-assembly hydrocarbon ring group and a bridged cyclic hydrocarbon ring group, and these groups include a group obtained by removing arbitrary (p+1) hydrogen atoms from a ring-assembly hydrocarbon ring and a group obtained by removing arbitrary (p+1) hydrogen atoms from a bridged cyclic hydrocarbon ring, respectively.

Examples of the ring-assembly hydrocarbon ring group include a bicyclohexane ring group and a perhydronaphthalene ring group. Examples of the bridged cyclic hydrocarbon ring group include a bicyclic hydrocarbon ring group such as pinane ring group, bornane ring group, norpinane ring group, norbornane ring group and bicyclooctane ring group (e.g., bicyclo[2.2.2]octane ring group, bicyclo[3.2.1]octane ring group), a tricyclic hydrocarbon ring group such as homobledane ring group, adamantane ring group, tricyclo[5.2.1.0^{2,6}]decane ring group and tricyclo[4.3.1.1^{2,5}]undecane ring group, and a tetracyclic hydrocarbon ring group such as tetracyclo[4.4.0.1^{2,5}.1^{7,10}]dodecane ring group and perhydro-1,4-methano-5,8-methanonaphthalene ring group. The bridged cyclic hydrocarbon ring group also includes a condensed cyclic hydrocarbon ring group, for example, a condensed ring group obtained by fusing a plurality of 5- to 8-membered cycloalkane ring groups, such as perhydronaphthalene (decalin) ring group, perhydroanthracene ring group, perhydrophenathrene ring group, perhydroacenaphthene ring group, perhydrofluorene ring group, perhydroindene ring group and perhydrophenalene ring group.

Preferred examples of the bridged cyclic hydrocarbon ring group include a norbornane ring group, an adamantane ring group, a bicyclooctane ring group, and a tricyclo[5,2,1,0^{2,6}]decane ring group. Of these bridged cyclic hydrocarbon ring groups, a norbornane ring group and an adamantane ring group are more preferred.

The linking group having a polycyclic hydrocarbon structure represented by Z may have a substituent. Examples of the substituent which may be substituted on Z include a substituent such as alkyl group, hydroxyl group, cyano group, keto group (e.g., alkylcarbonyl group), acyloxy group, —COOR, —CON(R)₂, —SO₂R, —SO₃R and —SO₂N(R)₂, wherein R represents a hydrogen atom, an alkyl group, a cycloalkyl group or an aryl group.

The alkyl group, alkylcarbonyl group, acyloxy group, —COOR, —CON(R)₂, —SO₂R, —SO₃R and —SO₂N(R)₂ as the substituent which may be substituted on Z may further have a substituent, and this substituent includes a halogen atom (preferably, fluorine atom).

In the linking group having a polycyclic hydrocarbon structure represented by Z, the carbon constituting the polycyclic ring (the carbon contributing to ring formation) may be carbonyl carbon. Also, as described above, the polycyclic ring may have, as a ring member, a heteroatom such as oxygen atom and sulfur atom. However, as described above, Z does not contain an ester bond as an atomic group constituting the polycyclic ring.

Examples of the linking group represented by L₄ and L₅ include —COO—, —OCO—, —CONH—, —NHCO—, —CO—, —O—, —S—, —SO—, —SO₂—, an alkylene group (preferably having a carbon number of 1 to 6), a cycloalkylene group (preferably having a carbon number of 3 to 10), an alkenylene group (preferably having a carbon number of 2 to 6), and a linking group formed by combining a plurality of these members, and a linking group having a total carbon number of 12 or less is preferred.

L₄ is preferably a single bond, an alkylene group, —COO—, —OCO—, —CONH—, —NHCO—, -alkylene group-COO—, -alkylene group-OCO—, -alkylene group-CONH—, -alkylene group-NHCO—, —CO—, —O—, —SO₂—, or -alkylene group-O—, more preferably a single bond, an alkylene group, -alkylene group-COO—, or -alkylene group-O—.

L₅ is preferably a single bond, an alkylene group, —COO—, —OCO—, —CONH—, —NHCO—, —COO-alkylene group-, —OCO-alkylene group-, —CONH-alkylene group-, —NHCO-alkylene group-, —CO—, —O—, —SO₂—, —O-alkylene group-, or —O-cycloalkylene group-, more preferably a single bond, an alkylene group, —COO-alkylene group-, —O-alkylcne group-, or —O-cycloalkylene group-.

In the descriptions above, the bond “-” at the left end means to be bonded to the ester bond on the main chain side in L₄ and bonded to Z in L₅, and the bond “-” at the right end means to be bonded to Z in L₄ and bonded to the ester bond connected to the group represented by (Ry₁)(Ry₂)(Ry₃)C— in L₅.

L₄ and L₅ may be bonded to the same atom constituting the polycyclic ring in Z.

p is preferably 1 or 2, more preferably 1.

Specific examples of the repeating unit represented by formula (IV) are illustrated below, but the present invention is not limited thereto. In specific examples, Xa represents a hydrogen atom, an alkyl group, a cyano group or a halogen atom.

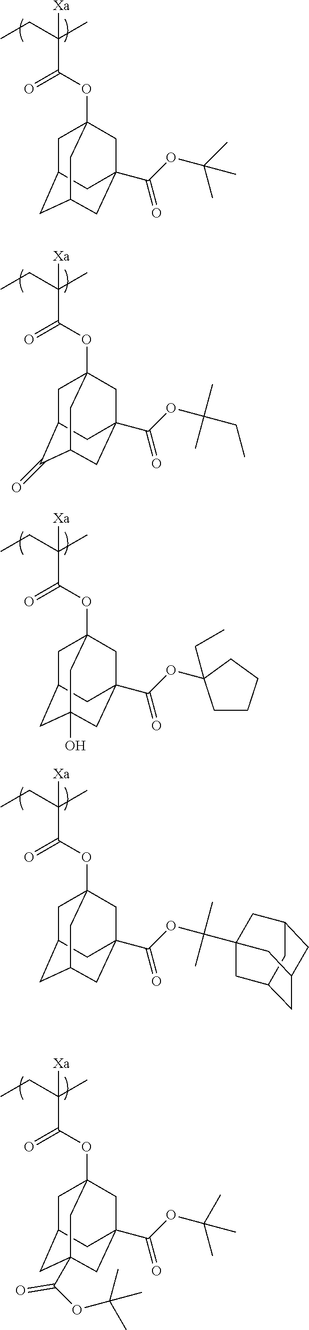

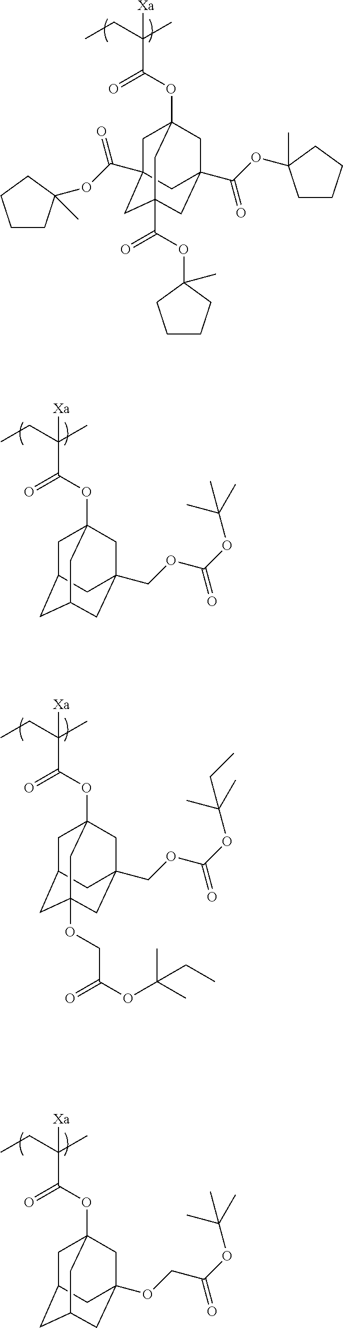

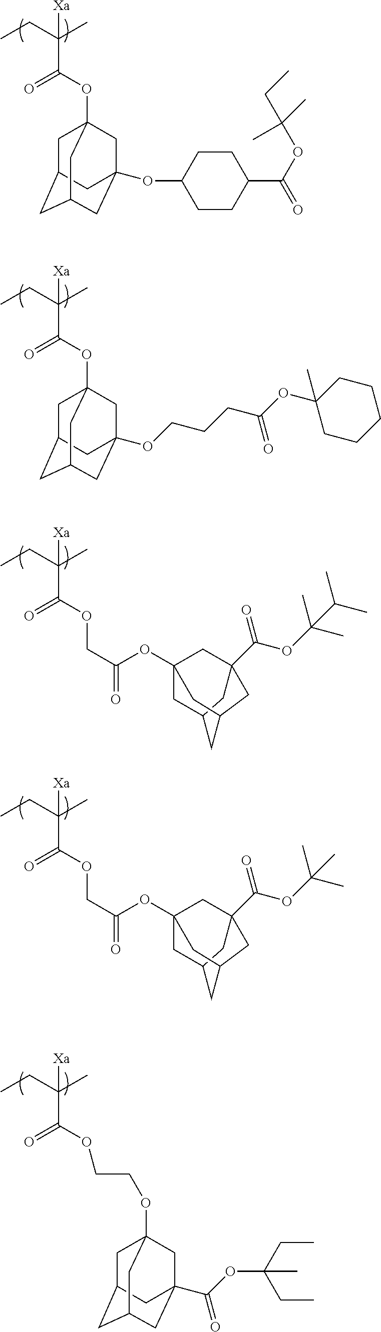

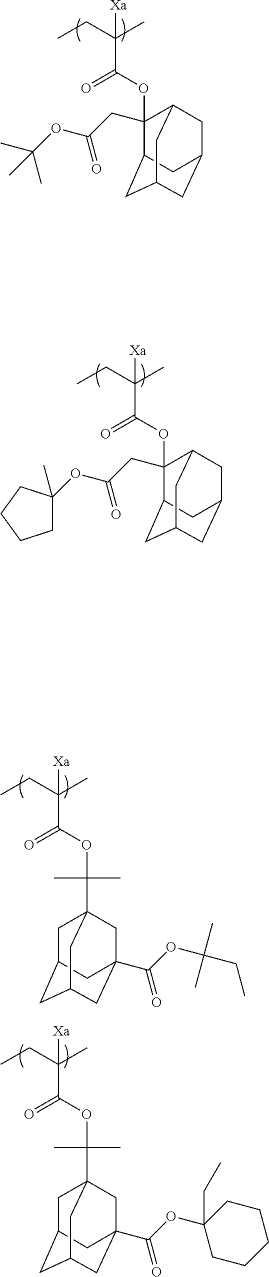

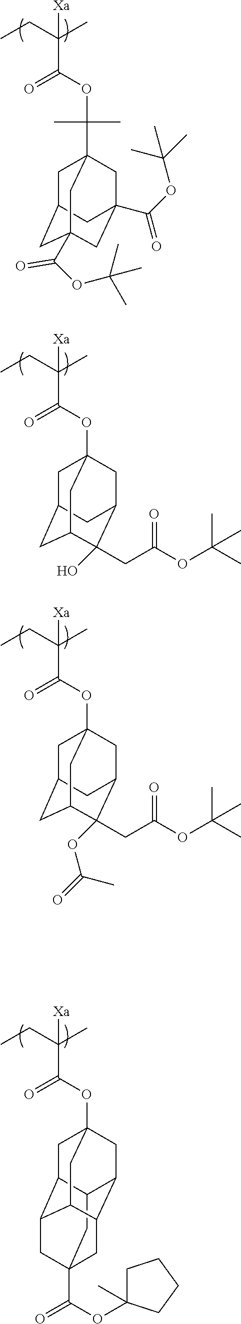

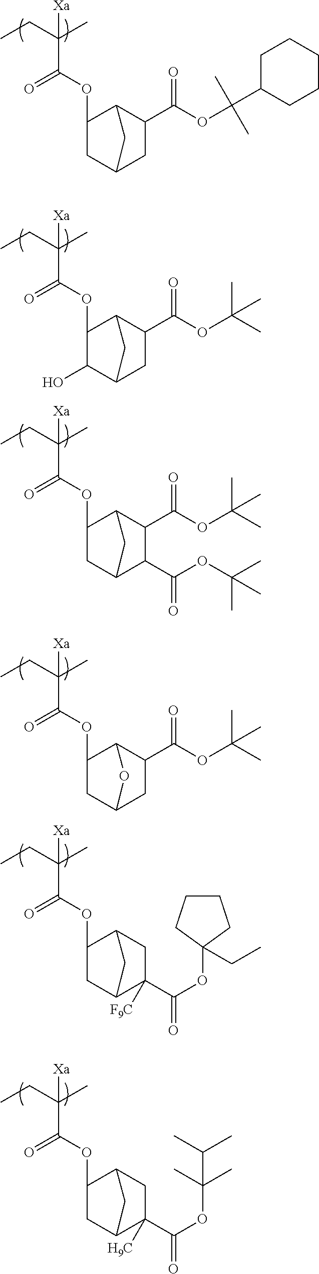

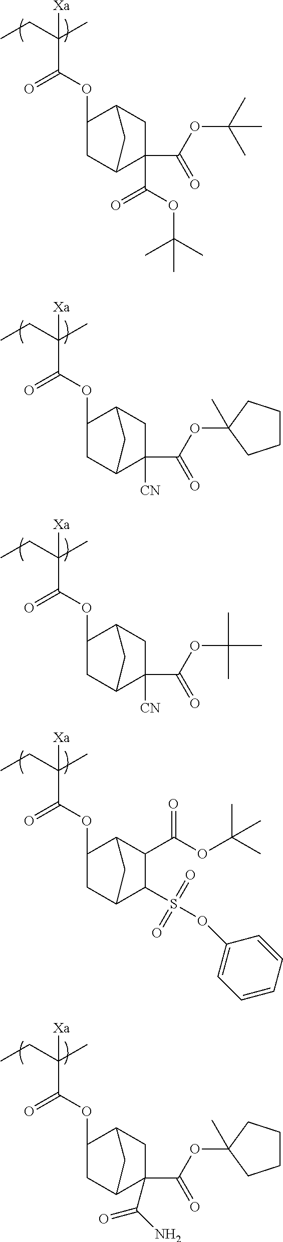

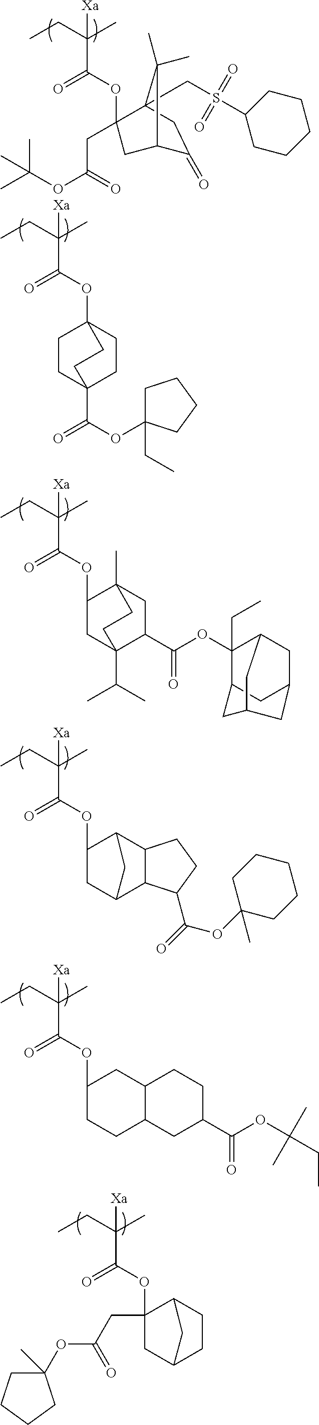

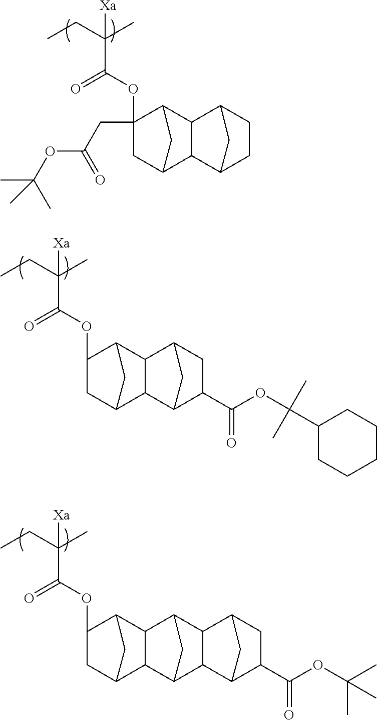

The different repeating unit may be also a structure illustrated in specific examples below. The present invention is not limited to these specific examples.

In specific examples. Xa represents a hydrogen atom, CH₃, CF₃ or CH₂OH. Z represents a substituent and when a plurality of Z's are present, each Z may be the same as or different from every other Z. p represents 0 or a positive integer. Specific examples and preferred examples of Z are the same as specific examples and preferred examples of the substituent which may be substituted on each of the groups such as Rx₁ to Rx₃.

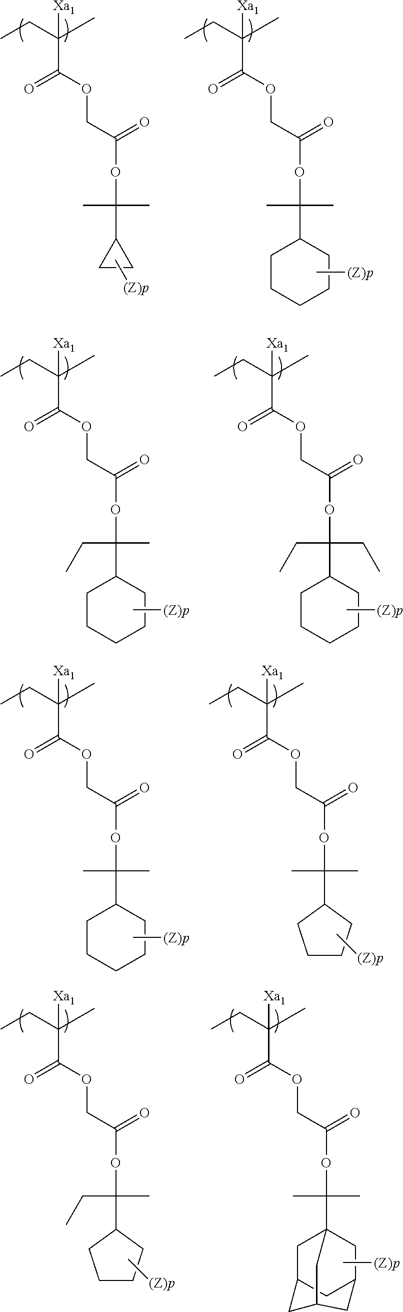

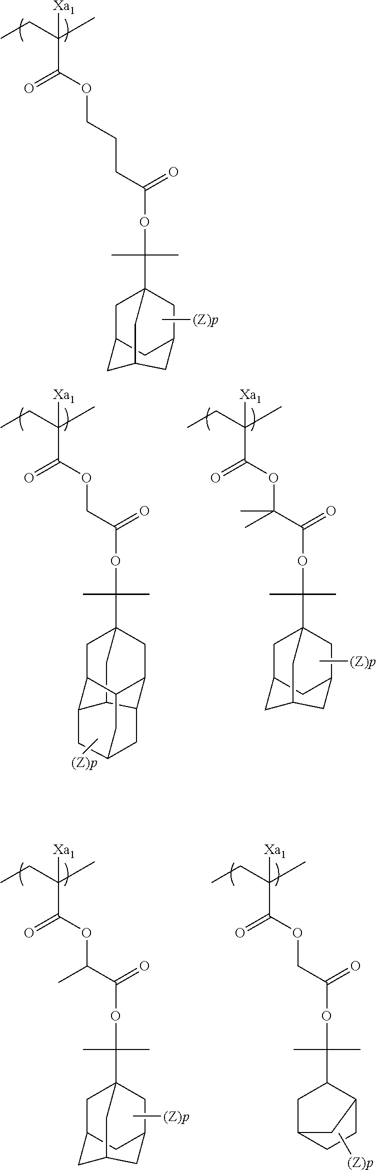

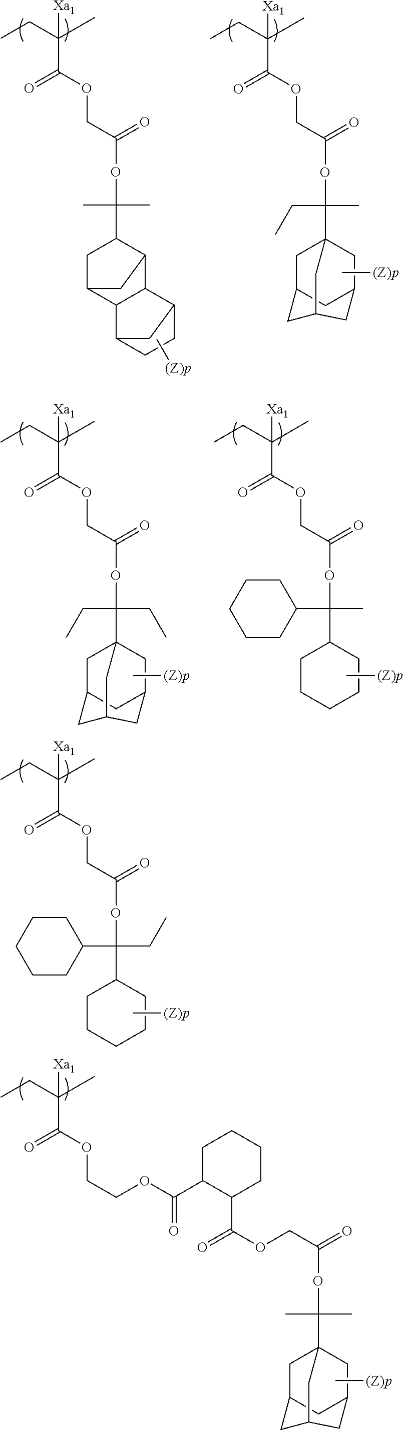

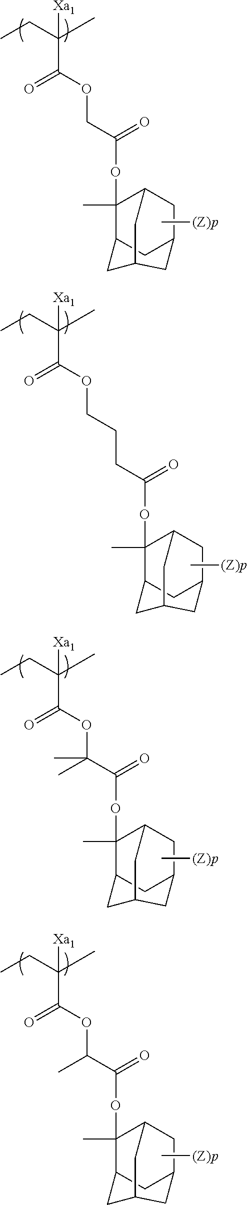

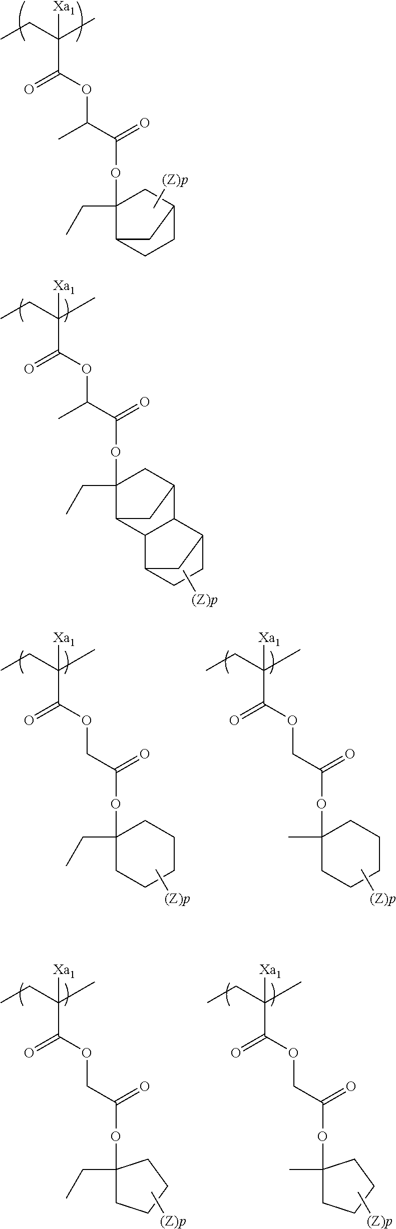

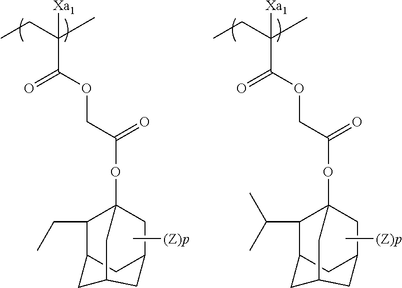

Also, the resin (A) may contain, as the different acid-decomposable repeating unit, a repeating unit illustrated below, which is a repeating unit capable of decomposing by the action of an acid to produce an alcoholic hydroxyl group.

In specific examples, Xa₁ represents a hydrogen atom, CH₃, CF₃ or CH₂OH.

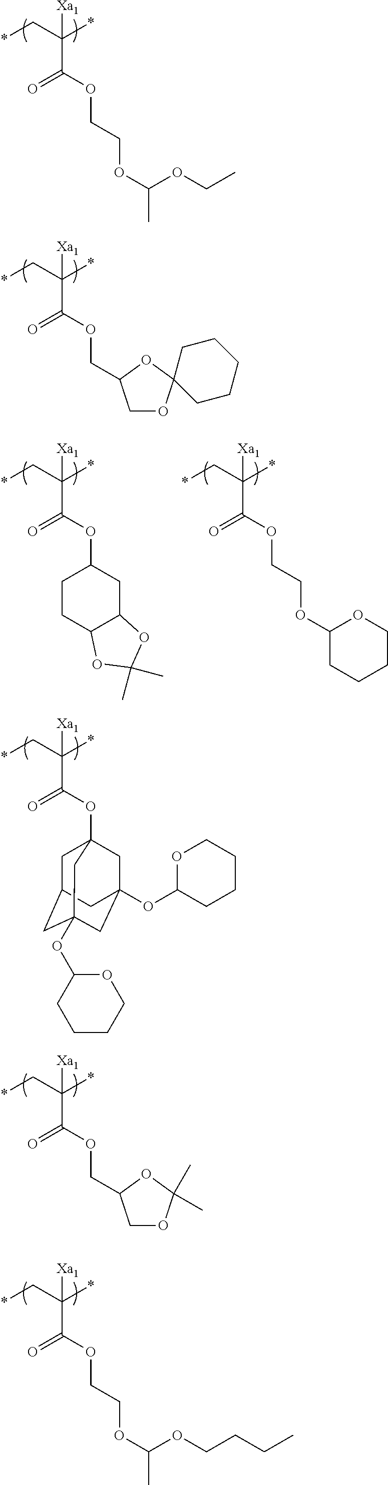

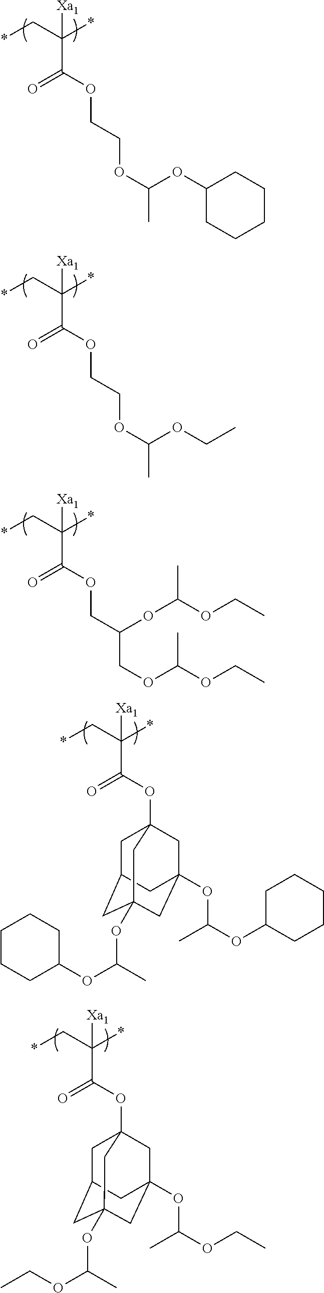

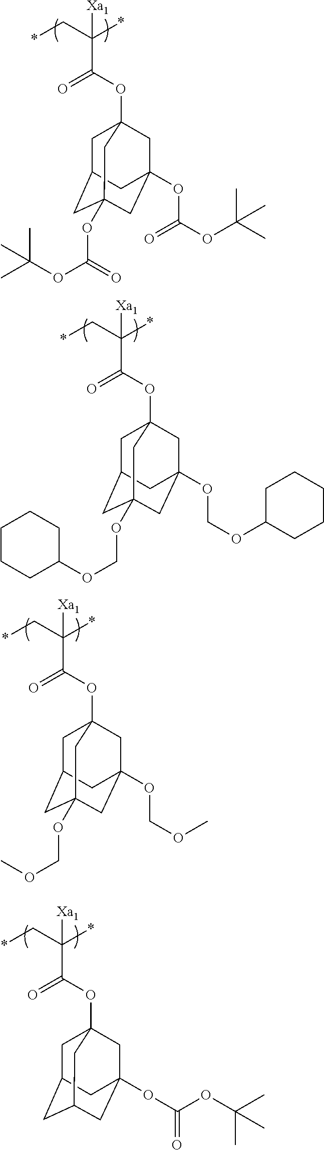

As for the different repeating unit, one kind may be used, or two or more kinds may be used in combination. In the case where two or more kinds of different repeating units having an acid-decomposable group are used in combination, the resin (A) preferably contains a repeating unit represented by formula (I) and a repeating unit represented by formula (IV).

The content of the total of the acid-decomposable group-containing repeating unit in the resin (A) (for example, in an embodiment where the resin (A) has the different acid-decomposable repeating unit, as the total of “the repeating unit represented by formula (I)” and “the different acid-decomposable repeating unit”) is preferably from 15 to 100 mol %, more preferably from 15 to 90 mol %, still more preferably from 40 to 80 mol %, based on all repeating units in the resin (A).

The resin (A) may also contain a repeating unit having a lactone structure or a sultone structure.

As the lactone group or sultone group, any may be used as long as it has a lactone structure or a sultone structure, but the structure is preferably a 5- to 7-membered ring lactone structure or a 5- to 7-membered ring sultone structure, more preferably a 5- to 7-membered ring lactone structure to which another ring structure is fused in the form of forming a bicyclo or spiro structure, or a 5- to 7-membered ring sultone structure to which another ring structure is fused in the form of forming a bicyclo or spiro structure. The resin more preferably contains a repeating unit having a lactone structure represented by any of the following formulae (LC1-1) to (LC1-17) or a sultone structure represented by any of the following formulae (SL1-1) to (SL1-3). The lactone structure or sultone structure may be bonded directly to the main chain. Preferred lactone structures are (LC1-1), (LC1-4), (LC1-5), (LC1-6), (LC1-13), (LC1-14) and (LC1-17), with (LC1-4) being more preferred. By using such a specific lactone structure, LER and development defect are improved.

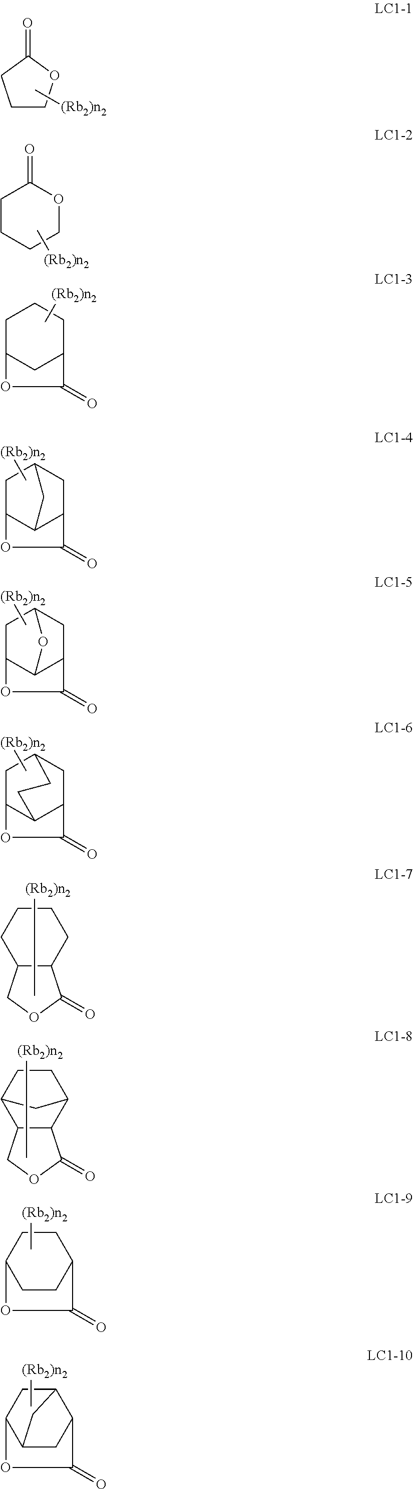

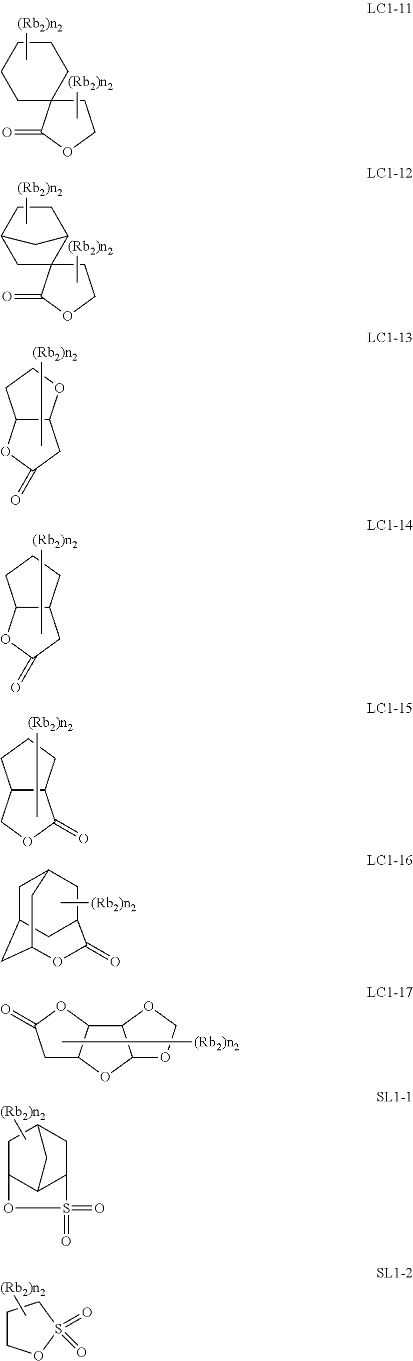

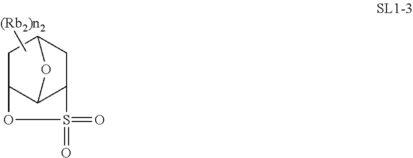

The lactone structure moiety or sultone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group, and an acid-decomposable group. Among these, an alkyl group having a carbon number of 1 to 4, a cyano group and an acid-decomposable group are more preferred. n₂ represents an integer of 0 to 4. When n₂ is an integer of 2 or more, each substituent (Rb₂) may be the same as or different from every other substituents (Rb₂), and also, the plurality of substituents (Rb₂) may combine with each other to form a ring.

The repeating unit having a lactone or sultone structure usually has an optical isomer, and any optical isomer may be used. One optical isomer may be used alone, or a mixture of a plurality of optical isomers may be used. In the case of mainly using one optical isomer, the optical purity (ee) thereof is preferably 90% or more, more preferably 95% or more.

The repeating unit having a lactone structure is preferably a repeating unit represented by the following formula (III):

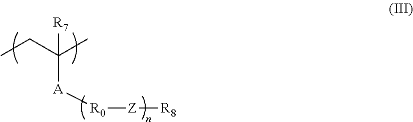

In formula (III), A represents an ester bond (a group represented by —COO—) or an amido bond (a group represented by —CONH—).

R₀ represents an alkylene group, a cycloalkylene group or a combination thereof. When a plurality of R₀s are present, each of R₀ independently represents, an alkylene group, a cycloalkylene group or a combination thereof.

Z represents a single bond, an ether bond, an ester bond, an amide bond, a urethane bond. When a plurality of Z's are present, each of Z independently represents, a single bond, an ether bond, an ester bond, an amide bond, a urethane bond. (a group represented by

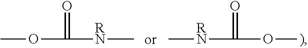

or a urea bond (a group represented by

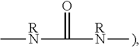

wherein each of R independently represents a hydrogen atom, an alkyl group, a cycloalkyl group or an aryl group.

R₈ represents a monovalent organic group having a lactone structure or a sultone structure.

n is the repetition number of the structure represented by —R₀—Z— and represents an integer of 0 to 5, preferably 0 or 1, more preferably 0. When n is 0, —R₀—Z— is not present, and a single bond is formed.

R₇ represents a hydrogen atom, a halogen atom or an alkyl group.

The alkylene group and cycloalkylene group of R₀ may have a substituent.

Z is preferably an ether bond or an ester bond, more preferably an ester bond.

The alkyl group of R₇ is preferably an alkyl group having a carbon number of 1 to 4, more preferably a methyl group or an ethyl group, still more preferably a methyl group.

The alkyl group in the alkylene group and cycloalkylene group of R₀ and in R₇ may be substituted, and examples of the substituent include a halogen atom such as fluorine atom, chlorine atom and bromine atom, a mercapto group, a hydroxyl group, an alkoxy group such as methoxy group, ethoxy group, isopropoxy group, tert-butoxy group and benzyloxy group, and an acyloxy group such as acetyloxy group and propionyloxy group.

R₇ is preferably a hydrogen atom, a methyl group, a trifluoromethyl group or a hydroxymethyl group.

The chain alkylene group in R₀ is preferably a chain alkylene group having a carbon number of 1 to 10, more preferably having a carbon number of 1 to 5, and examples thereof include a methylene group, an ethylene group and a propylene group. The cycloalkylene group is preferably a cycloalkylene group having a carbon number of 3 to 20, and examples thereof include a cyclohexylene group, a cyclopentylene group, a norbornylene group and an adamantylene group. For bringing out the effects of the present invention, a chain alkylene group is more preferred, and a methylene group is still more preferred.

The monovalent organic group having a lactone or sultone structure represented by R₈ is not limited as long as it has a lactone or sultone structure. Specific examples thereof include those having a lactone or sultone structure represented by any of formulae (LC1-1) to (LC1-17) and (SL1-1) to (SL1-3), and among these, the structure represented by (LC1-4) is preferred. In (LC1-1) to (LC1-17), n₂ is preferably 2 or less.

R₈ is preferably a monovalent organic group having an unsubstituted lactone or sultone structure, or a monovalent organic group having a lactone or sultone structure containing a methyl group, a cyano group or an alkoxycarbonyl group as a substituent, more preferably a monovalent organic group having a lactone structure containing a cyano group as a substituent (cyanolactone).

Specific examples of the repeating unit containing a group having a lactone or sultone structure are illustrated below, but the present invention is not limited thereto.

In specific examples, R represents a hydrogen atom, an alkyl group which may have a substituent, or a halogen atom, preferably a hydrogen atom, a methyl group, a hydroxymethyl group or an acetoxymethyl group.

(In the formulae, Rx represents H, CH₃, CH₂OH or CF₃.)

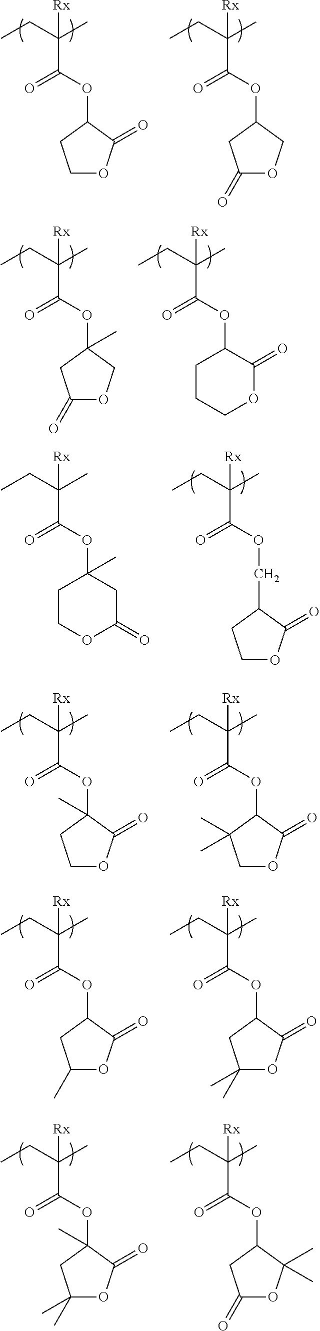

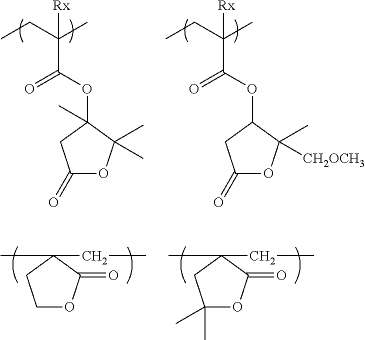

(in the formulae, Rx represents H, CH₃, CH₂OH or CF₃.)

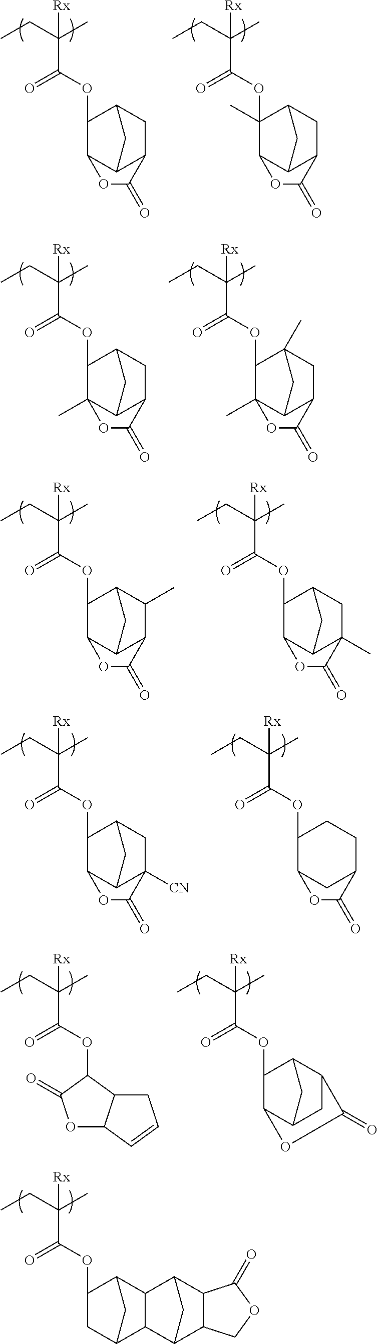

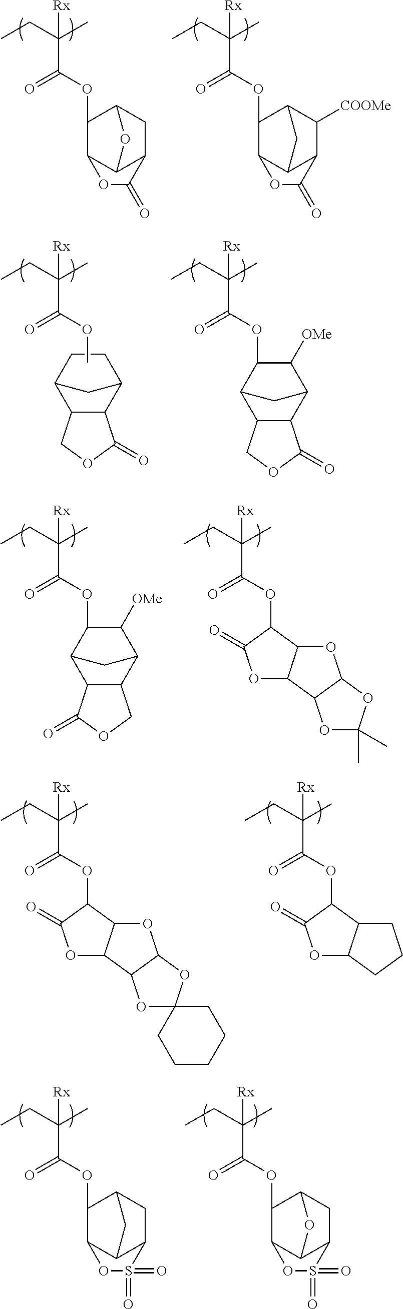

(In the formulae, Rx represents H, CH₃, CH₂OH or CF₃.)

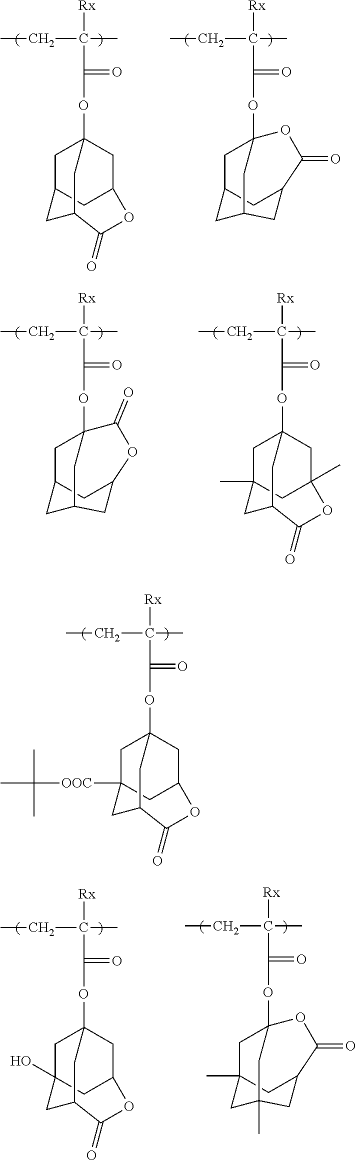

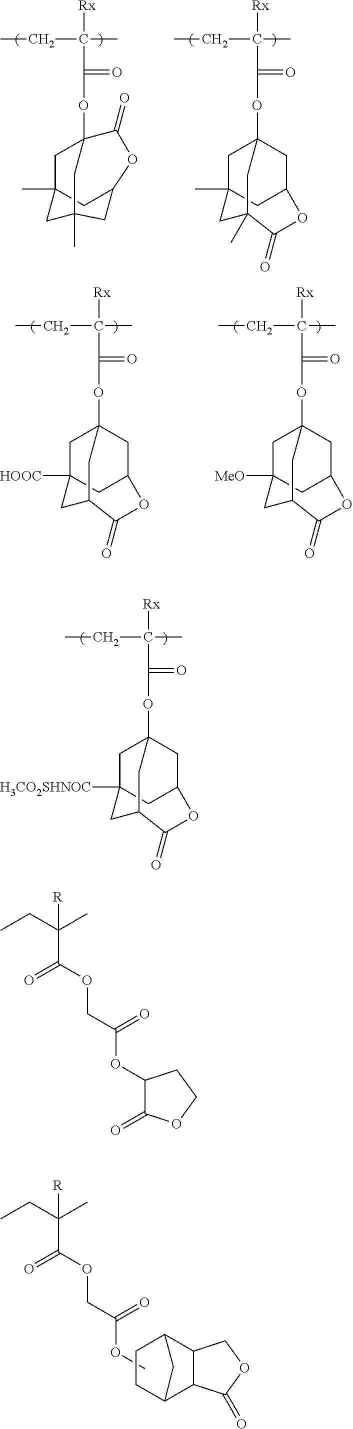

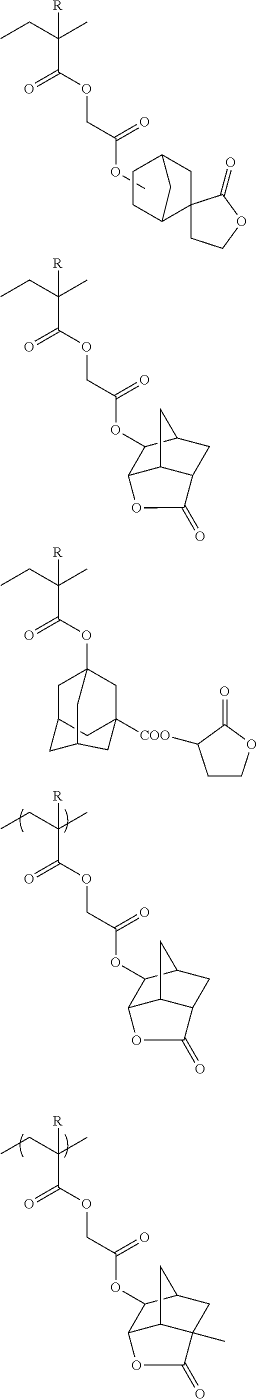

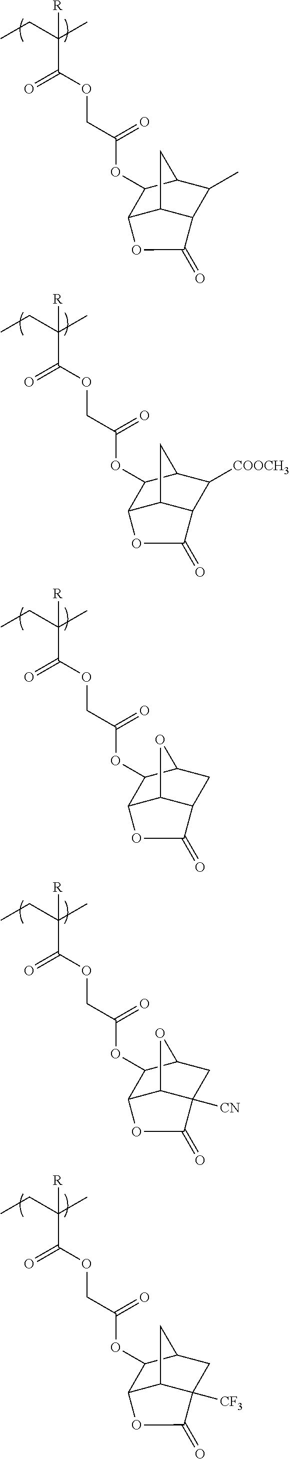

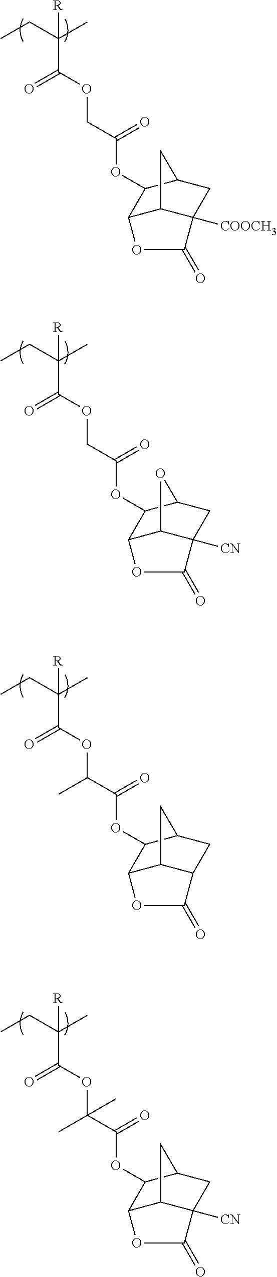

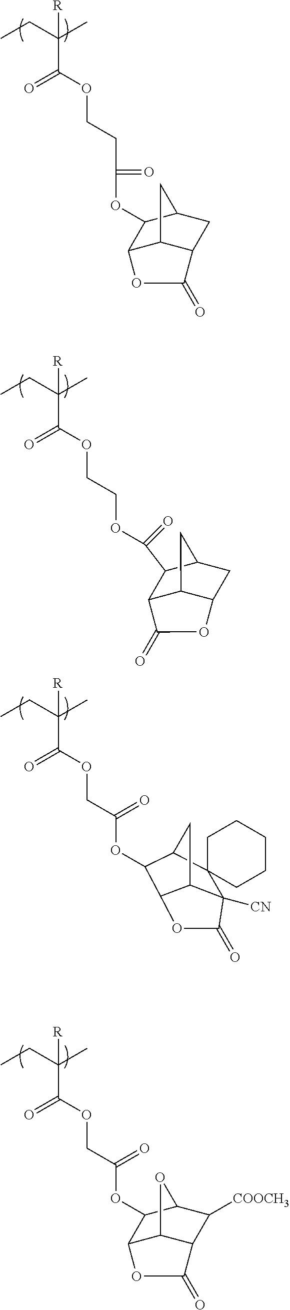

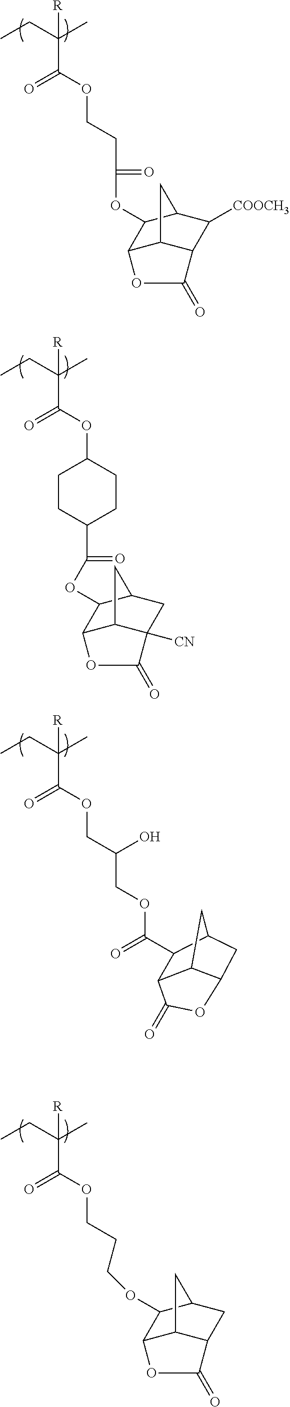

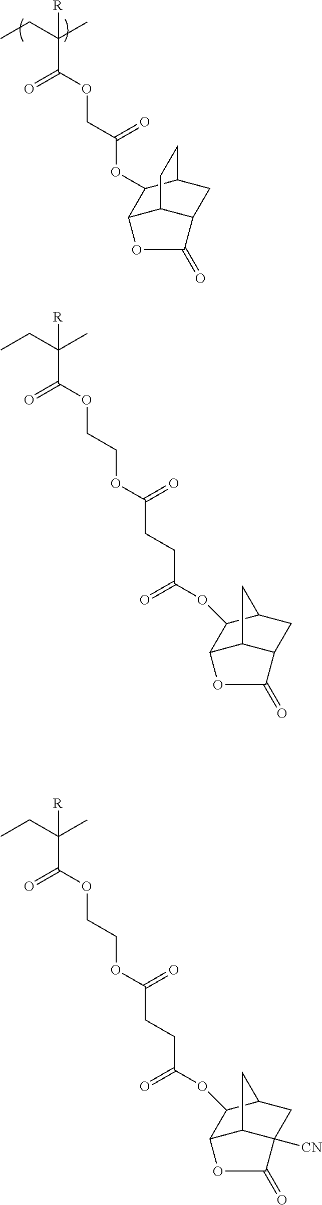

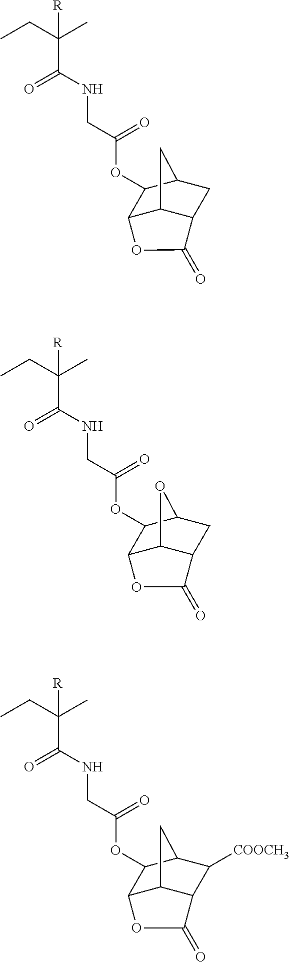

In order to increase the effects of the present invention, two or more kinds of repeating units having a lactone or sultone structure may be used in combination.

In the case where the resin (A) contains a repeating unit having a lactone or sultone structure, the content of the repeating unit having a lactone or sultone structure is preferably from 5 to 60 mol %, more preferably from 5 to 55 mol/%, still more preferably from 10 to 50 mol %, based on all repeating units in the resin (A).

The resin (A) preferably contains a repeating unit having a hydroxyl group or a cyano group, other than the repeating unit represented by formula (III). Thanks to this repeating unit, adherence to substrate and affinity for developer are enhanced. The repeating unit having a hydroxyl group or a cyano group is preferably a repeating unit having an alicyclic hydrocarbon structure substituted with a hydroxyl group or a cyano group and preferably has no acid-decomposable group. The alicyclic hydrocarbon structure in the alicyclic hydrocarbon structure substituted with a hydroxyl group or a cyano group is preferably an adamantyl group, a diamantyl group or a norbornyl group. The alicyclic hydrocarbon structure substituted with a hydroxyl group or a cyano group is preferably a partial structure represented by the following formulae (VIIa) to (VIId):

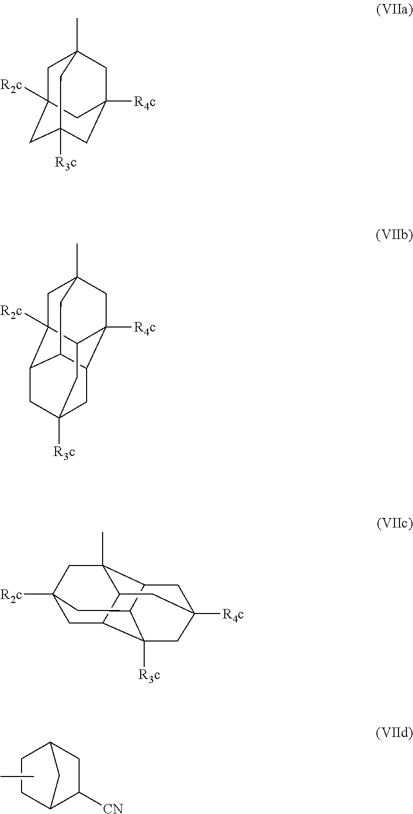

In formulae (VIa) to (VIIc), each of R₂c to R₄c independently represents a hydrogen atom, a hydroxyl group or a cyano group, provided that at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (AIIa) to (AIId):

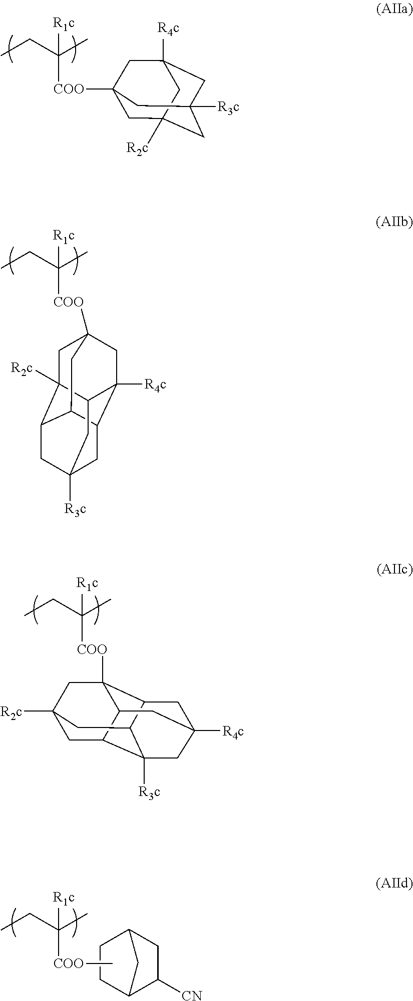

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc).

In the case where the resin (A) contains a repeating unit having a hydroxyl group or a cyano group, the content of the repeating unit having a hydroxyl group or a cyano group is preferably from 5 to 40 mol %, more preferably from 5 to 30 mol %, still more preferably from 10 to 30 mol %, based on all repeating units in the resin (A).

Specific examples of the repeating unit having a hydroxyl group or a cyano group are illustrated below, but the present invention is not limited thereto.

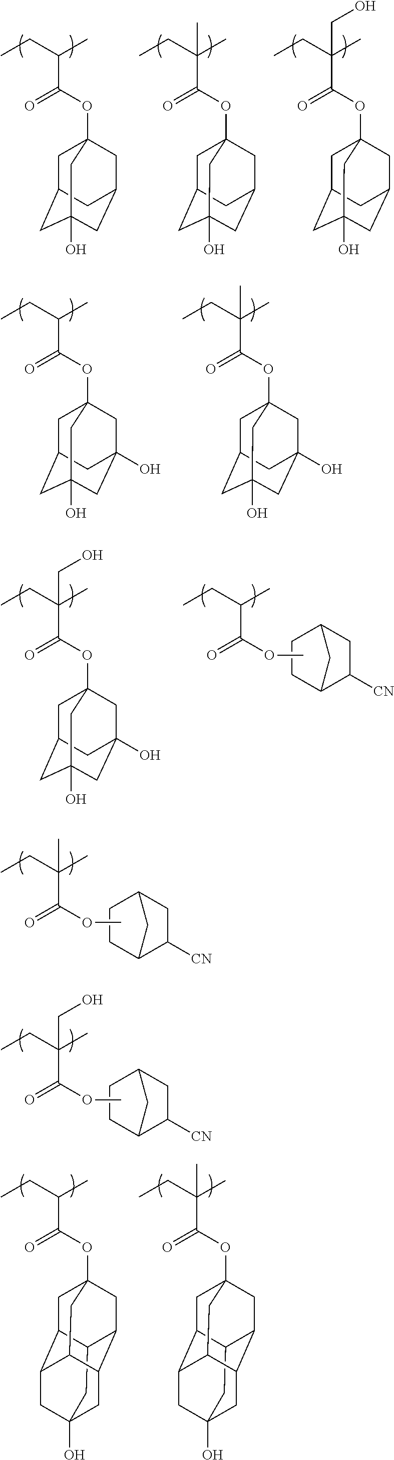

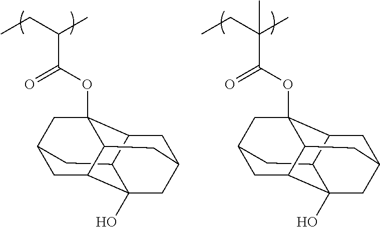

The resin (A) may contain a repeating unit having an acid group. The acid group includes a carboxyl group, a sulfonamide group, a sulfonylimide group, a bisulfonylimide group, and an aliphatic alcohol substituted with an electron-withdrawing group at the α-position (for example, hexafluoroisopropanol group), and it is preferred to contain a repeating unit having a carboxyl group. By virtue of containing a repeating unit having an acid group, the resolution increases in the usage of forming contact holes. As for the repeating unit having an acid group, all of a repeating unit where an acid group is directly bonded to the main chain of the resin, such as repeating unit derived from an acrylic acid or a methacrylic acid, a repeating unit where an acid group is bonded to the main chain of the resin through a linking group, and a repeating unit where an acid group is introduced into the polymer chain terminal by using an acid group-containing polymerization initiator or chain transfer agent at the polymerization, are preferred. The linking group may have a monocyclic or polycyclic cyclohydrocarbon structure. In particular, a repeating unit derived from an acrylic acid or a methacrylic acid is preferred.

The resin (A) may or may not contain a repeating unit having an acid group, but in the case of containing the repeating unit having an acid group, the content thereof is preferably 25 mol % or less, more preferably 20 mol % or less, based on all repeating units in the resin (A). In the case where the resin (A) contains a repeating unit having an acid group, the content of the acid group-containing repeating unit in the resin (A) is usually 1 mol % or more.

Specific examples of the repeating unit having an acid group are illustrated below, but the present invention is not limited thereto.

In specific examples, Rx represents H, CH₃, CH₂OH or CF₃.

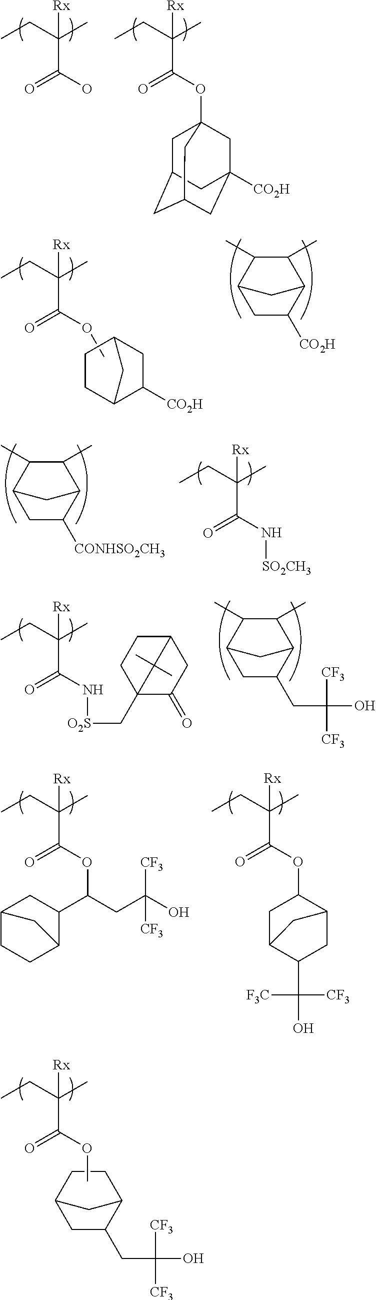

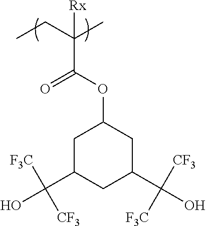

The resin (A) for use in the present invention may further contain a repeating unit having an alicyclic hydrocarbon structure free from a polar group (for example, the above-described acid group, a hydroxyl group or a cyano group) and not exhibiting acid decomposability. Thanks to this repeating unit, dissolution of a low molecular component from the resist film to the immersion liquid can be reduced at the immersion exposure and in addition, the solubility of the resin at the development using an organic solvent-containing developer can be appropriately adjusted. Such a repeating unit includes a repeating unit represented by formula (IV):

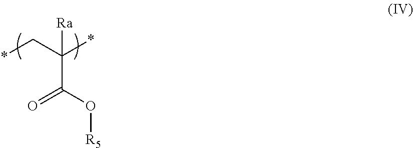

In formula (IV), R₅ represents a hydrocarbon group having at least one cyclic structure and having no polar group.

Ra represents a hydrogen atom, an alkyl group or a —CH₂—O—Ra₂ group, wherein Ra₂ represents a hydrogen atom, an alkyl group or an acyl group. Ra is preferably a hydrogen atom, a methyl group, a hydroxymethyl group or a trifluoromethyl group, more preferably a hydrogen atom or a methyl group.

The cyclic structure contained in R₅ includes a monocyclic hydrocarbon group and a polycyclic hydrocarbon group. Examples of the monocyclic hydrocarbon group include a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. The monocyclic hydrocarbon group is preferably a monocyclic hydrocarbon group having a carbon number of 3 to 7, more preferably a cyclopentyl group or a cyclohexyl group.

The polycyclic hydrocarbon group includes a ring-assembly hydrocarbon group and a bridged cyclic hydrocarbon group. Examples of the ring-assembly hydrocarbon group include a bicyclohexyl group and a perhydronaphthalenyl group. Examples of the bridged cyclic hydrocarbon ring include a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}.1^{7,10}]dodecane ring and perhydro-1,4-methano-5,8-methanonaphthalene ring. The bridged cyclic hydrocarbon ring also includes a condensed cyclic hydrocarbon ring, for example, a condensed ring formed by fusing a plurality of 5- to 8-membered cycloalkane rings, such as perhydronaphthalene (decalin) ring, perhydroanthracene ring, perhydrophenathrene ring, perhydroacenaphthene ring, perhydrofluorene ring, perhydroindene ring and perhydrophenalene ring.

Preferred examples of the bridged cyclic hydrocarbon ring include a norbornyl group, an adamantyl group, a bicyclooctanyl group and a tricyclo[5,2,1,0^{2,6}]decanyl group. Among these bridged cyclic hydrocarbon rings, a norbornyl group and an adamantyl group are more preferred.

Such an alicyclic hydrocarbon group may have a substituent, and preferred examples of the substituent include a halogen atom, an alkyl group, a hydroxyl group with a hydrogen atom being substituted for, and an amino group with a hydrogen atom being substituted for.

The halogen atom is preferably bromine atom, chlorine atom or fluorine atom, and the alkyl group is preferably a methyl group, an ethyl group, an n-butyl group or a tert-butyl group. This alkyl group may further have a substituent, and the substituent which may be further substituted on the alkyl group includes a halogen atom, an alkyl group, a hydroxyl group with a hydrogen atom being substituted for, and an amino group with a hydrogen atom being substituted for.

Examples of the substituent for the hydrogen atom include an alkyl group, a cycloalkyl group, an aralkyl group, a substituted methyl group, a substituted ethyl group, an alkoxycarbonyl group, and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group is preferably an alkoxycarbonyl group having a carbon number of 1 to 4.

The resin (A) may or may not contain a repeating unit having an alicyclic hydrocarbon structure free from a polar group and not exhibiting acid decomposability, but in the case of containing this repeating unit, the content thereof is preferably from 1 to 50 mol %, more preferably from 10 to 50 mol %, based on all repeating units in the resin (A).

Specific examples of the repeating unit having an alicyclic hydrocarbon structure free from a polar group and not exhibiting acid decomposability are illustrated below, but the present invention is not limited thereto. In the formulae, Ra represents H, CIH₃, CH₂OH or CF₃.

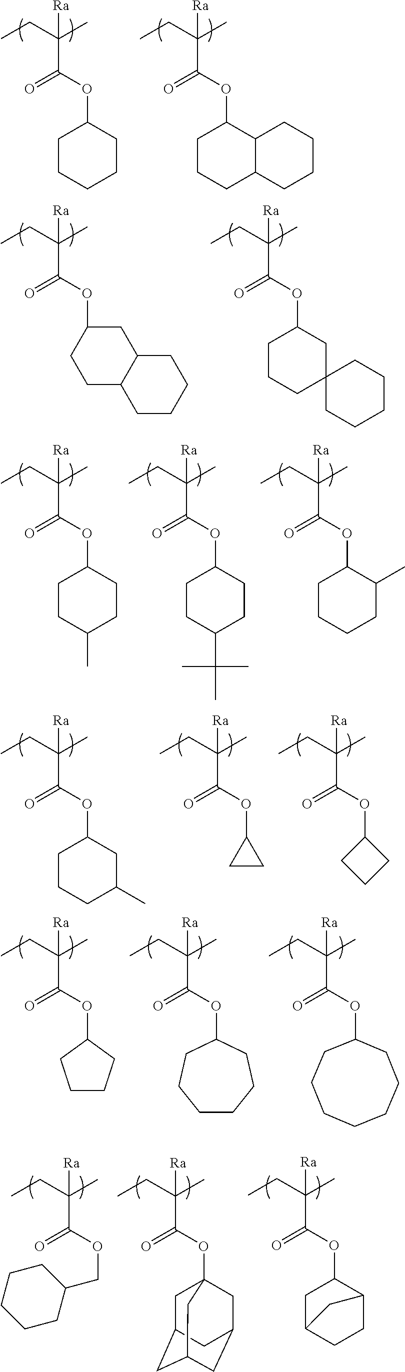

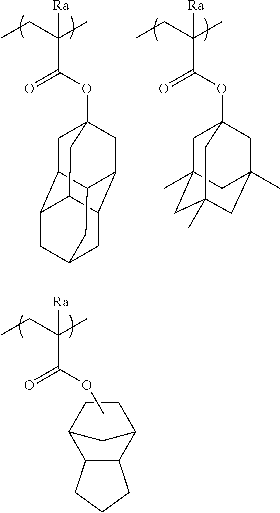

The resin (A) for use in the composition of the present invention may contain, in addition to the above-described repeating structural units, various repeating structural units for the purpose of controlling dry etching resistance, suitability for standard developer, adherence to substrate, resist profile and properties generally required of the actinic ray-sensitive or radiation-sensitive resin composition, such as resolution, heat resistance and sensitivity.

Examples of such a repeating structural unit include, but are not limited to, repeating structural units corresponding to the monomers described below.

Thanks to such a repeating structural unit, the performance required of the resin used in the composition of the present invention, particularly

(1) solubility for the coating solvent,

(2) film-forming property (glass transition point),

(3) alkali developability,

(4) film loss (selection of hydrophilic, hydrophobic or alkali-soluble group),

(5) adherence of unexposed area to substrate,

(6) dry etching resistance,

and the like, can be subtly controlled.

Examples of the monomer include a compound having one addition-polymerizable unsaturated bond selected from acrylic acid esters, methacrylic acid esters, acrylamides, methacrylamides, allyl compounds, vinyl ethers and vinyl esters.

Other than these compounds, an addition-polymerizable unsaturated compound copolymerizable with the monomers corresponding to the above-described various repeating structural units may be copolymerized.

In the resin (A) for use in the composition of the present invention, the molar ratio of respective repeating structural units contained is appropriately set to control dry etching resistance of the actinic ray-sensitive or radiation-sensitive resin composition, suitability for standard developer, adherence to substrate, resist profile and performances generally required of the actinic ray-sensitive or radiation-sensitive resin composition, such as resolution, heat resistance and sensitivity.

The form of the resin (A) for use in the present invention may be any of random type, block type, comb type and star type. The resin (A) can be synthesized, for example, by radical, cationic or anionic polymerization of unsaturated monomers corresponding to respective structures. It is also possible to obtain the target resin by polymerizing unsaturated monomers corresponding to precursors of respective structures and then performing a polymer reaction.

In the case where the composition of the present invention is used for ArF exposure, in view of transparency to ArF light, the resin (A) for use in the composition of the present invention preferably has substantially no aromatic ring (specifically, the proportion of an aromatic group-containing repeating unit in the resin is preferably 5 mol % or less, more preferably 3 mol % or less, and ideally 0 mol %, that is, not having an aromatic group). The resin (A) preferably has a monocyclic or polycyclic alicyclic hydrocarbon structure.

Also, in the case where the composition of the present invention contains the later-described resin (D), the resin (A) preferably contains no fluorine atom and no silicon atom in view of compatibility with the resin (D).

The resin (A) for use in the composition of the present invention is preferably a resin where all repeating units are composed of a (meth)acrylate-based repeating unit. In this case, all repeating units may be a methacrylate-based repeating unit, all repeating units may be an acrylate-based repeating unit, or all repeating units may be composed of a methacrylate-based repeating unit and an acrylate-based repeating unit, but the content of the acrylate-based repeating unit is preferably 50 mol % or less based on all repeating units.

In the case of irradiating the composition of the present invention with KrF excimer laser light, electron beam, X-ray or high-energy beam at a wavelength of 50 nm or less (e.g., EUV), the resin (A) preferably further contains a hydroxystyrene-based repeating unit. It is more preferred to contain a hydroxystyrene-based repeating unit, a hydroxystyrene-based repeating unit protected by an acid-decomposable group, and an acid-decomposable repeating unit such as tertiary alkyl (meth)acrylate.

Preferred examples of the hydroxystyrene-based repeating unit having an acid-decomposable group include repeating units composed of a tert-butoxycarbonyloxystyrene, a 1-alkoxyethoxystyrene and a tertiary alkyl (meth)acrylate. A repeating unit composed of a 2-alkyl-2-adamantyl (meth)acrylate, and a repeating unit composed of a dialkyl(1-adamantyl)methyl (meth)acrylate are more preferred.

The resin (A) for use in the present invention can be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone. The polymerization is more preferably performed using the same solvent as the solvent used in the photosensitive composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Examples of the preferred initiator include azobisisobutyronitrile, azobisdimethylvaleronitrile and dimethyl 2,2′-azobis(2-methylpropionate). The initiator is added additionally or in parts as needed. After the completion of reaction, the reaction solution is poured in a solvent, and the desired polymer is collected by a powder, solid or other recovery method. The concentration at the reaction is from 5 to 50 mass %, preferably from 10 to 30 mass %, and the reaction temperature is usually from 10 to 150° C., preferably from 30 to 120° C., more preferably from 60 to 100° C.

After the completion of reaction, the reaction solution is allowed to cool to room temperature and purified. The purification may be performed by a normal method, for example, a liquid-liquid extraction method of applying water washing or combining it with an appropriate solvent to remove residual monomers or oligomer components; a purification method in a solution sate, such as ultrafiltration of extracting and removing only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent for the polymer, and the solvent which can be used may be appropriately selected from, for example, a hydrocarbon, a halogenated hydrocarbon, a nitro compound, an ether, a ketone, an ester, a carbonate, an alcohol, a carboxylic acid, water, and a mixed solvent containing such a solvent, according to the kind of the polymer. Among these solvents, a solvent containing at least an alcohol (particularly, methanol or the like) or water is preferred as the precipitation or reprecipitation solvent.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by taking into consideration the efficiency or operability but is usually on the order of 0 to 50° C., preferably in the vicinity of room temperature (for example, approximately from 20 to 35° C.). The precipitation or reprecipitation operation may be performed using a commonly employed mixing vessel such as stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C., preferably on the order of 30 to 50° C.

Incidentally, after the resin is once precipitated and separated, the resin may be again dissolved in a solvent and then put into contact with a solvent in which the resin is slightly soluble or insoluble. That is, there may be used a method including, after the completion of radical polymerization reaction, bringing the polymer into contact with a solvent in which the polymer is slightly soluble or insoluble, to precipitate a resin (step a), separating the resin from the solution (step b), anew dissolving the resin in a solvent to prepare a resin solution A (step c), bringing the resin solution A into contact with a solvent in which the resin is slightly soluble or insoluble and which is in a volumetric amount of less than 10 times (preferably 5 times or less) the resin solution A, to precipitate a resin solid (step d), and separating the precipitated resin (step e).

Also, for keeping the resin from aggregation or the like after preparation of the composition, as described, for example, in JP-A-2009-037108, a step of dissolving the synthesized resin in a solvent to make a solution and heating the solution at approximately from 30 to 90° C. for approximately from 30 minutes to 4 hours may be added.

The weight average molecular weight of the resin (A) for use in the present invention is preferably from 1,000 to 200,000, more preferably from 2,000 to 50,000, still more preferably from 3,000 to 40,000, yet still more preferably from 3,000 to 30,000, in terms of polystyrene by the GPC method. When the weight average molecular weight is from 1,000 to 200,000, reduction in the heat resistance and dry etching resistance can be avoided and at the same time, the film-forming property can be prevented from deterioration due to impaired developability or increased viscosity.

The polydispersity (molecular weight distribution) is usually from 1.0 to 3.0, preferably from 1.0 to 2.6, more preferably from 1.0 to 2.0, still more preferably from 1.4 to 2.0. As the molecular weight distribution is smaller, not only the resolution and resist profile are more excellent and the side wall of the resist pattern is smoother but also the roughness is more improved.

In the actinic ray-sensitive or radiation-sensitive resin composition of the present invention, the blending ratio of the resin (A) in the entire composition is preferably from 30 to 99 mass %, more preferably from 60 to 95 mass %, based on the total solid content.

In the present invention, as for the resin (A), one kind of a resin may be used or a plurality of kinds of resins may be used in combination.

[2](B) Compound capable of generating an acid upon irradiation with an actinic ray or radiation

The composition for use in the present invention further contains (B) a compound capable of generating an acid upon irradiation with an actinic ray or radiation (hereinafter, sometimes referred to as an “acid generator”). The compound (B) capable of generating an acid upon irradiation with an actinic ray or radiation is preferably a compound capable of generating an organic acid upon irradiation with an actinic ray or radiation.

The acid generator which can be used may be appropriately selected from a photo-initiator for cationic photopolymerization, a photo-initiator for radical photopolymerization, a photo-decoloring agent for dyes, a photo-discoloring agent, a known compound capable of generating an acid upon irradiation with an actinic ray or radiation, which is used for microresist or the like, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Out of the acid generators, preferred compounds include compounds represented by the following formulae (ZI), (ZII) and (ZIII):

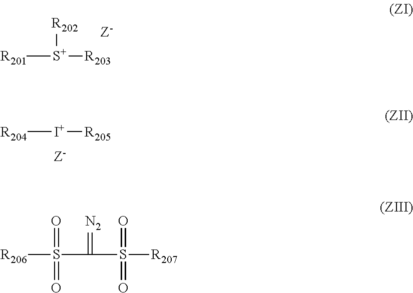

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain therein an oxygen atom, a sulfur atom, an ester bond, an amide bond or a carbonyl group. Examples of the group formed by combining two members out of R₂₀₁ to R₂₀₃ include an alkylene group (e.g., butylene, pentylene).

Z⁻ represents a non-nucleophilic anion.

Examples of the non-nucleophilic anion as Z⁻ include sulfonate anion, carboxylate anion, sulfonylimide anion, bis(alkylsulfonyl)imide anion and tris(alkylsulfonyl)methyl anion.

The non-nucleophilic anion is an anion having an extremely low ability of causing a nucleophilic reaction and this anion can suppress the decomposition with aging due to intramolecular nucleophilic reaction. Thanks to this anion, the aging stability of the resist composition is improved.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkylcarboxylate anion.

The aliphatic moiety in the aliphatic sulfonate anion and aliphatic carboxylate may be an alkyl group or a cycloalkyl group but is preferably an alkyl group having a carbon number of 1 to 30 or a cycloalkyl group having a carbon number of 3 to 30, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, and a bornyl group.

The aromatic group in the aromatic sulfonate anion and aromatic carboxylate anion is preferably an aryl group having a carbon number of 6 to 14, and examples thereof include a phenyl group, a tolyl group and a naphthyl group.

The alkyl group, cycloalkyl group and aryl group in the aliphatic sulfonate anion and aromatic sulfonate anion may have a substituent. Examples of the substituent on the alkyl group, cycloalkyl group and aryl group in the aliphatic sulfonate anion and aromatic sulfonate anion include a nitro group, a halogen atom (e.g., fluorine, chlorine, bromine, iodine), a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 1 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). The aryl group and ring structure in each group may further have, as a substituent, an alkyl group (preferably having a carbon number of 1 to 15) or a cycloalkyl group (preferably having a carbon number of 3 to 15).

The aralkyl group in the aralkylcarboxylate anion is preferably an aralkyl group having a carbon number of 7 to 12, and examples thereof include a benzyl group, a phenethyl group, a naphthylmethyl group, a naphthylethyl group, and a naphthylbutyl group.

The alkyl group, cycloalkyl group, aryl group and aralkyl group in the aliphatic carboxylate anion, aromatic carboxylate anion and aralkylcarboxylate anion may have a substituent. Examples of the substituent include the same halogen atom, alkyl group, cycloalkyl group, alkoxy group and alkylthio group as those in the aromatic sulfonate anion.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group.

Two alkyl groups in the bis(alkylsulfonyl)imide anion may combine to make an alkylene group (preferably having a carbon number of 2 to 4) and form a ring together with the imido group and two sulfonyl groups. Examples of the substituent which may be substituted on the alkyl group and the alkylene group formed by combining two alkyl groups in the bis(alkylsulfonyl)imide anion, include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom-substituted alkyl group being preferred.

Other examples of the non-nucleophilic anion include fluorinated phosphorus (e.g., PF₆⁻), fluorinated boron (e.g., BF₄⁻), and fluorinated antimony (e.g., SbF₆⁻).

The non-nucleophilic anion of Z is preferably an aliphatic sulfonate anion substituted with a fluorine atom at least at the α-position of sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having a carbon number of 4 to 8 or a benzenesulfonate anion having a fluorine atom, still more preferably nonafluorobutanesulfonate anion, perfluorooctanesulfonate anion, pentafluorobenzenesulfonate anion or 3,5-bis(trifluoromethyl)benzenesulfonate anion.

The acid generator is preferably a compound capable of generating an acid represented by the following formula (V) or (VI) upon irradiation with an actinic ray or radiation. The compound capable of generating an acid represented by the following formula (V) or (VI) has a cyclic organic group, so that the resolution and roughness performance can be more improved.

The non-nucleophilic anion described above can be an anion capable of generating an organic acid represented by the following formula (V) or (VI):

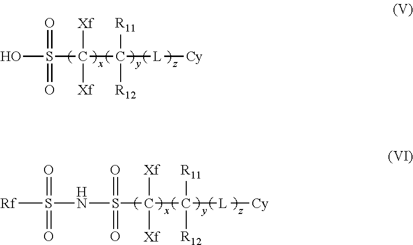

In the formulae, each of Xf independently represents a fluorine atom or an alkyl group substituted with at least one fluorine atom.

Each of R₁₁ and R₁₂ independently represents a hydrogen atom, a fluorine atom or an alkyl group.

Each L independently represents a divalent linking group.

Cy represents a cyclic organic group.

Rf represents a fluorine atom-containing group.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably from 1 to 10, more preferably from 1 to 4. Also, the alkyl group substituted with at least one fluorine atom is preferably a perfluoroalkyl group.

Xf is preferably a fluorine atom or a perfluoroalkyl group having a carbon number of 1 to 4. Specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₇, CH₂C₃F₇, CH₂CH₂C₃F₇, CH₂C₄F₉ or CH₂CH₂C₄F₉, more preferably a fluorine atom or CF₃, and it is still more preferred that both Xf are a fluorine atom.

Each of R₁₁ and R₁₂ independently represents a hydrogen atom, a fluorine atom or an alkyl group. The alkyl group may have a substituent (preferably fluorine atom) and is preferably an alkyl group having a carbon number of 1 to 4, more preferably a perfluoroalkyl group having a carbon number of 1 to 4. Specific examples of the alkyl group having a substituent of R₁₁ and R₁₂ include CF₃, C₂F₅, C₃F₇, C₄F₉, C₅F₁₁, C₅F₁₃, C₇F₁₅, C₈F₁₇, CH₂CF₃, CH₂CH₂CF₃, CH₂C₂F, CH₂CH₂C₂F₅, CH₂C₃F₇, CH₂CH₂C₃F₇, CH₂C₄F₉ and CH₂CH₂C₄F₉, with CF₃ being preferred.

L represents a divalent linking group. Examples of the divalent linking group include —COO—, —OCO—, —CONH—, —NHCO—, —CO—, —O—, —S—, —SO—, —SO₂—, an alkylene group (preferably having a carbon number of 1 to 6), a cycloalkylene group (preferably having a carbon number of 3 to 10), an alkenylene group (preferably having a carbon number of 2 to 6), and a divalent linking group formed by combining a plurality of these members. Among these, —COO—, —OCO—, —CONH—, —NHCO—, —CO—, —O—, —SO₂—, —COO-alkylene group-, —OCO-alkylene group-, —CONH-alkylene group- and —NHCO-alkylene group- are preferred, and —COO—, —OCO—, —CONH—, —SO₂—, —COO-alkylene group- and —OCO-alkylene group- are more preferred.

Cy represents a cyclic organic group. Examples of the cyclic organic group include an alicyclic group, an aryl group and a heterocyclic group

The alicyclic group may be monocyclic or polycyclic. The monocyclic alicyclic group includes, for example, a monocyclic cycloalkyl group such as cyclopentyl group, cylohexyl group and cyclooctyl group. The polycyclic alicyclic group includes, for example, a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint of suppressing diffusion in film at the PEB (post-exposure baking) step and improving MEEF (Mask Error Enhancement Factor).

The aryl group may be monocyclic or polycyclic. Examples of the aryl group include a phenyl group, a naphthyl group, a phenanthryl group and an anthryl group. Among these, a naphthyl group is preferred because of its relatively low light absorbance at 193 nm.

The heterocyclic group may be monocyclic or polycyclic, but a polycyclic heterocyclic group can more suppress diffusion of an acid. The heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heterocyclic ring not having aromaticity include a tetrahydropyran ring, a lactone ring and a decahydroisoquinoline ring. The heterocyclic ring in the heterocyclic group is preferably a furan ring, a thiophene ring, a pyridine ring or a decahydroisoquinoline ring. Examples of the lactone ring or sultone ring include lactone structures or sultone structures exemplified in the resin (A) above.

The above-described cyclic organic group may have a substituent, and examples of the substituent include an alkyl group (may be linear or branched, preferably having a carbon number of 1 to 12), a cycloalkyl group (may be monocyclic, polycyclic or spirocyclic, preferably having a carbon number of 3 to 20), an aryl group (preferably having a carbon number of 6 to 14), a hydroxyl group, an alkoxy group, an ester group, an amido group, a urethane group, a ureido group, a thioether group, a sulfonamido group, and a sulfonic acid ester group. The carbon constituting the cyclic organic group (the carbon contributing to ring formation) may be carbonyl carbon.

x is preferably from 1 to 8, more preferably from 1 to 4, still more preferably 1. y is preferably from 0 to 4, more preferably 0. z is preferably from 0 to 8, more preferably from 0 to 4.

The fluorine atom-containing group represented by Rf includes, for example, an alkyl group having at least one fluorine atom, a cycloalkyl group having at least one fluorine atom, and an aryl group having at least one fluorine atom.

The alkyl group, cycloalkyl group and aryl group may be substituted with a fluorine atom or may be substituted with another fluorine atom-containing substituent. In the case where Rf is a cycloalkyl group having at least one fluorine atom or an aryl group having at least one fluorine atom, the another fluorine-containing substituent includes, for example, an alkyl group substituted with at least one fluorine atom.

Also, the alkyl group, cycloalkyl group and aryl group may be further substituted with a fluorine atom-free substituent. Examples of this substituent include those not containing a fluorine atom out of those described above for Cy.

Examples of the alkyl group having at least one fluorine atom represented by Rf are the same as those described above as the alkyl group substituted with at least one fluorine atom represented by Xf. Examples of the cycloalkyl group having at least one fluorine atom represented by Rf include a perfluorocyclopentyl group and a perfluorocyclohexyl group. Examples of the aryl group having at least one fluorine atom represented by Rf include a perfluorophenyl group.

The organic group represented by R₂₀₁, R₂₀₂ and R₂₀₃ includes, for example, corresponding groups in the later-described compounds (ZI-1), (ZI-2), (ZI-3) and (ZI-4).

The compound may be a compound having a plurality of structures represented by formula (ZI). For example, the compound may be a compound having a structure where at least one of R₂₀₁ to R₂₀₃ in a compound represented by formula (ZI) is bonded to at least one of R₂₀₁ to R₂₀₃ in another compound represented by formula (ZI) through a single bond or a linking group.

Compounds (ZI-1), (ZI-2), (ZI-3) and (ZI-4) described below are more preferred as the component (ZI).

The compound (ZI-1) is an arylsulfonium compound where at least one of R₂₀₁ to R₂₀₃ in formula (ZI) is an aryl group, that is, a compound having an arylsulfonium as the cation.

In the arylsulfonium compound, all of R₂₀₁ to R₂₀₃ may be an aryl group or a part of R₂₀ to R₂₀₃ may be an aryl group, with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, more preferably a phenyl group. The aryl group may be an aryl group having a heterocyclic structure containing an oxygen atom, a nitrogen atom, a sulfur atom or the like. Examples of the heterocyclic structure include a pyrrole residue, a furan residue, a thiophene residue, an indole residue, a benzofuran residue, and a benzothiophene residue. In the case where the arylsulfonium compound has two or more aryl groups, these two or more aryl groups may be the same or different.

The alkyl or cycloalkyl group which is contained, if desired, in the arylsulfonium compound is preferably a linear or branched alkyl group having a carbon number of 1 to 15 or a cycloalkyl group having a carbon number of 3 to 15, and examples thereof include a methyl group, an ethyl group, a propyl group, an n-butyl group, a sec-butyl group, a tert-butyl group, a cyclopropyl group, a cyclobutyl group, and a cyclohexyl group.

The aryl group, alkyl group and cycloalkyl group of R₂₀₁ to R₂₀₃ may have, as a substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4, or an alkoxy group having a carbon number of 1 to 4. The substituent may be substituted on any one of three members R₂₀₁ to R₂₀₃ or may be substituted on all of these three members. In the case where R₂₀₁ to R₂₀₃ are an aryl group, the substituent is preferably substituted on the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein encompasses an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ is independently preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10 (e.g., methyl, ethyl, propyl, butyl, pentyl) and a cycloalkyl group having a carbon number of 3 to 10 (e.g., cyclopentyl, cyclohexyl, norbornyl). The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5 (e.g., methoxy, ethoxy, propoxy, butoxy, pentoxy).

R₂₀₁ to R₂₀₃ may be further substituted with a halogen atom, an alkoxy group (for example, having a carbon number of 1 to 5), a hydroxyl group, a cyano group or a nitro group.

The compound (ZI-3) is described below.

The compound (ZI-3) is a compound represented by the following formula (ZI-3), and this is a compound having a phenacylsulfonium salt structure.

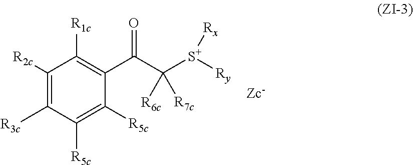

In formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group.

Any two or more members out of R_{1c} to R_{5c}, a pair of R_{5c} and R_{6c}, a pair of R_{6c} and R_{7c}, a pair of R_{5c} and Rₓ, or a pair of Rₓ and R_{y} may combine together to form a ring structure. This ring structure may contain an oxygen atom, a sulfur atom, a ketone group, an ester bond or an amide bond.

The ring structure above includes an aromatic or non-aromatic hydrocarbon ring, an aromatic or non-aromatic heterocyclic ring, and a polycyclic condensed ring formed by combining two or more of these rings. The ring structure includes a 3- to 10-membered ring and is preferably a 4- to 8-membered ring, more preferably a 5- or 6-membered ring.

Examples of the group formed by combining any two or more members of R_{1c} to R_{5c}, a pair of R_{6c} and R_{7c}, or a pair of Rₓ and R_{y} include a butylene group and a pentylene group.

The group formed by combining a pair of R_{5c} and R_{6c} or a pair of R_{5c} and Rₓ is preferably a single bond or an alkylene group, and examples of the alkylene group include a methylene group and an ethylene group.

Zc⁻ represents a non-nucleophilic anion, and examples thereof are the same as those of the non-nucleophilic anion of Z⁻ in formula (ZI).

The alkyl group as R₁ₐ to R_{7c} may be either linear or branched and is, for example, an alkyl group having a carbon number of 1 to 20, preferably a linear or branched alkyl group having a carbon number of 1 to 12 (such as methyl group, ethyl group, linear or branched propyl group, linear or branched butyl group, or linear or branched pentyl group). The cycloalkyl group includes, for example, a cycloalkyl group having a carbon number of 3 to 10 (such as cyclopentyl group or cyclohexyl group).

The aryl group as R_{1c} to R_{5c} is preferably an aryl group having a carbon number of 5 to 15, and examples thereof include a phenyl group and a naphthyl group.

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (such as methoxy group, ethoxy group, linear or branched propoxy group, linear or branched butoxy group, or linear or branched pentoxy group), or a cyclic alkoxy group having a carbon number of 3 to 10 (such as cyclopentyloxy group or cyclohexyloxy group).

Specific examples of the alkoxy group in the alkoxycarbonyl group as R_{1c} to R_{5c} are the same as specific examples of the alkoxy group of R_{1c} to R_{5c}.

Specific examples of the alkyl group in the alkylcarbonyloxy group and alkylthio group as R_{1c} to R_{5c} are the same as specific examples of the alkyl group of R_{1c} to R_{5c}.

Specific examples of the cycloalkyl group in the cycloalkylcarbonyloxy group as R_{1c} to R_{5c} are the same as specific examples of the cycloalkyl group of R_{1c} to R_{5c}.

Specific examples of the aryl group in the aryloxy group and arylthio group as R_{1c} to R_{5c} are the same as specific examples of the aryl group of R_{1c} to R_{5c}.

A compound where any one of R_{1c} to R_{5c} is a linear or branched alkyl group, a cycloalkyl group, or a linear, branched or cyclic alkoxy group is preferred, and a compound where the sum of carbon numbers of R_{1c} to R_{5c} is from 2 to 15 is more preferred. Thanks to such a compound, the solvent solubility is more enhanced and production of particles during storage can be suppressed.

The ring structure which may be formed by combining any two or more members of R_{1c} to R_{5c} with each other is preferably a 5- or 6-membered ring, more preferably a 6-membered ring (such as phenyl ring).

The ring structure which may be formed by combining R_{5c} and R_{6c} with each other includes a 4-membered or higher membered ring (preferably a 5- or 6-membered ring) formed together with the carbonyl carbon atom and carbon atom in formula (I) by combining R_{5c} and R_{6c} with each other to constitute a single bond or an alkylene group (such as methylene group or ethylene group).

The aryl group as R_{6c} and R_{7c} is preferably an aryl group having a carbon number of 5 to 15, and examples thereof include a phenyl group and a naphthyl group.

An embodiment where both of R_{6c} and R_{7c} are an alkyl group is preferred, an embodiment where each of R_{6c} and R_{7c} is a linear or branched alkyl group having a carbon number of 1 to 4 is more preferred, and an embodiment where both are a methyl group is still more preferred.

In the case where R_{6c} and R_{7c} are combined to form a ring, the group formed by combining R_{6c} and R_{7c} is preferably an alkylene group having a carbon number of 2 to 10, and examples thereof include an ethylene group, a propylene group, a butylene group, a pentylene group, and a hexylene group. Also, the ring formed by combining R_{6c} and R_{7c} may contain a heteroatom such as oxygen atom in the ring.

Examples of the alkyl group and cycloalkyl group as Rₓ and R_{y} are the same as those of the alkyl group and cycloalkyl group in R_{1c} to R_{7c}.

Examples of the 2-oxoalkyl group and 2-oxocycloalkyl group as Rₓ and R_{y} include a group having >C═O at the 2-position of the alkyl group or cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}. The alkyl group is, for example, an alkyl group having a carbon number of 1 to 12, preferably a linear alkyl group having a carbon number of 1 to 5 (such as methyl group or ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having a carbon number of 3 to 10).

The vinyl group as Rₓ and R_{y} is not particularly limited but is preferably an unsubstituted vinyl group or a vinyl group substituted with a monocyclic or polycyclic cycloalkyl group (preferably a cycloalkyl group having a carbon number of 3 to 10).

The ring structure which may be formed by combining R_{5c} and Rx with each other includes a 5-membered or higher membered ring (preferably a 5-membered ring) formed together with the sulfur atom and carbonyl carbon atom in formula (I) by combining R_{5c} and Rₓ with each other to constitute a single bond or an alkylene group (such as methylene group or ethylene group).

The ring structure which may be formed by combining Rₓ and R_{y} with each other includes a 5- or 6-membered ring, preferably a 5-membered ring (that is, tetrahydrothiophene ring), formed by divalent Rₓ and R_{y} (for example, a methylene group, an ethylene group, or a propylene group) together with the sulfur atom in formula (ZI-3).

Each of Rₓ and R_{y} is preferably an alkyl or cycloalkyl group having a carbon number of 4 or more, more preferably 6 or more, still more preferably 8 or more.

Each of R_{1c} to R_{7c}, Rₓ and R_{y} may further have a substituent, and examples of such a substituent include a halogen atom (e.g., fluorine), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

In formula (ZI-3), it is more preferred that each of R_{1c}, R_{2c}, R_{4c} and R_{5c} independently represents a hydrogen atom and R_{3c} represents a group except for a hydrogen atom, that is, represents an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Specific examples of the cation in the compound represented by formula (ZI-2) or (ZI-3) for use in the present invention are illustrated below.

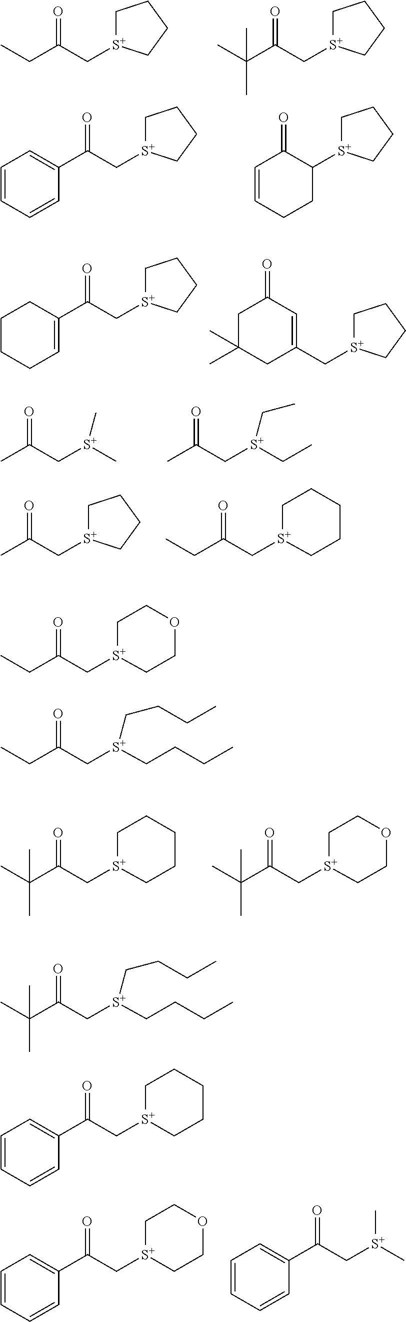

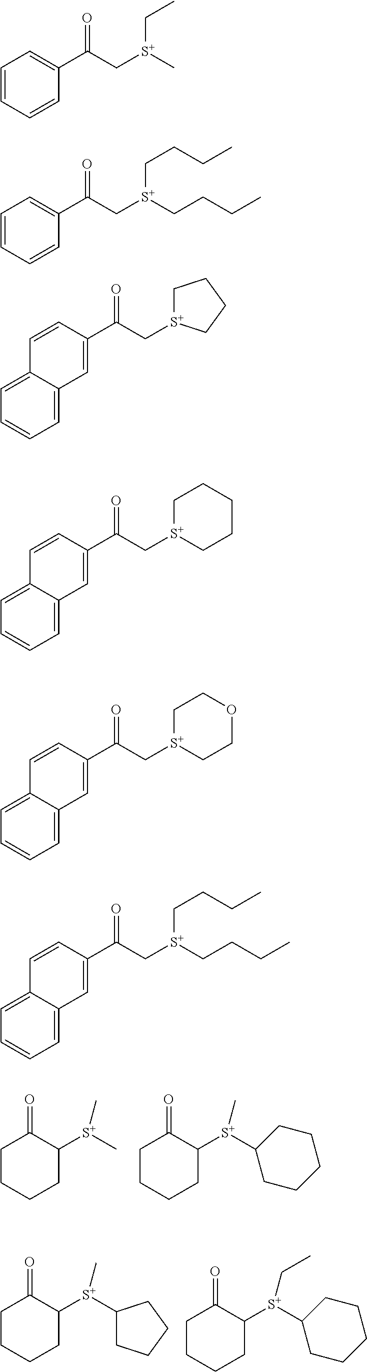

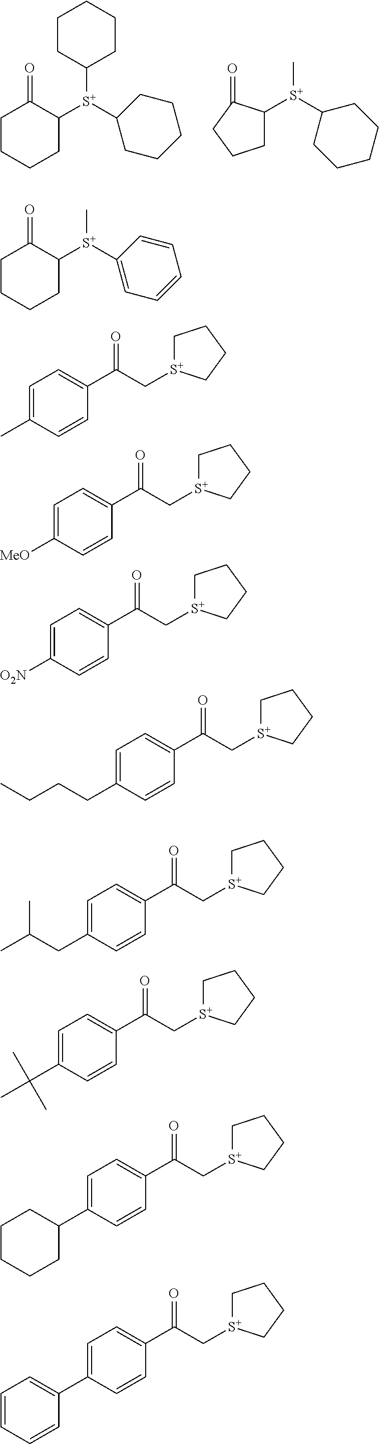

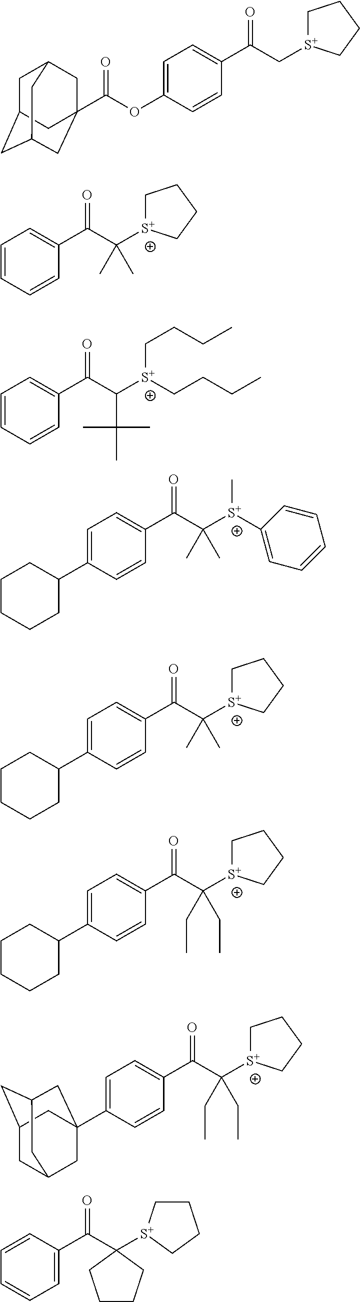

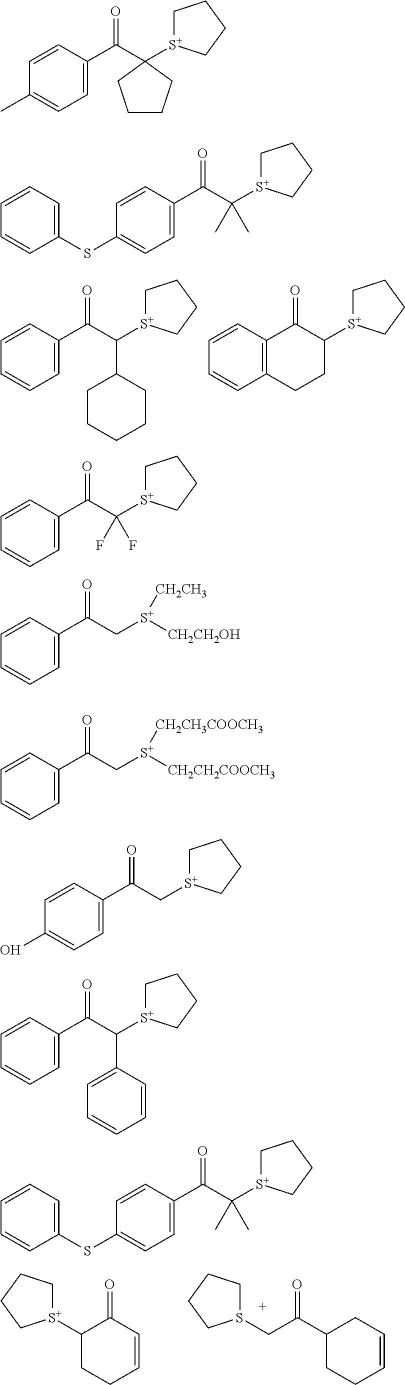

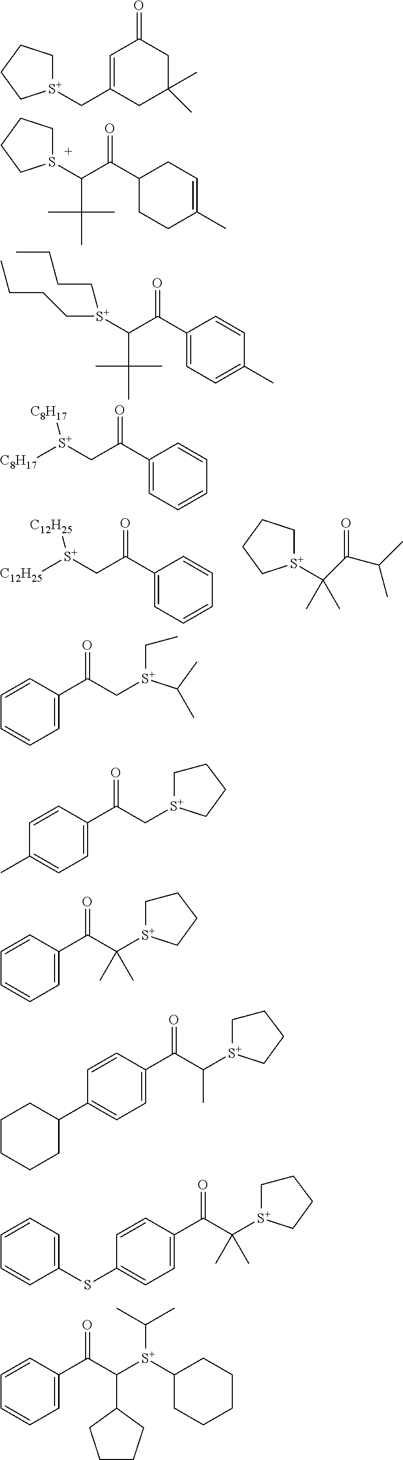

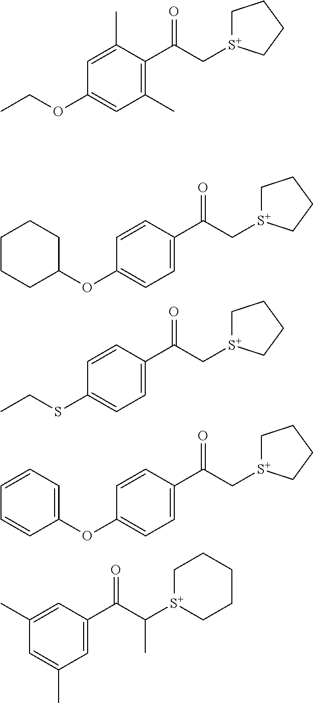 [SMILES: CCOc1cc(C)c(C(=O)C[S+]2CCCC2)c(C)c1 ; O=C(C[S+]1CCCC1)c1ccc(OC2CCCCC2)cc1 ; CCSc1ccc(C(=O)C[S+]2CCCC2)cc1 ; O=C(C[S+]1CCCC1)c1ccc(Oc2ccccc2)cc1 ; Cc1cc(C)cc(C(=O)C(C)[S+]2CCCCC2)c1]

The compound (ZI-4) is described below.

The compound (ZI-4) is represented by the following formula (ZI-4):

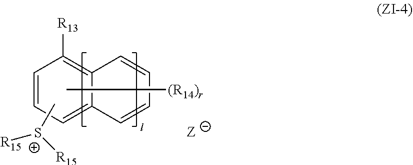

In formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

R₁₄ represents, when a plurality of R₁₄s are present, each independently represents, a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

Each of R₁s independently represents an alkyl group, a cycloalkyl group, or a naphthyl group. Two R₁s may combine with each other to form a ring. These groups may have a substituent.

l represents an integer of 0 to 2.

r represents an integer of 0 to 8.

Z⁻ represents a non-nucleophilic anion, and examples thereof are the same as those of the nucleophilic anion of Z in formula (ZI).

In formula (ZI-4), the alkyl group of R₁₃, R₁₄ and R₁₅ is a linear or branched alkyl group preferably having a carbon number of 1 to 10, and preferred examples thereof include a methyl group, an ethyl group, an n-butyl group and a tert-butyl group.

The cycloalkyl group of R₁₃, R₁₄ and R₁₅ includes a monocyclic or polycyclic cycloalkyl group (preferably a cycloalkyl group having a carbon number of 3 to 20) and, among others, cyclopropyl, cyclopentyl, cyclohexyl, cycloheptyl and cyclooctyl are preferred.

The alkoxy group of R₁₃ and R₁₄ is a linear or branched alkoxy group preferably having a carbon number of 1 to 10, and preferred examples thereof include a methoxy group, an ethoxy group, an n-propoxy group, and an n-butoxy group.

The alkoxycarbonyl group of R₁₃ and R₁₄ is a linear or branched alkoxycarbonyl group preferably having a carbon number of 2 to 11, and preferred examples thereof include a methoxycarbonyl group, an ethoxycarbonyl group and an n-butoxycarbonyl group.

The group having a cycloalkyl group of R₁₃ and R₁₄ includes a monocyclic or polycyclic cycloalkyl group (preferably a cycloalkyl group having a carbon number of 3 to 20), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and preferably has a monocyclic cycloalkyl group. The monocyclic cycloalkyloxy group having a total carbon number of 7 or more indicates a monocyclic cycloalkyloxy group where a cycloalkyloxy group such as cyclopropyloxy group, cyclobutyloxy group, cyclopentyloxy group, cyclohexyloxy group, cycloheptyloxy group, cyclooctyloxy group and cyclododecanyloxy group arbitrarily has a substituent such as alkyl group (e.g., methyl, ethyl, propyl, butyl, pentyl, hexyl, heptyl, octyl, dodecyl, 2-ethylhexyl, isopropyl, sec-butyl, tert-butyl, isoamyl), hydroxyl group, halogen atom (e.g., fluorine, chlorine, bromine, iodine), nitro group, cyano group, amido group, sulfonamido group, alkoxy group (e.g., methoxy, ethoxy, hydroxyethoxy, propoxy, hydroxypropoxy, butoxy), alkoxycarbonyl group (e.g., methoxycarbonyl, ethoxycarbonyl), acyl group (e.g., formyl, acetyl, benzoyl), acyloxy group (e.g., acetoxy, butyryloxy) and carboxy group and where the total carbon number inclusive of the carbon number of an arbitrary substituent on the cycloalkyl group is 7 or more.

Examples of the polycyclic cycloalkyloxy group having a total carbon number of 7 or more include a norbornyloxy group, a tricyclodecanyloxy group, a tetracyclodecanyloxy group, and an adamantyloxy group.

The alkoxy group having a monocyclic or polycyclic cycloalkyl group of R₁₃ and R₁₄ preferably has a total carbon number of 7 or more, more preferably a total carbon number of 7 to 15, and is preferably an alkoxy group having a monocyclic cycloalkyl group. The alkoxy group having a total carbon number of 7 or more and having a monocyclic cycloalkyl group indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, tert-butoxy and isoamyloxy and where the total carbon number inclusive of the carbon number of the substituent is 7 or more. Examples thereof include a cyclohexylmethoxy group, a cyclopentylethoxy group, and a cyclohexylethoxy group, with a cyclohexylmethoxy group being preferred.

Examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group, with a norbornylmethoxy group and a norbornylethoxy group being preferred.

Specific examples of the alkyl group in the alkylcarbonyl group of R₁₄ are the same as those of the alkyl group of R₁₃ to R₁₅.

The alkylsulfonyl or cycloalkylsulfonyl group of R₁, is a linear, branched or cyclic alkylsulfonyl group preferably having a carbon number of 1 to 10, and preferred examples thereof include a methanesulfonyl group, an ethanesulfonyl group, an n-propanesulfonyl group, an n-butanesulfonyl group, a cyclopentanesulfonyl group, and a cyclohexanesulfonyl group.

Examples of the substituent which may be substituted on each of the groups above include a halogen atom (e.g., fluorine), a hydroxyl group, a carboxyl group, a cyano group, a nitro group, an alkoxy group, an alkoxyalkyl group, an alkoxycarbonyl group, and an alkoxycarbonyloxy group.

Examples of the alkoxy group include a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

Examples of the alkoxyalkyl group include a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

Examples of the alkoxycarbonyl group include a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

Examples of the alkoxycarbonyloxy group include a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

The ring structure which may be formed by combining two R₁₅s with each other includes a 5- or 6-membered ring, preferably a 5-membered ring (that is, tetrahydrothiophene ring), formed by two R₁₅s together with the sulfur atom in formula (ZI-4) and may be fused with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. As for the substituent on the ring structure, a plurality of substituents may be present, and they may combine with each other to form a ring (for example, an aromatic or non-aromatic hydrocarbon ring, an aromatic or non-aromatic heterocyclic ring, or a polycyclic condensed ring formed by combining two or more of these rings).

In formula (ZI-4), R₁₅ is preferably, for example, a methyl group, an ethyl group, a naphthyl group, or a divalent group capable of forming a tetrahydrothiophene ring structure together with the sulfur atom when two R₁₅s are combined with each other.

The substituent which may be substituted on R₁₃ and R₁₄ is preferably a hydroxyl group, an alkoxy group, an alkoxycarbonyl group, or a halogen atom (particularly fluorine atom).

l is preferably 0 or 1, more preferably 1.

r is preferably from 0 to 2.

Specific examples of the cation in the compound represented by formula (ZI-4) for use in the present invention are illustrated below.

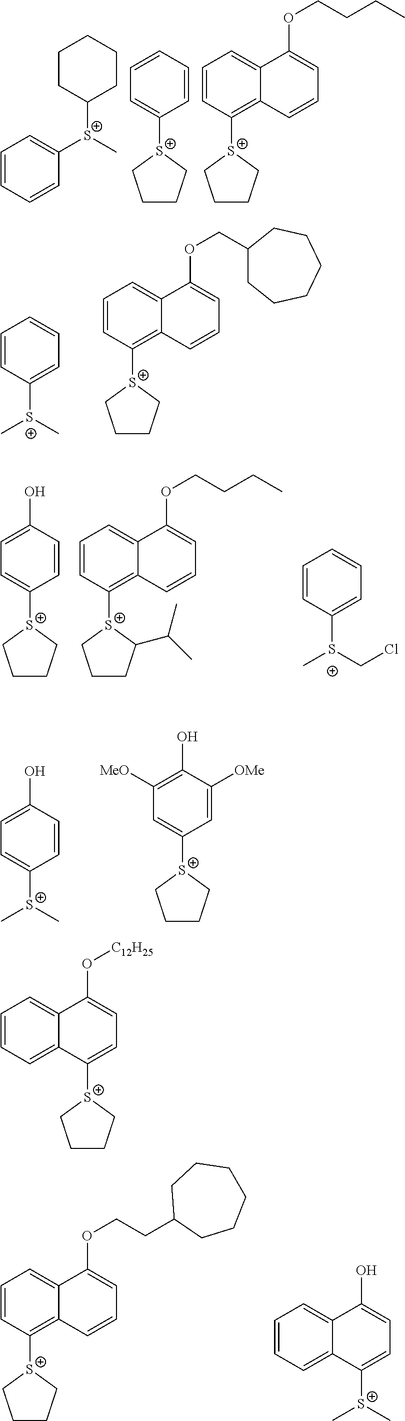

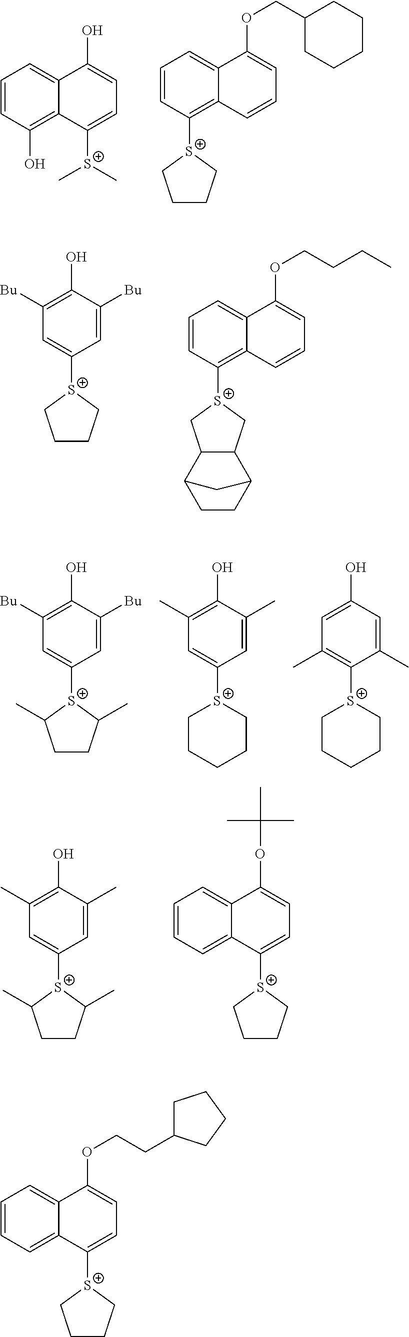

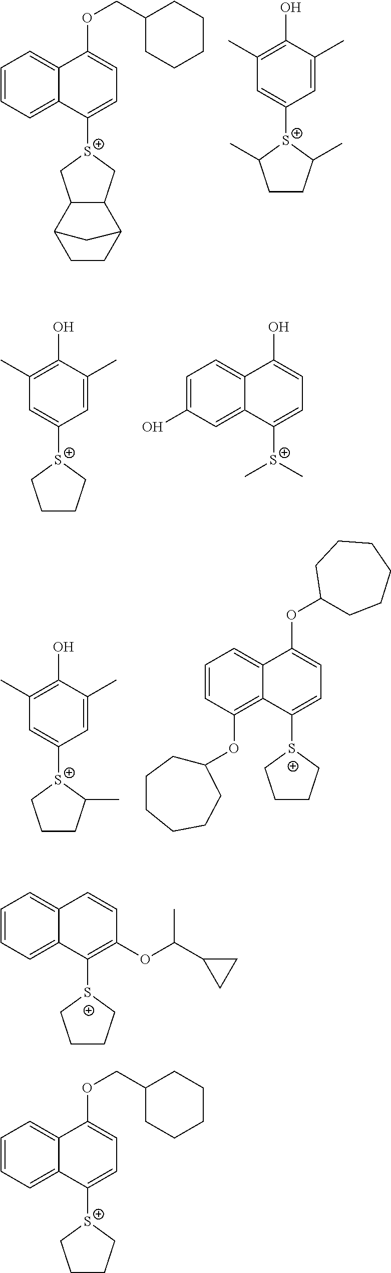

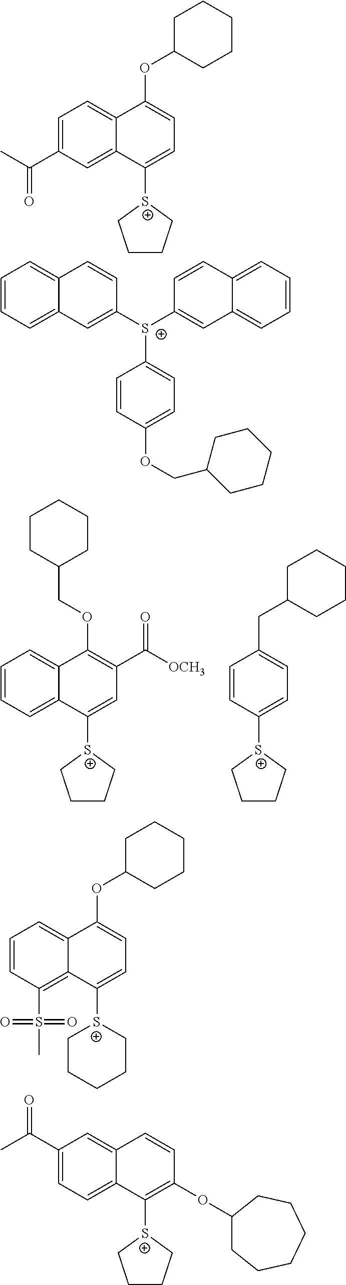 [SMILES: CC(=O)c1ccc2c(OC3CCCCC3)ccc([S+]3CCCC3)c2c1 ; c1ccc2cc([S+](c3ccc(OCC4CCCCC4)cc3)c3ccc4ccccc4c3)ccc2c1 ; COC(=O)c1cc([S+]2CCCC2)c2ccccc2c1OCC1CCCCC1 ; c1cc([S+]2CCCC2)ccc1CC1CCCCC1 ; CS(=O)(=O)c1cccc2c(OC3CCCCC3)ccc([S+]3CCCCC3)c12 ; CC(=O)c1ccc2c([S+]3CCCC3)c(OC3CCCCCC3)ccc2c1]

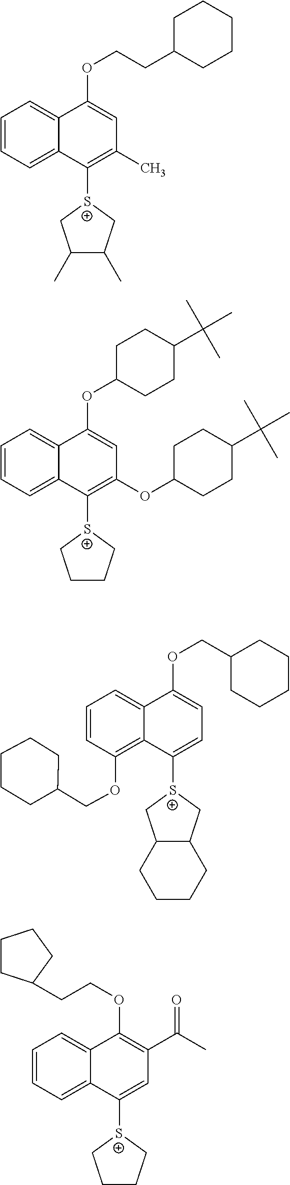 [SMILES: Cc1cc(OCCC2CCCCC2)c2ccccc2c1[S+]1CC(C)C(C)C1 ; CC(C)(C)C1CCC(Oc2cc(OC3CCC(C(C)(C)C)CC3)c3ccccc3c2[S+]2CCCC2)CC1 ; c1cc(OCC2CCCCC2)c2c([S+]3CC4CCCCC4C3)ccc(OCC3CCCCC3)c2c1 ; CC(=O)c1cc([S+]2CCCC2)c2ccccc2c1OCCC1CCCC1]

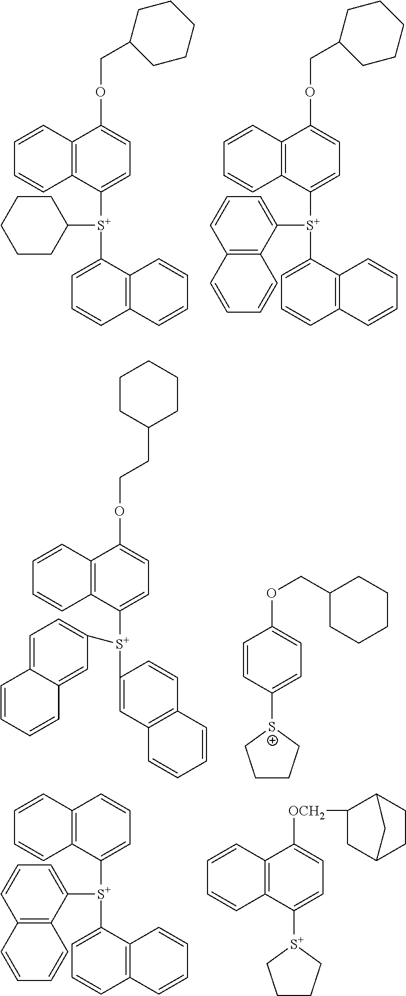

Formulae (ZII) and (ZIII) are described below.

In formulae (ZII) and (ZIII), each of R₂₀₄ to R₂₀₇ independently represents an aryl group, an alkyl group or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure containing an oxygen atom, a nitrogen atom, a sulfur atom or the like.

Examples of the skeletal structure of the aryl group having a heterocyclic structure include pyrrole, furan, thiophene, indole, benzofuran, and benzothiophene.

The alkyl group and cycloalkyl group in R₂₀₄ to R₂₀₇ are preferably a linear or branched alkyl group having a carbon number of 1 to 10 (e.g., methyl, ethyl, propyl, butyl, pentyl) and a cycloalkyl group having a carbon number of 3 to 10 (e.g., cyclopentyl, cyclohexyl, norbornyl).

The aryl group, alkyl group and cycloalkyl group of R₂₀₄ to R₂₀₇ may have a substituent. Examples of the substituent which may be substituted on the aryl group, alkyl group and cycloalkyl group of R₂₀₄ to R₂₀₇ include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group, and a phenylthio group.

Z⁻ represents a non-nucleophilic anion, and examples thereof are the same as those of the non-nucleophilic anion of Z⁻ in formula (ZI).

Other examples of the acid generator include compounds represented by the following formulae (ZIV), (ZV) and (ZVI):

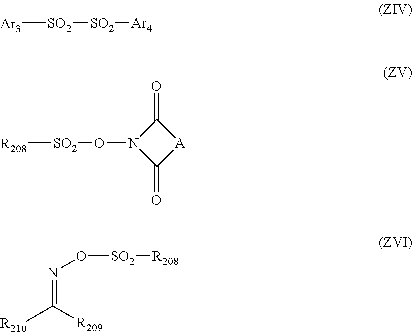

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group, or an aryl group.

A represents an alkylene group, an alkenylene group, or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI-1).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI-2).

The alkylene group of A includes an alkylene group having a carbon number of 1 to 12 (e.g., methylene, ethylene, propylene, isopropylene, butylene, isobutylene); the alkenylene group of A includes an alkenylene group having a carbon number of 2 to 12 (e.g., ethenylene, propenylene, butenylene); and the arylene group of A includes an arylene group having a carbon number of 6 to 10 (e.g., phenylene, tolylene, naphthylene).

Among the acid generators, more preferred are the compounds represented by formulae (ZI) to (ZIII).

Also, the acid generator is preferably a compound that generates an acid having one sulfonic acid group or imide group, more preferably a compound that generates a monovalent perfluoroalkanesulfonic acid, a compound that generates an aromatic sulfonic acid substituted with a monovalent fluorine atom or a fluorine atom-containing group, or a compound that generates an imide acid substituted with a monovalent fluorine atom or a fluorine atom-containing group, still more preferably a sulfonium salt of fluoro-substituted alkanesulfonic acid, fluorine-substituted benzenesulfonic acid, fluorine-substituted imide acid or fluorine-substituted methide acid. In particular, the acid generator which can be used is preferably a compound that generates a fluoro-substituted alkanesulfonic acid, a fluoro-substituted benzenesulfonic acid or a fluoro-substituted imide acid, where pKa of the acid generated is −1 or less, and in this case, the sensitivity is enhanced.

Among the acid generators, particularly preferred examples are illustrated below.

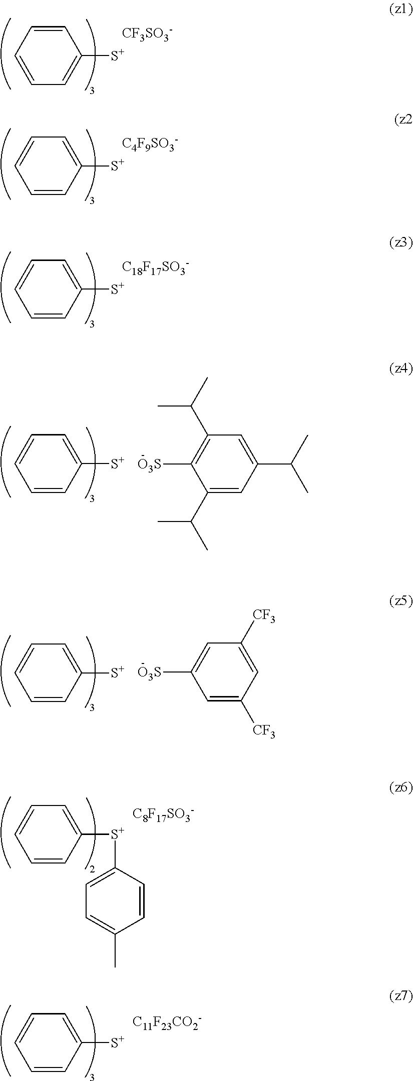

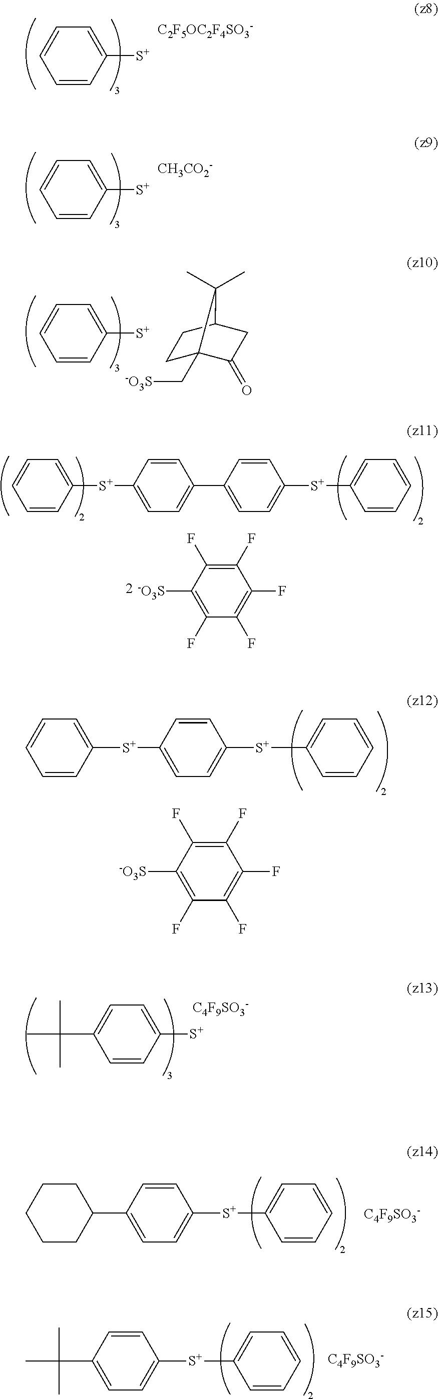

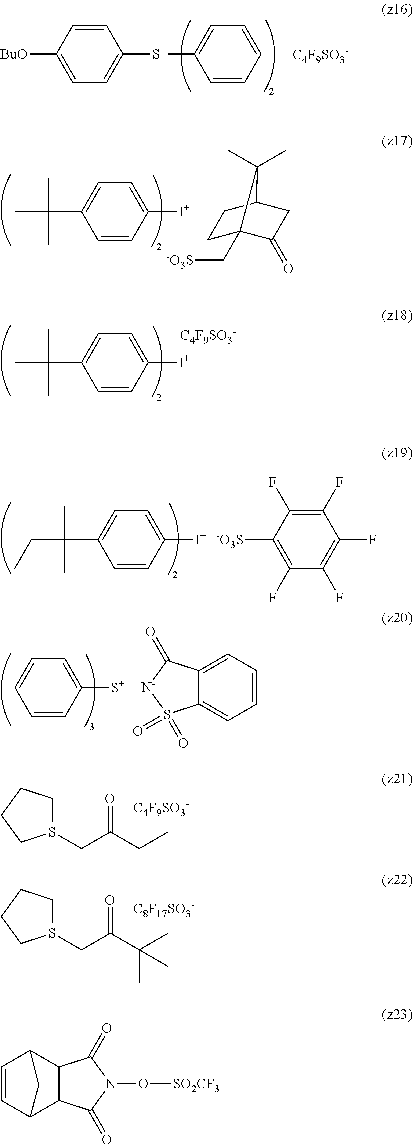

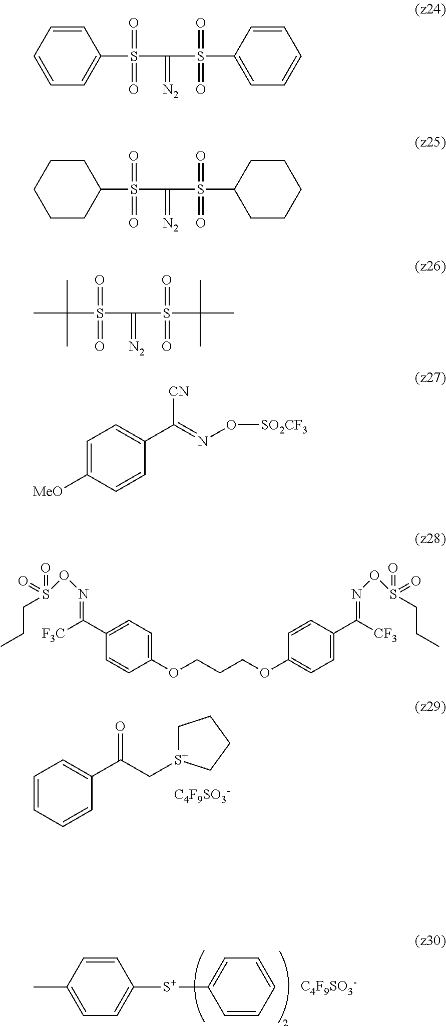

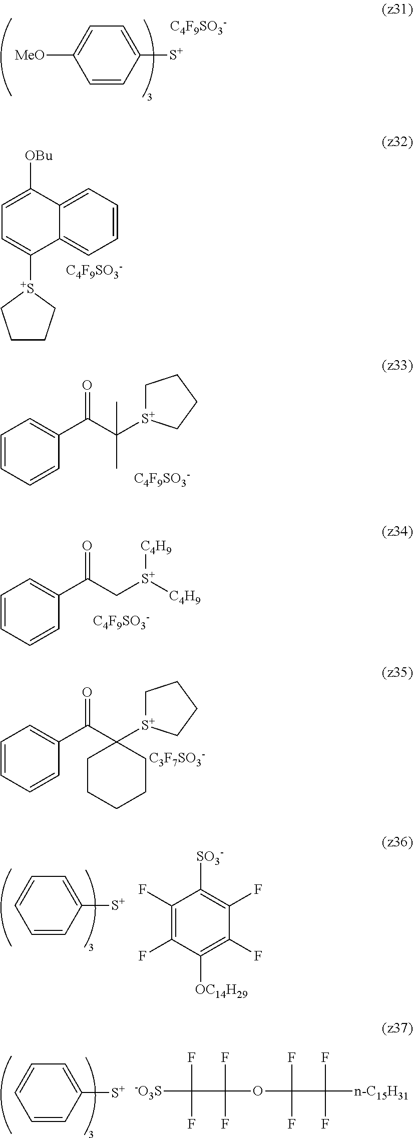

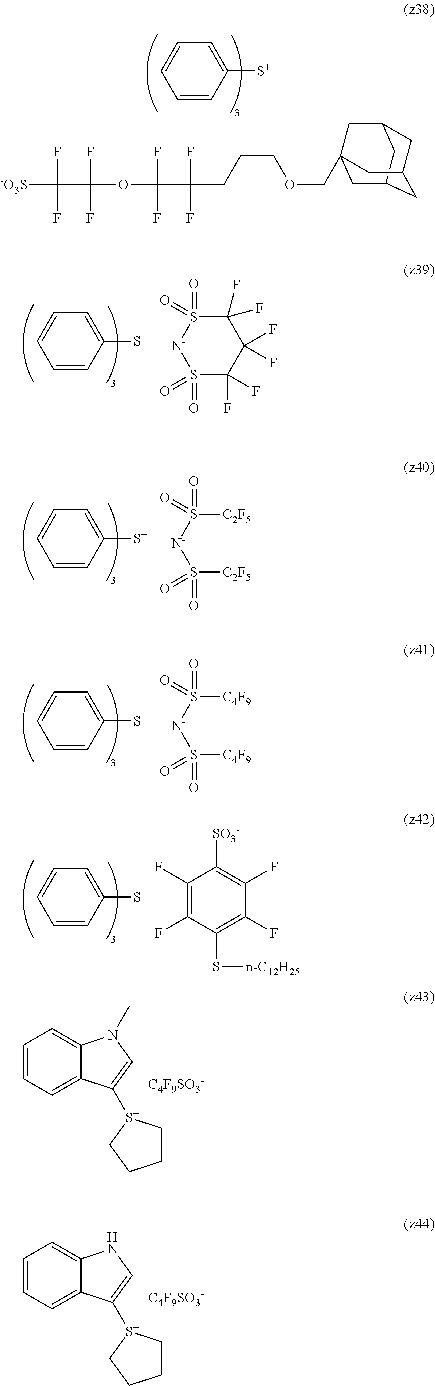

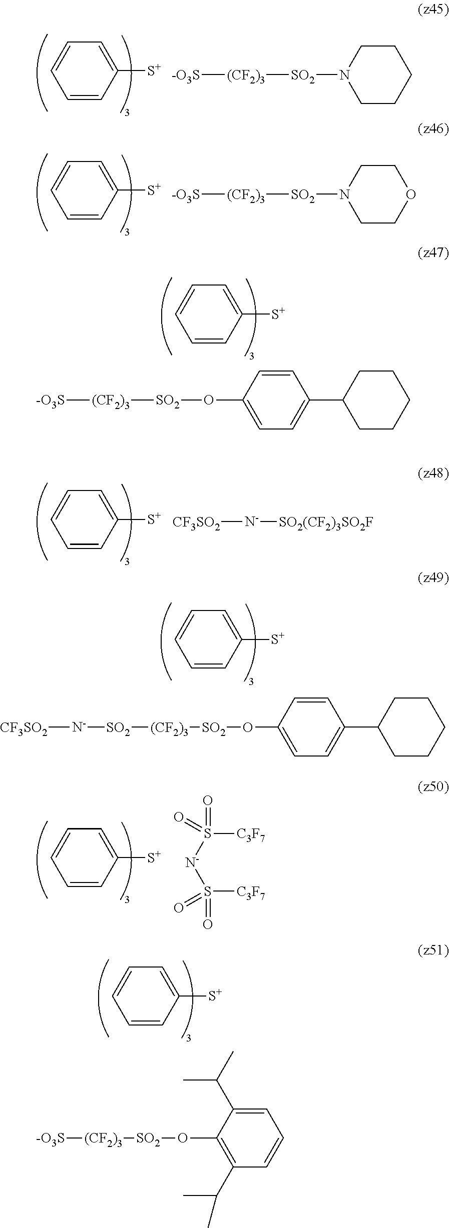

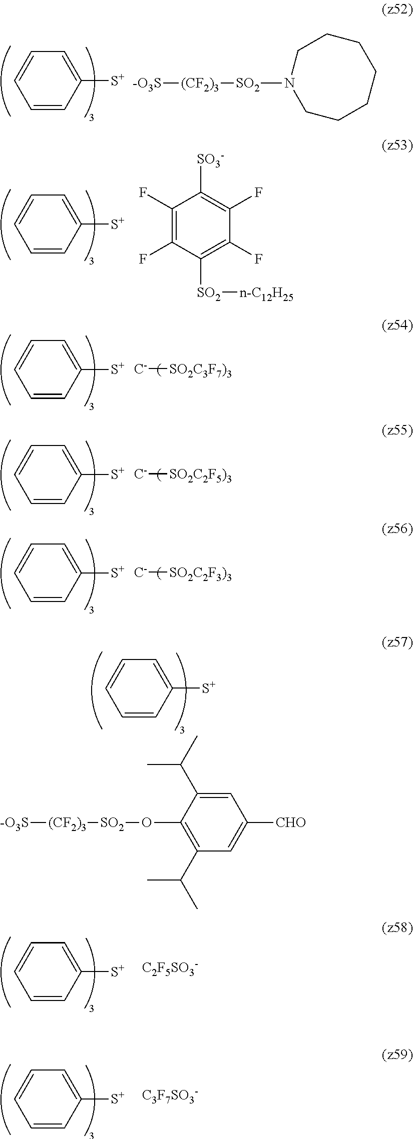

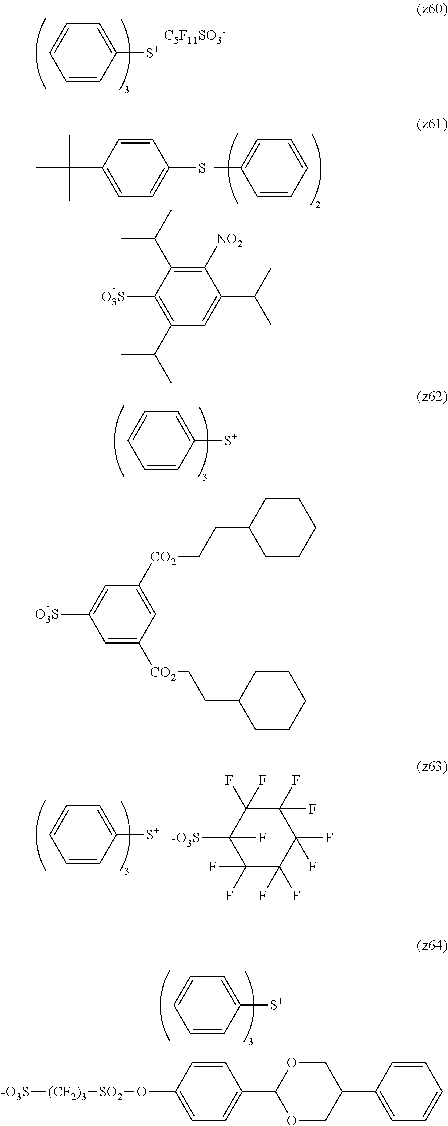

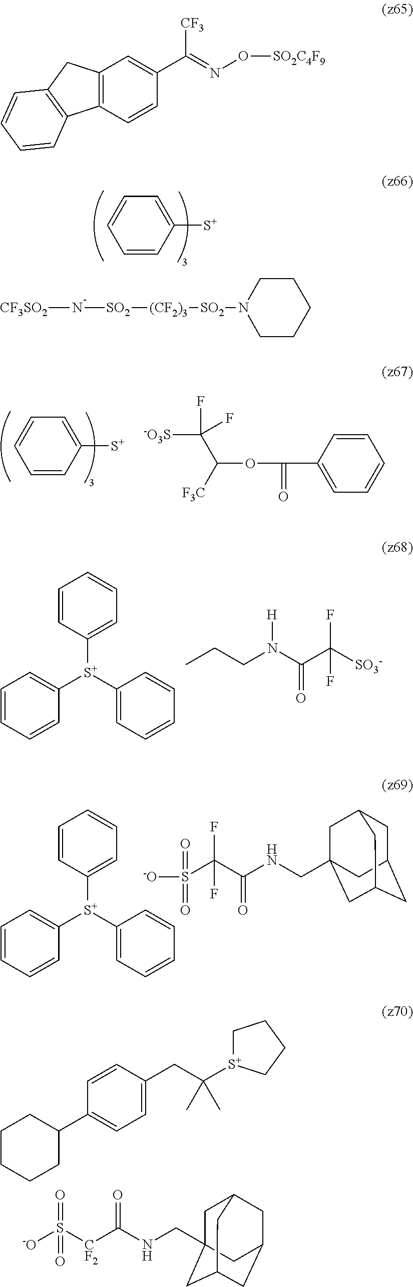

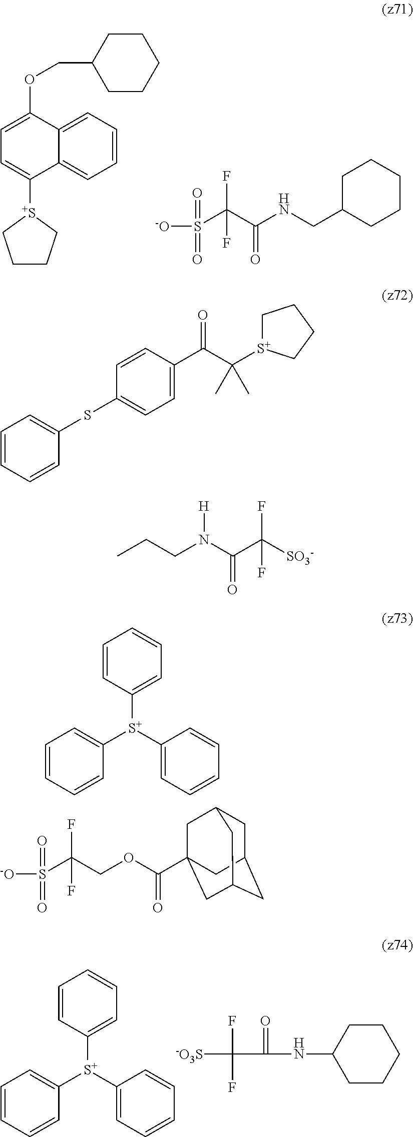

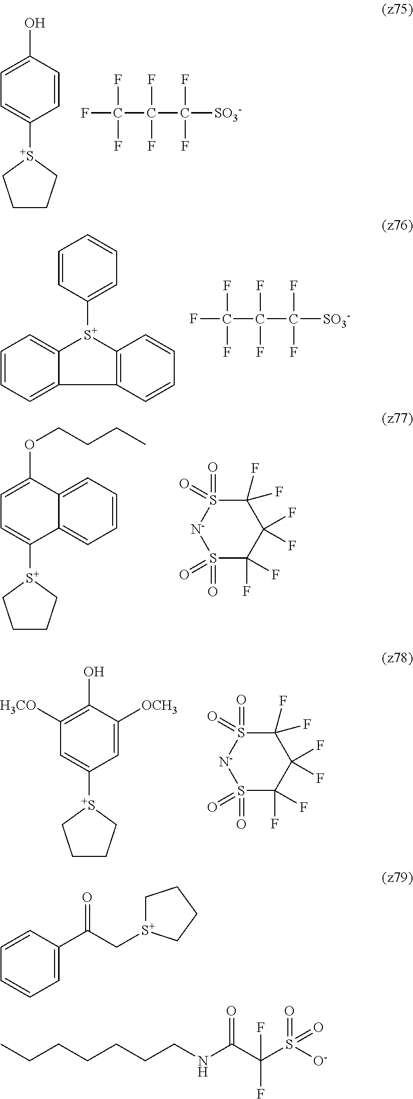

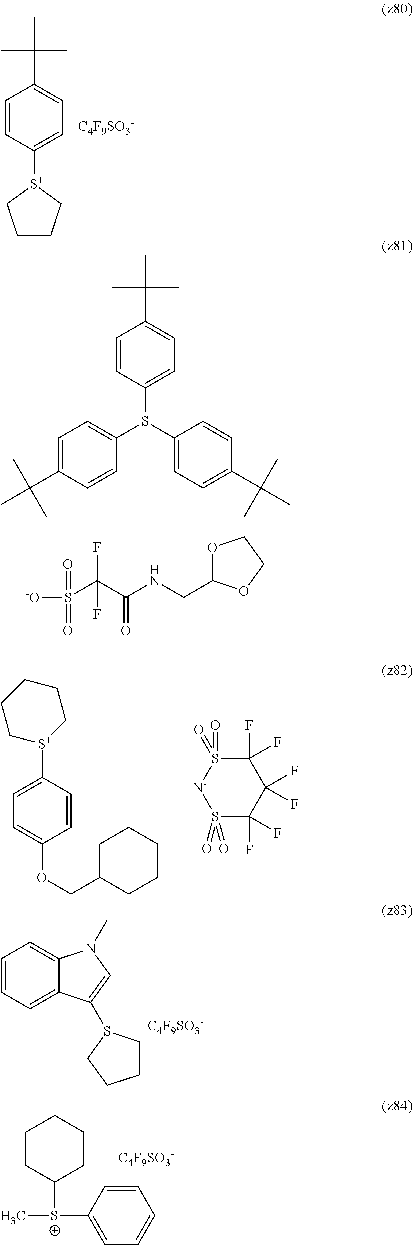

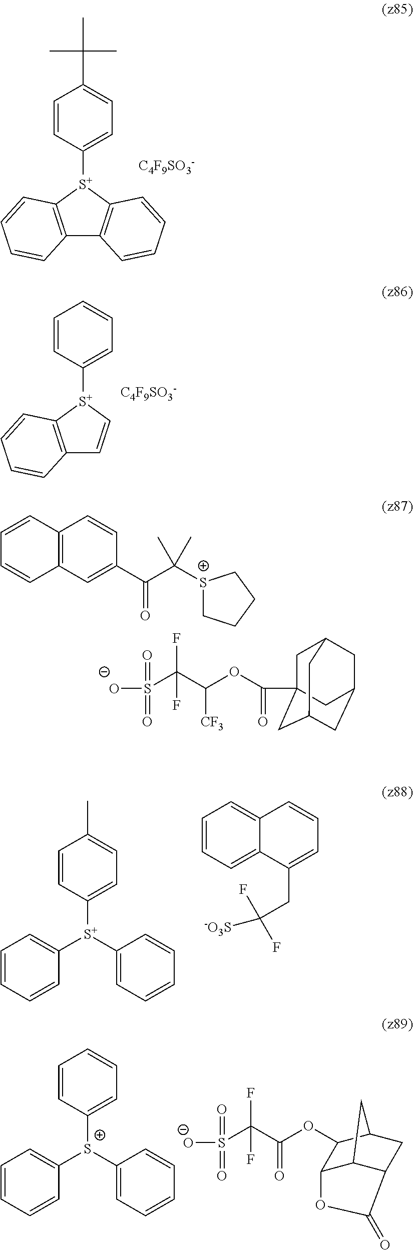

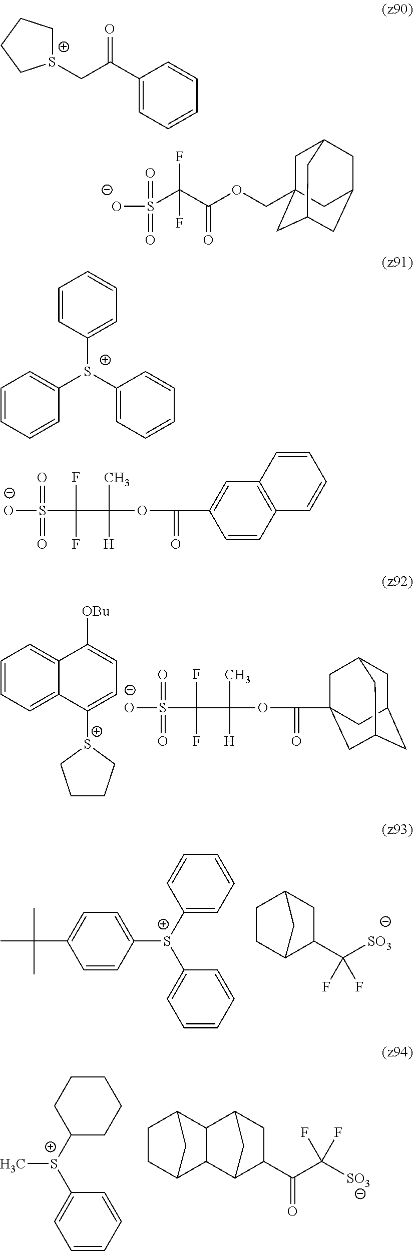

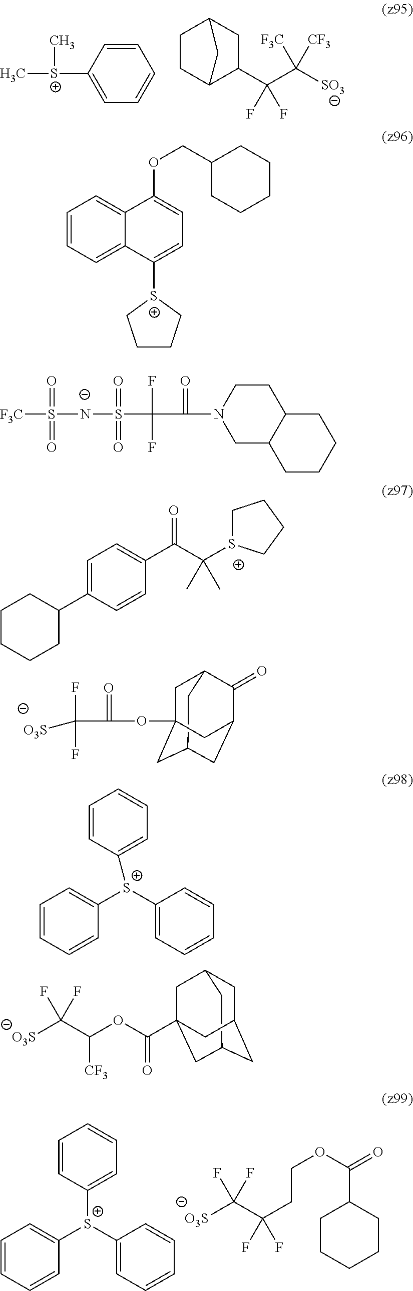

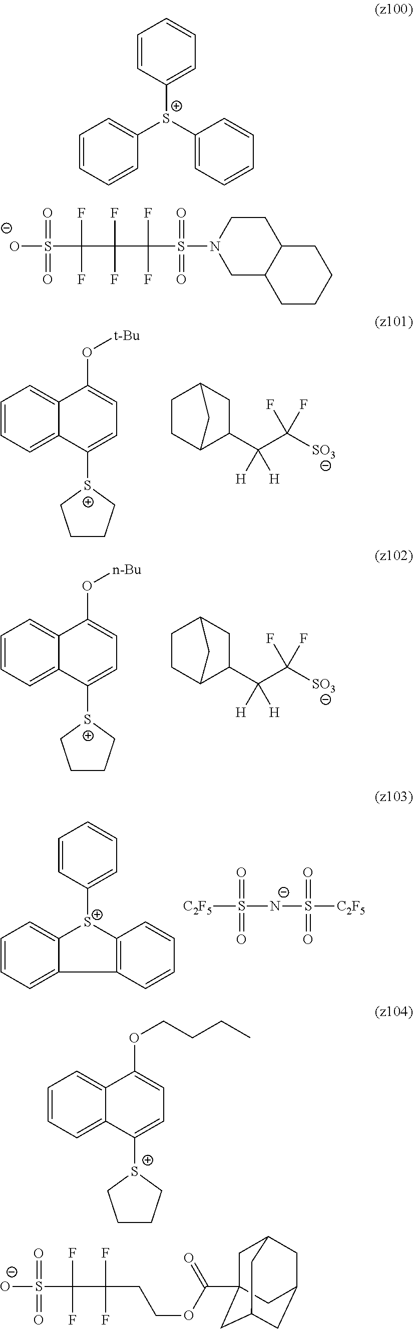

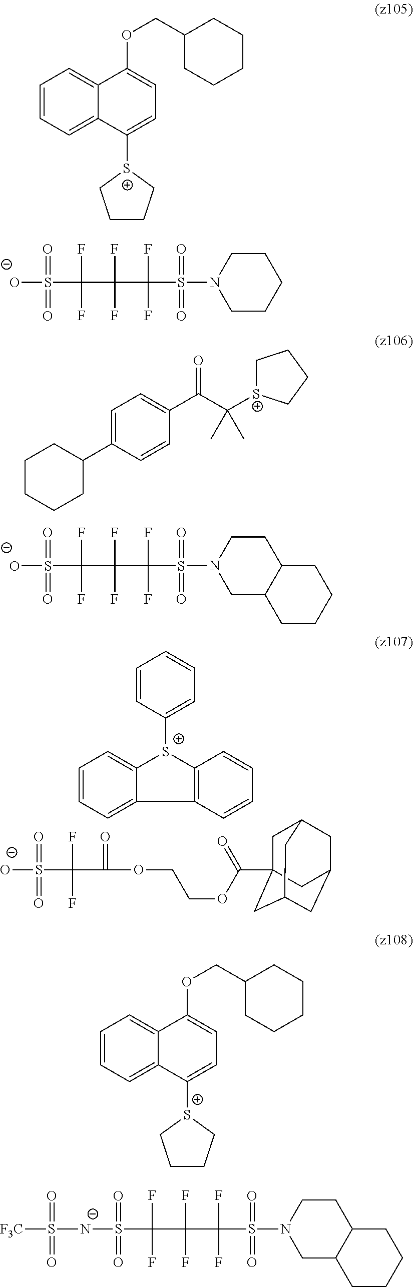

The acid generator can be synthesized by a known method, for example, can be synthesized according to the method described in JP-A-2007-161707.

As for the acid generator, one kind may be used alone, or two or more kinds may be used in combination.

The content of the compound capable of generating an acid upon irradiation with an actinic ray or radiation (excluding a case where the compound is represented by formula (ZI-3) or (ZI-4)) in the composition is preferably from 0.1 to 30 mass %, more preferably from 0.5 to 25 mass %, still more preferably from 3 to 20 mass %, yet still more preferably from 3 to 15 mass %, based on the total solid content of the actinic ray-sensitive or radiation-sensitive resin composition.

In the case where the acid generator is represented by formula (ZI-3) or (ZI-4), the content thereof is preferably from 5 to 35 mass %, more preferably from 8 to 30 mass %, still more preferably from 9 to 30 mass %, yet still more preferably from 9 to 25 mass %, based on the total solid content of the composition.

[3](C) Resin having at least one repeating unit (x) out of a repeating unit represented by the following formula (II) and a repeating unit represented by the following formula (III) and containing substantially neither fluorine atom nor silicon atom

The actinic ray-sensitive or radiation-sensitive resin composition of the present invention contains (C) a resin having at least one repeating unit (x) out of a repeating unit represented by the following formula (II) and a repeating unit represented by the following formula (III) and containing substantially neither fluorine atom nor silicon atom (hereinafter, sometimes referred to as “hydrophobic resin (C)” or simply as “resin (C)”).

The resin (C) contains substantially neither fluorine atom nor silicon atom. More specifically, the content of the repeating unit having a fluorine atom or a silicon atom is preferably 5 mol % or less, more preferably 3 mol % or less, still more preferably 1 mol % or less, based on all repeating units in the resin (C), and ideally, the content is 0 mol %, that is, the resin does not contain a fluorine atom and a silicon atom.

If the resin (C) substantially contains a fluorine atom or a silicon atom, the unexposed area of the resist film containing the resin (C) is considered to be enhanced in the affinity for an organic solvent-containing developer at the development, leading to an increase of scum.

The repeating unit represented by formula (II) is described in detail below.

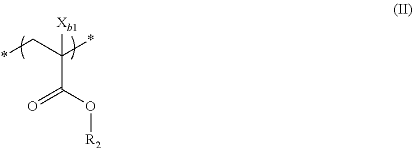

In formula (II), X_{b1} represents a hydrogen atom, an alkyl group, a cyano group or a halogen atom, and R₂ represents an organic group having one or more CH₃ partial structures and being stable to acid. Here, more specifically, the organic group stable to acid is preferably an organic group not having “a group capable of decomposing by the action of an acid to produce a polar group” described in the resin (A) above.

The alkyl group of X_{b1} is preferably an alkyl group having a carbon number of 1 to 4, and examples thereof include a methyl group, an ethyl group, a propyl group, a hydroxymethyl group, and a trifluoromethyl group, with a methyl group being preferred.

X_{b1} is preferably a hydrogen atom or a methyl group.

As described above, R₂ is an organic group having one or more CH₃ partial structures and being stable to acid.

The CH₃ partial structure as used herein is a partial structure represented by —CH₃ contained in the substituent represented by R₂ in the repeating unit represented by formula (II) and encompasses a CH₃ partial structure contained in an ethyl group, a propyl group or the like.

R₂ includes an alkyl group, a cycloalkyl group, an alkenyl group, a cycloalkenyl group, an aryl group, and an aralkyl group, each having one or more CH₃ partial structures.

These cycloalkyl, alkenyl, cycloalkenyl, aryl and aralkyl groups may further have an alkyl group as a substituent.

R₂ is preferably an alkyl group or an alkyl-substituted cycloalkyl group, each having one or more CH₃ partial structures.

The organic group having one or more CH₃ partial structures and being stable to acid of R₂ preferably contains from two to ten, more preferably from two to eight, CH₃ partial structures.

The alkyl group having at least one CH₃ partial structure of R₂ is preferably a branched alkyl group having a carbon number of 3 to 20. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. Among these, an isobutyl group, a tert-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group are more preferred.

The cycloalkyl group having at least one CH₃ partial structure of R₂ may be monocyclic or polycyclic and specifically includes a group having a carbon number of 5 or more and having a monocyclo, bicyclo, tricyclo or tetracyclo structure or the like. The carbon number thereof is preferably from 6 to 30, more preferably from 7 to 25. Preferred examples of the cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group, and a cyclododecanyl group. Among these, an adamantyl group, a norbornyl group, a cyclohexyl group, a cyclopentyl group, a tetracyclododecanyl group and a tricyclodecanyl group are more preferred, and a norbornyl group, a cyclopentyl group and a cyclohexyl group are still more preferred.

The alkenyl group having at least one CH₃ partial structure of R₂ is preferably a linear or branched alkenyl group having a carbon number of 1 to 20, more preferably a branched alkenyl group.

The aryl group having at least one CH₃ partial structure of R₂ is preferably an aryl group having a carbon number of 6 to 20, and examples thereof include a phenyl group and a naphthyl group, with a phenyl group being preferred.

The aralkyl group having at least one CH₃ partial structure of R₂ is preferably an aralkyl group having a carbon number of 7 to 12, and examples thereof include a benzyl group, a phenethyl group and a naphthylmethyl group.

Specific examples of the hydrocarbon group having at least two CH₃ partial structures of R₂ include an isopropyl group, an isobutyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-tert-butylcyclohexyl group, and an isobornyl group. Among these, an isobutyl group, a tert-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-tert-butylcyclohexyl group and an isobornyl group are preferred.

Specific preferred examples of the repeating unit represented by formula (II) are illustrated below, but the present invention is not limited thereto.

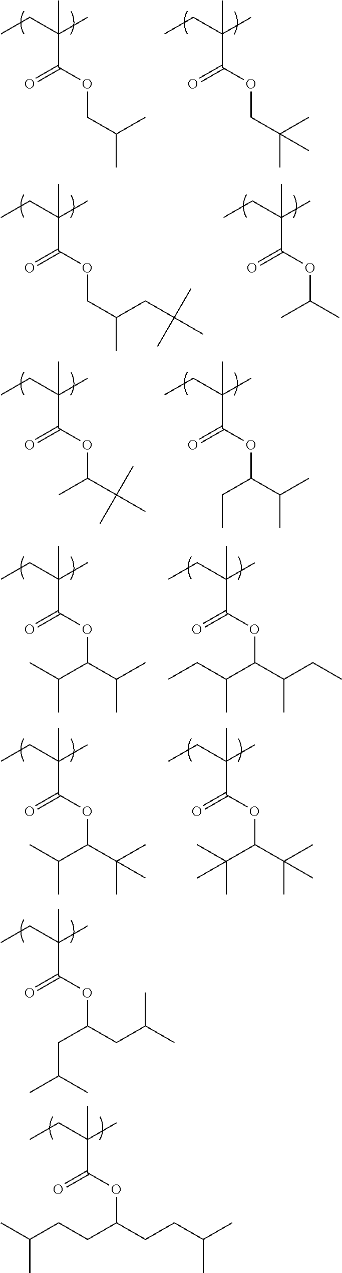

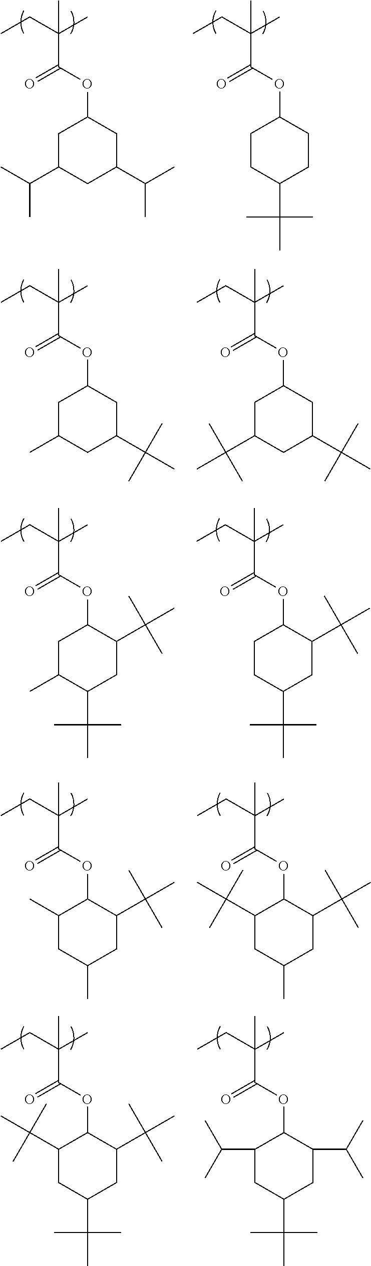

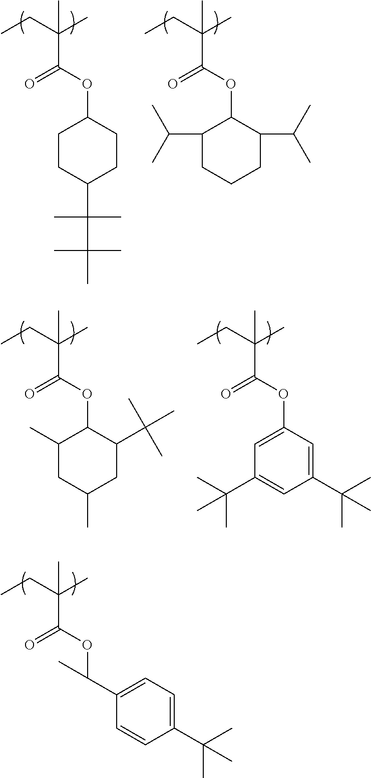

The repeating unit represented by formula (II) is preferably a repeating unit stable to acid (non-acid-decomposable repeating unit) and specifically, is preferably a repeating unit free from a group capable of decomposing by the action of an acid to produce a polar group.

The repeating unit represented by formula (III) is described in detail below.

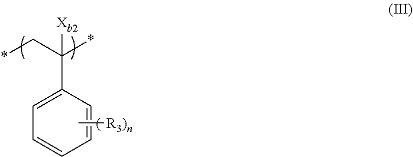

In formula (III), X_{b2} represents a hydrogen atom, an alkyl group, a cyano group or a halogen atom, R₃ represents an organic group having one or more CH₃ partial structures and being stable to acid, and n represents an integer of 1 to 5.

The alkyl group of X_{b2} is preferably an alkyl group having a carbon number of 1 to 4 and examples thereof include a methyl group, an ethyl group, a propyl group, a hydroxymethyl group and a trifluoromethyl group.

X_{b2} is preferably a hydrogen atom.

R₃ is an organic group stable to acid and therefore, more specifically, is preferably an organic group free from “a group capable of decomposing by the action of an acid to produce a polar group”, which is described in the resin (A) above.

R₃ includes an alkyl group having one or more CH₃ partial structures.

The organic group having one or more CH₃ partial structures and being stable to acid of R₃ preferably contains from one to ten, more preferably from one to eight, still more preferably from one to six, CH₃ partial structures.

The alkyl group having at least one CH₃ partial structure of R₃ is preferably a branched alkyl group having a carbon number of 3 to 20. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethyhexyl group, a 2,6-dimethylheptyl group, a 1,5-dimethyl-3-heptyl group and a 2,3,5,7-tetramethyl-4-heptyl group. Among these, an isobutyl group, a tert-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

Specific examples of the alkyl group having at least two CH₃ partial structures of R, include an isopropyl group, an isobutyl group, a tert-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. Among these, those having a carbon number of 5 to 20, that is, an isobutyl group, a tert-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and a 2,6-dimethylheptyl group, are preferred.

n represents an integer of 1 to 5, preferably an integer of 1 to 3, more preferably an integer of 1 to 2.

Specific preferred examples of the repeating unit represented by formula (III) are illustrated below, but the present invention is not limited thereto.

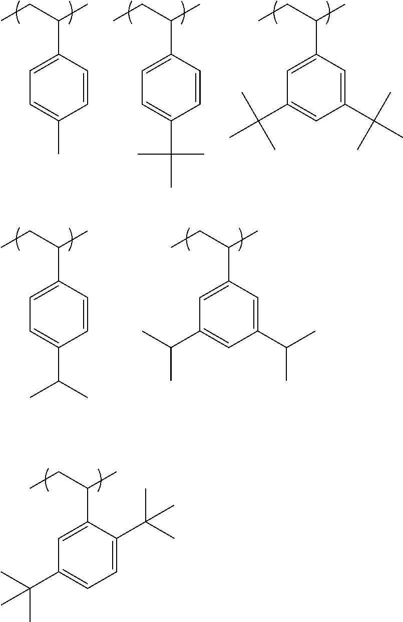

The repeating unit represented by formula (III) is preferably a repeating unit stable to acid (non-acid-decomposable repeating unit) and specifically, is preferably a repeating unit free from a group capable of decomposing by the action of an acid to produce a polar group.

The content of the at least one repeating unit (x) out of a repeating unit represented by formula (II) and a repeating unit represented by formula (II) is preferably 90 mol % or more, more preferably 95 mol % or more, based on all repeating units in the resin (C). The content is usually 100 mol % or less based on all repeating units in the resin (C).

If the content of the at least one repeating unit (x) out of a repeating unit represented by formula (II) and a repeating unit represented by formula (III) is less than 90 mol % based on all repeating units in the resin (C), the surface free energy of the resin (C) is increased and in turn, the resin (C) is less likely to be unevenly distributed to the surface of the resist film, as a result, the static/dynamic contact angle of the resist film for water is decreased and a residual water defect is readily produced.

The repeating unit (x) preferably contains at least one repeating unit out of “(II′) a repeating unit where in formula (II), R₂ is a group having three or more CH₃ partial structures” and “(III′) a repeating unit where in formula (III), R₃ is a group having three or more CH₃ partial structures”.

When the repeating unit (x) contains at least one repeating unit out of repeating units (II′) and (III′), the surface free energy of the resin (C) is more reduced and as described above, the solubility of the resin (C) in the surface layer part of the resist film for an organic solvent-containing developer is more increased. This is considered to ensure that in the negative resist pattern formation, the solubility of the unexposed area for a developer is enhanced and the bridge margin is improved.

The content of the at least one repeating unit out of the repeating unit (II′) and the repeating unit (III′) is preferably 10 mol % or more, more preferably 20 mol % or more, still more preferably 30 mol % or more, based on all repeating units in the resin (C).

In the repeating unit (II′), R₂ is preferably a group containing from three to ten, more preferably from three to eight, CH₃ partial structures.

In the repeating unit (III′), R₃ is preferably a group containing from three to ten, more preferably from three to eight, CH₃ partial structures.

Furthermore, if the resin (C) is kept from unevenly distributing to the surface of the resist film, the reaction to make the resist film insoluble or slightly soluble in an organic solvent-containing developer is prevented from uniformly proceeding with respect to the thickness direction of the resist film, as a result, the pattern dimension uniformity and exposure latitude (EL) are likely to be deteriorated in the region defining a hole pattern.

The resin (C) may also appropriately contain other repeating units different from the repeating unit represented by formula (II) or (III).

Other repeating units include, for example, a repeating unit having an acid-decomposable group, a repeating unit having a lactone structure, a repeating unit having a hydroxyl group or a cyano group, a repeating unit having an acid group (alkali-soluble group), and a repeating unit having an alicyclic hydrocarbon structure free from a polar group and not exhibiting acid decomposability.

However, the resin (C) is preferably stable to acid. Specifically, in the pattern forming method of the present invention, the resin (C) is preferably not decomposed by the action of an acid generated from the acid generator through (ii) the step of exposing the film and a post-exposure baking step (PEB) that is preferably performed, and (iii) the step of performing development by using an organic solvent-containing developer to form a negative pattern. More specifically, the resin (C) is preferably free from a repeating unit capable of decomposing by the action of an acid to produce a polar group. Still more specifically, the content of the repeating unit capable of decomposing by the action of an acid to produce a polar group is preferably 5 mol % or less, more preferably 3 mol % or less, still more preferably 1 mol % or less, based on all repeating units in the resin (C), and ideally, the content is 0 mol %, that is, it is preferred that the resin (C) does not contain a repeating unit capable of decomposing by the action of an acid to produce a polar group.

In addition, the resin (C) is preferably stable to alkali and specifically, is preferably substantially free from a group capable of being decomposed by an alkali, typified by (y) a lactone structure-containing group, an acid anhydride group or an imide group, which may be contained in the later-described resin (D). More specifically, in the resin (C), the content of the repeating unit having a group capable of being decomposed by an alkali is preferably 5 mol % or less, more preferably 3 mol % or less, still more preferably 1 mol % or less, based on all repeating units in the resin (C), and above all, the content is preferably 0 mol %, that is, it is particularly preferred that the resin (C) does not contain a repeating unit having a group capable of being decomposed by an alkali.

Specific preferred examples of other repeating units which may be contained in the resin (C) are illustrated below, but the present invention is not limited thereto. In the formulae, Ra represents H, CH₃, CH₂OH or CF₃.

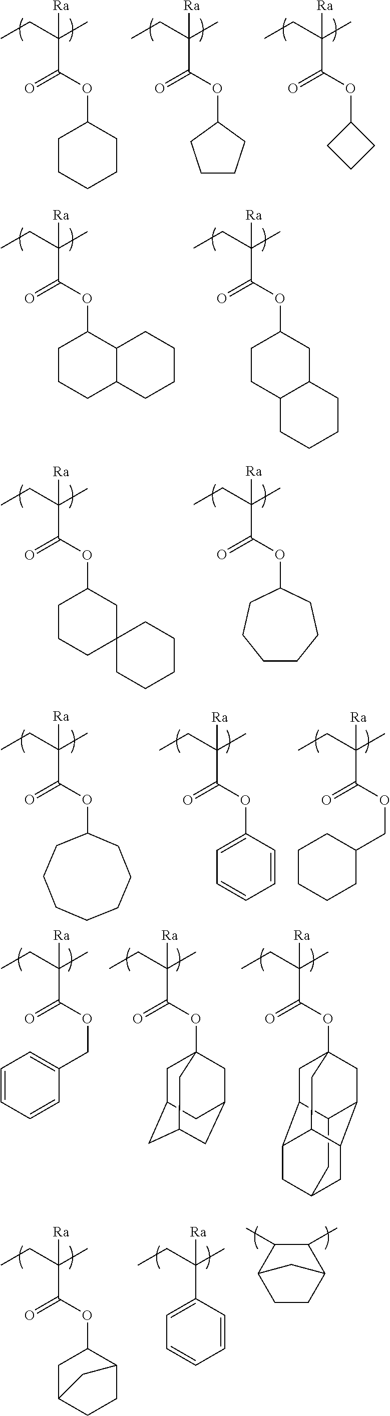

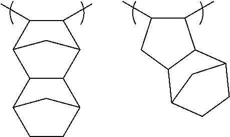

The resin (C) may or may not contain the above-described other repeating units, but in the case of containing other repeating units, the content thereof is preferably from 1 to 10 mol %, more preferably from 1 to 8 mol %, still more preferably from 1 to 5 mol %, based on all repeating units in the resin (C).

The weight average molecular weight of the hydrophobic resin (C) is, in terms of polystyrene by the GPC method, preferably 1,000 or more, more preferably 5,000 or more, still more preferably 15,000 or more.

As for the hydrophobic resin (C), one resin may be used, or a plurality of resins may be used in combination.

The content of the hydrophobic resin (C) in the composition is preferably from 0.01 to 20 mass %, more preferably from 0.05 to 15 mass %, still more preferably from 0.1 to 8 mass %, based on the total solid content of the composition of the present invention.

As the hydrophobic resin (C), various commercially available products may be used, or the resin may be synthesized by an ordinary method (for example, radical polymerization).

Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred.

The reaction solvent, the polymerization initiator, the reaction conditions (such as temperature and concentration), and the method for purification after reaction are the same as those described for the resin (P).

Specific examples of the resin (C) are illustrated below. Also, the molar ratio of repeating units (corresponding to respective repeating units starting from the left), weight average molecular weight and polydispersity of each resin are shown in Table 1 below.

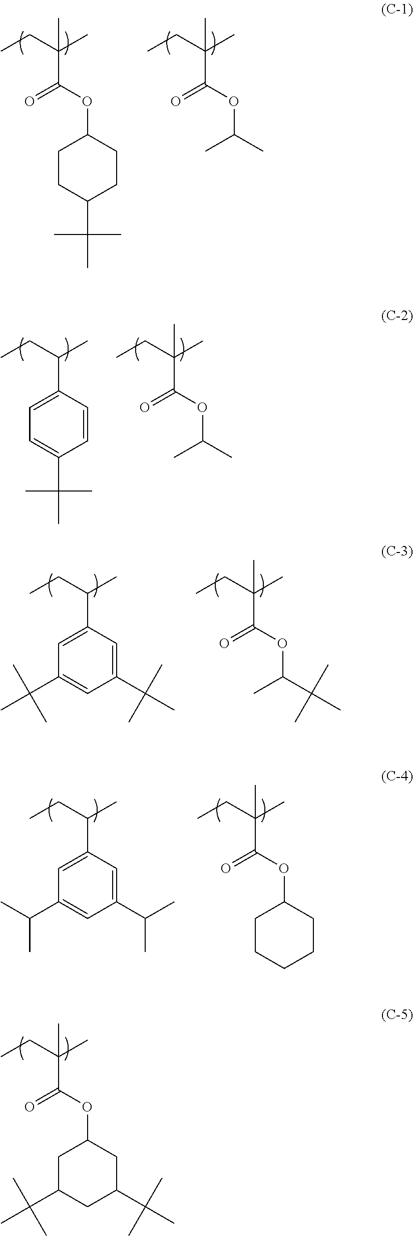

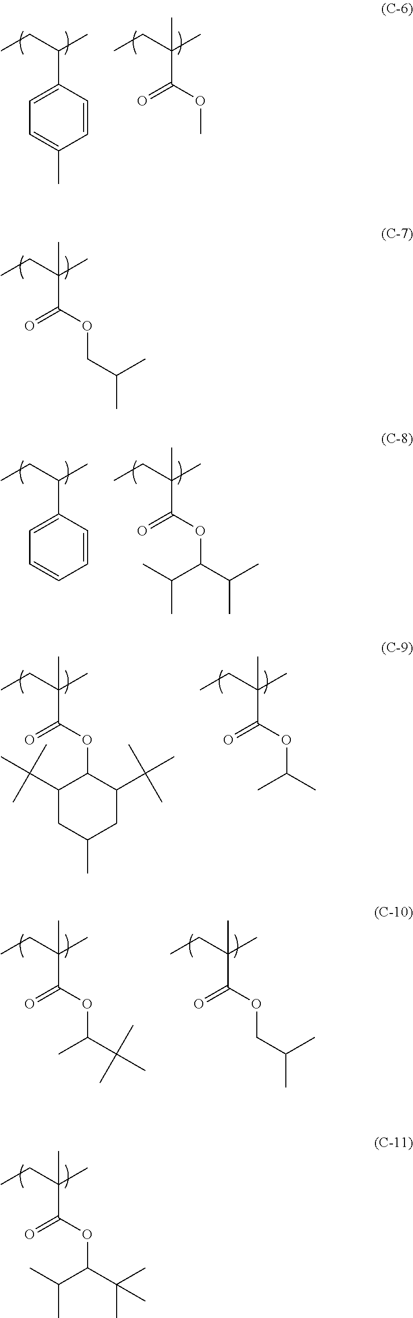

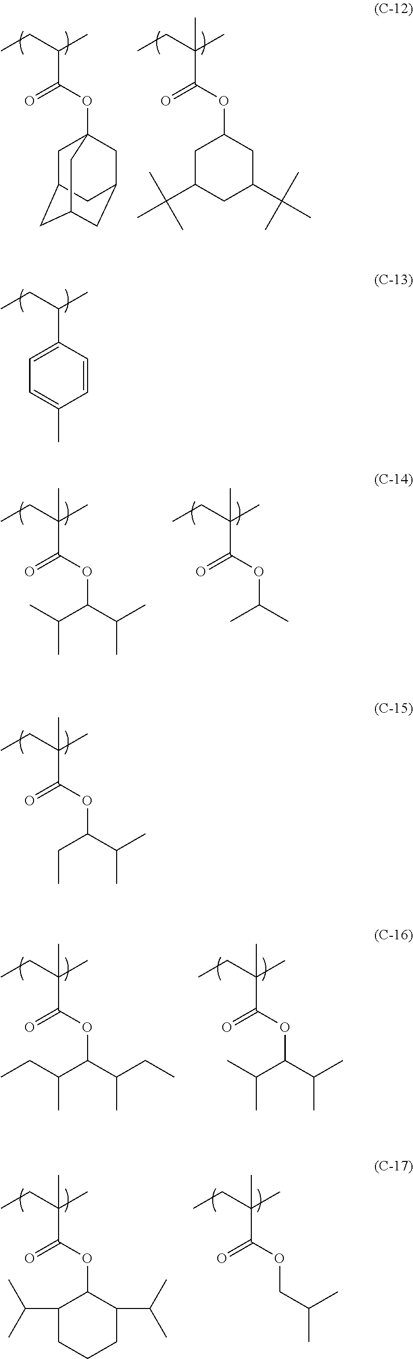

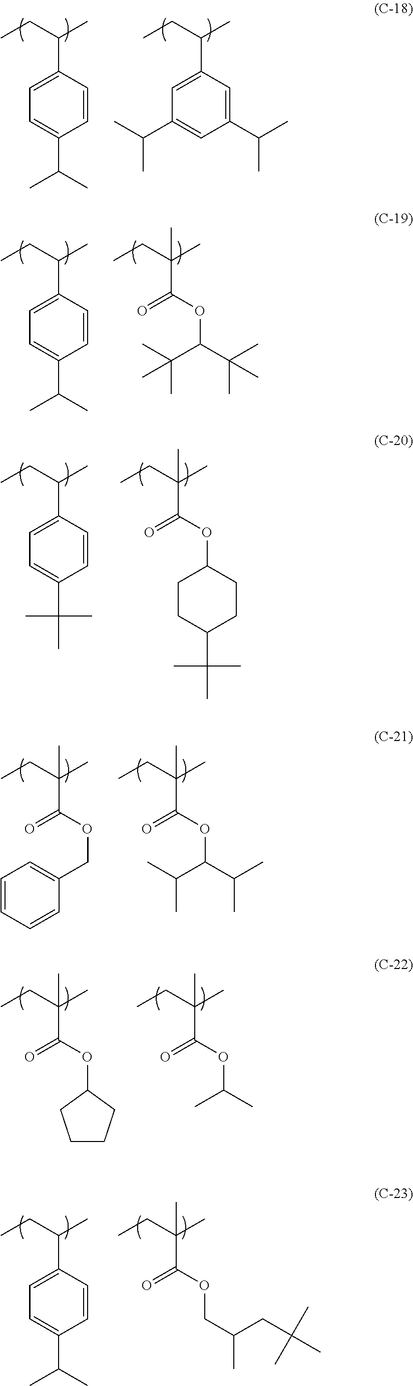

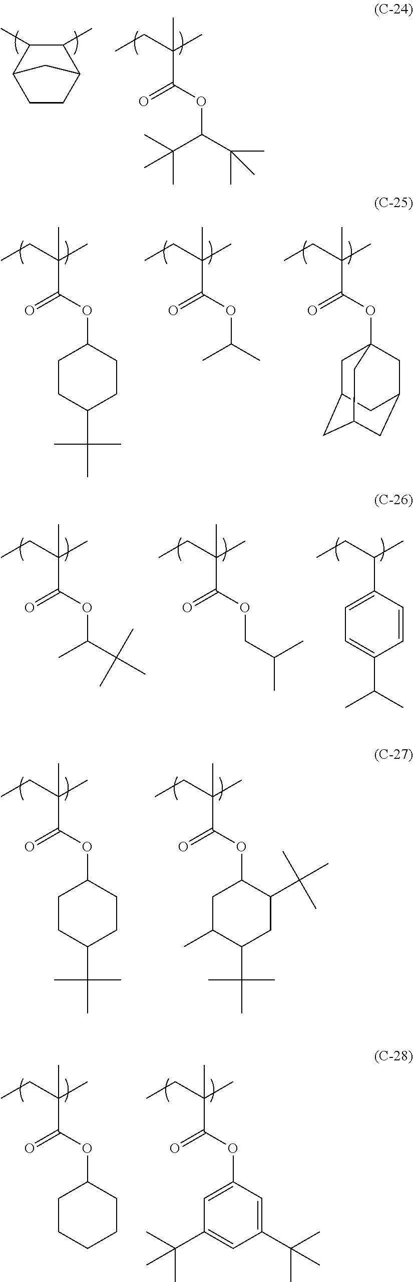

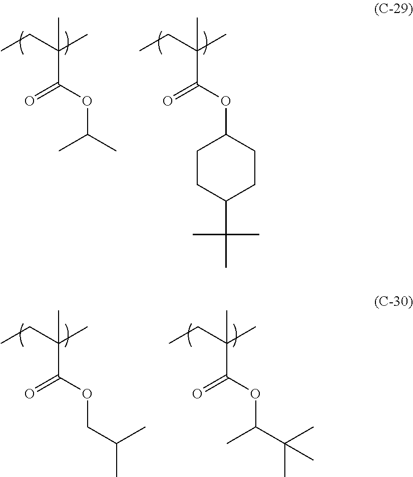

TABLE 1

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |
| C-29 | 90/10 | 21500 | 1.78 |
| C-30 | 80/20 | 8900 | 1.83 |

[5](D) Combined hydrophobic resin having at least either a fluorine atom or a silicon atom and being different from the resin (A) and the resin (C)

The actinic ray-sensitive or radiation-sensitive resin composition of the present invention may contain a hydrophobic resin having at least either a fluorine atom or a silicon atom and being different from the resin (A) and the resin (C) (hereinafter, sometimes referred to as “combined hydrophobic resin (D)” or simply as “resin (D)”), particularly when the composition is applied to immersion exposure. The combined hydrophobic resin (D) is unevenly distributed to the film surface layer and when the immersion medium is water, the static/dynamic contact angle of the resist film surface for water as well as the followability of immersion liquid can be enhanced.

The combined hydrophobic resin (D) is preferably designed to, as described above, be unevenly distributed to the interface but unlike a surfactant, need not have necessarily a hydrophilic group in the molecule and may not contribute to uniform mixing of polar/nonpolar substances.

The combined hydrophobic resin (D) contains a fluorine atom and/or a silicon atom. The fluorine atom and/or silicon atom in the combined hydrophobic resin (D) may be contained in the main chain of the resin or may be contained in the side chain.

In the case where the combined hydrophobic resin (D) contains a fluorine atom, the resin preferably contains a fluorine atom-containing alkyl group, a fluorine atom-containing cycloalkyl group or a fluorine atom-containing aryl group, as a fluorine atom-containing partial structure.

The fluorine atom-containing alkyl group (preferably having a carbon number of 1 to 10, more preferably a carbon number of 1 to 4) is a linear or branched alkyl group with at least one hydrogen atom being substituted for by a fluorine atom and may further have a substituent other than fluorine atom.

The fluorine atom-containing cycloalkyl group is a monocyclic or polycyclic cycloalkyl group with at least one hydrogen atom being substituted for by a fluorine atom and may further have a substituent other than fluorine atom.

The fluorine atom-containing aryl group is an aryl group such as phenyl group or naphthyl group with at least one hydrogen atom being substituted for by a fluorine atom and may further have a substituent other than fluorine atom.

As the fluorine atom-containing alkyl group, fluorine atom-containing cycloalkyl group and fluorine atom-containing aryl group, the groups represented by the following formulae (F2) to (F4) are preferred, but the present invention is not limited thereto.

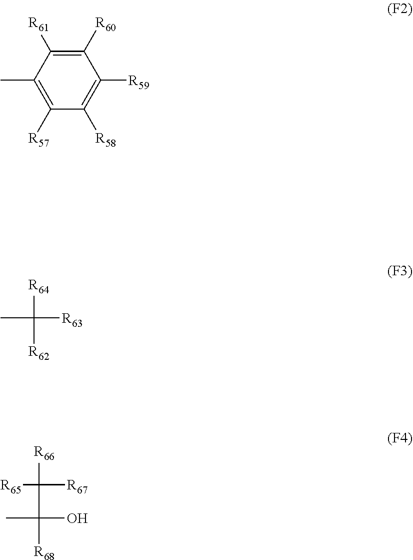

In formulae (F2) to (F4), each of R₅₇ to R₆₈ independently represents a hydrogen atom, a fluorine atom, or an alkyl group (linear or branched), provided that at least one of R₅₇ to R₆₁, at least one of R₆₂ to R₆₄, and at least one of R₆₅ to R₆₈ each independently represents a fluorine atom or an alkyl group (preferably having a carbon number of 1 to 4) with at least one hydrogen atom being substituted for by a fluorine atom.

It is preferred that all of R₅₇ to R₆₁ and R₆₅ to R₆₇ are a fluorine atom. Each of R₆₂, R₆₃ and R₆₈ is preferably an alkyl group (preferably having a carbon number of 1 to 4) with at least one hydrogen atom being substituted for by a fluorine atom, more preferably a perfluoroalkyl group having a carbon number of 1 to 4. R₆₂ and R₆₃ may combine with each other to form a ring.

Specific examples of the group represented by formula (F2) include a p-fluorophenyl group, a pentafluorophenyl group, and a 3,5-di(trifluoromethyl)phenyl group.

Specific examples of the group represented by formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Among these, a hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

The fluorine atom-containing partial structure may be bonded directly to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more of these groups and bonds.

Specific examples of the repeating unit having a fluorine atom are illustrated below, but the present invention is not limited thereto.

In specific examples, X₁ represents a hydrogen atom, —CH₃, —F or —CF₃. X₂ represents —F or —CF₃.

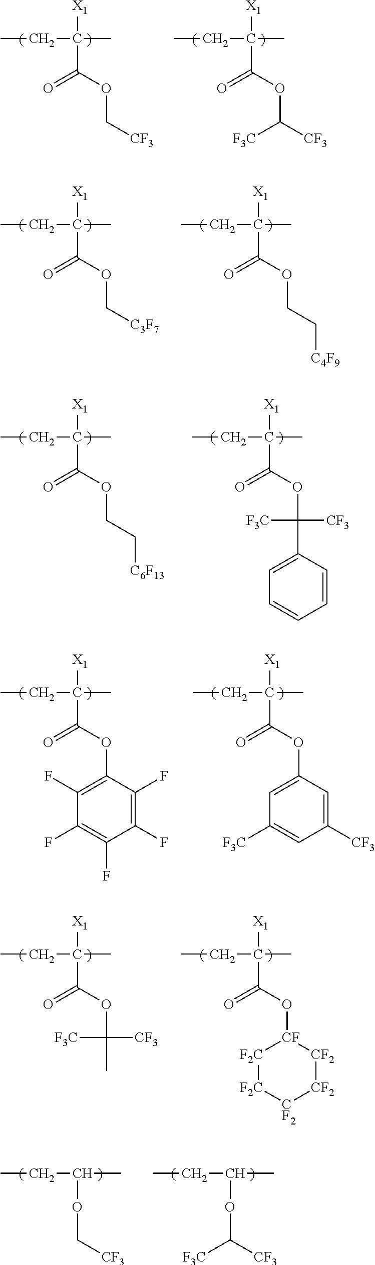

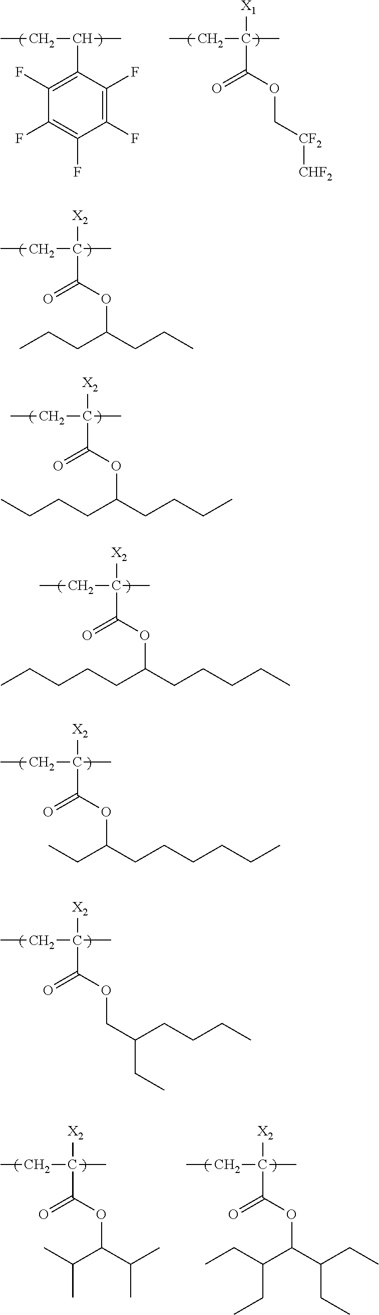

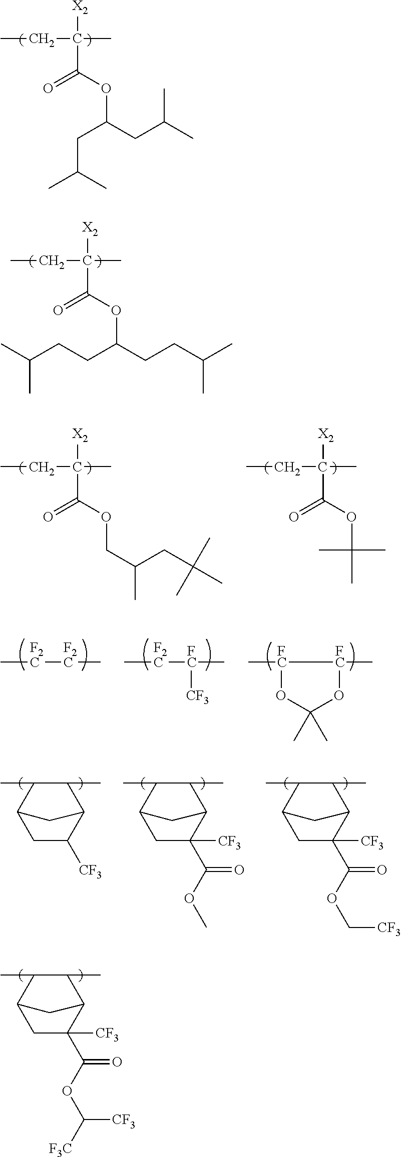

The combined hydrophobic resin (D) may contain a silicon atom. The resin preferably has an alkylsilyl structure (preferably a trialkylsilyl group) or a cyclic siloxane structure, as a silicon atom-containing partial structure.

Specific examples of the alkylsilyl structure and cyclic siloxane structure include groups represented by the following formulae (CS-1) to (CS-3):

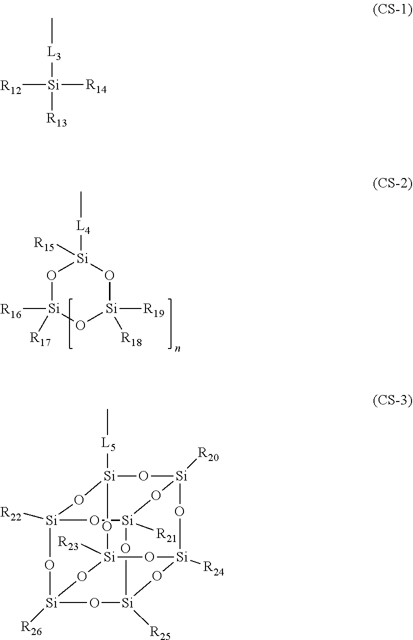

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group is a sole member or a combination of two or more members (preferably having a total carbon number of 12 or less), selected from the group consisting of an alkylene group, a phenylene group, an ether bond, a thioether bond, a carbonyl group, an ester bond, an amide bond, a urethane bond and a urea bond.

n represents an integer of 1 to 5. n is preferably an integer of 2 to 4.

Specific examples of the repeating unit having a group represented by formulae (CS-1) to (CS-3) are illustrated below, but the present invention is not limited thereto. In specific examples, X₁ represents a hydrogen atom, —CH₃, —F or —CF₃.

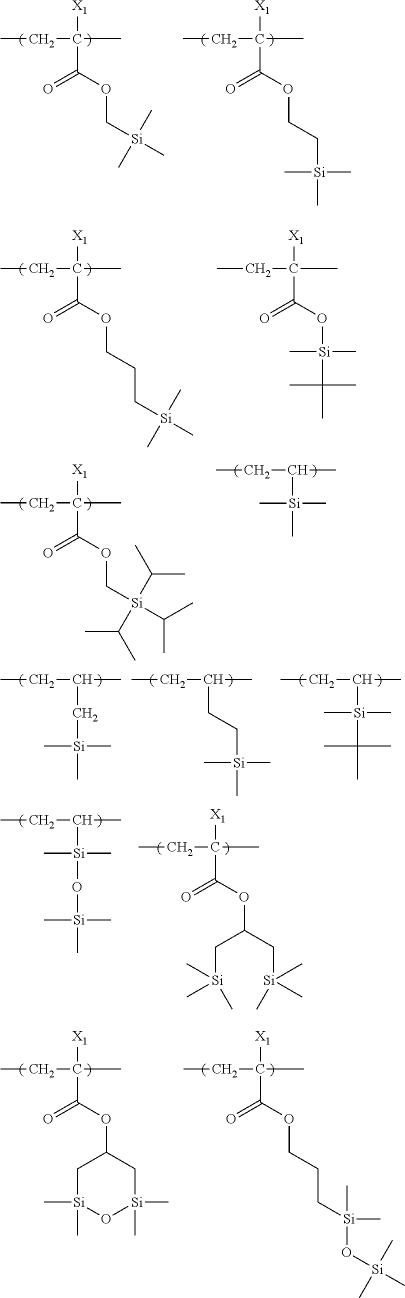

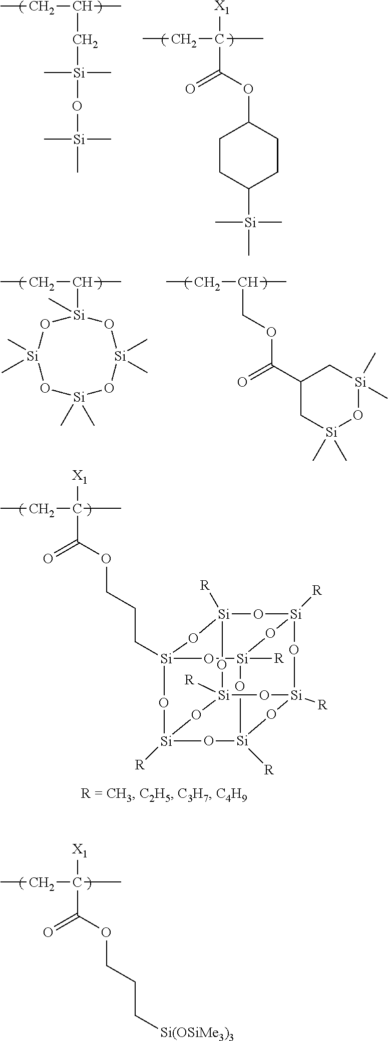

Furthermore, the combined hydrophobic resin (D) may contain at least one group selected from the group consisting of the following (x) to (z):

(x) an acid group,

(y) a lactone structure-containing group, an acid anhydride group, or an acid imide group, and

(z) a group capable of decomposing by the action of an acid.

Examples of the acid group (x) include a phenolic hydroxyl group, a carboxylic acid group, a fluorinated alcohol group, a sulfonic acid group, a sulfonamide group, a sulfonylimide group, an (alkylsulfonyl)alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred acid groups are a fluorinated alcohol group (preferably hexafluoroisopropanol), a sulfonimide group and a bis(alkylcarbonyl)methylene group.

The repeating unit having (x) an acid group includes, for example, a repeating unit where the acid group is directly bonded to the main chain of the resin, such as repeating unit derived from an acrylic acid or a methacrylic acid, and a repeating unit where the acid group is bonded to the main chain of the resin through a linking group, and the acid group may be also introduced into the terminal of the polymer chain by using an acid group-containing polymerization initiator or chain transfer agent at the polymerization. All of these cases are preferred. The repeating unit having (x) an acid group may have at least either a fluorine atom or a silicon atom.

The content of the repeating unit having (x) an acid group is preferably from 1 to 50 mol %, more preferably from 3 to 35 mol %, still more preferably from 5 to 20 mol %, based on all repeating units in the combined hydrophobic resin (D).

Specific examples of the repeating unit having (x) an acid group are illustrated below, but the present invention is not limited thereto. In the formulae, Rx represents a hydrogen atom, CH₃, CF₃ or CH₂OH.

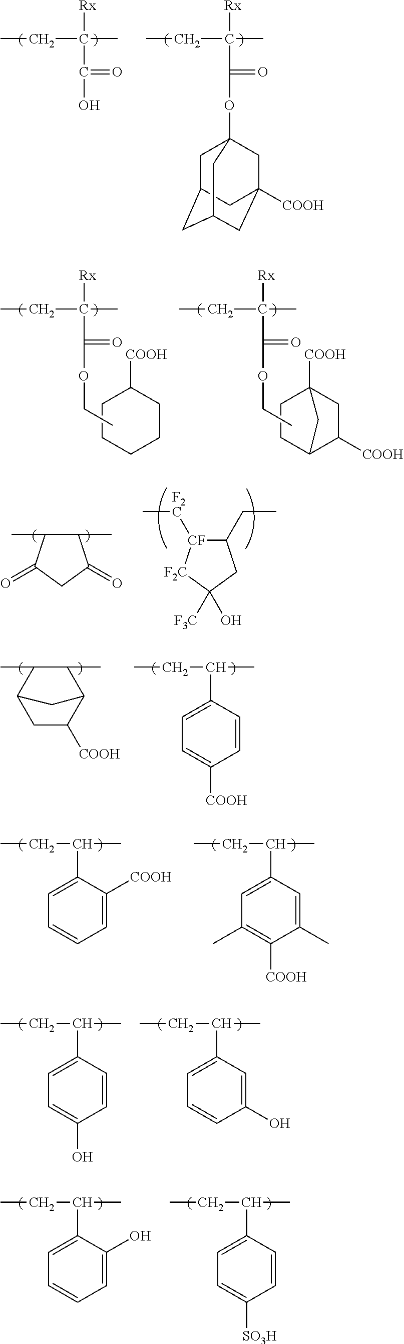

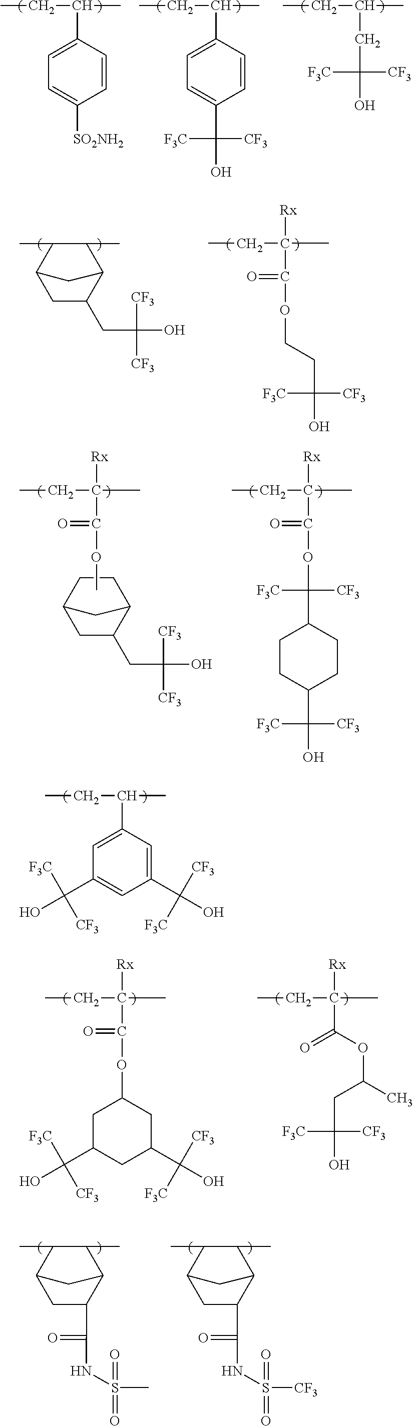

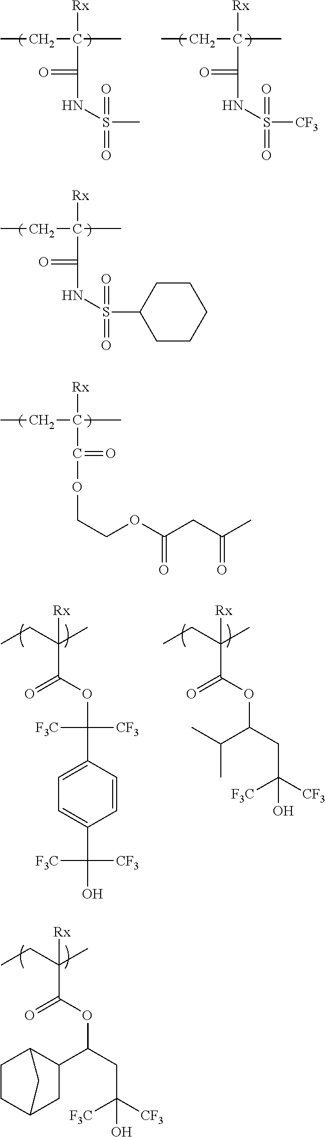

The (y) lactone structure-containing group, acid anhydride group or acid imide group is preferably a lactone structure-containing group.

The repeating unit containing such a group is, for example, a repeating unit where the group is directly bonded to the main chain of the resin, such as repeating unit derived from an acrylic acid ester or a methacrylic acid ester. This repeating unit may be a repeating unit where the group is bonded to the main chain of the resin through a linking group. Alternatively, in this repeating unit, the group may be introduced into the terminal of the resin by using a polymerization initiator or chain transfer agent containing the group at the polymerization.

Examples of the repeating unit having a lactone structure-containing group are the same as those of the repeating unit having a lactone structure described above in the paragraph of the acid-decomposable resin (A).

The content of the repeating unit having a lactone structure-containing group, an acid anhydride group or an acid imide group is preferably from 1 to 100 mol %, more preferably from 3 to 98 mol %, still more preferably from 5 to 95 mol %, based on all repeating units in the combined hydrophobic resin (D).

Examples of the repeating unit having (z) a group capable of decomposing by the action of an acid, contained in the combined hydrophobic resin (D), are the same as those of the repeating unit having an acid-decomposable group as previously described in the resin (A). The repeating unit having (z) a group capable of decomposing by the action of an acid may contain at least either a fluorine atom or a silicon atom. In the combined hydrophobic resin (D), the content of the repeating unit having (z) a group capable of decomposing by the action of an acid is preferably from 1 to 80 mol %, more preferably from 10 to 80 mol/%, still more preferably from 20 to 60 mol %, based on all repeating units in the resin (D).

The combined hydrophobic resin (D) may further contain a repeating unit represented by the following formula (II):

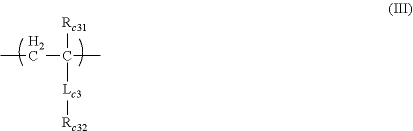

In formula (III), R_{c31} represents a hydrogen atom, an alkyl group (which may be substituted with a fluorine atom or the like), a cyano group, or a —CH₂—O—R_{ac2} group, wherein R_{ac2} represents a hydrogen atom, an alkyl group, or an acyl group. R_{c31} is preferably a hydrogen atom, a methyl group, a hydroxymethyl group or a trifluoromethyl group, more preferably a hydrogen atom or a methyl group.

R_{c32} represents a group having an alkyl group, a cycloalkyl group, an alkenyl group, a cycloalkenyl group or an aryl group. These groups may be substituted with a fluorine atom or a silicon atom-containing group.

L_{c3} represents a single bond or a divalent linking group.

In formula (III), the alkyl group of R_{c32} is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The aryl group is preferably an aryl group having a carbon number of 6 to 20, more preferably a phenyl group or a naphthyl group, and these groups may have a substituent.

R_{c32} is preferably an unsubstituted alkyl group or an alkyl group substituted with a fluorine atom.

The divalent linking group of L₀₃ is preferably an alkylene group (preferably having a carbon number of 1 to 5), an ether bond, a phenylene group, or an ester bond (a group represented by —COO—).

The content of the repeating unit represented by formula (III) is preferably from 1 to 100 mol/o %, more preferably from 10 to 90 mol %, still more preferably from 30 to 70 mol %, based on all repeating units in the hydrophobic resin (D).

It is also preferred that the combined hydrophobic resin (D) further contains a repeating unit represented by the following formula (CII-AB):

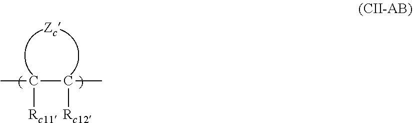

In formula (CII-AB), each of R_{c11}′ and R_{c12}′ independently represents a hydrogen atom, a cyano group, a halogen atom, or an alkyl group.

Z_{c}′ represents an atomic group for forming an alicyclic structure containing two carbon atoms (C—C) to which Z_{c}′ is bonded.

The content of the repeating unit represented by formula (CII-AB) is preferably from 1 to 100 mol %, more preferably from 10 to 90 mol %, still more preferably from 30 to 70 mol %, based on all repeating units in the hydrophobic resin (D).

Specific examples of the repeating units represented by formulae (III) and (CII-AB) are illustrated below, but the present invention is not limited thereto. In the formulae, Ra represents H, CH₃, CH₂OH, CF or N,

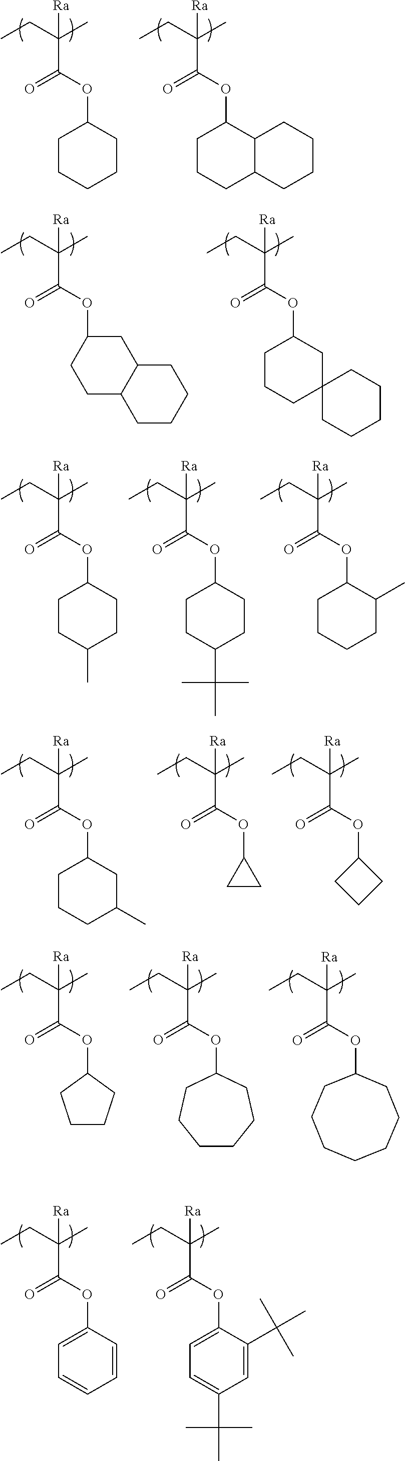

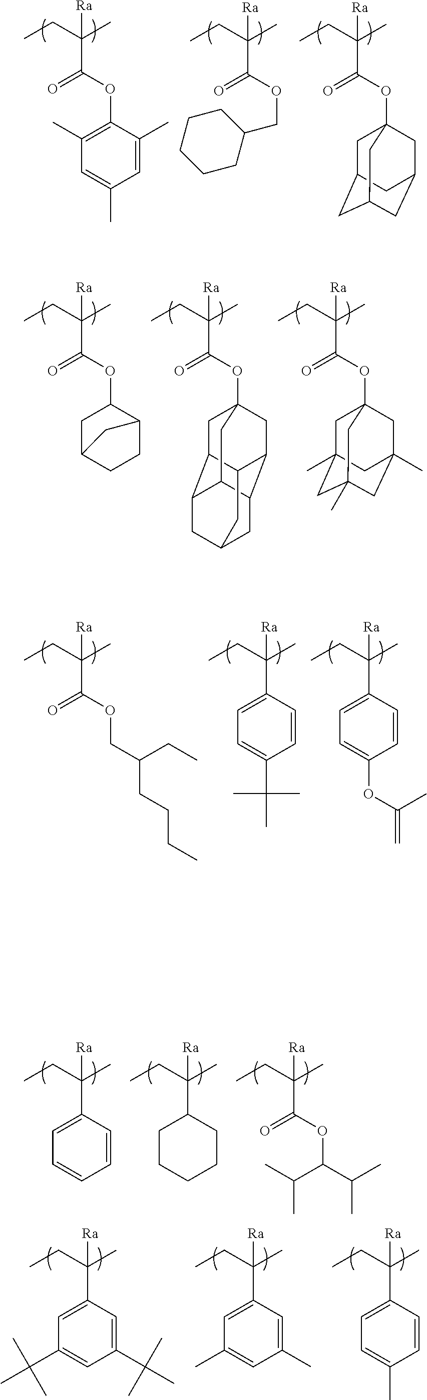

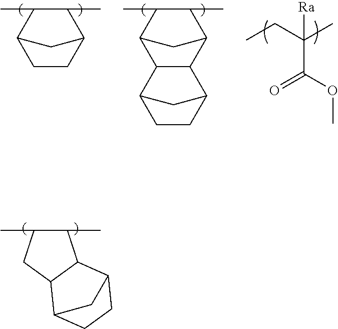

In the case where the combined hydrophobic resin (D) contains a fluorine atom, the fluorine atom content is preferably from 5 to 80 mass %, more preferably from 10 to 80 mass %, based on the weight average molecular weight of the combined hydrophobic resin (D). Also, the fluorine atom-containing repeating unit preferably accounts for 10 to 100 mol %, more preferably from 30 to 100 mol %, based on all repeating units contained in the combined hydrophobic resin (D).

In the case where the combined hydrophobic resin (D) contains a silicon atom, the silicon atom content is preferably from 2 to 50 mass %, more preferably from 2 to 30 mass %, based on the weight average molecular weight of the combined hydrophobic resin (D). Also, the silicon atom-containing repeating unit preferably accounts for 10 to 100 mol %, more preferably from 20 to 100 mol %, based on all repeating units contained in the combined hydrophobic resin (D).

The weight average molecular in terms of standard polystyrene of the combined hydrophobic resin (D) is preferably from 1,000 to 100,000, more preferably from 1,000 to 50,000, still more preferably from 2,000 to 15,000.

As for the combined hydrophobic resin (D), one resin may be used, or a plurality of resins may be used in combination.

The content of the combined hydrophobic resin (D) in the composition is preferably from 0.01 to 10 mass %/e, more preferably from 0.05 to 8 mass %, still more preferably from 0.1 to 5 mass %, based on the total solid content of the composition of the present invention.

In the combined hydrophobic resin (D), similarly to the resin (A), it is of course preferred that the content of impurities such as metal is small, but the content of residual monomers or oligomer components is also preferably from 0.01 to 5 mass %, more preferably from 0.01 to 3 mass %, still more preferably from 0.05 to 1 mass %. With the content in this range, an actinic ray-sensitive or radiation-sensitive resin composition free from in-liquid extraneous substances and change with aging of sensitivity or the like can be obtained. Furthermore, in view of resolution, resist profile, side wall of resist pattern, roughness and the like, the molecular weight distribution (Mw/Mn, sometimes referred to as “polydispersity”) is preferably from 1 to 5, more preferably from 1 to 3, still more preferably from 1 to 2.

As the combined hydrophobic resin (D), various commercially products may be used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred.

The reaction solvent, the polymerization initiator, the reaction conditions (such as temperature and concentration) and the method for purification after reaction are the same as those described for the resin (A), but in the synthesis of the combined hydrophobic resin (D), the concentration at the reaction is preferably from 30 to 50 mass %.

Specific examples of the combined hydrophobic resin (D) are illustrated below. Also, the molar ratio of repeating units (corresponding to repeating units starting from the left), weight average molecular weight and polydispersity of each resin are shown in Table 2 later.

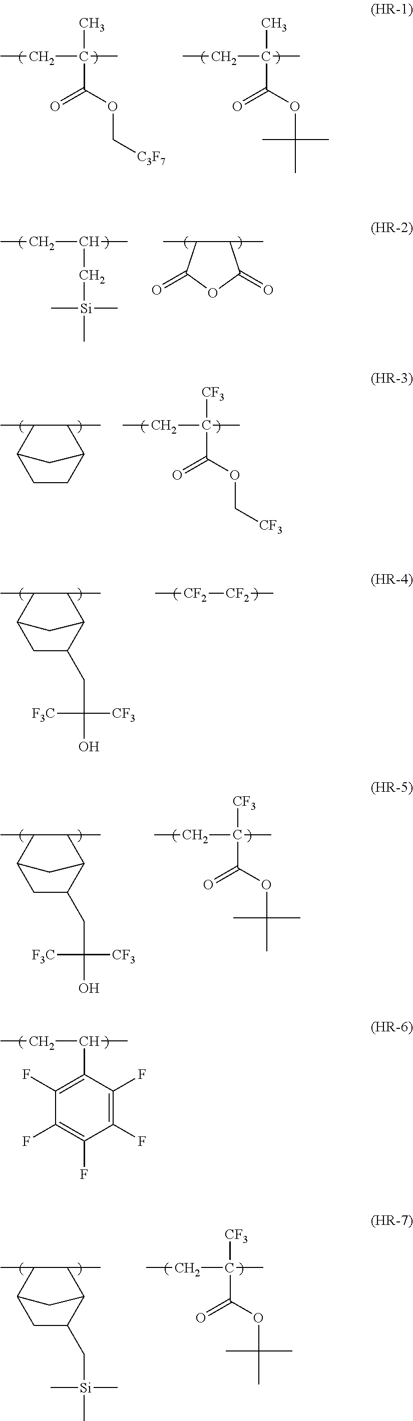

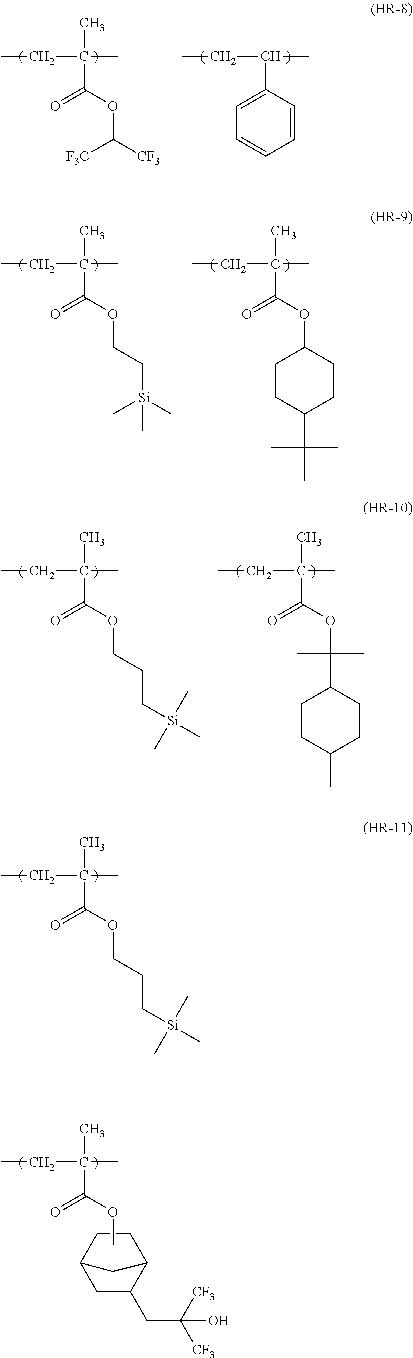

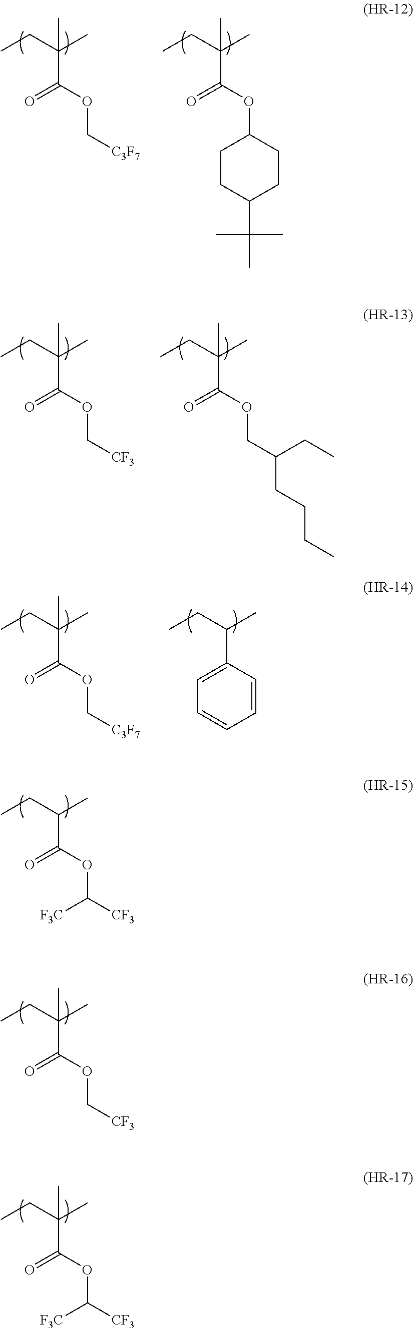

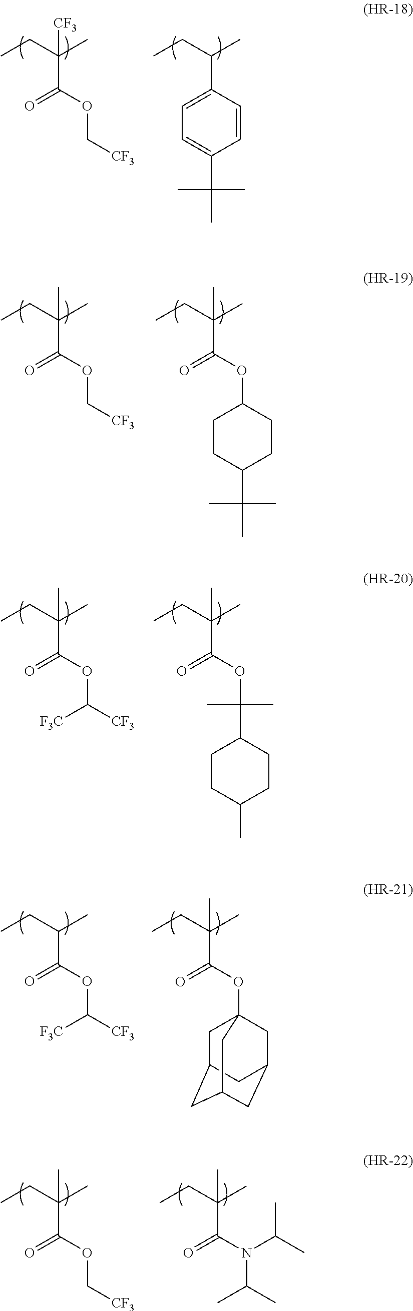

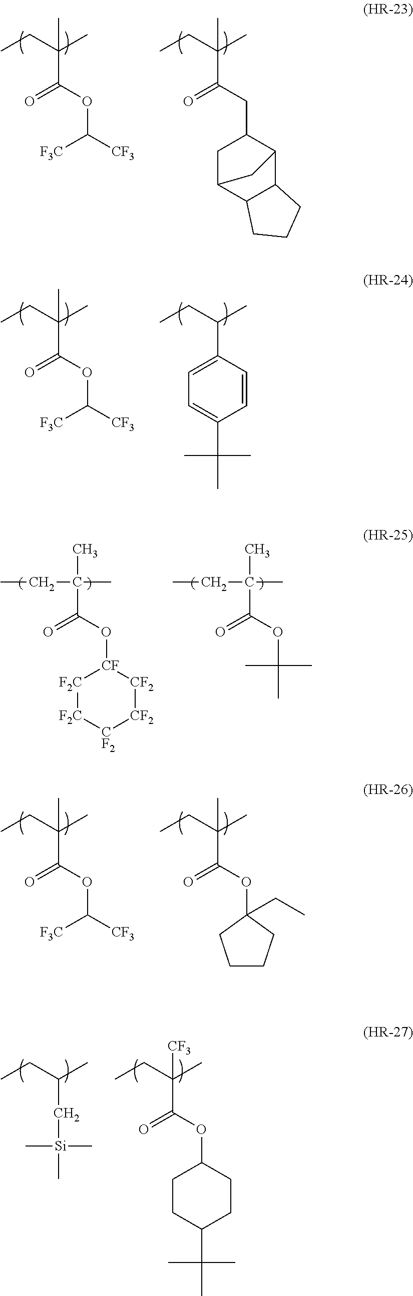

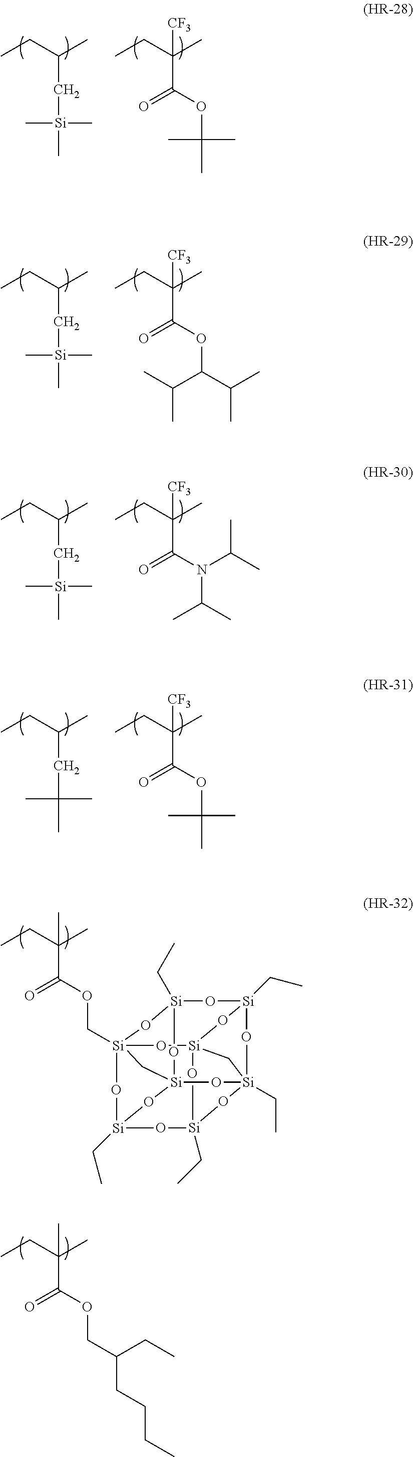

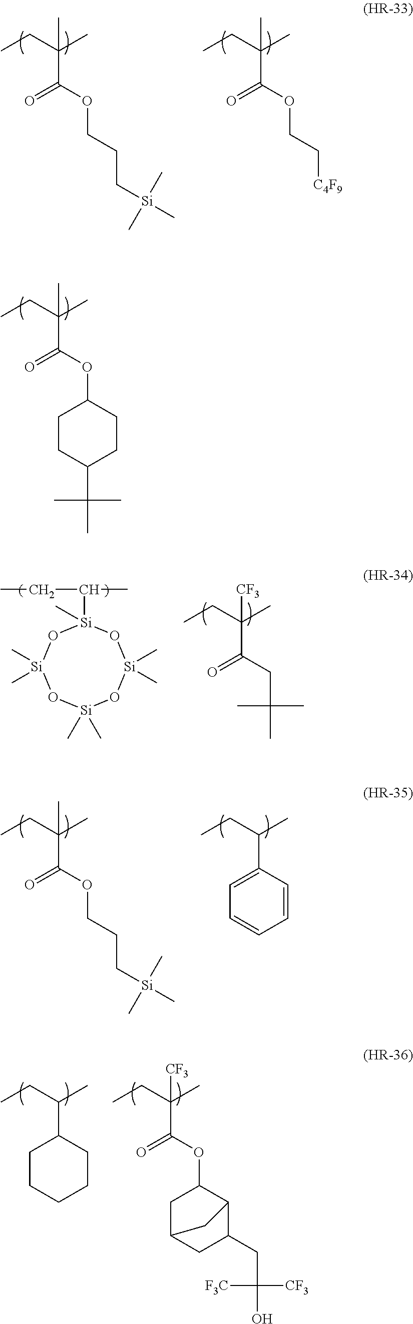

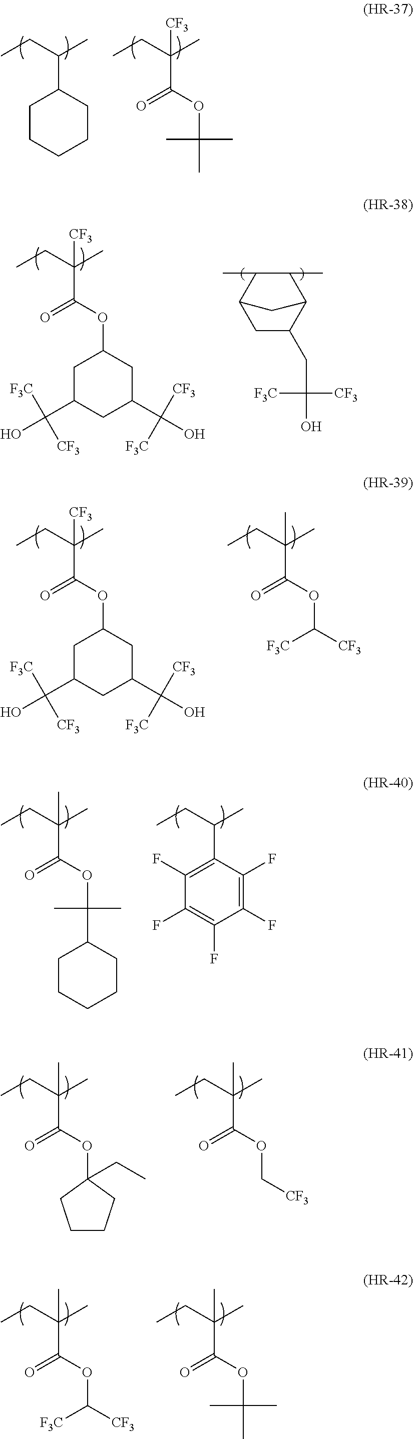

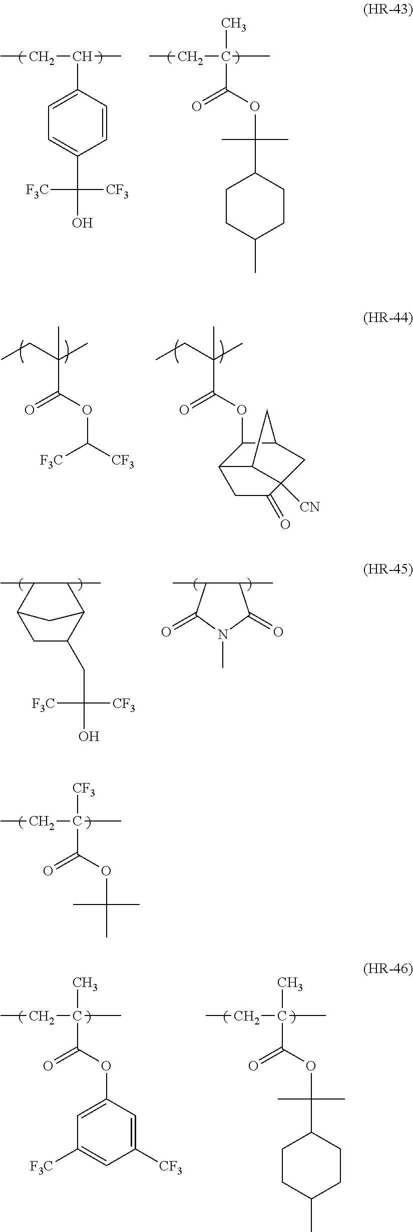

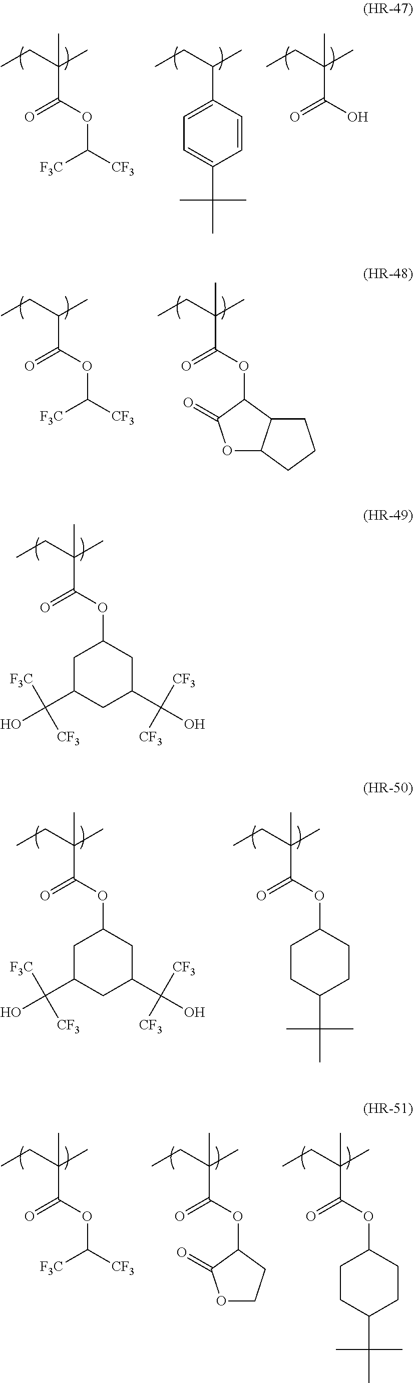

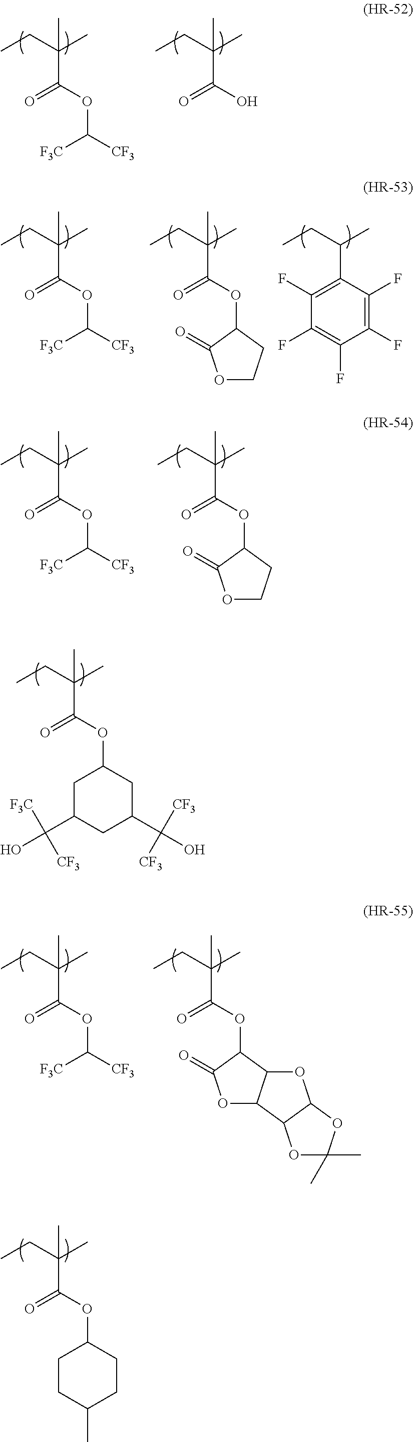

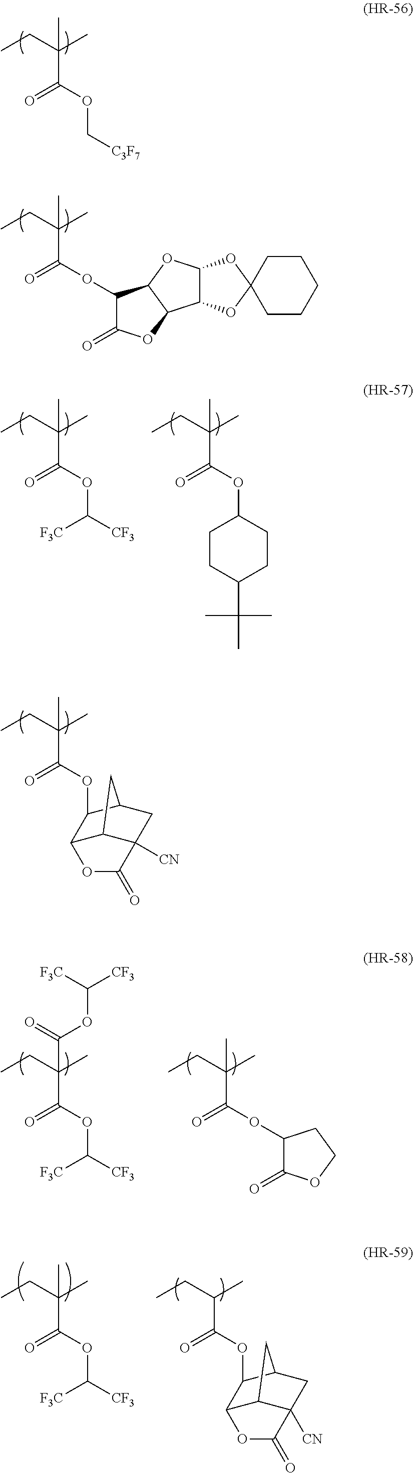

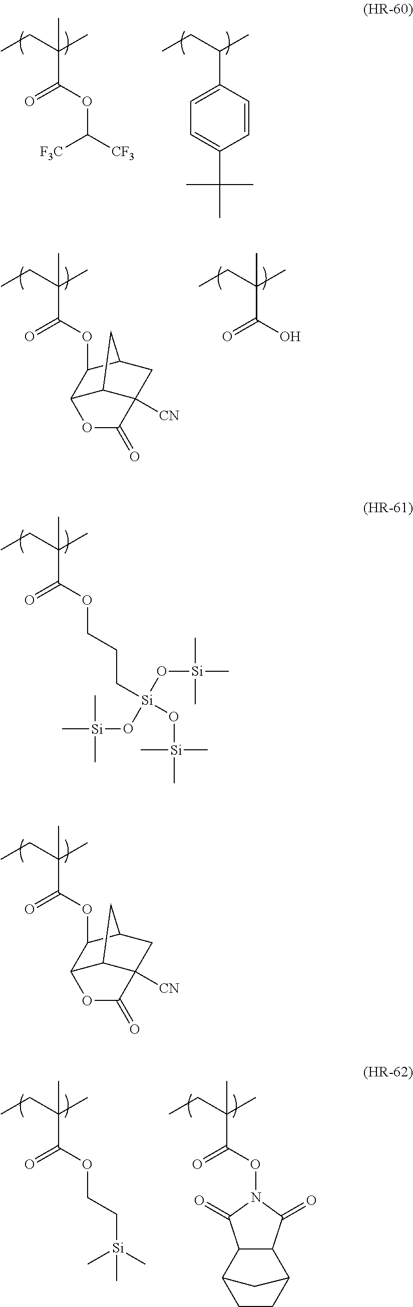

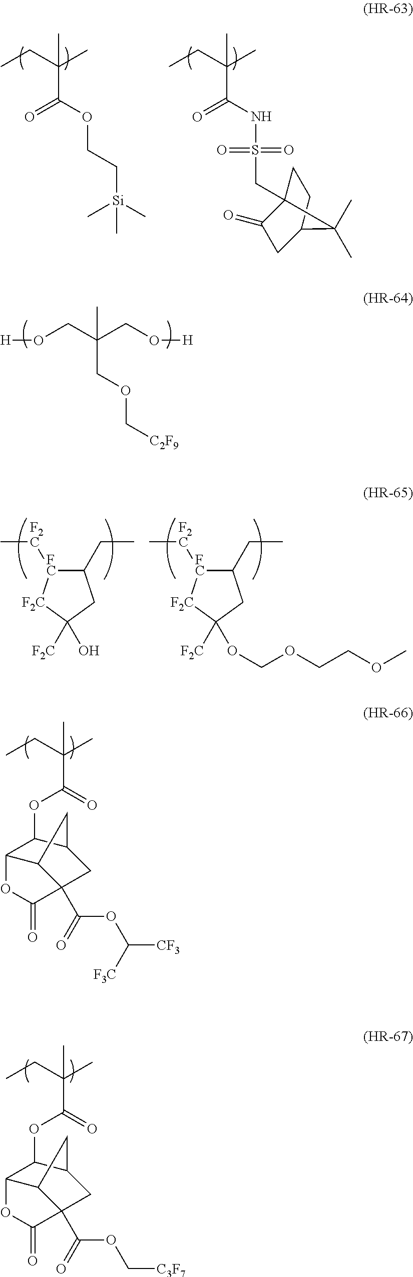

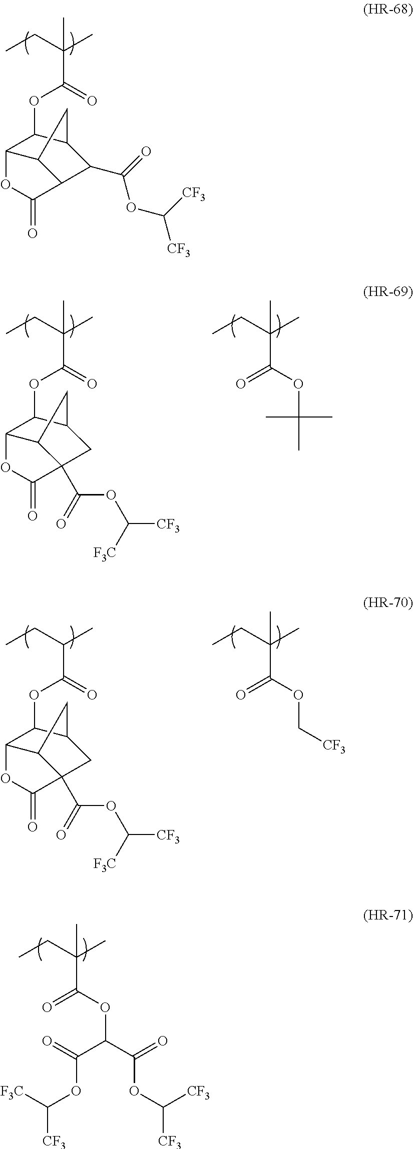

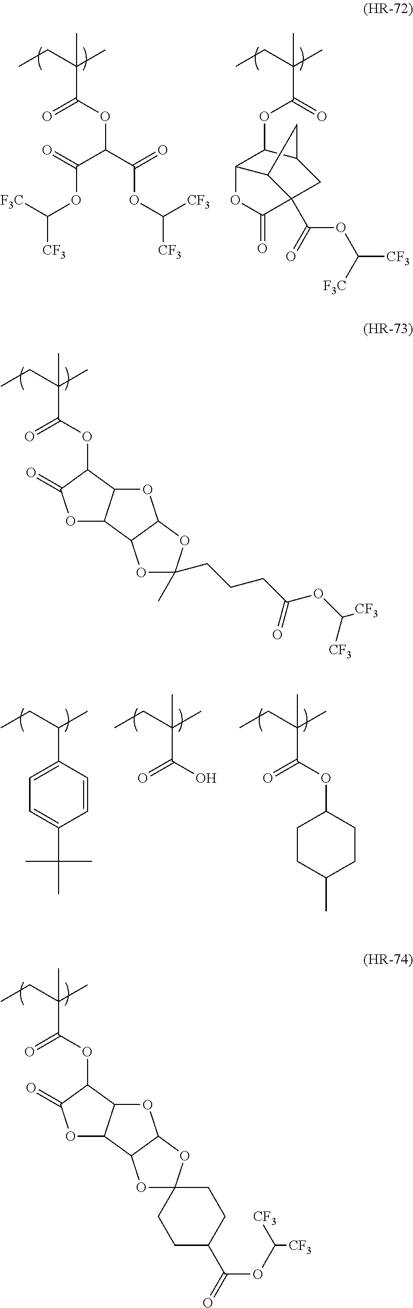

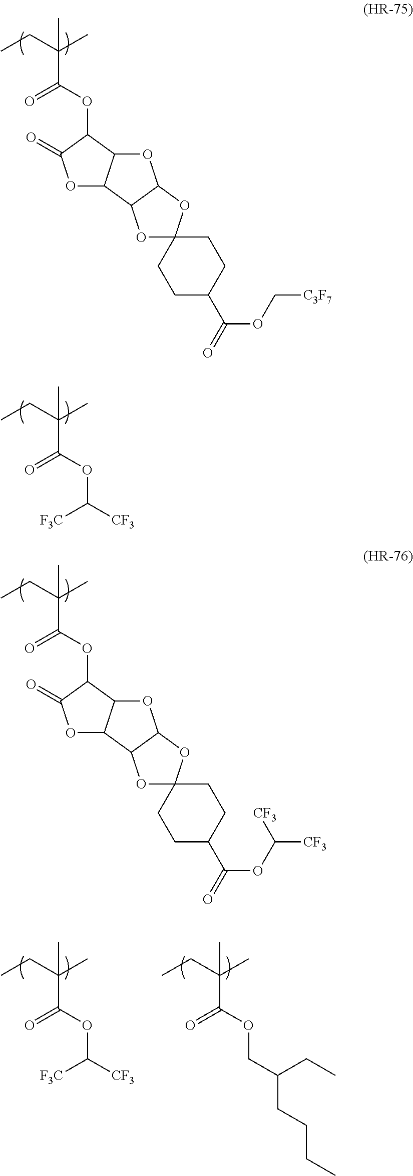

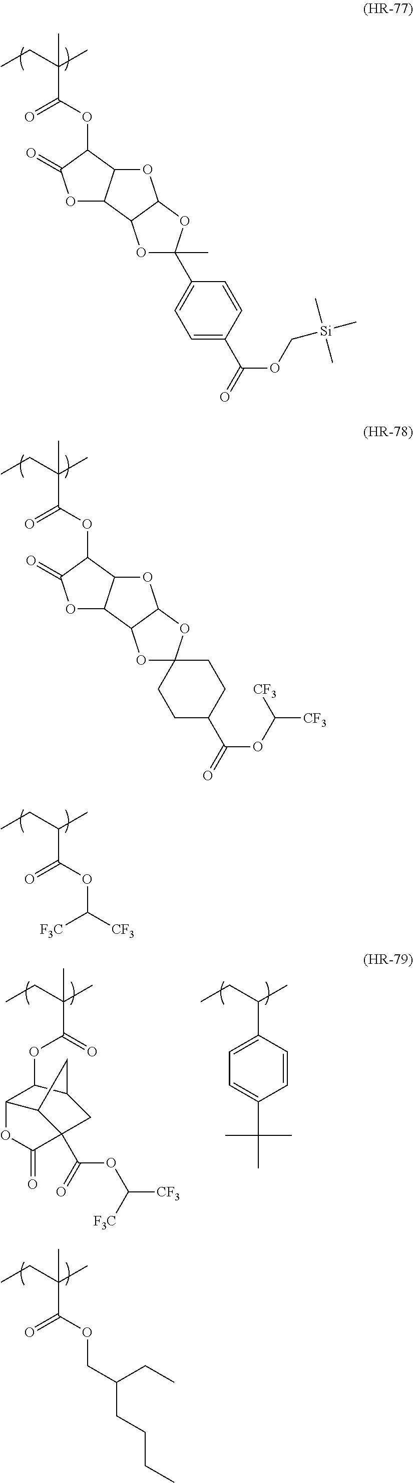

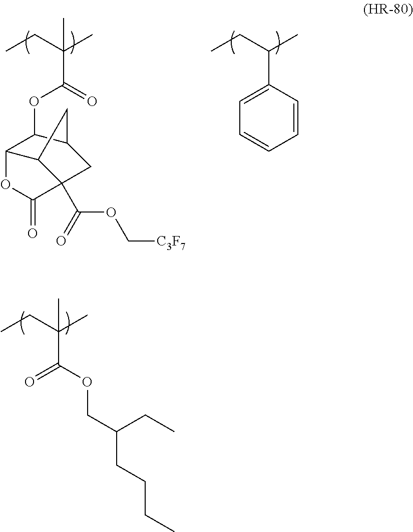

TABLE 2

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |

[6-1](N) Basic compound or ammonium salt compound of which basicity decreases upon irradiation with an actinic ray or radiation

The actinic ray-sensitive or radiation-sensitive resin composition of the present invention preferably contains a basic compound or ammonium salt compound of which basicity decreases upon irradiation with an actinic ray or radiation (hereinafter sometimes referred to as “compound (N)”).

The compound (N) is preferably (N-1) a compound having a basic functional group or an ammonium group and a group capable of generating an acidic functional group upon irradiation with an actinic ray or radiation. That is, the compound (N) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

The compound which is generated by the decomposition of the compound (N) or (N-1) upon irradiation with an actinic ray or radiation and of which basicity is decreased includes compounds represented by the following formulae (PA-I), (PA-II) and (PA-III), and from the standpoint that excellent effects can be attained in a high level in terms of all of LWR, local pattern dimension uniformity and DOF, compounds represented by formulae (PA-II) and (PA-III) are preferred.

The compound represented by formula (PA-I) is described below.

Q-A₁-(X)—B—R (PA-I)

In formula (PA-I), A represents a single bond or a divalent linking group.

Q represents —SO₃H or —CO₂H. Q corresponds to an acidic functional group that is generated upon irradiation with an actinic ray or radiation.

X represents —SO₂— or —CO—.

n represents 0 or 1.

B represents a single bond, an oxygen atom or —N(Rx)-.

Rx represents a hydrogen atom or a monovalent organic group.

R represents a monovalent organic group having a basic functional group, or a monovalent organic group having an ammonium group.

The divalent linking group of A, is preferably a divalent organic group having a carbon number of 2 to 12, and examples thereof include an alkylene group and a phenylene group. An alkylene group having at least one fluorine atom is preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of the hydrogen atom is replaced by a fluorine atom, more preferably an alkylene group where the carbon atom bonded to the Q site has a fluorine atom, still more preferably a perfluoroalkylene group, yet still more preferably a perfluoroethylene group, a perfluoropropylene group or a perfluorobutylene group.

The monovalent organic group in Rx is preferably a monovalent organic group having a carbon number of 4 to 30, and examples thereof include an alkyl group, a cycloalkyl group, an aryl group, an aralkyl group and an alkenyl group.

The alkyl group in Rx may have a substituent and is preferably a linear or branched alkyl group having a carbon number of 1 to 20, and the alkyl chain may contain an oxygen atom, a sulfur atom or a nitrogen atom.

Here, the alkyl group having a substituent includes particularly a group where a cycloalkyl group is substituted on a linear or branched alkyl group (for example, an adamantylmethyl group, an adamantylethyl group, a cycohexylethyl group and a camphor residue).

The cycloalkyl group in Rx may have a substituent and is preferably a cycloalkyl group having a carbon number of 3 to 20, and the ring may contain an oxygen atom.

The aryl group in Rx may have a substituent and is preferably an aryl group having a carbon number of 6 to 14.

The aralkyl group in Rx may have a substituent and is preferably an aralkyl group having a carbon number of 7 to 20.

The alkenyl group in Rx may have a substituent, and examples thereof include a group having a double bond at an arbitrary position of the alkyl group described as Rx.

Preferred examples of the partial structure of the basic functional group include a crown ether structure, a primary to tertiary amine structure, and a nitrogen-containing heterocyclic structure (e.g., pyridine, imidazole, pyrazine).

Preferred examples of the partial structure of the ammonium group include a primary to tertiary ammonium structure, a pyridinium structure, an imidazolinium structure and a pyrazinium structure.

The basic functional group is preferably a functional group having a nitrogen atom, more preferably a structure having a primary to tertiary amino group or a nitrogen-containing heterocyclic structure. In such a structure, from the standpoint of enhancing the basicity, it is preferred that all atoms adjacent to nitrogen atom contained in the structure are a carbon atom or a hydrogen atom. Also, in view of enhancing the basicity, an electron-withdrawing functional group (e.g., carbonyl group, sulfonyl group, cyano group, halogen atom) is preferably not bonded directly to nitrogen atom.

The monovalent organic group in the monovalent organic group (group R) containing such a structure is preferably an organic group having a carbon number of 4 to 30, and examples thereof include an alkyl group, a cycloalkyl group, an aryl group, an aralkyl group and an alkenyl group. Each of these groups may have a substituent.

Examples of the alkyl group, cycloalkyl group, aryl group, aralkyl group and alkenyl group in the alkyl group, cycloalkyl group, aryl group, aralkyl group and alkenyl group each containing a basic functional group or an ammonium group of R are the same as those of the alkyl group, cycloalkyl group, aryl group, aralkyl group and alkenyl group described as Rx.

Examples of the substituent which may be substituted on each of the groups above include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 20). The cyclic structure in the aryl group, cycloalkyl group and the like may further have an alkyl group (preferably having a carbon number of 1 to 20) as a substituent. The aminoacyl group may further have one or two alkyl groups (preferably having a carbon number of 1 to 20) as a substituent.

When B is —N(Rx)-, R and Rx are preferably combined to form a ring. By forming a ring structure, the stability is enhanced and the composition using this compound is also enhanced in the storage stability. The number of carbons constituting the ring is preferably from 4 to 20, and the ring may be monocyclic or polycyclic and may contain an oxygen atom, a sulfur atom or a nitrogen atom.

Examples of the monocyclic structure include a 4- to 8-membered ring containing a nitrogen atom. Examples of the polycyclic structure include a structure composed by combining two monocyclic structures or three or more monocyclic structures. The monocyclic structure and polycyclic structure may have a substituent, and preferred examples of the substituent include a halogen atom, a hydroxyl group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 15), an acyloxy group (preferably having a carbon number of 2 to 15), an alkoxycarbonyl group (preferably having a carbon number of 2 to 15), and an aminoacyl group (preferably having a carbon number of 2 to 20). The cyclic structure in the aryl group, cycloalkyl group and the like may further have an alkyl group (preferably having a carbon number of 1 to 15) as a substituent. The aminoacyl group may have one or two alkyl groups (preferably having a carbon number of 1 to 15) as a substituent.

Out of the compounds represented by formula (PA-I), a compound where the Q site is a sulfonic acid can be synthesized using a general sulfonamidation reaction. For example, this compound can be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through a reaction with an amine compound.

The compound represented by formula (PA-II) is described below.

Q₁-X₁—NH—X₂-Q₂ (PA-II)

In formula (PA-II), each of Q₁ and Q₂ independently represents a monovalent organic group, provided that either one of Q₁ and Q₂ has a basic functional group. It is also possible that Q₁ and Q₂ are combined to form a ring and the ring formed has a basic functional group.

Each of X₁ and X₂ independently represents —CO— or —SO₂—.

Here, —NH— corresponds to an acidic functional group that is generated upon irradiation with an actinic ray or radiation.

The monovalent organic group of Q₁ and Q₂ in formula (PA-II) is preferably a monovalent organic group having a carbon number of 1 to 40, and examples thereof include an alkyl group, a cycloalkyl group, an aryl group, an aralkyl group, and an alkenyl group.

The alkyl group of Q₁ and Q₂ may have a substituent and is preferably a linear or branched alkyl group having a carbon number of 1 to 30, and the alkyl chain may contain an oxygen atom, a sulfur atom or a nitrogen atom.

The cycloalkyl group of Q₁ and Q₂ may have a substituent and is preferably a cycloalkyl group having a carbon number of 3 to 20, and the ring may contain an oxygen atom or a nitrogen atom.

The aryl group of Q₁ and Q₂ may have a substituent and is preferably an aryl group having a carbon number of 6 to 14.

The aralkyl group of Q₁ and Q₂ may have a substituent and is preferably an aralkyl group having a carbon number of 7 to 20.

The alkenyl group of Q₁ and Q₂ may have a substituent and includes a group having a double bond at an arbitrary position of the alkyl group above.

Examples of the substituent which may be substituted on each of the groups above include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 10). The cyclic structure in the aryl group, cycloalkyl group and the like may further have an alkyl group (preferably having a carbon number of 1 to 10) as a substituent. The aminoacyl group may further have an alkyl group (preferably having a carbon number of 1 to 10) as a substituent. Examples of the alkyl group having a substituent include a perfluoroalkyl group such as perfluoromethyl group, perfluoroethyl group, perfluoropropyl group and perfluorobutyl group.

Preferred examples of the partial structure of the basic functional group contained in at least either Q₁ or Q₂ are the same as those described for the basic functional group contained in R of formula (PA-I).

Examples of the structure where Q₁ and Q₂ are combined to form a ring and the ring formed has a basic functional group include a structure where an alkylene group, an oxy group, an imino group or the like is further bonded to the organic group of Q₁ or Q₂.

In formula (PA-II), at least either one of X₁ and X₂ is preferably —SO₂—.

The compound represented by formula (PA-III) is described below.

Q₁-X₁—NH—X₂-A₂-(X₃)ₘ—B-Q₃ (PA-III)

In formula (PA-III), each of Q₁ and Q₃ independently represents a monovalent organic group, provided that either one of Q₁ and Q₃ has a basic functional group. It is also possible that Q₁ and Q₃ are combined to form a ring and the ring formed has a basic functional group.

Each of X₁, X₂ and X₃ independently represents —CO— or —SO₂—.

A₂ represents a divalent linking group.

B represents a single bond, an oxygen atom or —N(Qx)-.

Qx represents a hydrogen atom or a monovalent organic group.

When B is —N(Qx)-, Q₃ and Qx may combine to form a ring.

m represents 0 or 1.

Here, —NH— corresponds to an acidic functional group that is generated upon irradiation with an actinic ray or radiation.

Q₁ has the same meaning as Q₁ in formula (PA-II).

Examples of the organic group of Q₃ are the same as those of the organic group of Q₁ and Q₂ in formula (PA-II).

Examples of the structure where Q₁ and Q₃ are combined to form a ring and the ring formed has a basic functional group include a structure where an alkylene group, an oxy group, an imino group or the like is further bonded to the organic group of Q₁ or Q₃.

The divalent linking group of A₂ is preferably a divalent linking group having a carbon number of 1 to 8 and containing a fluorine atom, and examples thereof include a fluorine atom-containing alkylene group having a carbon number of 1 to 8, and a fluorine atom-containing phenylene group. A fluorine atom-containing alkylene group is more preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of the hydrogen atom is replaced by a fluorine atom, more preferably a perfluoroalkylene group, still more preferably a perfluoroethylene group having a carbon number of 2 to 4.

The monovalent organic group of Qx is preferably an organic group having a carbon number of 4 to 30, and examples thereof include an alkyl group, a cycloalkyl group, an aryl group, an aralkyl group and an alkenyl group. Examples of the alkyl group, cycloalkyl group, aryl group, aralkyl group and alkenyl group are the same as those for Rx in formula (PA-I).

In formula (PA-III), each of X₁, X₂ and X₃ is preferably —SO₂—.

The compound (N) is preferably a sulfonium salt compound of the compound represented by formula (PA-I), (PA-II) or (PA-III), or an iodonium salt compound of the compound represented by formula (PA-I), (PA-II) or (PA-III), more preferably a compound represented by the following formula (PA1) or (PA2):

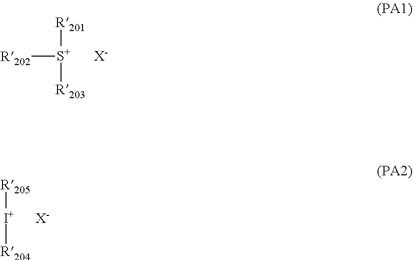

In formula (PA1), each of R′₂₀₁, R′₂₀₂ and R′₂₀₃ independently represents an organic group, and specific examples thereof are the same as those for R₂₀₁, R₂₀₂ and R₂₀₃ of formula (ZI) in the component (B).

X⁻ represents a sulfonate or carboxylate anion resulting from removal of a hydrogen atom in the —SO₃H moiety or —COOH moiety of the compound represented by formula (PA-I), or an anion resulting from removal of a hydrogen atom in the —NH— moiety of the compound represented by formula (PA-II) or (PA-III).

In formula (PA2), each of R′₂₀₄ and R′₂₀₅ independently represents an aryl group, an alkyl group or a cycloalkyl group. Specific examples thereof are the same as those for R₂₀₄ and R₂₀₅ of formula (ZII) in the component (B).

X⁻ represents a sulfonate or carboxylate anion resulting from removal of a hydrogen atom in the —SO₃H moiety or —COOH moiety of the compound represented by formula (PA-I), or an anion resulting from removal of a hydrogen atom in the —NH— moiety of the compound represented by formula (PA-II) or (PA-III).

The compound (N) decomposes upon irradiation with an actinic ray or radiation to generate, for example, a compound represented by formula (PA-I), (PA-II) or (PA-III).

The compound represented by formula (PA-1) is a compound having a sulfonic acid group or a carboxylic acid group together with a basic functional group or an ammonium group and thereby being reduced in or deprived of the basicity or changed from basic to acidic relative to the compound (N).

The compound represented by formula (PA-II) or (PA-III) is a compound having an organic sulfonylimino group or an organic carbonylimino group together with a basic functional group and thereby being reduced in or deprived of the basicity or changed from basic to acidic relative to the compound (N).

In the present invention, the expression “reduced in the basicity upon irradiation with an actinic ray or radiation” means that the acceptor property for a proton (an acid generated upon irradiation with an actinic ray or radiation) of the compound (N) is decreased by the irradiation with an actinic ray or radiation. The expression “reduced in the acceptor property” means that when an equilibrium reaction of producing a noncovalent bond complex as a proton adduct from a basic functional group-containing compound and a proton takes place or when an equilibrium reaction of causing the counter cation of the ammonium group-containing compound to be exchanged with a proton takes place, the equilibrium constant in the chemical equilibrium decreases.

The compound (N) whose basicity decreases upon irradiation with an actinic ray or radiation is contained in the resist film, so that in the unexposed area, the acceptor property of the compound (N) is sufficiently brought out and an unintended reaction between an acid diffused from the exposed area or the like and the resin (A) can be inhibited, whereas in the exposed area, the acceptor property of the compound (N) decreases and the intended reaction of an acid with the resin (A) unfailingly occurs. It is presumed that by virtue of such an operation mechanism, a pattern excellent in terms of line width roughness (LWR), local pattern dimension uniformity, focus latitude (DOF) and pattern profile is obtained.

The basicity can be confirmed by measuring the pH, or a calculated value can be computed using a commercially available software.

Specific examples of the compound (N) capable of generating a compound represented by formula (PA-I) upon irradiation with an actinic ray or radiation are illustrated below, but the present invention is not limited thereto.

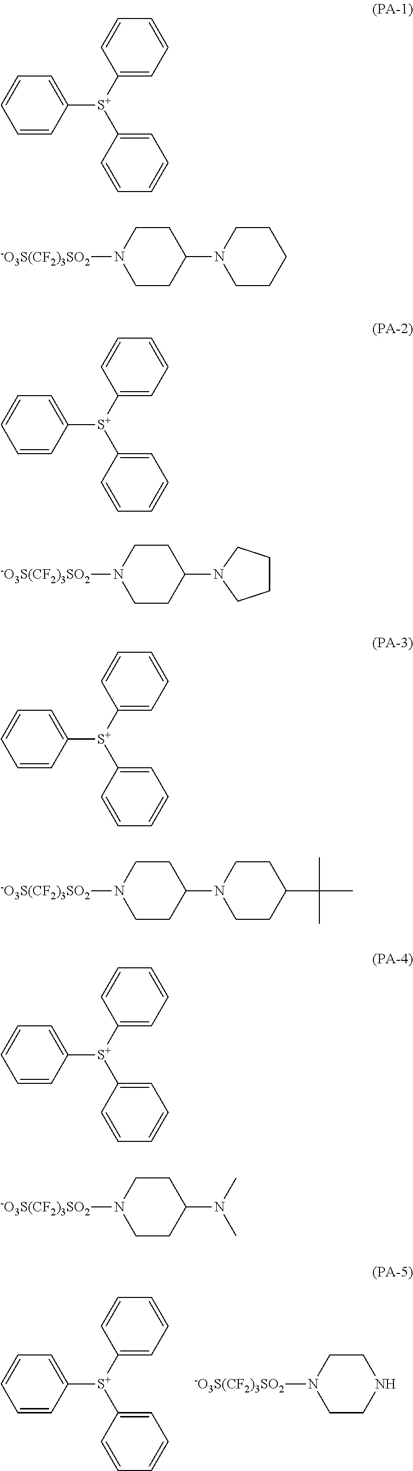

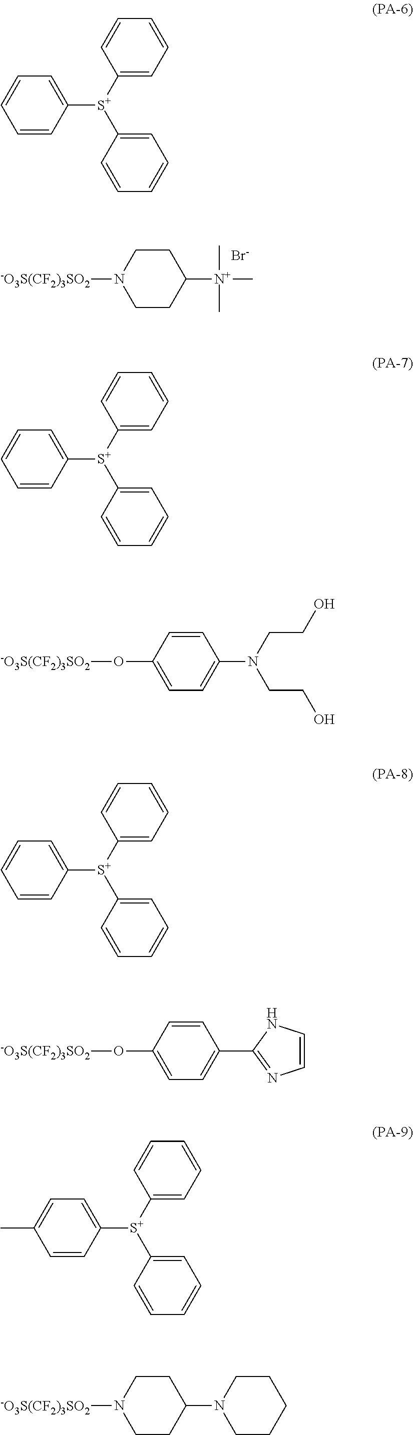

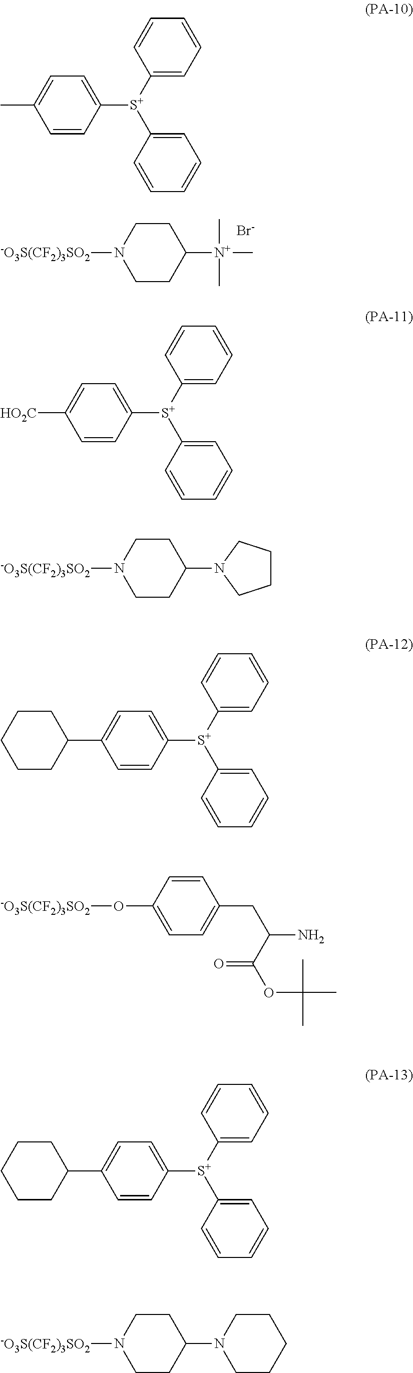

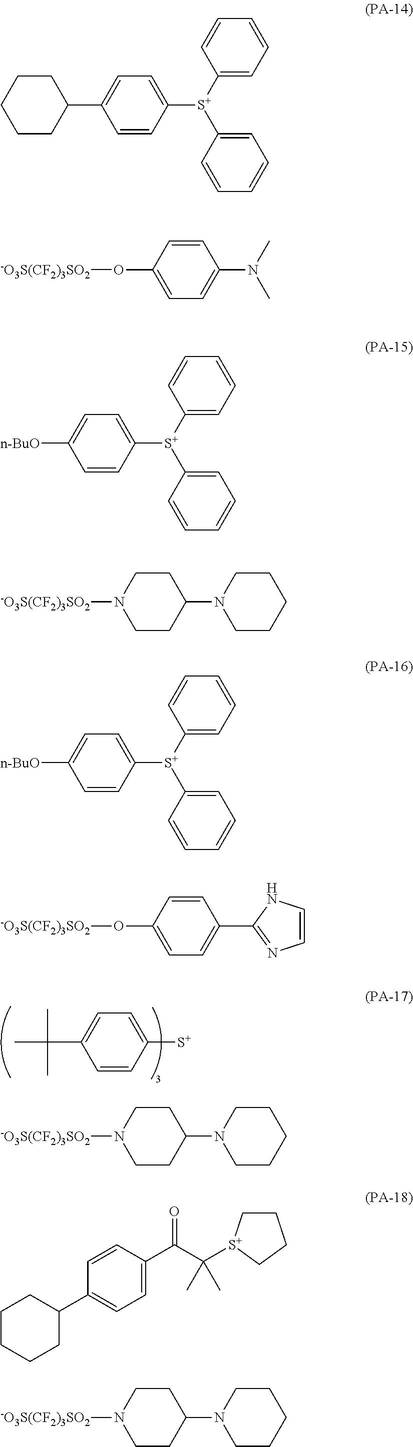

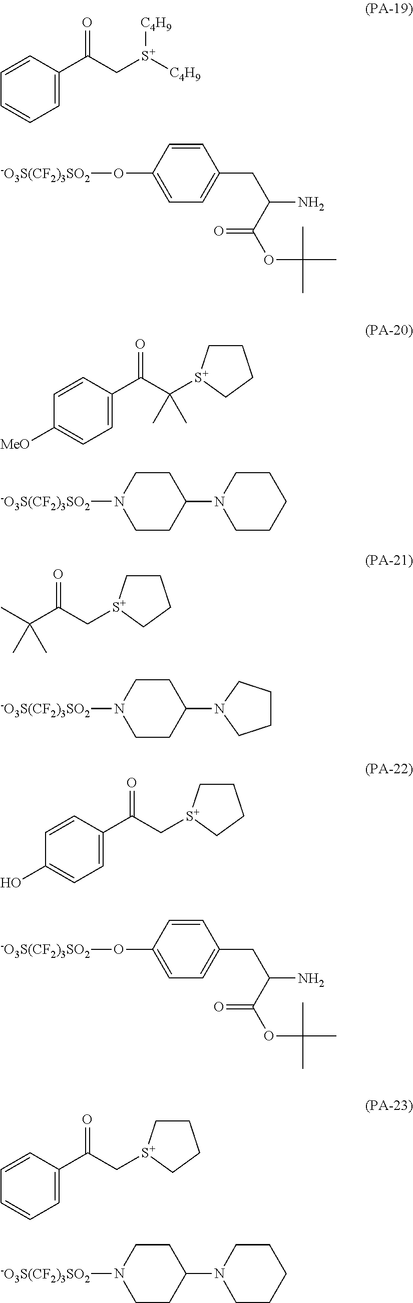

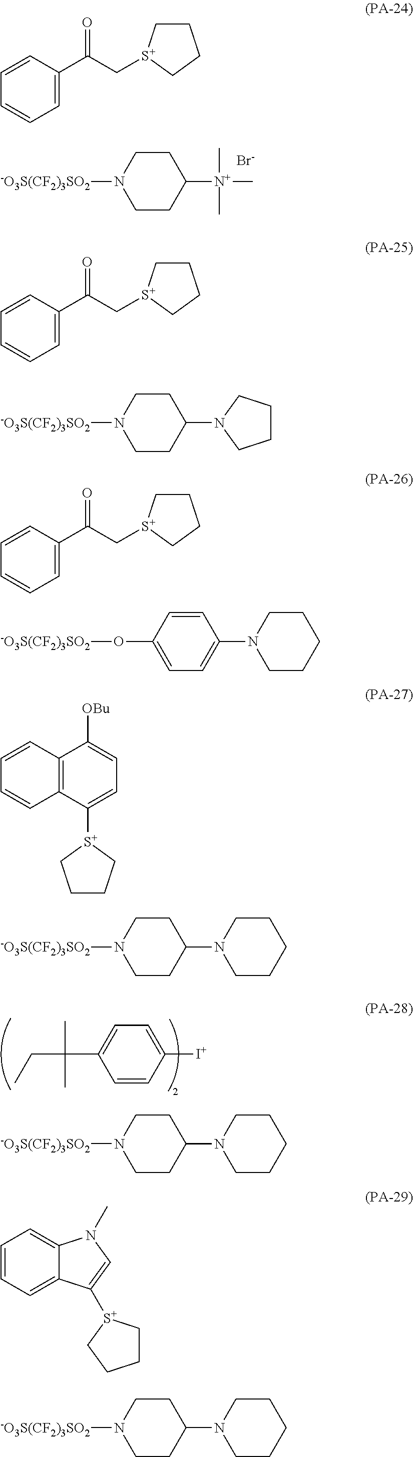

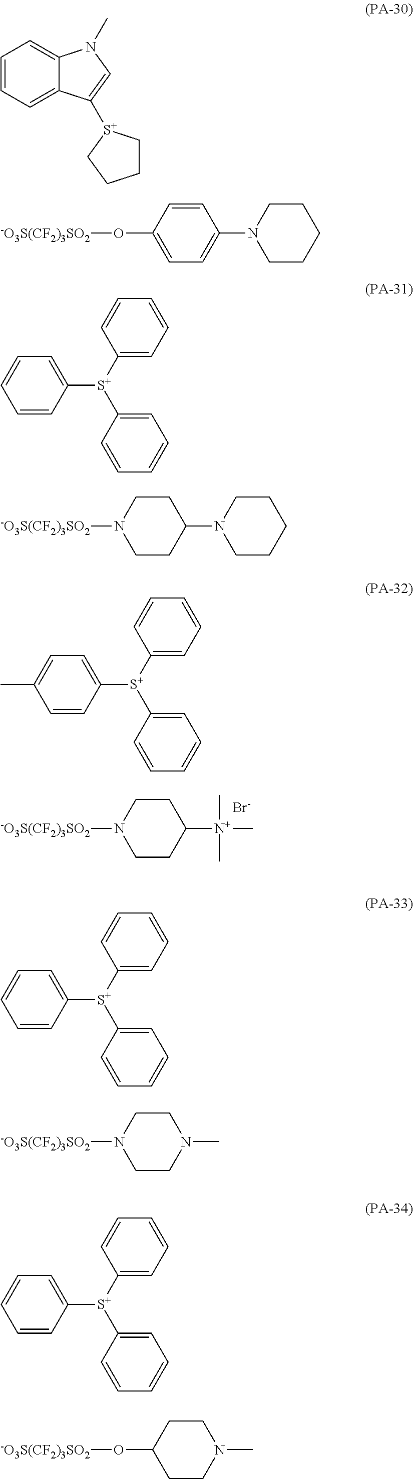

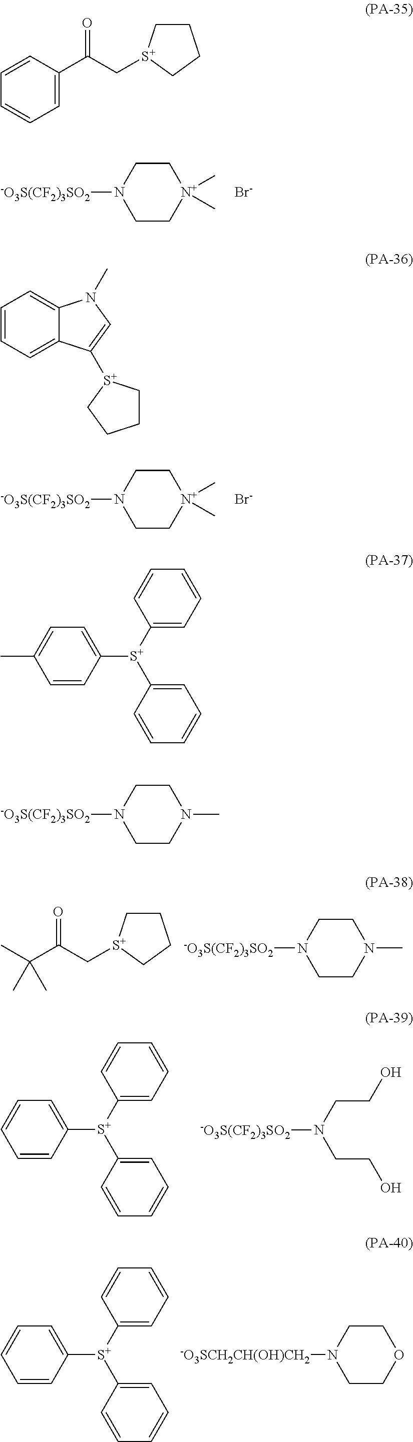

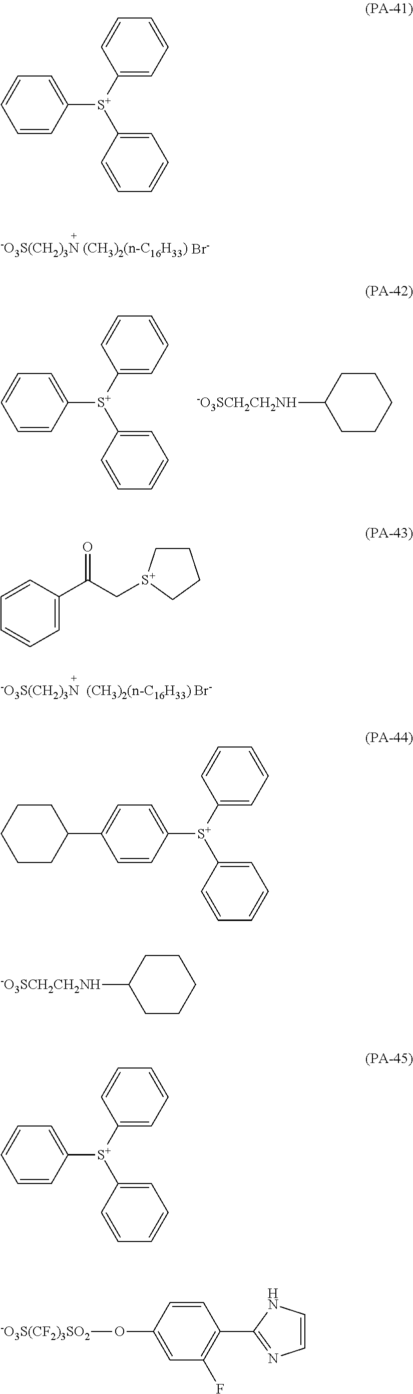

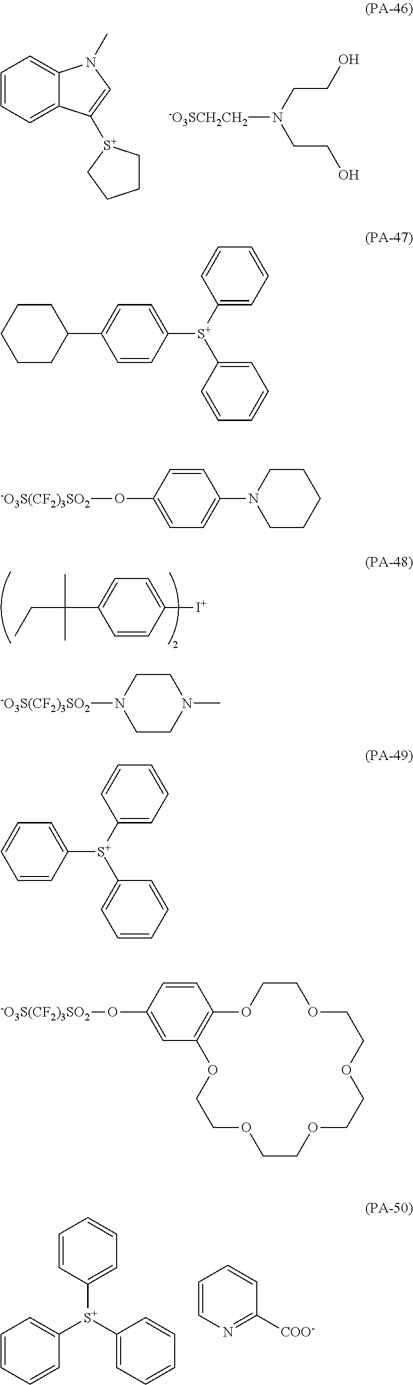

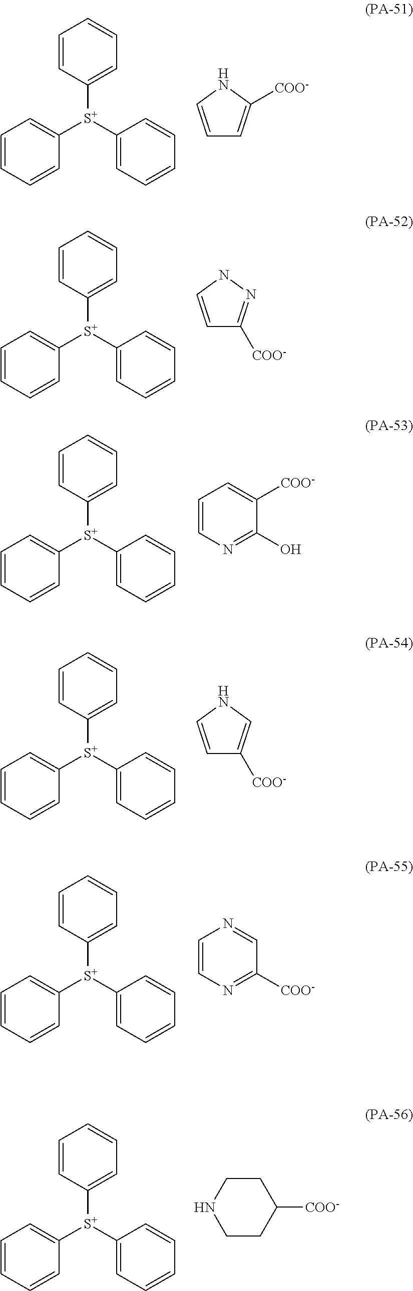

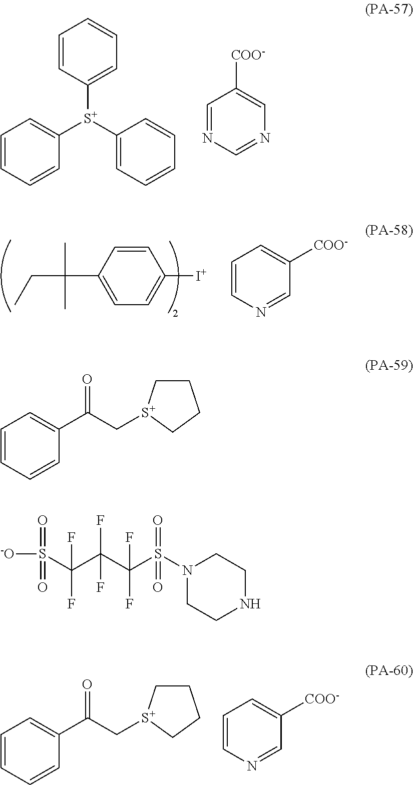

These compounds can be easily synthesized from a compound represented by formula (PA-I) or a lithium, sodium or potassium salt thereof and a hydroxide, bromide, chloride or the like of iodonium or sulfonium, by utilizing the salt exchange method described in JP-T-11-501909 (the term “JP-T” as used herein means a “published Japanese translation of a PCT patent application”) or JP-A-2003-246786. The synthesis may be also performed in accordance with the synthesis method described in JP-A-7-333851.

Specific examples of the compound (N) capable of generating a compound represented by formula (PA-II) or (PA-III) upon irradiation with an actinic ray or radiation are illustrated below, but the present invention is not limited thereto.

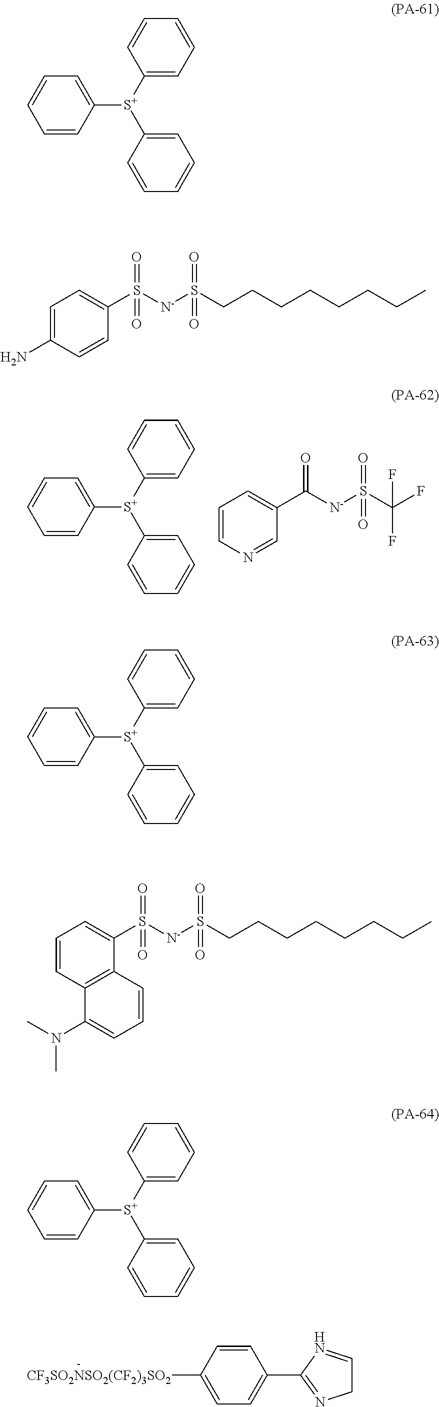

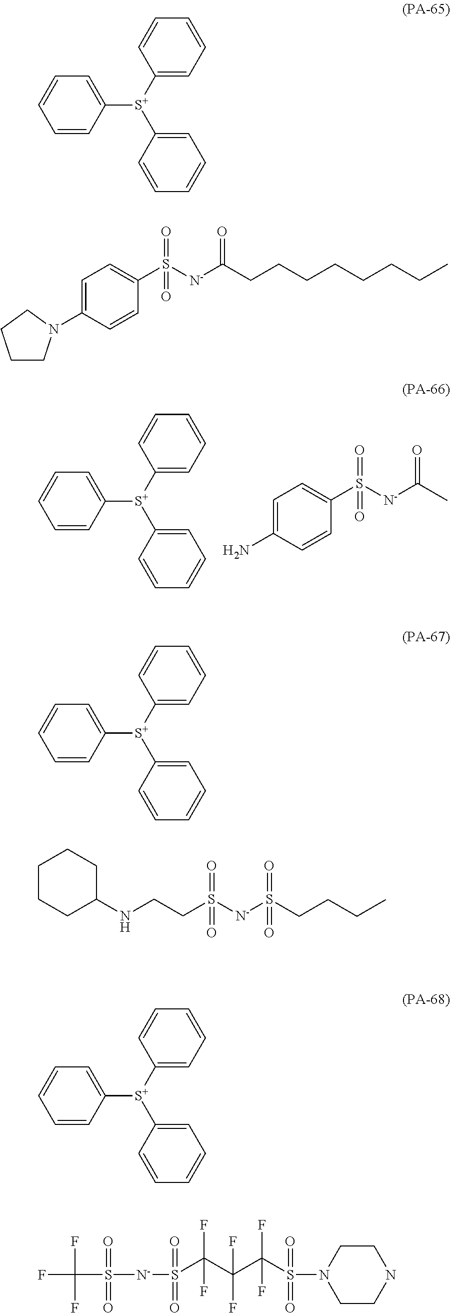

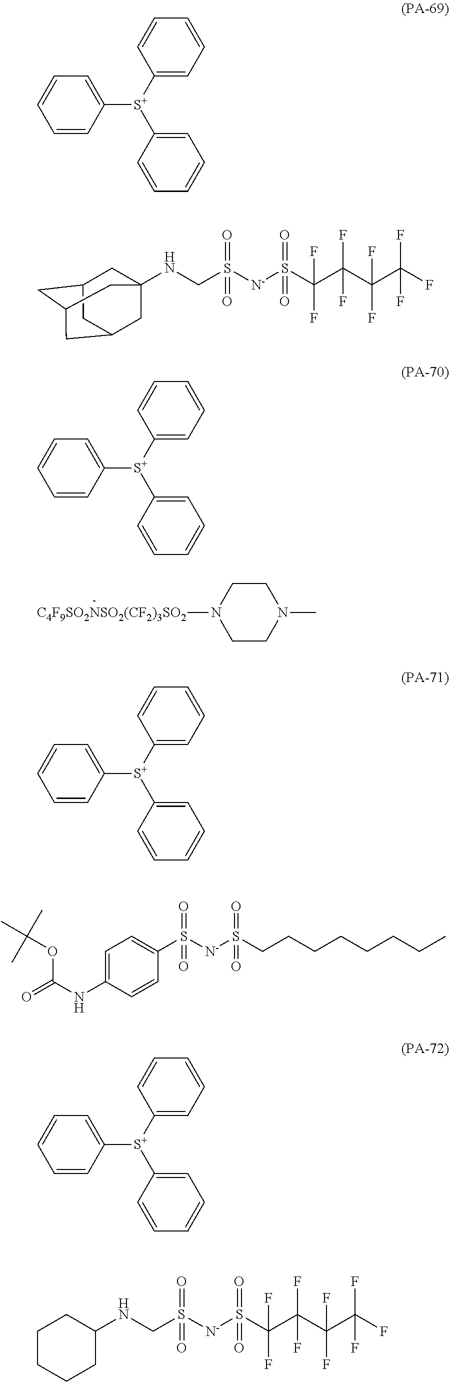

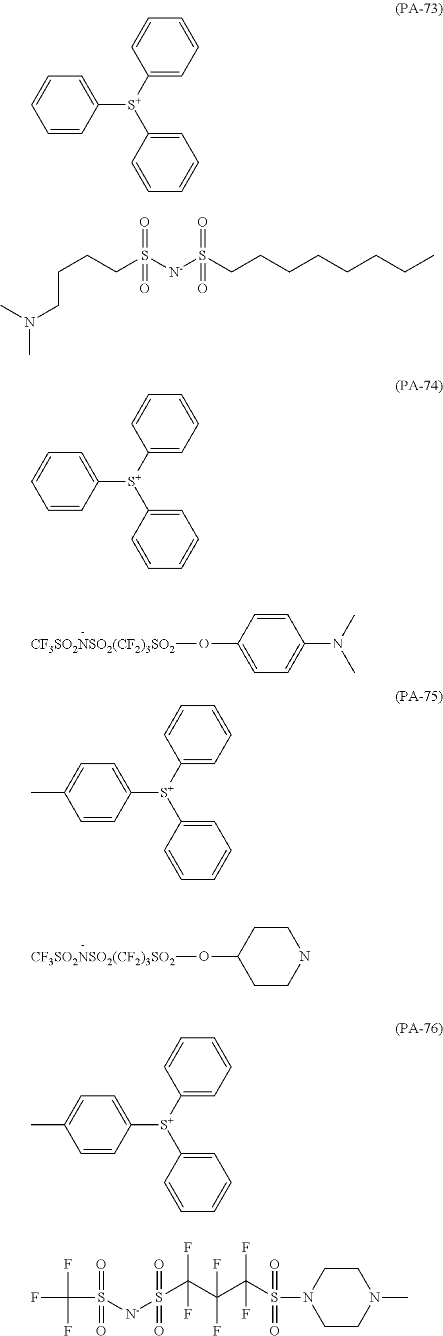

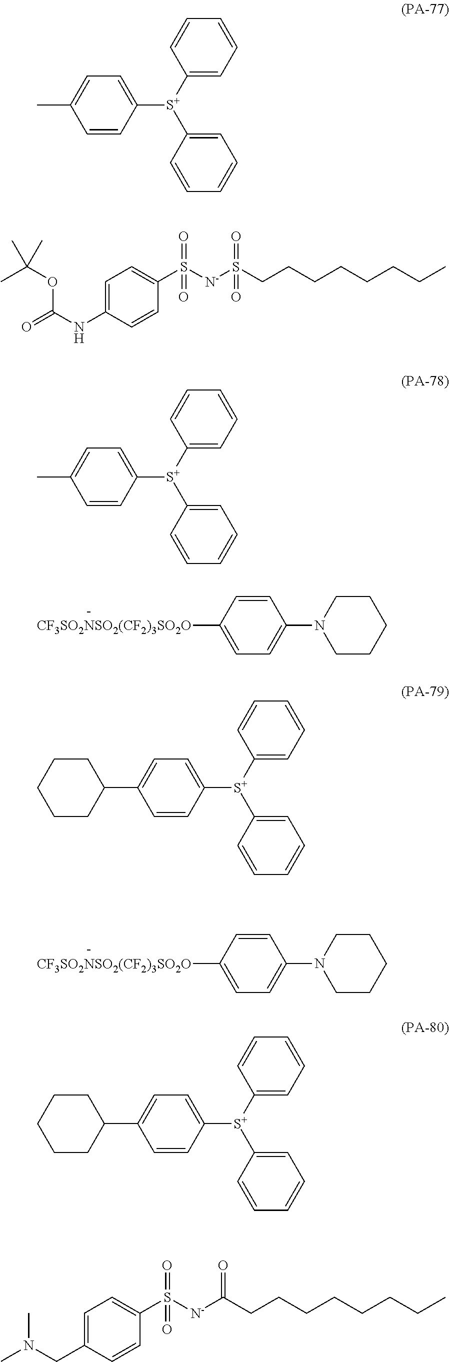

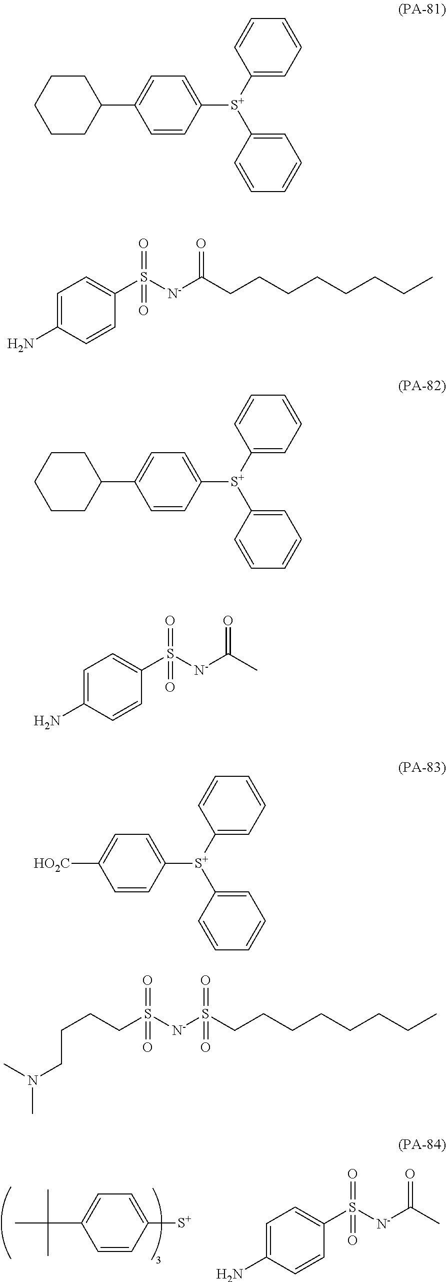

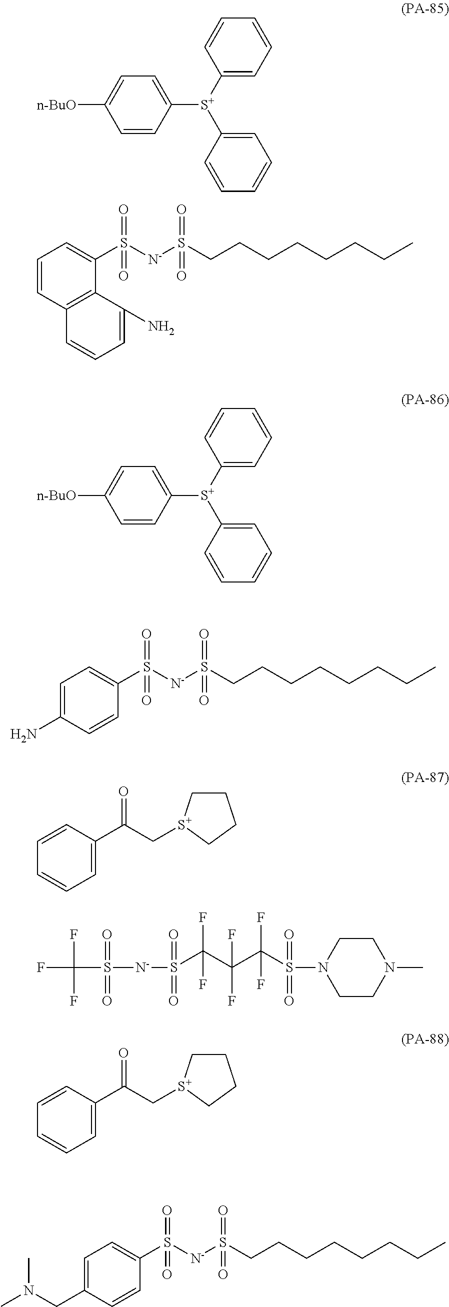

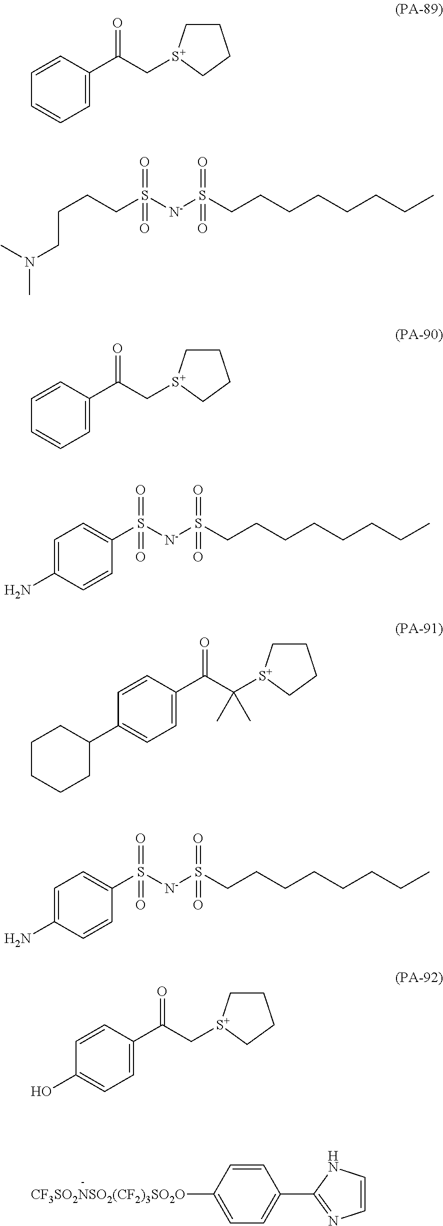

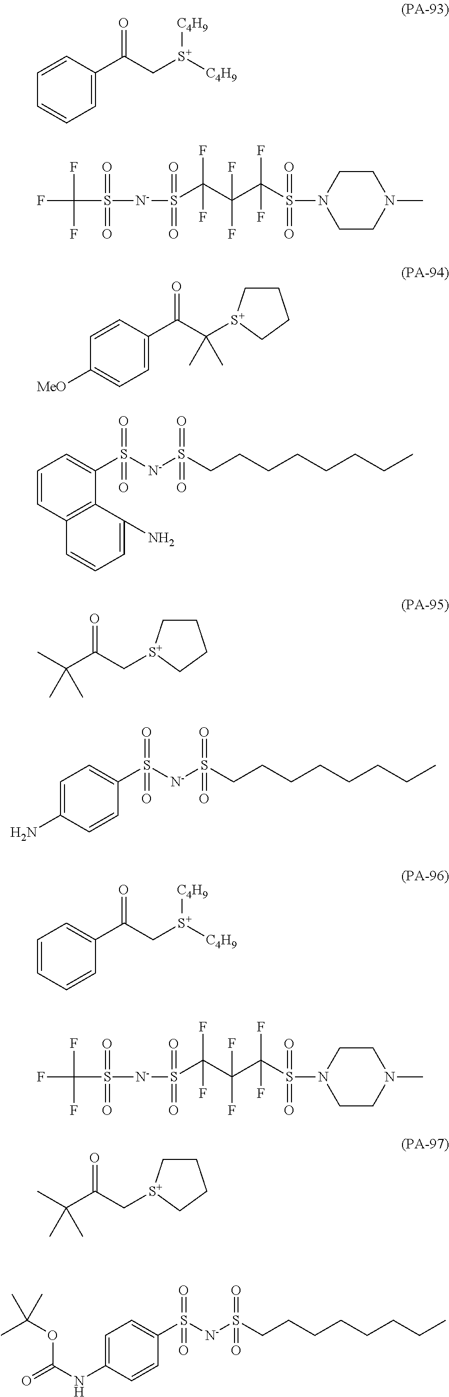

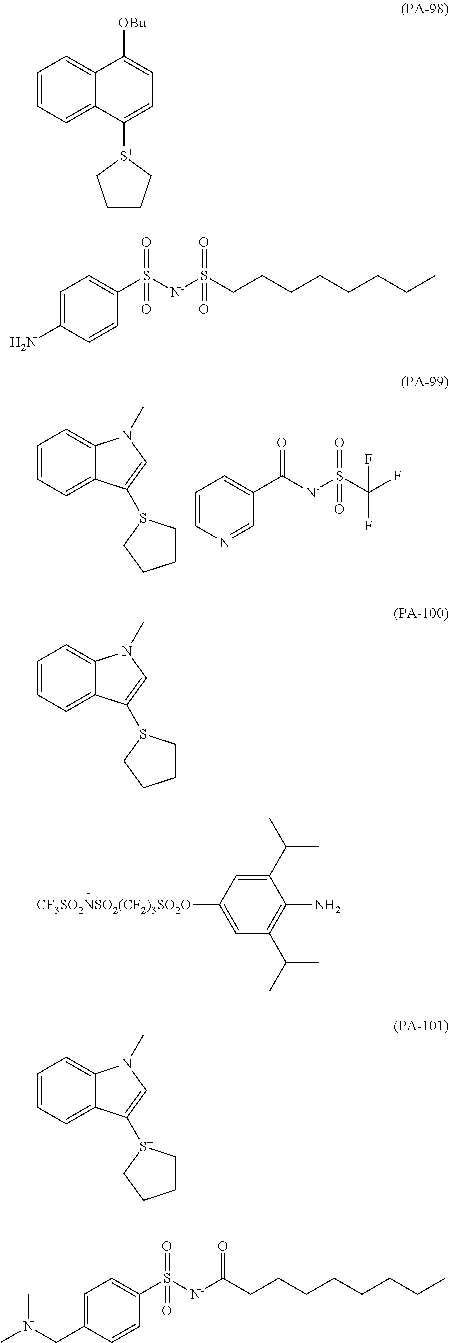

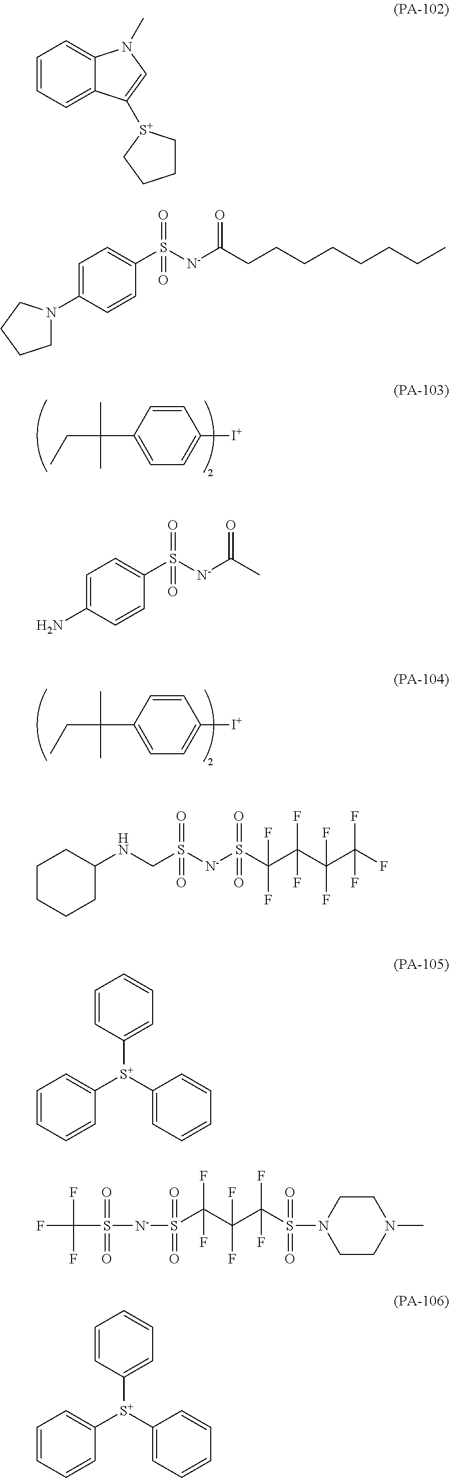

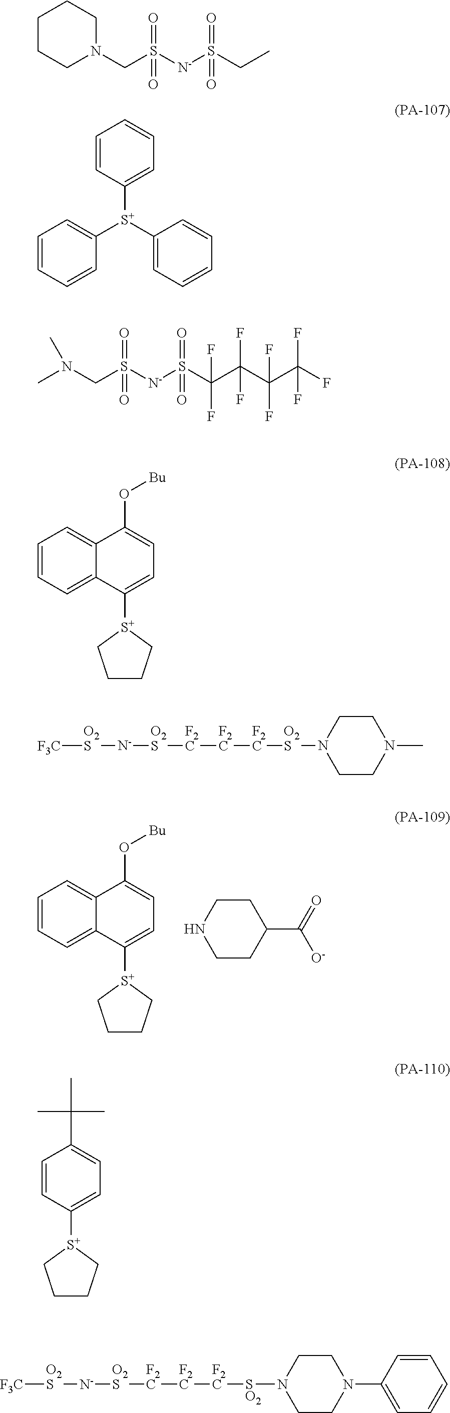

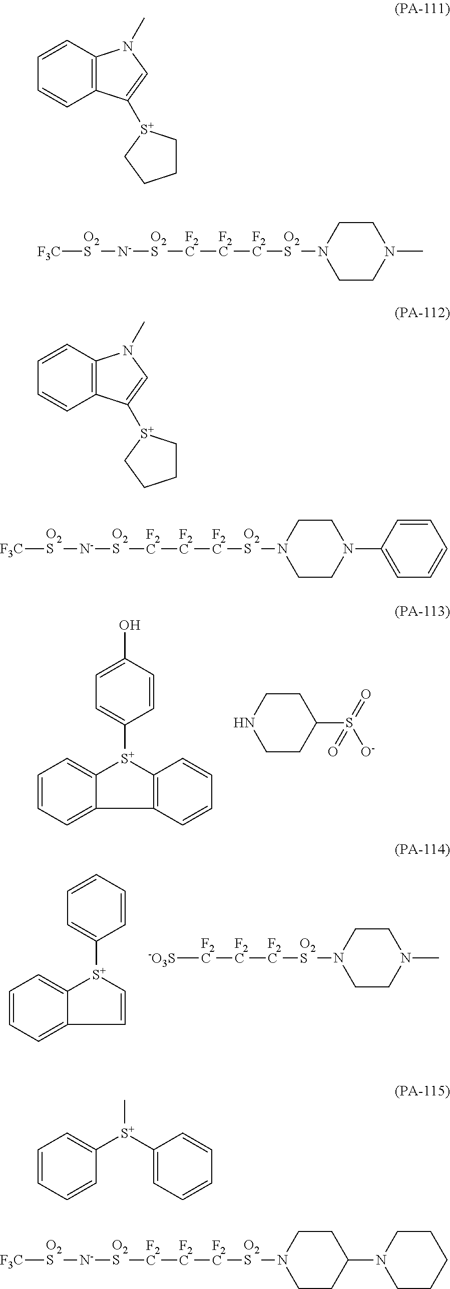

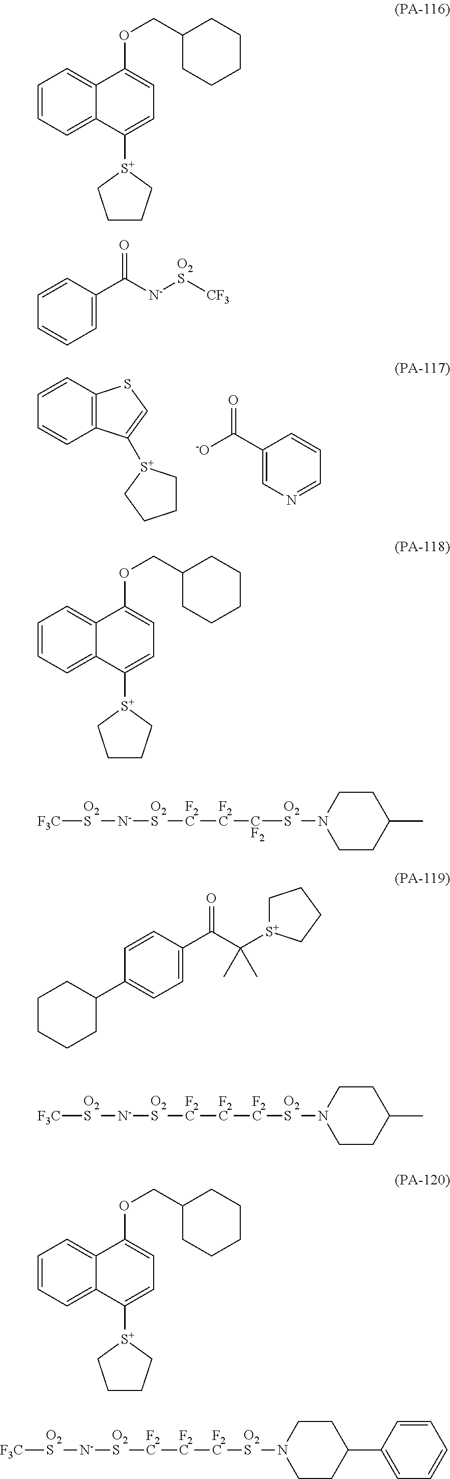

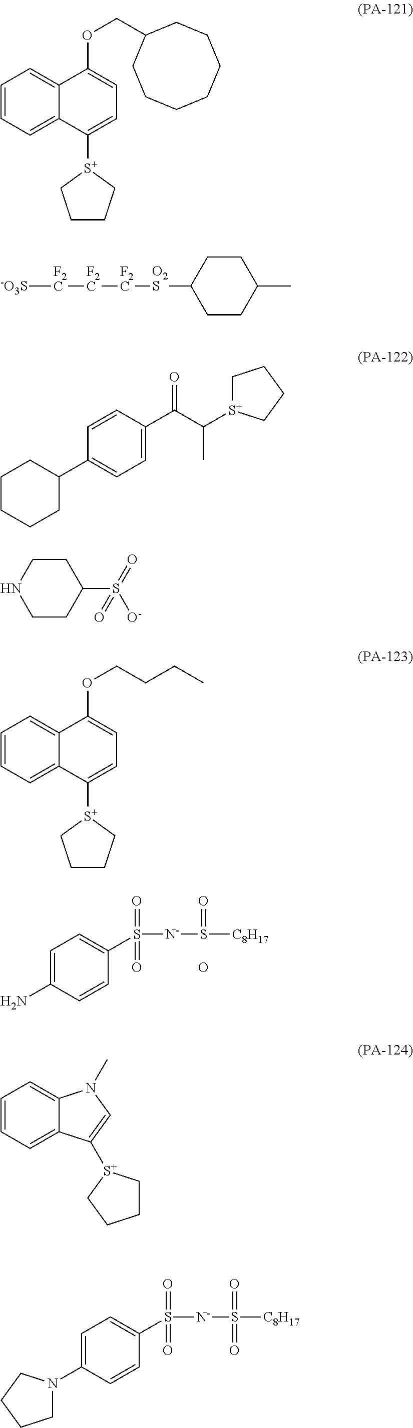

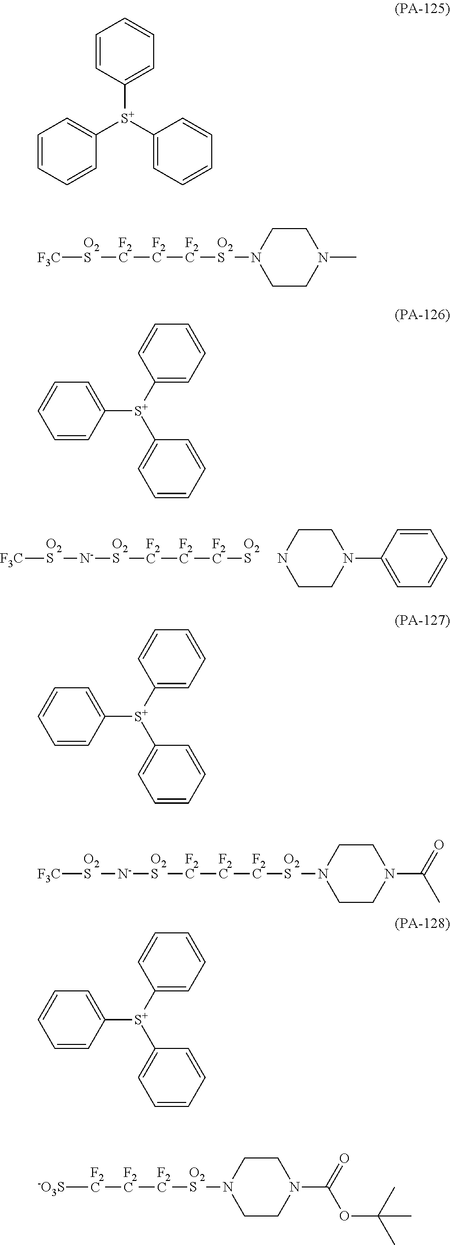

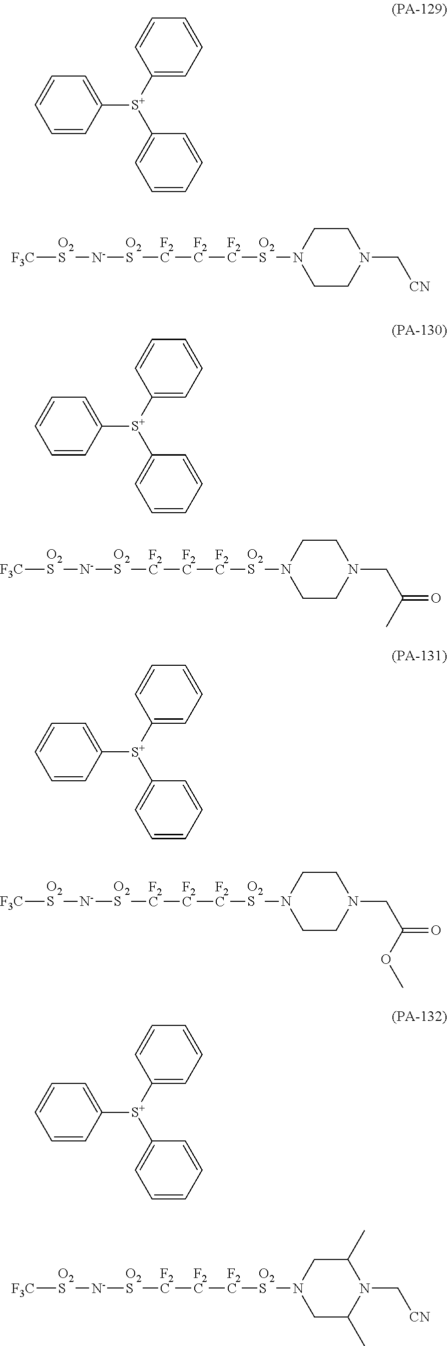

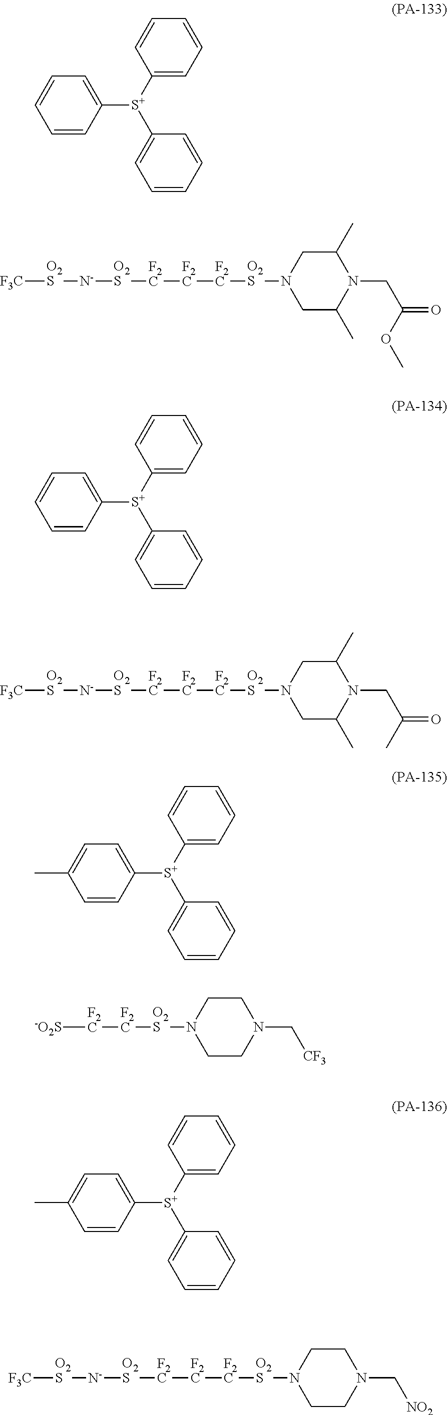

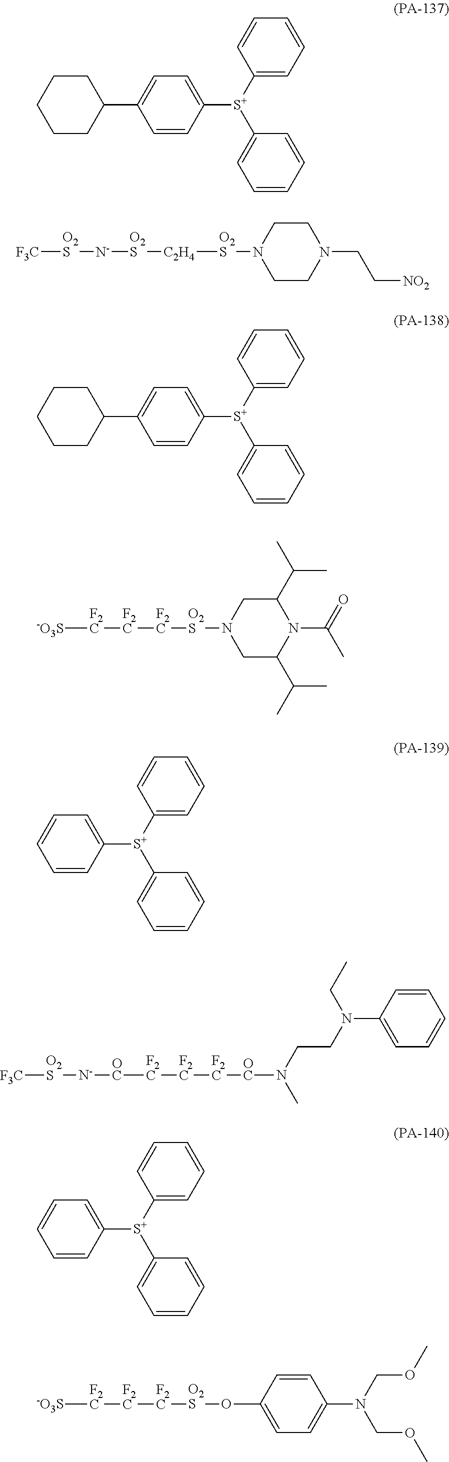

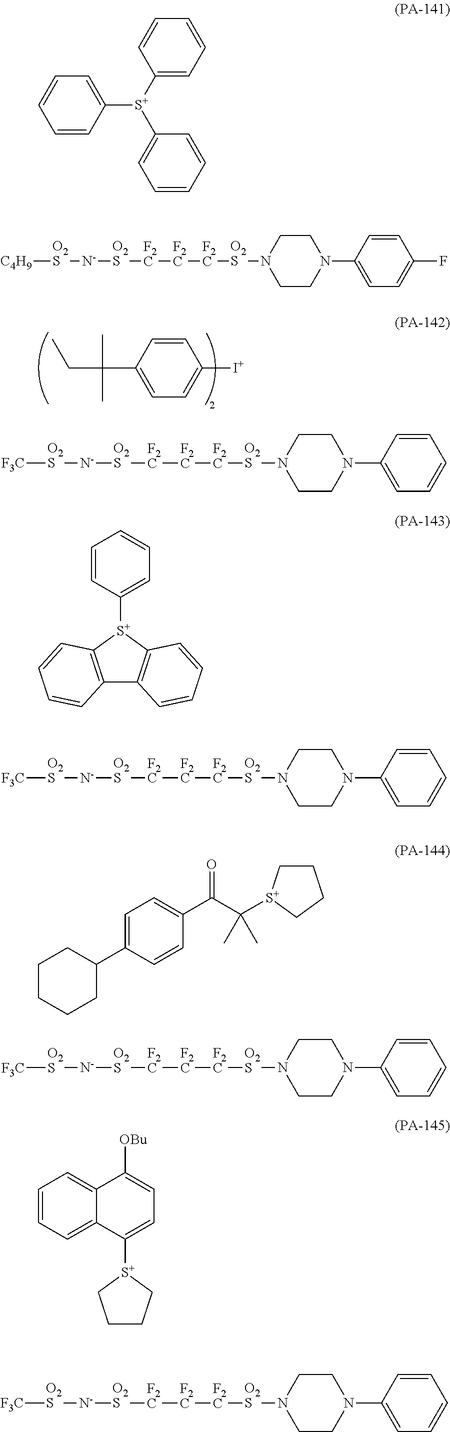

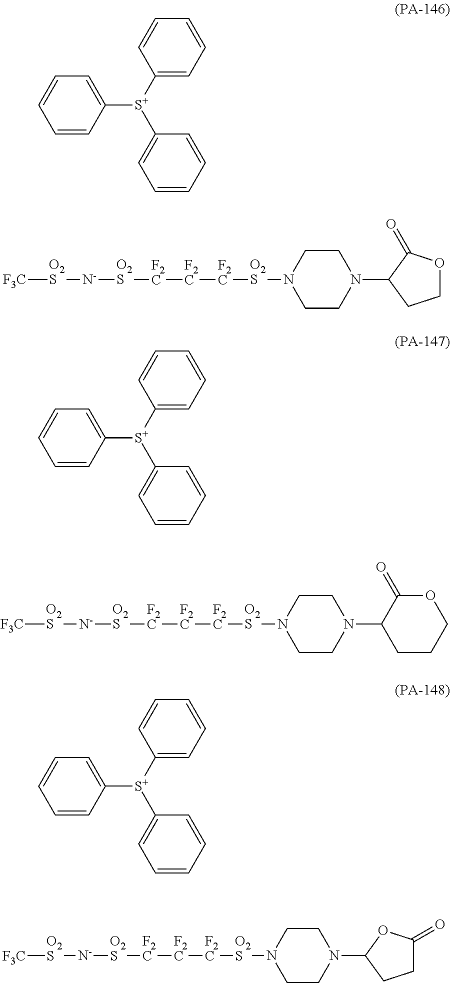 [SMILES: c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1OCCCC1N1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1CCC(N2CCN(S(=O)(=O)C(F)(F)C(F)(F)C(F)(F)S(=O)(=O)[N-]S(=O)(=O)C(F)(F)F)CC2)O1]

These compounds can be easily synthesized by using a general sulfonic acid esterification reaction or sulfonamidation reaction. For example, the compound may be obtained by a method of selectively reacting one sulfonyl halide moiety of a bis-sulfonyl, halide compound with an amine, alcohol or the like containing a partial structure represented by formula (PA-II) or (PA-III) to form a sulfonamide bond or a sulfonic acid ester bond and then hydrolyzing other sulfonyl halide moiety, or a method of ring-opening a cyclic sulfonic anhydride by an amine or alcohol containing a partial structure represented by formula (PA-II). The amine or alcohol containing a partial structure represented by formula (PA-II) or (PA-III) can be synthesized by reacting an amine or alcohol with an anhydride (e.g., (R′O₂C)₂O, (R′SO₂)₂O) or an acid chloride compound (e.g., R′O₂CCl, R′SO₂Cl) under basic conditions (R′ is, for example, a methyl group, an n-octyl group or a trifluoromethyl group). In particular, the synthesis may be performed in accordance with synthesis examples and the like in JP-A-2006-330098.

The molecular weight of the compound (N) is preferably from 500 to 1,000.

The actinic ray-sensitive or radiation-sensitive resin composition of the present invention may or may not contain the compound (N), but in the case of containing the compound (N), the content thereof is preferably from 0.1 to 20 mass %, more preferably from 0.1 to 10 mass %, based on the solid content of the actinic ray-sensitive or radiation-sensitive resin composition.

### [6-2](N′) Basic Compound

The actinic ray-sensitive or radiation-sensitive resin composition of the present invention may contain (N′) a basic compound so as to reduce the change in performance with aging from exposure to heating.

Preferred basic compounds include compounds having a structure represented by the following formulae (A) to (E):

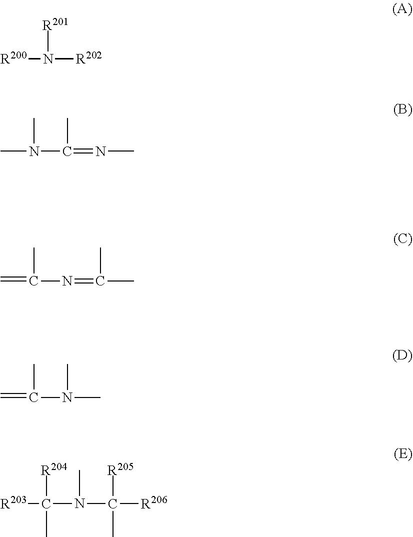

In formulae (A) to (E), each of R²⁰⁰, R²⁰¹ and R²⁰², which may be the same or different, represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine with each other to form a ring. Each of R²⁰³, R²⁰⁴, R²⁰⁵ and R₂₀₆, which may be the same or different, represents an alkyl group having a carbon number of 1 to 20.

As for the alkyl group, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

The alkyl group in formulae (A) to (E) is more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include a triarylsulfonium hydroxide, a phenacylsulfonium hydroxide, and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure becomes a carboxylate, and examples thereof include an acetate, an adamantane-1-carboxylate, and a perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Other preferred basic compounds include a phenoxy group-containing amine compound, a phenoxy group-containing ammonium salt compound, a sulfonic acid ester group-containing amine compound, and a sulfonic acid ester group-containing ammonium salt compound.

In the phenoxy group-containing amine compound, phenoxy group-containing ammonium salt compound, sulfonic acid ester group-containing amine compound and sulfonic acid ester group-containing ammonium salt compound, at least one alkyl group is preferably bonded to the nitrogen atom and also, the alkyl chain preferably contains an oxygen atom therein to form an oxyalkylene group. The number of oxyalkylene groups in the molecule is 1 or more, preferably from 3 to 9, more preferably from 4 to 6. Among oxyalkylene groups, those having a structure of —CH₂CH₂O—, —CH(CH₃)CH₂O— or —CH₂CH₂CH₂O— are preferred.

Specific examples of the phenoxy group-containing amine compound, phenoxy group-containing ammonium salt compound, sulfonic acid ester group-containing amine compound and sulfonic acid ester group-containing ammonium salt compound include, but are not limited to, Compounds (C1-1) to (C3-3) illustrated in paragraph [0066] of U.S. Patent Application Publication 2007/0224539.

A nitrogen-containing organic compound having a group capable of leaving by the action of an acid may be also used as a kind of the basic compound. Examples of this compound include a compound represented by the following formula (F). Incidentally, the compound represented by the following formula (F) exhibits an effective basicity in the system as a result of elimination of the group capable of leaving by the action of an acid.

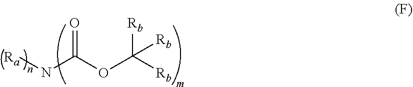

In formula (F), each Ra independently represents a hydrogen atom, an alkyl group, a cycloalkyl group, an aryl group, or an aralkyl group. Also, when n=2, two Ra's may be the same or different, and two Ra's may combine with each other to form a divalent heterocyclic hydrocarbon group (preferably having a carbon number of 20 or less) or a derivative thereof.

Each Rb independently represents a hydrogen atom, an alkyl group, a cycloalkyl group, an aryl group, or an aralkyl group, provided that in —C(Rb)(Rb)(Rb), when one or more Rb's are a hydrogen atom, at least one of remaining Rb's is a cyclopropyl group or a 1-alkoxyalkyl group.

At least two Rb's may combine to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In formula (F), each of the alkyl group, cycloalkyl group, aryl group and aralkyl group represented by Ra and Rb may be substituted with a functional group such as hydroxyl group, cyano group, amino group, pyrrolidino group, piperidino group, morpholino group and oxo group, an alkoxy group, or a halogen atom.

Examples of the alkyl group, cycloalkyl group, aryl group and aralkyl group (each of these alkyl group, cycloalkyl group, aryl group and aralkyl group may be substituted with the above-described functional group, an alkoxy group or a halogen atom) of R include:

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more groups of cycloalkyl group such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydrofuran, tetrahydropyran, indole, indoline, quinoline, perhydroquinoline, indazole and benzimidazole, or a group where the group derived from a heterocyclic compound is substituted with one or more kinds of or one or more groups of linear or branched alkyl group or aromatic compound-derived group; a group where the group derived from a linear or branched alkane or the group derived from a cycloalkane is substituted with one or more kinds of or one or more groups of aromatic compound-derived group such as phenyl group, naphthyl group and anthracenyl group; and a group where the substituent above is substituted with a functional group such as hydroxyl group, cyano group, amino group, pyrrolidino group, piperidino group, morpholino group and oxo group.

Examples of the divalent heterocyclic hydrocarbon group (preferably having a carbon number of 1 to 20) formed by combining Ra's with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[44.4]dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more groups of linear or branched alkane-derived group, cycloalkane-derived group, aromatic compound-derived group, heterocyclic compound-derived group, and functional group such as hydroxyl group, cyano group, amino group, pyrrolidino group, piperidino group, morpholino group and oxo group.

Specific examples of the compound represented by formula (F) are illustrated below.

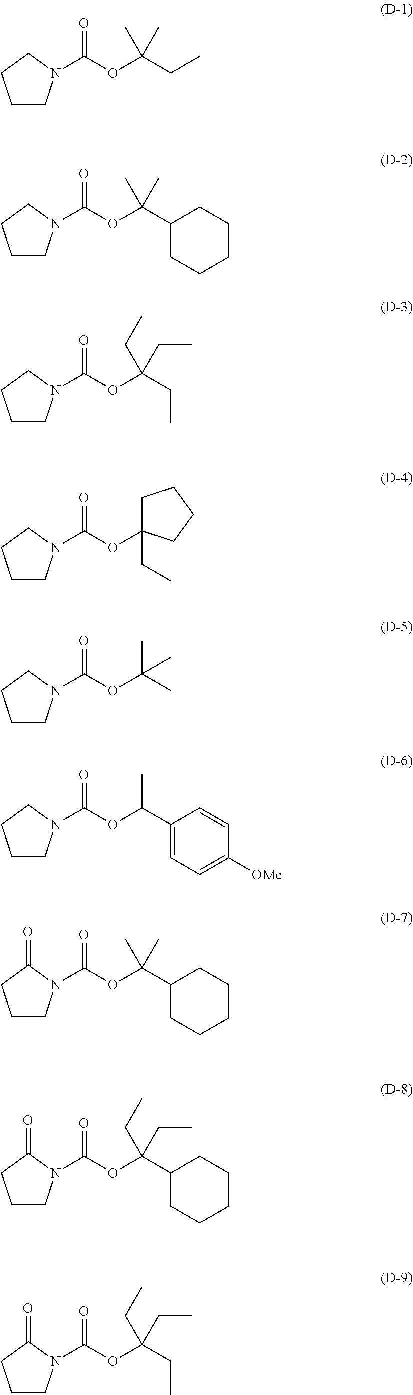

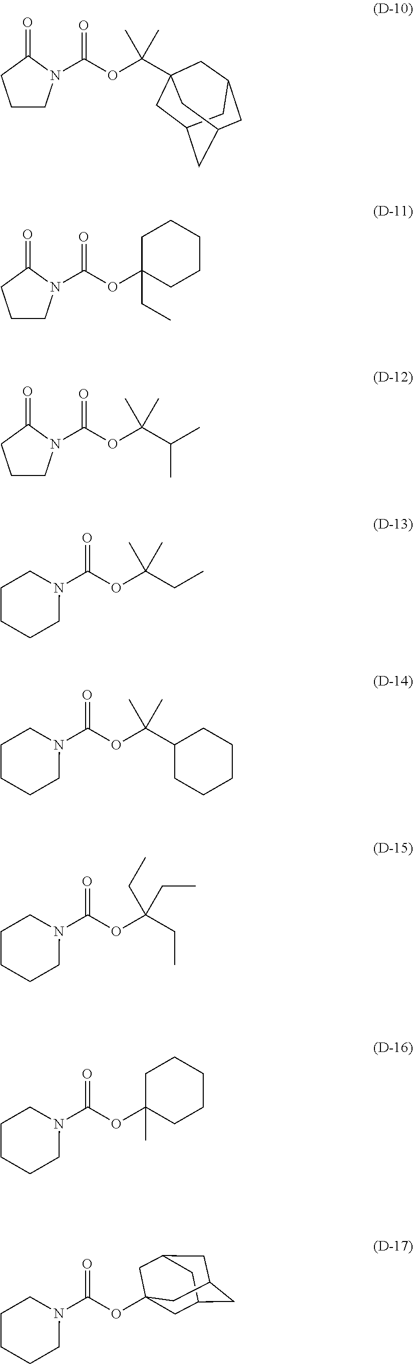

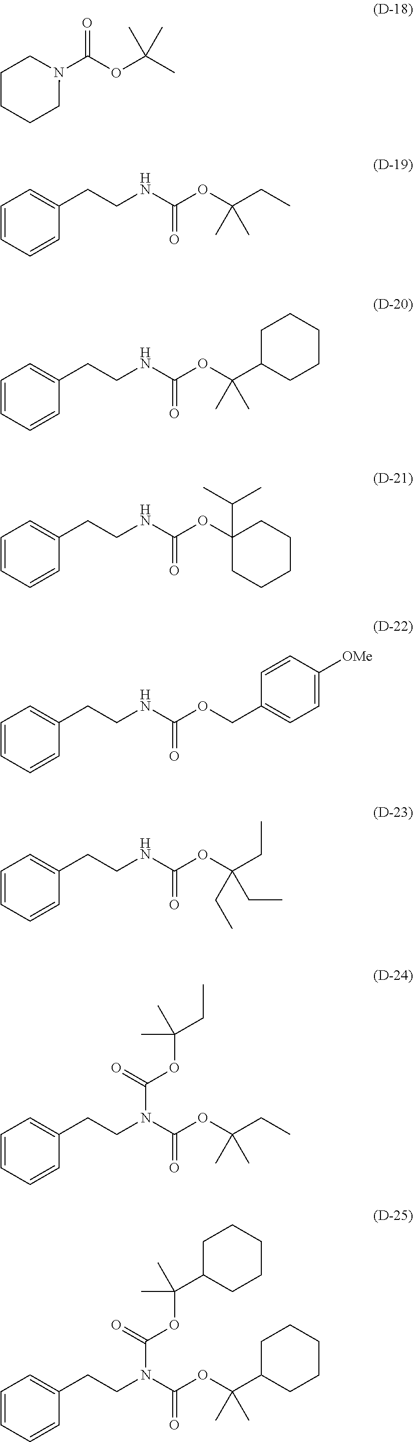

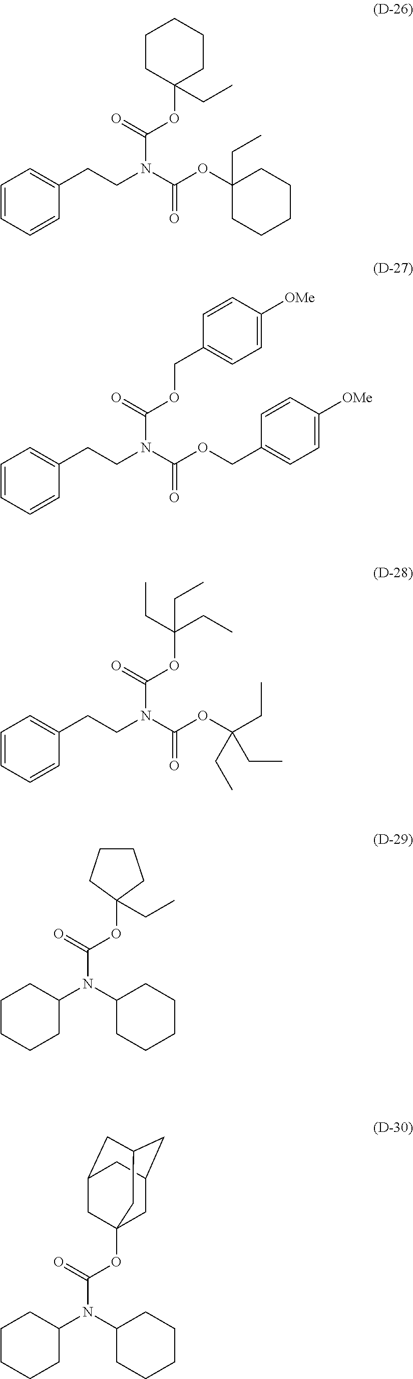 [SMILES: CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1 ; O=C(OC12CC3CC(CC(C3)C1)C2)N(C1CCCCC1)C1CCCCC1]

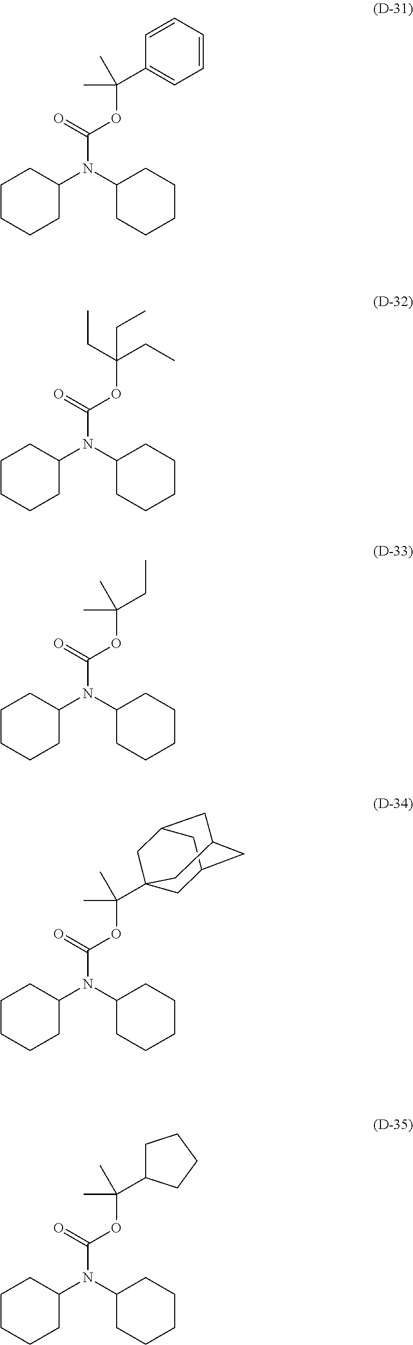 [SMILES: CC(C)(OC(=O)N(C1CCCCC1)C1CCCCC1)c1ccccc1 ; CCC(CC)(CC)OC(=O)N(C1CCCCC1)C1CCCCC1 ; CCC(C)(C)OC(=O)N(C1CCCCC1)C1CCCCC1 ; CC(C)(OC(=O)N(C1CCCCC1)C1CCCCC1)C12CC3CC(CC(C3)C1)C2 ; CC(C)(OC(=O)N(C1CCCCC1)C1CCCCC1)C1CCCC1]

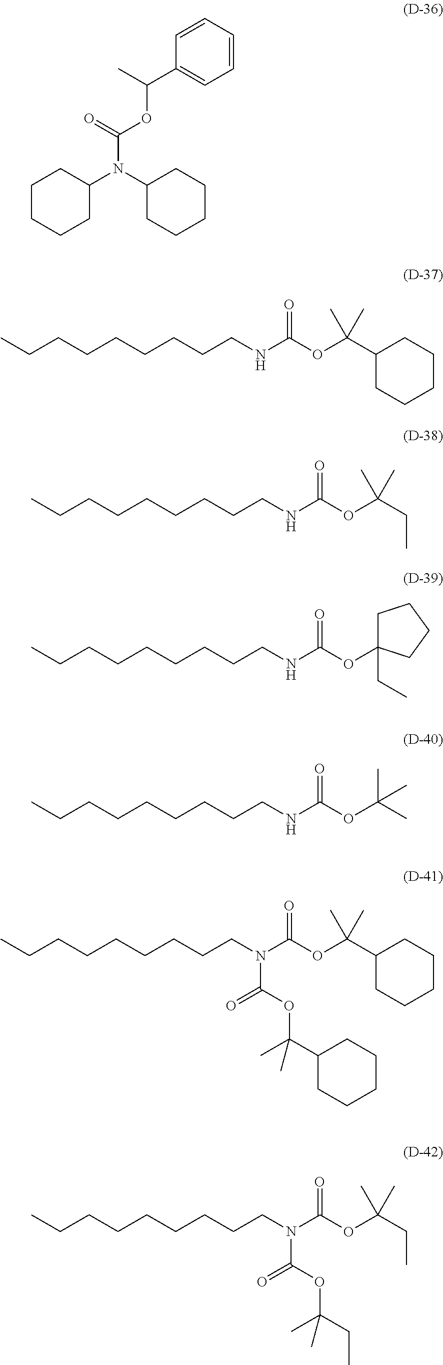

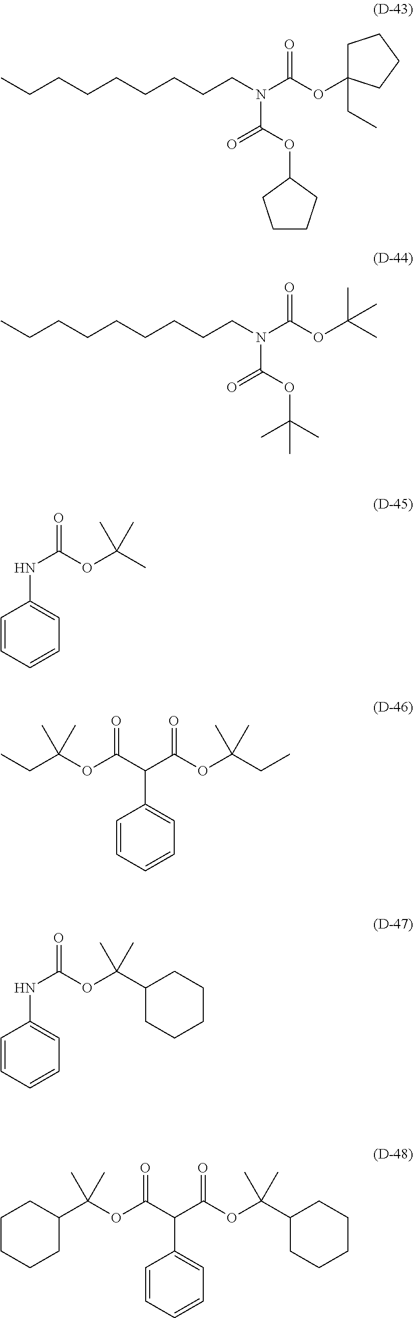

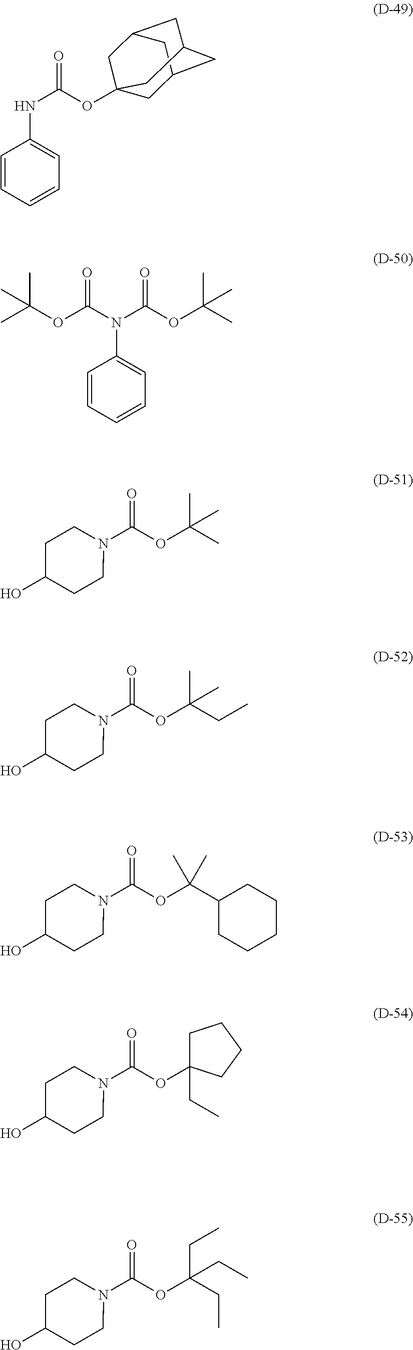

As for the compound represented by formula (F), a commercially available product may be used, or the compound may be synthesized from a commercially available amine by the method described, for example, in Protective Groups in Organic Synthesis, 4th edition. As a most general method, the compound can be synthesized in accordance with the method described, for example, in JP-A-2009-199021.

As the basic compound, a compound having an amine oxide structure may be also used. Specific examples of the compound which can be used include triethylaminepyridine N-oxide, tributylamine N-oxide, triethanolamine N-oxide, tris(methoxyethyl)amine N-oxide, tris(2-(methoxymethoxy)ethyl)amine=oxide, 2,2′,2″-nitrilotriethylpropionate N-oxide, N-2-(2-methoxyethoxy)methoxyethylmorpholine N-oxide, and amine oxide compounds exemplified in JP-A-2008-102383.

The molecular weight of the basic compound is preferably from 250 to 2,000, more preferably from 400 to 1,000. In view of more reduction of LWR and uniformity of local pattern dimension, the molecular weight of the basic compound is preferably 400 or more, more preferably 500 or more, still more preferably 600 or more.

Such a basic compound (N′) may be used in combination with the compound (N), and one basic compound is used alone, or two or more basic compounds are used in combination.

The actinic ray-sensitive or radiation-sensitive resin composition of the present invention may or may not contain the basic compound, but in the case of containing the basic compound, the amount used thereof is usually from 0.001 to 10 mass %, preferably from 0.01 to 5 mass %, based on the solid content of the actinic ray-sensitive or radiation-sensitive resin composition.

The ratio between the acid generator and the basic compound used in the composition is preferably acid generator/basic compound (molar ratio)=from 2.5 to 300. That is, the molar ratio is preferably 2.5 or more in view of sensitivity and resolution and is preferably 300 or less from the standpoint of preventing the resolution from reduction due to thickening of the resist pattern with aging after exposure until heat treatment. The acid generator/basic compound (molar ratio) is more preferably from 5.0 to 200, still more preferably from 7.0 to 150.

### [7](E) Solvent

Examples of the solvent which can be used at the preparation of the actinic ray-sensitive or radiation-sensitive resin composition of the present invention include an organic solvent such as alkylene glycol monoalkyl ether carboxylate, alkylene glycol monoalkyl ether, alkyl lactate, alkyl alkoxypropionate, cyclic lactone (preferably having a carbon number of 4 to 10), monoketone compound (preferably having a carbon number of 4 to 10) which may have a ring, alkylene carbonate, alkyl alkoxyacetate and alkyl pyruvate.

Specific examples of these solvents include those described in paragraphs [0441] to [0455] of U.S. Patent Application Publication No. 2008/0187860.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds exemplified above, but preferred examples of the solvent containing a hydroxyl group include an alkylene glycol monoalkyl ether and an alkyl lactate, with propylene glycol monomethyl ether (PGME, another name: 1-methoxy-2-propanol) and ethyl lactate being more preferred. Preferred examples of the solvent not containing a hydroxyl group include an alkylene glycol monoalkyl ether acetate, an alkyl alkoxypropionate, a monoketone compound which may contain a ring, a cyclic lactone, and an alkyl acetate. Among these, propylene glycol monomethyl ether acetate (PGMEA, another name: 1-methoxy-2-acetoxypropane), ethyl ethoxypropionate, 2-heptanone, γ-butyrolactone, cyclohexanone and butyl acetate are more preferred, and propylene glycol monomethyl ether acetate, ethyl ethoxypropionate and 2-heptanone are most preferred.

The mixing ratio (by mass) of the solvent containing a hydroxyl group to the solvent not containing a hydroxyl group is from 1/99 to 99/1, preferably from 10/90 to 90/10, more preferably from 20/80 to 60/40. A mixed solvent in which the solvent not containing a hydroxyl group is contained in a ratio of 50 mass % or more is particularly preferred in view of coating uniformity.

The solvent preferably contains propylene glycol monomethyl ether acetate and is preferably a solvent composed of propylene glycol monomethyl ether acetate alone or a mixed solvent of two or more kinds of solvents containing propylene glycol monomethyl ether acetate.

### [8](F) Surfactant

The actinic ray-sensitive or radiation-sensitive resin composition of the present invention may or may not further contain a surfactant, but in the case of containing a surfactant, it is preferred to contain any one of fluorine-containing and/or silicon-containing surfactants (a fluorine-containing surfactant, a silicon-containing surfactant and a surfactant containing both a fluorine atom and a silicon atom), or two or more thereof.

By containing the surfactant, the actinic ray-sensitive or radiation-sensitive resin composition of the present invention can give a resist pattern improved in the sensitivity, resolution and adherence and reduced in the development defect when an exposure light source with a wavelength of 250 nm or less, particularly 220 nm or less, is used.

The fluorine-containing and/or silicon-containing surfactants include the surfactants described in paragraph [0276] of U.S. Patent Application Publication No. 2008/0248425, and examples thereof include EFtop EF301 and EF303 (produced by Shin-Akita Kasei K.K.); Florad FC430, 431 and 4430 (produced by Sumitomo 3M Inc.); Megaface F171. F173, F176, F189, F113, F110, F177, F120 and R08 (produced by DIC Corp.); Surflon S-382, SC101, 102, 103, 104, 105 and 106, and KH-20 (produced by Asahi Glass Co., Ltd.); Troysol S-366 (produced by Troy Chemical); OF-300 and GF-150 (produced by Toagosei Chemical Industry Co., Ltd.); Surflon S-393 (produced by Seimi Chemical Co., Ltd.); EFtop EF121, EF122A, EFI22B, RF122C, EF125M, EFI35M, EF351, EF352, EF801, EF802 and EF601 (produced by JEMCO Inc.); PF636, PF656, PF6320 and PF6520 (produced by OMNOVA); and FTX-204G, 208G, 218G, 2300i, 204D, 208D, 212D, 218D and 222D (produced by NEOS Co., Ltd.). In addition, polysiloxane polymer KP-341 (produced by Shin-Etsu Chemical Co., Ltd.) may be also used as the silicon-containing surfactant.

Other than those known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

Examples of the surfactant coming under the surfactant above include Megaface F178, F-470, F-473, F-475, F-476 and F-472 (produced by DIC Corp.); a copolymer of a C₆H₃ group-containing acrylate (or methacrylate) with a (poly(oxyalkylene)) acrylate (or methacrylate); and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactants, described in paragraph [0280] of U.S. Patent Application Publication No. 2008/0248425 may be also used.

One of these surfactants may be used alone, or some of them may be used in combination.

In the case where the actinic ray-sensitive or radiation-sensitive resin composition contains a surfactant, the amount of the surfactant used is preferably from 0.0001 to 2 mass/o %, more preferably from 0.0005 to 1 mass %, based on the total amount of the actinic ray-sensitive or radiation-sensitive resin composition (excluding the solvent).

On the other hand, when the amount added of the surfactant is set to 10 ppm or less based on the total amount of the actinic ray-sensitive or radiation-sensitive resin composition (excluding the solvent), the hydrophobic resin is more unevenly distributed to the surface, so that the resist film surface can be made more hydrophobic and the followability of water at the immersion exposure can be enhanced.

### [9](G) Other Additives

The actinic ray-sensitive or radiation-sensitive resin composition of the present invention may or may not contain an onium carboxylate. Examples of the onium carboxylate include those described in paragraphs [0605] to [0606] of U.S. Patent Application Publication No. 2008/0187860.

Such an onium carboxylate can be synthesized by reacting a sulfonium hydroxide, iodonium hydroxide or ammonium hydroxide and a carboxylic acid with silver oxide in an appropriate solvent.

In the case where the actinic ray-sensitive or radiation-sensitive resin composition contains an onium carboxylate, the content thereof is generally from 0.1 to 20 mass %, preferably from 0.5 to 10 mass %, more preferably from 1 to 7 mass %, based on the total solid content of the composition.

The actinic ray-sensitive or radiation-sensitive resin composition of the present invention may further contain, for example, a dye, a plasticizer, a photosensitizer, a light absorber, an alkali-soluble resin, a dissolution inhibitor, and a compound for accelerating dissolution in a developer (for example, a phenol compound having a molecular weight of 1,000 or less, or a carboxyl group-containing alicyclic or aliphatic compound), if desired.

The phenol compound having a molecular weight of 1,000 or less can be easily synthesized by one skilled in the art by referring to the method described, for example, in JP-A-4-122938, JP-A-2-28531, U.S. Pat. No. 4,916,210 and European Patent 219294.

Specific examples of the carboxyl group-containing alicyclic or aliphatic compound include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid, and a cyclohexanedicarboxylic acid.

From the standpoint of enhancing the resolution, the actinic ray-sensitive or radiation-sensitive resin composition of the present invention is preferably used in a film thickness of 30 to 250 nm, more preferably from 30 to 200 nm. Such a film thickness can be achieved by setting the solid content concentration in the composition to an appropriate range, thereby imparting an appropriate viscosity and enhancing the coatability and film-forming property.

The solid content concentration of the actinic ray-sensitive or radiation-sensitive resin composition of the present invention is usually from 1.0 to 10 mass %, preferably from 2.0 to 5.7 mass %, more preferably from 2.0 to 5.3 mass %. By setting the solid content concentration to the range above, the resist solution can be uniformly coated on a substrate and furthermore, a resist pattern improved in the line width roughness can be formed. The reason therefor is not clearly known, but it is considered that thanks to a solid content concentration of 10 mass % or less, preferably 5.7 mass % or less, aggregation of materials, particularly, a photoacid generator, in the resist solution is suppressed, as a result, a uniform resist film can be formed.

The solid content concentration is a weight percentage of the weight of resist components excluding the solvent, based on the total weight of the actinic my-sensitive or radiation-sensitive resin composition.

The actinic ray-sensitive or radiation-sensitive resin composition of the present invention is used by dissolving the components above in a predetermined organic solvent, preferably in the above-described mixed solvent, filtering the solution through a filter, and coating the filtrate on a predetermined support (substrate). The filter used for filtration is preferably a polytetrafluoroethylene-, polyethylene- or nylon-made filter having a pore size of 0.1 μm or less, more preferably 0.05 μm or less, still more preferably 0.03 μm or less. In the filtration through a filter, as described, for example, in JP-A-2002-62667, circulating filtration may be performed, or the filtration may be performed by connecting a plurality of kinds of filters in series or in parallel. Also, the composition may be filtered a plurality of times. Furthermore, a deaeration treatment or the like may be subjected to the composition before and after filtration through a filter.

### [10] Pattern Forming Method

The pattern forming method (negative pattern forming method) of the present invention includes at least:

(i) a step of forming a film (resist film) from an actinic ray-sensitive or radiation-sensitive resin composition,

(ii) a step of exposing the film, and

(iii) a step of performing development by using an organic solvent-containing developer to a negative pattern.

The exposure in the step (ii) may be immersion exposure.

The pattern forming method of the present invention preferably includes (iv) a heating step after the exposure step (ii).

The pattern forming method of the present invention may further include (v) a step of performing development by using an alkali developer.

In the pattern forming method of the present invention, the exposure step (ii) may be performed a plurality of times.

In the pattern forming method of the present invention, the heating step (v) may be performed a plurality of times.

The resist film is formed from the above-described actinic ray-sensitive or radiation-sensitive resin composition of the present invention and, more specifically, is preferably formed on a substrate. In the pattern forming method of the present invention, the step of forming a film on a substrate by using the actinic ray-sensitive or radiation-sensitive resin composition, the step of exposing the film, and the development step can be performed by generally known methods.

It is also preferred to include, after film formation, a pre-baking step (PB) before entering the exposure step.

Furthermore, it is also preferred to include a post-exposure baking step (PEB) after the exposure step but before the development step.

As for the heating temperature, both PB and PEB are preferably performed at 70 to 130° C. more preferably at 80 to 120° C.

The heating time is preferably from 30 to 300 seconds, more preferably from 30 to 180 seconds, still more preferably from 30 to 90 seconds.

The heating can be performed using a device attached to an ordinary exposure/developing machine or may be performed using a hot plate or the like.

Thanks to baking, the reaction in the exposed area is accelerated, and the sensitivity and pattern profile are improved.

The light source of the exposure apparatus for use in the present invention is not particularly limited in its wavelength but includes, for example, infrared light, visible light, ultraviolet light, far ultraviolet light, extreme-ultraviolet light, X-ray and electron beam and is preferably far ultraviolet light having a wavelength of 250 nm or less, more preferably 220 nm or less, still more preferably from 1 to 200 nm. Specific examples thereof include KrF excimer laser (248 nm), ArF excimer laser (193 nm), F₂ excimer laser (157 nm), X-ray, EUV (13 nm) and electron beam. Among these, KrF excimer laser, ArF excimer laser, EUV and electron beam are preferred, and ArF excimer laser is more preferred.

In the present invention, an immersion exposure method can be applied in the step of performing exposure.

The immersion exposure method is a technique to increase the resolution, and this is a technique of performing the exposure by filling a high refractive-index liquid (hereinafter, sometimes referred to as an “immersion liquid”) between the projection lens and the sample.

As for the “effect of immersion”, assuming that λ₀ is the wavelength of exposure light in air, n is the refractive index of the immersion liquid for air, θ is the convergence half-angle of beam and NA₀=sin θ, the resolution and the depth of focus in immersion can be expressed by the following formulae. Here, k₁ and k₂ are coefficients related to the process.

(Resolution)=k₁*(λ₀/n)/NA₀

(Depth of focus)=±k₂*(λ₀/n)/NA₀²

That is, the effect of immersion is equal to use of an exposure wavelength of 1/n. In other words, in the case of a projection optical system having the same NA, the depth of focus, can be made n times larger by the immersion. This is effective for all pattern profiles and furthermore, can be combined with the super-resolution technology under study at present, such as phase-shift method and modified illumination method.

In the case of performing immersion exposure, a step of washing the film surface with an aqueous chemical solution may be performed (1) before the exposure step after forming the film on a substrate and/or (2) after the step of exposing the film through an immersion liquid but before the step of heating the film.

The immersion liquid is preferably a liquid being transparent to light at the exposure wavelength and having as small a temperature coefficient of refractive index as possible in order to minimize the distortion of an optical image projected on the film. Particularly, when the exposure light source is ArF excimer laser (wavelength: 193 nm), water is preferably used in view of easy availability and easy handleability in addition to the above-described aspects.

In the case of using water, an additive (liquid) capable of decreasing the surface tension of water and increasing the interface activity may be added in a small ratio. This additive is preferably an additive that does not dissolve the resist layer on the wafer and at the same time, gives only a negligible effect on the optical coat at the undersurface of the lens element.

Such an additive is preferably, for example, an aliphatic alcohol having a refractive index substantially equal to that of water, and specific examples thereof include methyl alcohol, ethyl alcohol and isopropyl alcohol. By virtue of adding an alcohol having a refractive index substantially equal to that of water, even when the alcohol component in water is evaporated and its content concentration is changed, the change in the refractive index of the liquid as a whole can be advantageously made very small.

On the other hand, if a substance opaque to light at 193 nm or an impurity greatly differing in the refractive index from water is mingled, this incurs distortion of the optical image projected on the resist. Therefore, the water used is preferably distilled water. Furthermore, pure water after filtration through an ion exchange filter or the like may be also used.

The electrical resistance of water used as the immersion liquid is preferably 18.3 MQcm or more, and TOC (total organic carbon) is preferably 20 ppb or less. The water is preferably subjected to a deaeration treatment.

Also, the lithography performance can be enhanced by raising the refractive index of the immersion liquid. From such a standpoint, an additive for increasing the refractive index may be added to water, or heavy water (D₂O) may be used in place of water.

In the case where the film formed using the composition of the present invention is exposed through an immersion medium, the above-described hydrophobic resin (D) may be further added, if desired. The receding contact angle on the surface is increased by the addition of the hydrophobic resin (D). The receding contact angle of the film is preferably from 60 to 90°, more preferably 70° or more.

In the immersion exposure step, the immersion liquid must move on a wafer following the movement of an exposure head that is scanning the wafer at a high speed and forming an exposure pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

In order to prevent the film from directly contacting with the immersion liquid, a film (hereinafter, sometimes referred to as a “topcoat”) slightly soluble in the immersion liquid may be provided between the film formed using the composition of the present invention and the immersion liquid. The functions required of the topcoat are suitability for coating as a resist overlayer, transparency to radiation, particularly, radiation having a wavelength of 193 unm, and sparing solubility in immersion liquid. The topcoat is preferably unmixable with the resist and capable of being uniformly coated as a resist overlayer.

In view of transparency to light at 193 nm, the topcoat is preferably an aromatic-free polymer.

Specific examples thereof include a hydrocarbon polymer, an acrylic acid ester polymer, a polymethacrylic acid, a polyacrylic acid, a polyvinyl ether, a silicon-containing polymer, and a fluorine-containing polymer. The above-described hydrophobic resin (D) is suitable also as the topcoat. If impurities are dissolved out into the immersion liquid from the topcoat, the optical lens is contaminated. For this reason, residual monomer components of the polymer are preferably little contained in the topcoat.

When removing the topcoat, a developer may be used, or a release agent may be separately used. The release agent is preferably a solvent less likely to permeate the film. From the standpoint that the removing step can be performed simultaneously with the development step of the film, the topcoat is preferably removable with an alkali developer and in view of removal with an alkali developer, the topcoat is preferably acidic, but in consideration of non-intermixing with the film, the topcoat may be neutral or alkaline.

The difference in the refractive index between the topcoat and the immersion liquid is preferably null or small. In this case, the resolution can be enhanced. In the case where the exposure light source is ArF excimer laser (wavelength: 193 nm), water is preferably used as the immersion liquid and therefore, the topcoat for ArF immersion exposure preferably has a refractive index close to the refractive index (1.44) of water. Also, in view of transparency and refractive index, the topcoat is preferably a thin film.

The topcoat is preferably unmixable with the film and further unmixable also with the immersion liquid. From this standpoint, when the immersion liquid is water, the solvent used for the topcoat is preferably a medium that is sparingly soluble in the solvent used for the composition of the present invention and is insoluble in water. Furthermore, when the immersion liquid is an organic solvent, the topcoat may be either water-soluble or water-insoluble.

In the present invention, the substrate on which the film is formed is not particularly limited, and an inorganic substrate such as silicon, SiN, SiO₂ and SiN, a coating-type inorganic substrate such as SOG, or a substrate generally used in the process of producing a semiconductor such as IC or producing a liquid crystal device or a circuit board such as thermal head or in the lithography of other photo-fabrication processes can be used. If desired, an organic antireflection film may be formed between the film and the substrate.

In the case where the pattern forming method of the present invention further includes a step of developing the film with an alkali developer, examples of the alkali developer which can be used include an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, or cyclic amines such as pyrrole and piperidine.

This alkaline aqueous solution may be also used after adding thereto alcohols and a surfactant each in an appropriate amount.

The alkali concentration of the alkali developer is usually from 0.1 to 20 mass %.

The pH of the alkali developer is usually from 10.0 to 15.0.

In particular, an aqueous 2.38 mass % tetramethylammonium hydroxide solution is preferred.

As for the rinsing solution in the rinsing treatment performed after the alkali development, pure water is used, and the pure water may be used after adding thereto a surfactant in an appropriate amount.

After the development or rinsing, a treatment of removing the developer or rinsing solution adhering on the pattern by a supercritical fluid may be performed.

As for the developer which can be used in the step of developing the film by using an organic solvent-containing developer (hereinafter, sometimes referred to as an “organic developer”), a polar solvent such as ketone-based solvent, ester-based solvent, alcohol-based solvent, amide-based solvent and ether-based solvent, or a hydrocarbon-based solvent can be used.

Examples of the ketone-based solvent include 1-octanone, 2-octanone, I-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol.

Examples of the ether-based solvent include, in addition to the glycol ether-based solvents above, dioxane and tetrahydrofuran.

Examples of the amide-based solvent which can be used include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include an aromatic hydrocarbon-based solvent such as toluene and xylene, and an aliphatic hydrocarbon-based solvent such as pentane, hexane, octane and decane.

A plurality of these solvents may be mixed, or the solvent may be used by mixing it with a solvent other than those described above or with water. However, in order to sufficiently bring out the effects of the present invention, the water content ratio in the entire developer is preferably less than 10 mass/%, and it is more preferred to contain substantially no water.

That is, the amount of the organic solvent used in the organic developer is preferably from 90 to 100 mass %, more preferably from 95 to 100 mass %, based on the total amount of the developer.

In particular, the organic developer is preferably a developer containing at least one kind of an organic solvent selected from the group consisting of a ketone-based solvent, an ester-based solvent, an alcohol-based solvent, an amide-based solvent and an ether-based solvent.

The vapor pressure at 20° C. of the organic developer is preferably 5 kPa or less, more preferably 3 kPa or less, still more preferably 2 kPa or less. By setting the vapor pressure of the organic developer to 5 kPa or less, evaporation of the developer on a substrate or in a development cup is suppressed and the temperature uniformity in the wafer plane is enhanced, as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone and methyl isobutyl ketone; an ester-based solvent such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate; an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an ether-based solvent such as tetrahydrofuran; an amide-based solvent such as N-methyl-2-pyrrolidone, N,N-dimethylacetamide and N,N-dimethylformamide; an aromatic hydrocarbon-based solvent such as toluene and xylene; and an aliphatic hydrocarbon-based solvent such as octane and decane.

Specific examples of the solvent having a vapor pressure of 2 kPa or less that is a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate; an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an amide-based solvent such as N-methyl-2-pyrrolidone, N,N-dimethylacetamide and N,N-dimethylformamide; an aromatic hydrocarbon-based solvent such as xylene; and an aliphatic hydrocarbon-based solvent such as octane and decane.

In the organic developer, a surfactant can be added in an appropriate amount, if desired.

The surfactant is not particularly limited but, for example, ionic or nonionic fluorine-containing and/or silicon-containing surfactants can be used. Examples of the fluorine-containing and/or silicon-containing surfactants include surfactants described in JP-A-62-36663. JP-A-61-226746, JP-A-61-226745, JP-A-62-170950, JP-A-63-34540, JP-A-7-230165, JP-A-8-62834, JP-A-9-54432, JP-A-9-5988 and U.S. Pat. Nos. 5,405,720, 5,360,692, 5,529,881, 5,296,330, 5,436,098, 5,576,143, 5,294,511 and 5,824,451. A nonionic surfactant is preferred. The nonionic surfactant is not particularly limited, but use of a fluorine-containing surfactant or a silicon-containing surfactant is more preferred.

The amount of the surfactant used is usually from 0.001 to 5 mass %, preferably from 0.005 to 2 mass %, more preferably from 0.01 to 0.5 mass %, based on the total amount of the developer.

As regards the developing method, for example, a method of dipping the substrate in a bath filled with the developer for a fixed time (dipping method), a method of raising the developer on the substrate surface by the effect of a surface tension and keeping it still for a fixed time, thereby performing the development (puddling method), a method of spraying the developer on the substrate surface (spraying method), and a method of continuously ejecting the developer on the substrate spinning at a constant speed while scanning with a developer ejecting nozzle at a constant rate (dynamic dispense method) may be applied.

In the case where the above-described various developing methods include a step of ejecting the developer toward the resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, still more preferably 1 mL/sec/mm² or less. The flow velocity has no particular lower limit but in view of throughput, is preferably 0.2 mL/sec/mm² or more.

By setting the ejection pressure of the ejected developer to the range above, pattern defects attributable to the resist scum after development can be greatly reduced.

Details of this mechanism are not clearly known, but it is considered that thanks to the ejection pressure in the above-described range, the pressure imposed on the resist film by the developer becomes small and the resist film or resist pattern is kept from inadvertent chipping or collapse.

Here, the ejection pressure (mL/sec/mm²) of the developer is a value at the outlet of a development nozzle in a developing apparatus.

Examples of the method for adjusting the ejection pressure of the developer include a method of adjusting the ejection pressure by a pump or the like, and a method of supplying the developer from a pressurized tank and adjusting the pressure to change the ejection pressure.

After the step of developing the film by using an organic solvent-containing developer, a step of stopping the development by replacing the solvent with another solvent may be practiced.

The pattern forming method preferably includes a step of rinsing the film with a rinsing solution after the step of developing the film by using an organic solvent-containing developer.

The rinsing solution used in the rinsing step after the step of developing the film by using an organic solvent-containing developer is not particularly limited as long as it does not dissolve the resist pattern, and a solution containing a general organic solvent may be used. As for the rinsing solution, a rinsing solution containing at least one kind of an organic solvent selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, ketone-based solvent, ester-based solvent, alcohol-based solvent, amide-based solvent and ether-based solvent, are the same as those described above for the organic solvent-containing developer.

After the step of developing the film by using an organic solvent-containing developer, more preferably, a step of rinsing the film by using a rinsing solution containing at least one kind of an organic solvent selected from the group consisting of a ketone-based solvent, an ester-based solvent, an alcohol-based solvent and an amide-based solvent is preformed; still more preferably, a step of rinsing the film by using a rinsing solution containing an alcohol-based solvent or an ester-based solvent is performed; yet still more preferably, a step of rinsing the film by using a rinsing solution containing a monohydric alcohol is performed; and most preferably, a step of rinsing the film by using a rinsing solution containing a monohydric alcohol having a carbon number of 5 or more is performed.

The monohydric alcohol used in the rinsing step includes a linear, branched or cyclic monohydric alcohol, and specific examples of the monohydric alcohol which can be used include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol and 4-octanol. As for the particularly preferred monohydric alcohol having a carbon number of 5 or more, 1-hexanol, 2-hexanol, 4-methyl-2-pentanol, 1-pentanol, 3-methyl-1-butanol and the like can be used.

A plurality of these components may be mixed, or the solvent may be used by mixing it with an organic solvent other than those described above.

The water content ratio in the rinsing solution is preferably 10 mass % or less, more preferably 5 mass % or less, still more preferably 3 mass % or less. By setting the water content ratio to 10 mass % or less, good development characteristics can be obtained.

The vapor pressure at 20° C. of the rinsing solution used after the step of developing the film by using an organic solvent-containing developer is preferably from 0.05 to 5 kPa, more preferably from 0.1 to 5 kPa, and most preferably from 0.12 to 3 kPa. By setting the vapor pressure of the rinsing solution to the range from 0.05 to 5 kPa, the temperature uniformity in the wafer plane is enhanced and moreover, swelling due to permeation of the rinsing solution is suppressed, as a result, the dimensional uniformity in the wafer plane is improved.

The rinsing solution may be also used after adding thereto a surfactant in an appropriate amount.

In the rinsing step, the wafer after development using an organic solvent-containing developer is rinsed using the above-described organic solvent-containing rinsing solution. The method for rinsing treatment is not particularly limited, but examples of the method which can be applied include a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method). Above all, it is preferred to perform the rinsing treatment by the spin coating method and after the rinsing, remove the rinsing solution from the substrate surface by spinning the substrate at a rotational speed of 2,000 to 4,000 rpm. It is also preferred to include a heating step (Post Bake) after the rinsing step. The developer and rinsing solution remaining between patterns and in the inside of the pattern are removed by the baking. The heating step after the rinsing step is performed at usually from 40 to 160° C., preferably from 70 to 95° C., for usually from 10 seconds to 3 minutes, preferably from 30 to 90 seconds.

The present invention also relates to a method for manufacturing an electronic device, having the pattern forming method of the present invention, and an electronic device manufactured by this manufacturing method.

The electronic device of the present invention is suitably mounted on electric electronic equipment (such as home electronic device, OA/media-related device, optical device and communication device).

### Examples

### Synthesis of Resin (P-1)

In a nitrogen stream, 28.3 g of cyclohexanone was put in a three-neck flask and heated at 80° C. Subsequently, Monomer 1 (14.8 g) and Monomer 2 (12.6 g) shown below were dissolved in cyclohexanone (58.8 g) to prepare a monomer solution. Furthermore, 0.55 g (2.0 mol % based on the total amount of monomers) of polymerization initiator V-601 (produced by Wako Pure Chemical Industries, Ltd.) was added and dissolved, and the resulting solution was added dropwise to the flask over 6 hours. After the completion of dropwise addition, the reaction was further allowed to proceed at 80° C. for 2 hours. The reaction solution was left standing to cool and then added dropwise to a mixed solvent of 690 g of heptane/76.9 g of ethyl acetate, and the powder precipitated was collected by filtration and dried, as a result, 22.3 g of Resin (P-1) was obtained. The mass average molecular weight of Resin (P-1) as determined by GPC (carrier: tetrahydrofuran (THF)) was 21,000 and the polydispersity (Mw/Mn) was 1.69. The compositional ratio (molar ratio) as determined from ¹³C-NMR was 50/50.

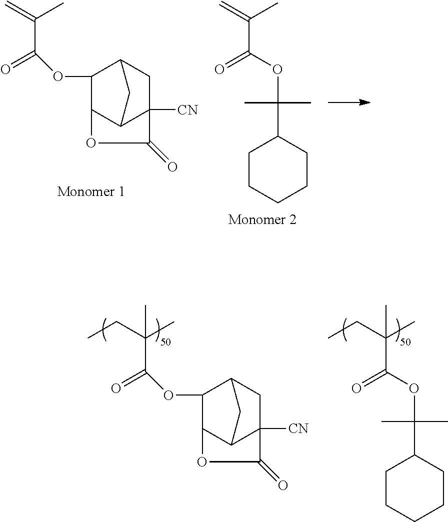

Resins (P-2) to (P-11) and (CX-1) to (CX-3) were synthesized in the same manner as Resin (P-1).

The structure, compositional ratio (molar ratio) of repeating units, mass average molecular weight and polydispersity of each of the resins synthesized are shown below.

| | | |
|---|---|---|
| (P-1) | 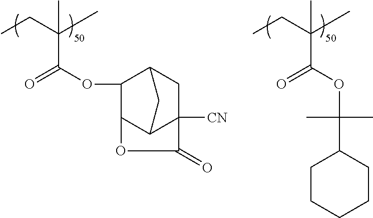 | Mw = 21000 Mw/Mn = 1.69 |
| (P-2) | 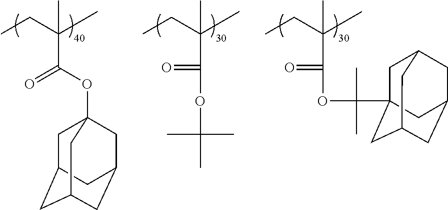 | Mw = 25700 Mw/Mn = 1.77 |
| (P-3) | 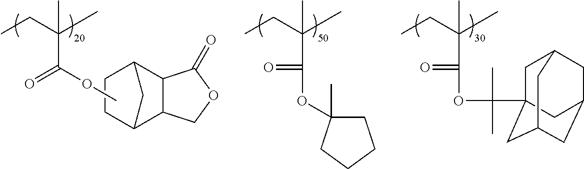 | Mw = 9900 Mw/Mn = 1.71 |
| (P-4) | 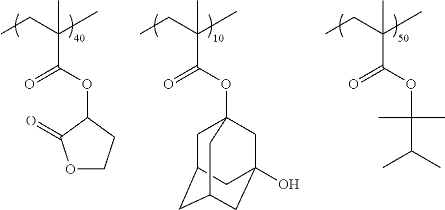 | Mw = 21200 Mw/Mn = 1.59 |
| (P-5) | 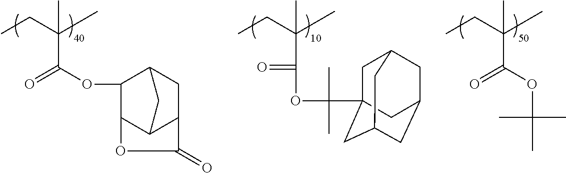 | Mw = 18900 Mw/Mn = 1.72 |
| (P-6) | 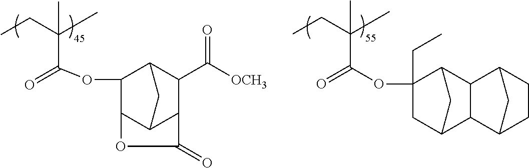 | Mw = 14500 Mw/Mn = 1.69 |
| (P-7) | 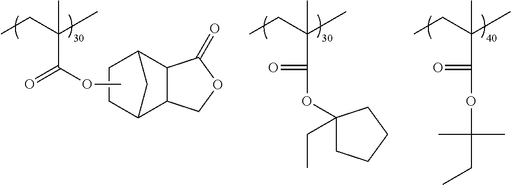 | Mw = 16200 Mw/Mn = 1.79 |
| (P-8) | 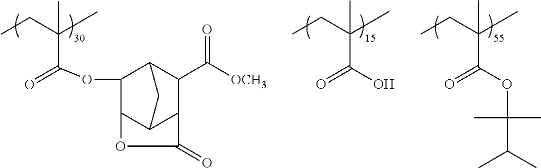 | Mw = 17300 Mw/Mn = 1.83 |
| (P-9) | 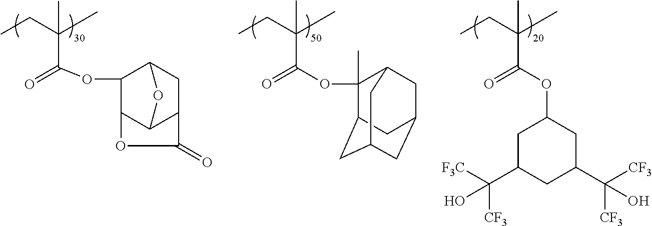 | Mw = 11200 Mw/Mn = 1.67 |
| (P-10) | 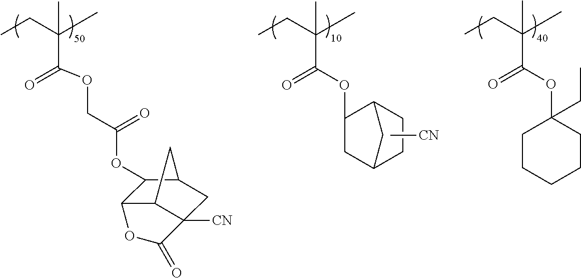 | Mw = 14300 Mw/Mn = 1.55 |
| (P-11) | 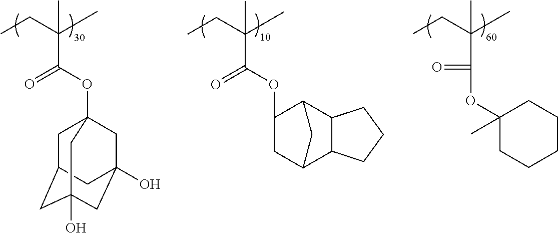 | Mw = 17400 Mw/Mn = 1.64 |
| (CX-1) | 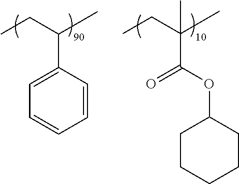 | Mw = 25100 Mw/Mn = 1.71 |
| (CX-2) | 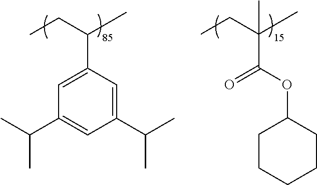 | Mw = 25900 Mw/Mn = 1.61 |
| (CX-3) | 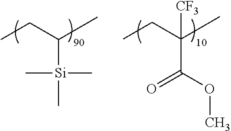 | Mw = 21500 Mw/Mn = 1.57 |

### <Acid Generator>

The following compounds were used as the acid generator.

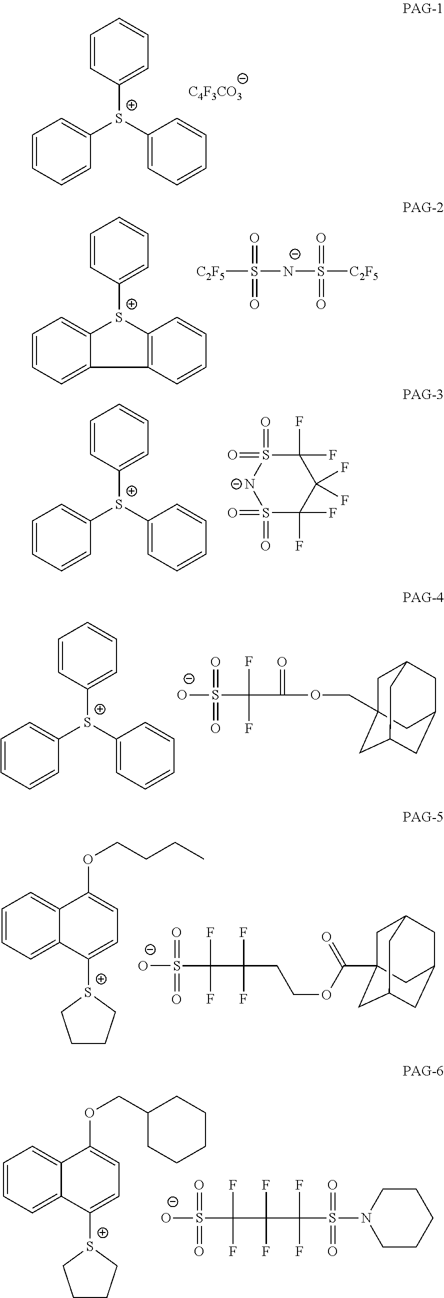

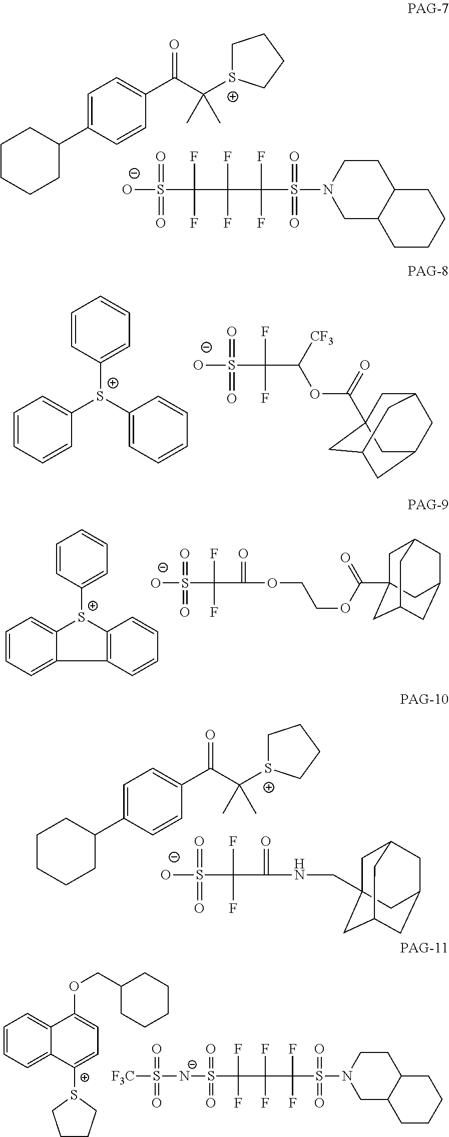

<Basic Compound (N) Whose Basicity Decreases Upon Irradiation with an Actinic Ray or Radiation, and Basic Compound (N′)>

The following compounds were used as a basic compound whose basicity decreases upon irradiation with an actinic ray or radiation, or a basic compound.

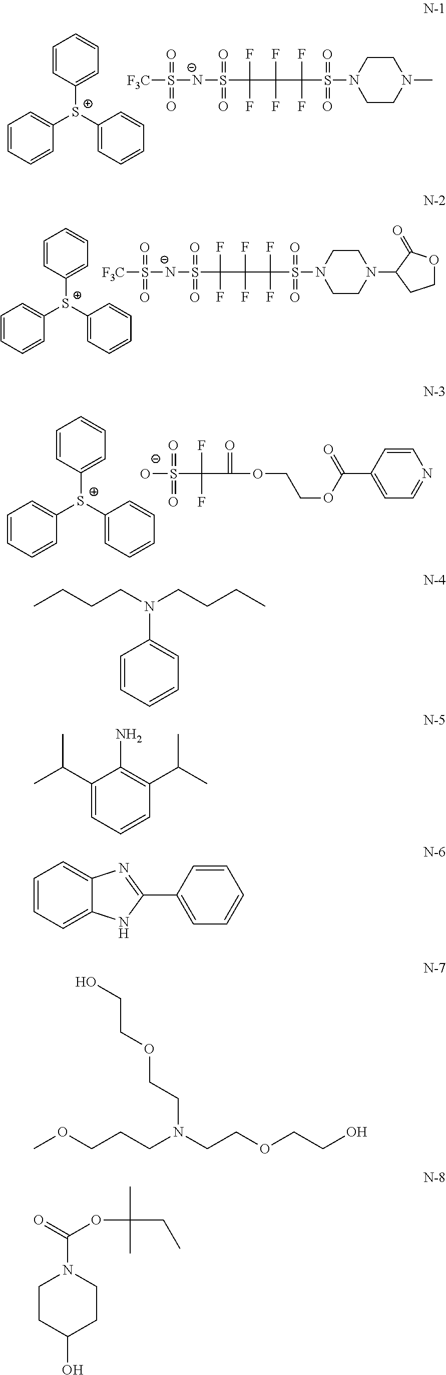

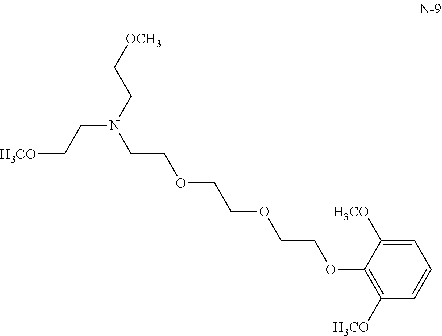 [SMILES: COCCN(CCOC)CCOCCOCCOc1c(OC)cccc1OC]

### <Hydrophobic Resin>

As the hydrophobic resin, a resin appropriately selected from Resins (C-1) to (C-30) was used.

### <Surfactant>

As the surfactant, the followings were used.

W-1: Megaface F176 (produced by DIC Corp.; fluorine-containing)
W-2: PolyFox PF-6320 (produced by OMNOVA Solutions Inc.; fluorine-containing)
W-3: Polysiloxane Polymer KP-341 (produced by Shin-Etsu Chemical Co., Ltd.; silicon-containing)
W-4: Troysol S-366 (produced by Troy Chemical)
W-5: KH-20 (produced by Asahi Glass Co., Ltd.)

### <Solvent>

As the solvent, the followings were used.

### (Group a)

SL-1: Propylene glycol monomethyl ether acetate (PGMEA)
SL-2: Propylene glycol monomethyl ether propionate

### SL-3: 2-Heptanone

### (Group b)

SL-4: Ethyl lactate
SL-5: Propylene glycol monomethyl ether (PGME)

### SL-6: Cyclohexanone

### (Group c)

### SL-7: γ-Butyrolactone

SL-8: Propylene carbonate

### <Developer>

As the developer, the followings were used

### SG-1: 2-Nonanone

SG-2: Diisobutyl ketone
SG-3: Cyclohexyl acetate
SG-4: Isobutyl isobutyrate
SG-5: Isopentyl acetate

### SG-6: Phenetole

SG-7: Dibutyl ether
SG-8: Butyl acetate

### <Rinsing Solution>

As the rinsing solution, the followings were used.

SR-1: 4-Methyl-2-pentanol

### SR-2: 1-Hexanol

### Examples 1 to 17 and Comparative Examples 1 to 3

### ArF Immersion Exposure

### (Preparation of Resist)

The components shown in Table 3 below were dissolved in the solvent shown in the same Table to give a total solid content of 3.8 mass %, and the obtained solution was filtered through a polyethylene filter having a pore size of 0.03 μm to prepare an actinic ray-sensitive or radiation-sensitive resin composition (resist composition). An organic antireflection film, ARC29SR (produced by Nissan Chemical Industries, Ltd.), was coated on a silicon wafer (12 inch, 300 mmφ) and baked at 205° C. for 60 seconds to form an antireflection film having a thickness of 95 nm, and the actinic ray-sensitive or radiation-sensitive resin composition was coated thereon and baked (PB: Prebake) at 100° C. over 60 seconds to form a resist film having a thickness of 100 nm.

The obtained wafer was patternwise exposed through a square-array halftone mask having a hole portion of 60 nm and a hole-to-hole pitch of 90 am (here, because of negative image formation, the portions corresponding to holes were light-shielded) by using an ArF excimer laser immersion scanner (XT1700i, manufactured by ASML NA: 1.20, C-Quad, outer sigma: 0.900, inner sigma: 0.812, XY deflection). As for the immersion liquid, ultrapure water was used. Thereafter, the resist film was heated at 105° C. for 60 seconds (PEB: Post Exposure Bake), developed by puddling the organic solvent-based developer shown in the Table below for 30 seconds, and then rinsed by puddling the rising solution shown in the Table below for 30 seconds while rotating the wafer at a rotational speed of 1,000 rpm. Subsequently, the wafer was rotated at a rotational speed of 4,000 rpm for 30 seconds, whereby a contact hole pattern having a hole diameter of 45 nm was obtained.

### [Exposure Latitude (EL, %)]

The hole size was observed by a critical dimension scanning electron microscope (SEM, S-938011, manufactured by Hitachi, Ltd.), and the optimum exposure dose when resolving a contact hole pattern with hole portions having an average size of 45 nm was taken as the sensitivity (Eₒₚₜ) (mJ/cm²). Based on the determined optimum exposure dose (Eₒₚₜ), the exposure dose when giving a target hole size value of 45 nm±10% (that is, 40.5 nm and 49.5 nm) was determined. Thereafter, the exposure latitude (EL, %) defined by the following formula was calculated. As the value of EL is larger, the performance change due to change in the exposure dose is smaller and this is better.

[EL (%)]=[(exposure dose when the hole portion becomes 40.5 nm)−(exposure dose when the hole portion becomes 49.5 nm)]/Eₒₚₜ×100

[Local Pattern Dimension Uniformity (Local CDU, nm)]

Within one shot exposed at the optimum exposure dose determined in the evaluation of exposure latitude, arbitrary 25 holes in each of 20 regions spaced apart by a gap of 1 μm (that is, 500 holes in total) were measured for the hole size. The standard deviation thereof was determined, and 3σ was computed therefrom. A smaller value indicates less dimensional variation and higher performance.

### [Scum]

The obtained wafer was exposed through a 6% halftone mask having a 1:1 line-and-space pattern with a line width of 45 nm by using an ArF excimer laser immersion scanner (XT1700i, manufactured by ASML, NA: 1.20). As for the immersion liquid, ultrapure water was used. Thereafter, the resist film was heated at 105° C. for 60 seconds, then developed by puddling the organic solvent-based developer shown in Table 3 below for 30 seconds, and rinsed with the rinsing solution shown in Table 3 below for 30 seconds while rotating the wafer at a rotational speed of 1,000 rpm.

The development residue (scum) in the thus-obtained 1:1 line-and-space resist pattern with a line width of 45 nm was observed using a scanning electron microscope (S-4800, manufactured by Hitachi, Ltd.), and the sample was rated AA when scum was not generated at all, rated C when scum was significantly generated, and rated B when intermediate therebetween.

### <Evaluation of WM (Watermark) Defect Performance>

In the observation of a 1:1 line-and-space pattern with a line width of 45 nm resolved at the optimum exposure dose above, random-mode measurement was performed using a defect inspection apparatus. 2360, manufactured by KLA-Tencor Corporation by setting the pixel size to 0.16 μm and the threshold value to 20, and after detecting development defects extracted from differences produced by superimposition of pixel units with a comparative image, the development defects were observed by SEM VISION G3 (manufactured by APPLIED MATERIALS, Inc.) to determine the number of WM defects on the wafer.

The marks AA, A, B and C were given when the number of WM defects observed on the wafer was 0, from 1 to 4, from 5 to 9, and 10 or more, respectively. A smaller value indicates a higher WM defect performance.

### <Evaluation of Bridge Margin>

An organic antireflection film, ARC29SR (produced by Nissan Chemical Industries, Ltd.), was coated on a silicon wafer and baked at 205° C. for 60 seconds to form an antireflection film having a thickness of 95 nm, and the resist composition was coated thereon and baked at 100° C. for 60 seconds to form a resist film having a thickness of 100 nm. The obtained wafer was patternwise exposed through an exposure mask (line/space=1/1) by using an ArF excimer laser immersion scanner (XT1700i, manufactured by ASML, NA: 1.20, C-Quad, outer sigma: 0.981, inner sigma: 0.895, XY deflection). As for the immersion liquid, ultrapure water was used. Thereafter, the resist film was heated at 100° C. for 60 seconds, developed by pudding a developer for 30 seconds, rinsed with a rinsing solution for 4 seconds in a puddleless manner and after rotating the wafer at a rotational speed of 4,000 rpm for 30 seconds, baked at 90° C. for 60 seconds to obtain a 1:1 line-and-space resist pattern with a pitch of 100 nm. The 1:1 line-and-space resist pattern with a pitch of 100 nm was observed using a critical dimension scanning electron microscope (SEM, S-938011, manufactured by Hitachi, Ltd.), and the minimum space dimension below which a bridge defect is generated in the 1:1 line-and-space resist pattern with a pitch of 100 nm at an optimum focus was determined by changing the exposure dose. A smaller value indicates less generation of bridge defects and a higher performance.

TABLE 3

| | | | Compound | | Compound | | Basic | | Hydrophobic | |
|---|---|---|---|---|---|---|---|---|---|---|
| Example | Resin | (g) | (B) | (g) | (N) | (g) | Compound | (g) | Resin (C) | (g) |
| Example 1 | P-1 | 10 | PAG-8 | 1.18 | N-1 | 0.54 | | | C-4 | 0.06 |
| Example 2 | P-2 | 10 | PAG-6 | 1.18 | N-1 | 0.54 | | | C-1 | 0.06 |
| Example 3 | P-3 | 10 | PAG-4 | 1.04 | | | N-5 | 0.14 | C-12 | 0.06 |
| Example 4 | P-4 | 10 | PAG-3 | 2.39 | N-1 | 0.64 | | | C-2 | 0.06 |
| Example 5 | P-5 | 10 | PAG-2 | 2.22 | N-1 | 0.64 | | | C-5 | 0.06 |
| Example 6 | P-6 | 10 | PAG-1 | 1.50 | | | N-9 | 0.12 | C-7 | 0.06 |
| Example 7 | P-7 | 10 | PAG-5 | 1.45 | | | N-8 | 0.12 | C-15/C-16 | 0.04/ |
| | | | | | | | | | | 0.02 |
| Example 8 | P-8 | 10 | PAG-11 | 1.33 | | | N-4/N-7 | 0.04/ | C-3 | 0.06 |
| | | | | | | | | 0.04 | | |
| Example 9 | P-9 | 10 | PAG-10 | 1.28 | N-2 | 0.64 | N-8 | 0.14 | C-20 | 0.06 |
| Example 10 | P-10 | 10 | PAG-7 | 1.32 | N-3 | 0.76 | | | C-8 | 0.06 |
| Example 11 | P-11 | 10 | PAG-9 | 1.14 | N-1 | 0.58 | | | C-13 | 0.06 |
| Example 12 | P-7 | 10 | PAG-6/ | 0.880/ | N-3 | 0.14 | | | C-14 | 0.06 |
| | | | PAG-7 | 0.750 | | | | | | |
| Example 13 | P-5 | 10 | PAG-2 | 2.22 | N-1/N-2 | 0.40/ | | | C-25 | 0.06 |
| | | | | | | 0.40 | | | | |
| Example 14 | P-4 | 10 | PAG-7 | 1.14 | | | N-6 | 0.08 | C-17/C-20 | 0.03/ |
| | | | | | | | | | | 0.03 |
| Example 15 | P-1/ | 5/5 | PAG-6 | 1.48 | N-2 | 0.44 | | | C-11 | 0.06 |
| | P-10 | | | | | | | | | |
| Example 16 | P-3 | 10 | PAG-1 | 1.45 | N-3 | 0.58 | | | C-29 | 0.06 |
| Example 17 | P-5 | 10 | PAG-2 | 1.33 | N-1 | 0.64 | | | C-30 | 0.06 |
| Comparative | P-1 | 10 | PAG-8 | 1.18 | N-1 | 0.54 | | | CX-1 | 0.06 |
| Example 1 | | | | | | | | | | |
| Comparative | P-1 | 10 | PAG-8 | 1.18 | N-1 | 0.54 | | | CX-2 | 0.06 |
| Example 2 | | | | | | | | | | |
| Comparative | P-1 | 10 | PAG-8 | 1.18 | N-1 | 0.54 | | | CX-3 | 0.06 |
| Example 3 | | | | | | | | | | |

| | | Mass | | | | Mass | Rinsing | Mass |
|---|---|---|---|---|---|---|---|---|
| Example | Solvent | Ratio | Surfactant | (g) | Developer | Ratio | Solution | Ratio |
| Example 1 | SL-1/SL-2 | 90/10 | W-1 | 0.003 | SG-4 | 100 | SR-2 | 100 |
| Example 2 | SL-5/SL-6 | 30/70 | none | none | SG-8 | 100 | SR-1 | 100 |
| Example 3 | SL-1/SL-8 | 70/30 | W-2 | 0.003 | SG-5 | 100 | SR-1 | 100 |
| Example 4 | SL-1/SL-5 | 60/40 | W-4 | 0.003 | SG-1 | 100 | SR-1 | 100 |
| Example 5 | SL-1/SL-4 | 60/40 | none | none | SG-6 | 100 | SR-1 | 100 |
| Example 6 | SL-1/SL-5 | 60/40 | W-5 | 0.003 | SG-2 | 100 | SR-1 | 100 |
| Example 7 | SL-5/SL-6 | 30/70 | W-4 | 0.003 | SG-8 | 100 | SR-1 | 100 |
| Example 8 | SL-1/SL-5 | 60/40 | none | none | SG-8 | 100 | SR-1/ | 90/10 |
| | | | | | | | SR-2 | |
| Example 9 | SL-1/SL-7 | 60/40 | none | none | SG-8 | 100 | SR-1 | 100 |
| Example 10 | SL-1/SL-3 | 80/20 | none | none | SG-7 | 100 | SR-1 | 100 |
| Example 11 | SL-1/SL-5 | 60/40 | W-3 | 0.003 | SG-3 | 100 | SR-1 | 100 |
| Example 12 | SL-1/SL-5 | 60/40 | none | none | SG-8 | 100 | SR-2 | 100 |
| Example 13 | SL-1/SL-2 | 90/10 | none | none | SG-6 | 100 | SR-1 | 100 |
| Example 14 | SL-1/SL-5 | 60/40 | W-3 | 0.003 | SG-1/ | 50/50 | SR-1 | 100 |
| | | | | | SG-7 | | | |
| Example 15 | SL-1/SL-5 | 60/40 | none | none | SG-4 | 100 | SR-1 | 100 |
| Example 16 | SL-1/SL-4 | 60/40 | none | none | SG-6 | 100 | SR-1 | 100 |
| Example 17 | SL-1/SL-7 | 60/40 | none | none | SG-8 | 100 | SR-1 | 100 |
| Comparative | SL-1/SL-2 | 90/10 | W-1 | 0.003 | SG-4 | 100 | SR-2 | 100 |
| Example 1 | | | | | | | | |
| Comparative | SL-1/SL-2 | 90/10 | W-1 | 0.003 | SG-4 | 100 | SR-2 | 100 |
| Example 2 | | | | | | | | |
| Comparative | SL-1/SL-2 | 90/10 | W-1 | 0.003 | SG-4 | 100 | SR-2 | 100 |
| Example 3 | | | | | | | | |

| | | Local | | | Bridge |
|---|---|---|---|---|---|
| | EL | CDU | | WM | Margin |
| Example | (%) | (nm) | Scum | Defect | (nm) |
| Example 1 | 18.0 | 4.8 | AA | AA | 31.7 |
| Example 2 | 18.1 | 5.2 | AA | AA | 31.3 |
| Example 3 | 18.2 | 4.8 | AA | AA | 30.1 |
| Example 4 | 17.5 | 5.3 | AA | AA | 28.8 |
| Example 5 | 17.3 | 5.0 | AA | AA | 29.7 |
| Example 6 | 17.5 | 4.9 | AA | AA | 42.6 |
| Example 7 | 18.1 | 5.2 | AA | AA | 29.3 |
| Example 8 | 18.5 | 5.3 | AA | AA | 28.5 |
| Example 9 | 18.3 | 4.7 | AA | AA | 31.4 |
| Example 10 | 17.7 | 4.8 | AA | AA | 29.1 |
| Example 11 | 17.9 | 5.0 | AA | AA | 46.5 |
| Example 12 | 18.1 | 4.8 | AA | AA | 28.5 |
| Example 13 | 17.8 | 4.4 | AA | AA | 32.1 |
| Example 14 | 18.2 | 4.6 | AA | AA | 28.2 |
| Example 15 | 17.9 | 5.0 | AA | AA | 30.6 |
| Example 16 | 17.5 | 5.3 | AA | AA | 38.5 |
| Example 17 | 17.3 | 5.2 | AA | AA | 33.4 |
| Comparative | 12.1 | 7.3 | B | C | 62.4 |
| Example 1 | | | | | |
| Comparative | 14.9 | 6.1 | B | B | 47.1 |
| Example 2 | | | | | |
| Comparative | 8.30 | 7.8 | C | A | 50.2 |
| Example 3 | | | | | |

The results of these evaluations are shown in Table 3 below.

As seen from the results in Table 3, by virtue of using the actinic ray-sensitive or radiation-sensitive resin compositions of Examples, in the formation of a fine pattern such as hole pattern having a hole diameter of 45 nm or less, a pattern excellent in the local pattern dimension uniformity (Local CDU) and exposure latitude (EL) and reduced in the generation of scum and residual water defect can be formed, as compared with Comparative Examples.

In particular, it is revealed that in Examples 1 to 5, 7 to 10 and 12 to 17 which are Example using a resin where the repeating unit (x) contains at least one repeating unit out of “(II′) a repeating unit where in formula (II), R₂ is a group having three or more CH₃ partial structures” and “(III′) a repeating unit where in formula (III), R₃ is a group having three or more CH₃ partial structures”, the bridge margin is excellent as compared with other Examples and Comparative Examples.

### INDUSTRIAL APPLICABILITY

According to the present invention, an actinic ray-sensitive or radiation-sensitive resin composition ensuring that in forming a fine pattern such as hole pattern having a hole diameter of 45 nm or less, a pattern excellent in the local pattern dimension uniformity (Local CDU) and exposure latitude (EL) and reduced in the generation of scum and residual water defect can be formed, a pattern forming method using the composition, a resist film, a manufacturing method of an electronic device, and an electronic device, can be provided.

This application is based on Japanese patent application No. 2012-019099 filed on Jan. 31, 2012, and Japanese patent application No. 2012-100181 filed on Apr. 25, 2012, the entire contents of which are hereby incorporated by reference, the same as if set forth at length.

1. An actinic ray-sensitive or radiation-sensitive resin composition, comprising:
(A) a resin containing a repeating unit represented by formula (I);
(B) a compound capable of generating an acid upon irradiation with an actinic ray or radiation; and
(C) a resin containing at least one repeating unit (x) out of a repeating unit represented by formula (II), and a repeating unit represented by formula (III) and containing substantially neither fluorine atom nor silicon atom,
wherein a content of the repeating unit (x) is 90% or more by mole based on all repeating units in the resin (C): 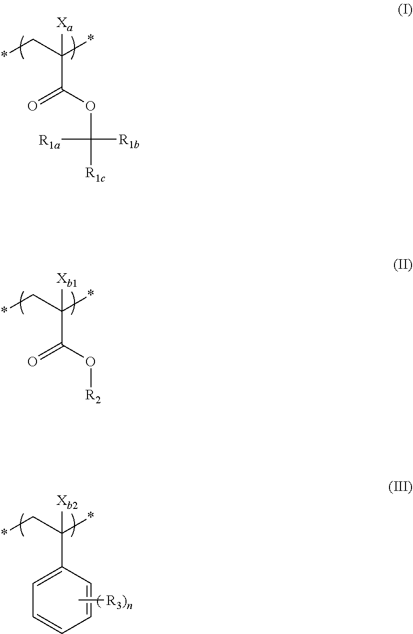
wherein Xa represents a hydrogen atom, an alkyl group, a cyano group or a halogen atom,
each of R₁ₐ, R_{1b} and R_{1c} independently represents an alkyl group or a cycloalkyl group,
two of R₁ₐ, R_{1b} and R_{1c} may combine to form a ring structure,
X_{b1} represents a hydrogen atom, an alkyl group, a cyano group or a halogen atom,
R₂ represents an organic group having at least one CH₃ partial structure and being stable to acid,
X_{b2} represents a hydrogen atom, an alkyl group, a cyano group or a halogen atom,
R₃ represents an organic group having at least one CH₃ partial structure and being stable to acid, and
n represents an integer of 1 to 5.

2. The actinic ray-sensitive or radiation-sensitive resin composition according to claim 1,
wherein the at least one repeating unit (x) contains at least one repeating unit out of a repeating unit (II′) where in the formula (II) R₂ is a group having three or more CH₃ partial structures and a repeating unit (III′) where in the formula (III) R₃ is a group having three or more CH₃ partial structures.

3. The actinic ray-sensitive or radiation-sensitive resin composition according to claim 1,
wherein a content of the repeating unit represented by formula (I) is 15% or more by mole based on all repeating units in the resin (A).

4. The actinic ray-sensitive or radiation-sensitive resin composition according to claim 1,
wherein the resin (C) contains a repeating unit represented by formula (II) and R₂ is an organic group having two or more CH₃ partial structures.

5. The actinic ray-sensitive or radiation-sensitive resin composition according to claim 1,
wherein the resin (C) is a resin stable to acid.

6. The actinic ray-sensitive or radiation-sensitive resin composition according to claim 1,
wherein a mass average molecular weight of the resin (C) is 15,000 or more.

7. The actinic ray-sensitive or radiation-sensitive resin composition according to claim 1,
wherein a content of the resin (C) is from 0.01 to 20% by mass based on a total solid content of the actinic ray-sensitive or radiation-sensitive resin composition.

8. The actinic ray-sensitive or radiation-sensitive resin composition according to claim 1,
wherein the compound (B) is a compound capable of generating an organic acid represented by the following formula (V) or (VI) upon irradiation with an actinic ray or radiation: 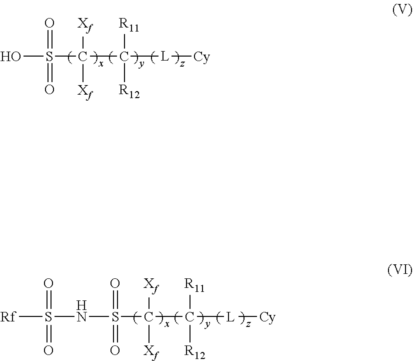
wherein each of Xf independently represents a fluorine atom or an alkyl group substituted with at least one fluorine atom,
each of R₁₁ and R₁₂ independently represents a hydrogen atom, a fluorine atom or an alkyl group,
each L independently represents a divalent linking group,
Cy represents a cyclic organic group,
Rf represents a fluorine atom-containing group,
x represents an integer of 1 to 20,
y represents an integer of 0 to 10, and
z represents an integer of 0 to 10.

9. The actinic ray-sensitive or radiation-sensitive resin composition according to claim 1, further comprising (D) a basic compound or ammonium salt compound of which basicity decreases upon irradiation with an actinic ray or radiation.

10. A resist film formed from the actinic ray-sensitive or radiation-sensitive resin composition according to claim 1.

11. A pattern forming method, comprising:
(i) forming a film by using the actinic ray-sensitive or radiation-sensitive resin composition according to claim 1,
(ii) exposing the film; and
(iii) performing development by using a developer containing an organic solvent to form a negative pattern.

12. The pattern forming method according to claim 11,
wherein the developer contains at least one kind of an organic solvent selected from the group consisting of a ketone-based solvent, an ester-based solvent, an alcohol-based solvent, an amide-based solvent and an ether-based solvent.

13. A method for manufacturing an electronic device, comprising the pattern forming method according to claim 11.

14. An electronic device manufactured by the manufacturing method of an electronic device according to claim 13.
